(19) United States
(12) Patent Application Publication
(10) Pub. No.: US 2015/0147688 A1
(43) Pub. Date: May 28, 2015

(54) PATTERN FORMING METHOD, ACTINIC RAY-SENSITIVE OR RADIATION-SENSITIVE RESIN COMPOSITION, RESIST FILM, MANUFACTURING METHOD OF ELECTRONIC DEVICE USING THE SAME, AND ELECTRONIC DEVICE

(71) Applicant: FUJIFILM Corporation, Tokyo (JP)

(72) Inventors: Natsumi YOKOKAWA, Haibara-gun (JP); Shuji HIRANO, Haibara-gun (JP); Wataru NIHASHI, Haibara-gun (JP); Hiroo TAKIZAWA, Haibara-gun (JP)

(73) Assignee: FUJIFILM Corporation, Tokyo (JP)

(21) Appl. No.: 14/603,811

(22) Filed: Jan. 23, 2015

Related U.S. Application Data
(63) Continuation of application No. PCT/JP2013/070831, filed on Jul. 25, 2013.
(60) Provisional application No. 61/708,819, filed on Oct. 2, 2012.

(30) Foreign Application Priority Data
Jul. 27, 2012 (JP) 2012-167817
Mar. 15, 2013 (JP) 2013-054398

(51) Int. Cl. G03F 7/038; G03F 7/30

(52) U.S. Cl. CPC G03F 7/0388; G03F 7/30; G03F 7/038
USPC 430/18; 430/325; 430/311; 528/354

(57) ABSTRACT

There is provided a pattern forming method comprising (1) a step of forming a film by using an actinic ray-sensitive or radiation-sensitive resin composition containing (P) a resin having a repeating unit represented by the specific formula, (2) a step of exposing the film by using an actinic ray or radiation, and (3) a step of developing the exposed film by using an organic solvent-containing developer to form a negative pattern, wherein the content of the repeating unit represented by the specific formula is 25 mol % or more based on all repeating units in the resin (P).

### CROSS REFERENCE TO RELATED APPLICATION

This is a continuation of International Application No. PCT/JP2013/070831 filed on Jul. 25, 2013, and claims priority from Japanese Patent Application No. 2012-167817 filed on Jul. 27, 2012, U.S. Provisional Application No. 61/708,819 filed on Oct. 2, 2012, and Japanese Patent Application No. 2013-054398 filed on Mar. 15, 2013 the entire disclosures of which are incorporated therein by reference.

### TECHNICAL FIELD

The present invention relates to a pattern forming method, an actinic ray-sensitive or radiation-sensitive resin composition, a resist film, a manufacturing method of an electronic device using the same, and an electronic device. More specifically, the present invention relates to a pattern forming method, an actinic ray-sensitive or radiation-sensitive resin composition, and a resist film, which are suitably used in the ultramicrolithography process applicable to, for example, a process for producing VLSI or a high-capacity microchip, a process for fabricating a nanoimprint mold, and a process for producing a high-density information recording medium, and in other photofabrication processes, and also relates to a manufacturing method of an electronic device using the same, and an electronic device.

### BACKGROUND ART

In the process for producing a semiconductor device such as IC and LSI, microfabrication by lithography using a photoresist composition has been conventionally performed. Recently, with the increase in integration of an integrated circuit, formation of an ultrafine pattern in the sub-micron or quarter-micron region is required. To cope with this requirement, the exposure wavelength also tends to become shorter, for example, from g line to i line or further to KrF excimer laser light. At present, other than the excimer laser light, development of lithography using an electron beam, an X-ray or EUV light is also proceeding.

Among others, electron beam lithography is positioned as a next-generation or next-next-generation pattern formation technology and a high-sensitivity and high-resolution positive resist is being demanded. In particular, for shortening the wafer processing time, it is a very important task to increase the sensitivity, but in the positive resist for electron beam, when high sensitivity is pursued, this causes a problem that the resolution is likely to lower.

In this way, high sensitivity is in a trade-off relationship with high resolution and further with good pattern profile, and it is very important how to satisfy all of these properties at the same time.

Also, in the lithography using an X-ray, EUV light or the like as well, it is an important task to satisfy all of high sensitivity, high resolution and good pattern profile at the same time.

In order to solve these problems, for example, in JP-A-2010-256419 (the term “JP-A” as used herein means an “unexamined published Japanese patent application”), JPA-2000-29215 and JP-A-8-101507, a positive resist composition using a resin having an acetal-type protective group is disclosed, and it is stated that according to such a composition, the resolution, sensitivity and the like are improved.

In the positive image forming method, an isolated line or dot pattern can be successfully formed with this composition, but in the case of forming an isolated space or fine hole pattern, the pattern profile is liable to deteriorate.

In addition, a pattern forming method using an organic solvent-containing developer (organic developer) is also being developed recently (for example, JP-A-2012-008500 and JP-A-2010-217884). This method is supposed to enable formation of a high-definition fine pattern.

### SUMMARY OF INVENTION

However, in forming a fine pattern with a line width or space width of 50 nm or less by using an organic solvent-containing developer, it is presently demanded to further improve the performance in terms of resolution, sensitivity and resolution at the formation of an isolated space pattern.

An object of the present invention is to provide a pattern forming method, an actinic ray-sensitive or radiation-sensitive resin composition, and a resist film, ensuring that in the formation of an ultrafine pattern (for example, the line width or space width is of the order of several tens of nm), a line pattern with small line width roughness (LWR) can be formed at high resolution and high sensitivity and an isolated pattern can be formed at high resolution, and also provide a manufacturing method of an electronic device using the same, and an electronic device.

That is, the present invention is as follows.

[1] A pattern forming method comprising:

(1) a step of forming a film by using an actinic ray-sensitive or radiation-sensitive resin composition containing (P) a resin having a repeating unit represented by the following formula (I),

(2) a step of exposing the film by using an actinic ray or radiation, and

(3) a step of developing the exposed film by using an organic solvent-containing developer to form a negative pattern,

wherein the content of the repeating unit represented by formula (I) is 25 mol % or more based on all repeating units in the resin (P):

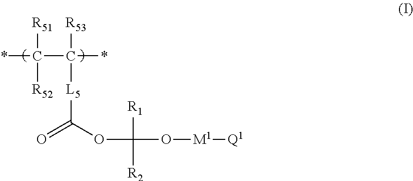

wherein

each of R₅₁, R₅₂ and R₅₃ independently represents a hydrogen atom, an alkyl group, a cycloalkyl group, a halogen atom, a cyano group or an alkoxycarbonyl group,

R₅₂ may combine with L₅ to form a ring, and in this case, R₅₂ represents an alkylene group;

L₅ represents a single bond or a divalent linking group, and in the case of forming a ring with R₅₂, L₅ represents a trivalent linking group;

R₁ represents a hydrogen atom or an alkyl group;

R₂ represents a hydrogen atom, an alkyl group, a cycloalkyl group, an aryl group, an aralkyl group, an alkoxy group, an acyl group or a heterocyclic group;

M′ represents a single bond or a divalent linking group;

Q¹ represents an alkyl group, a cycloalkyl group, an aryl group or a heterocyclic group, and Q′, M¹ and R₂ may combine with each other to form a ring; and

when M¹ is a divalent linking group, Q¹ may combine with M¹ through a single bond or another linking group to form a ring.

[2] The pattern forming method as described in [1],

wherein the content of the repeating unit represented by formula (I) is from 40 to 70 mol % based on all repeating units in the resin (P).

[3] The pattern forming method as described in [1] or [2],

wherein the resin (P) is a resin further having a repeating unit represented by the following formula (5) or (6):

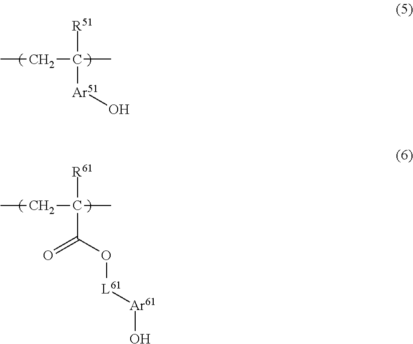

wherein each of R⁵¹ and R⁶¹ independently represents a hydrogen atom or a methyl group,

each of Ar⁵¹ and Ar⁶¹ independently represents an arylene group, and

R⁶¹ represents a single bond or an alkylene group.

[4] The pattern forming method as described in any one of [1] to [3],

wherein in formula (I), R₁ is a hydrogen atom.

[5] The pattern forming method as described in any one of [1] to [4],

wherein in formula (I), R₂ represents a group represented by —(CH₂)ₙ₁—C(R²¹)(R²²)(R²³),

each of R²¹ to R²³ independently represents a hydrogen atom, an alkyl group, a cycloalkyl group, an aryl group, an aralkyl group or a heterocyclic group,

each of at least two members of R²¹ to R²³ independently represents an alkyl group, a cycloalkyl group, an aryl group, an aralkyl group or a heterocyclic group,

at least two members of R²¹ to R²³ may combine with each other to form a ring, and

n1 represents an integer of 0 to 6.

[6] The pattern forming method as described in [5], wherein n1 is 0 or 1.
[7] The pattern forming method as described in [5],

wherein n1 is 1.

[8] The pattern forming method as described in [5],

wherein n1 is 0.

[9] The pattern forming method as described in any one of [5] to [8],

wherein each of R²¹ to R²³ is independently an alkyl group.

[10] The pattern forming method as described in any one of [1] to [9],

wherein in formula (I), L₅ is a single bond, a group represented by —COO-L₁- or a group represented by -L₂-O—CH₂—,

L₁ represents an alkylene group which may contain a heteroatom, and L₂ represents an arylene group.

[11] The pattern forming method as described in any one of [1] to [10],

wherein in formula (I), L₅ is a single bond.

[12] The pattern forming method as described in any one of [1] to [11],

wherein the resin (P) is a resin further having a repeating unit represented by the following formula (4):

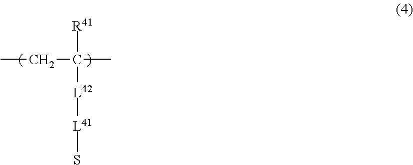

wherein R⁴¹ represents a hydrogen atom or a methyl group,

L⁴¹ represents a single bond or a divalent linking group,

L⁴² represents a divalent linking group, and

S represents a structural moiety capable of decomposing upon irradiation with an actinic ray or radiation to generate an acid in the side chain.

[13] An actinic ray-sensitive or radiation-sensitive resin composition used in the pattern forming method described in any one of [1] to [12].
[14] A resist film formed using the actinic ray-sensitive or radiation-sensitive resin composition described in [13],
[15] A method for manufacturing an electronic device, comprising the pattern forming method described in any one of [1] to [12].
[16] An electronic device manufactured by the manufacturing method of an electronic device described in [15].

According to the present invention, a pattern forming method, an actinic ray-sensitive or radiation-sensitive resin composition, and a resist film, ensuring that in the formation of an ultrafine pattern (for example, the line width or space width is of the order of several tens of nm), a line pattern with small line width roughness (LWR) can be formed at high resolution and high sensitivity and an isolated pattern can be formed at high resolution, as well as a manufacturing method of an electronic device using the same, and an electronic device, can be provided.

### DESCRIPTION OF EMBODIMENTS

The mode for carrying out the present invention is described below.

In the description of the present invention, when a group (atomic group) is denoted without specifying whether substituted or unsubstituted, the group encompasses both a group having no substituent and a group having a substituent. For example, “an alkyl group” without explicit depiction of whether substituted or unsubstituted encompasses not only an alkyl group having no substituent (unsubstituted alkyl group) but also an alkyl group having a substituent (substituted alkyl group).

The term “actinic ray” or “radiation” as used in the description of the present invention means, for example, a bright line spectrum of mercury lamp, a far ultraviolet ray typified by excimer laser, an extreme-ultraviolet (EUV) ray, an X-ray, or an electron beam (EB). Also, in the present invention, the “light” means an actinic ray or radiation.

In addition, unless otherwise indicated, the “exposure” as used in the present invention encompasses not only exposure to a mercury lamp, a far ultraviolet ray typified by excimer laser, an X-ray, EUV light or the like but also lithography with a particle beam such as electron beam and ion beam.

### [Pattern Forming Method]

The pattern forming method of the present invention is described below.

The pattern forming method of the present invention is a pattern forming method comprising (1) a step of forming a film by using an actinic ray-sensitive or radiation-sensitive resin composition containing (P) a resin having a repeating unit represented by following formula (I), (2) a step of exposing the film by using an actinic ray or radiation, and (3) a step of developing the exposed film by using an organic solvent-containing developer to form a negative pattern; wherein the content of the repeating unit represented by formula (I) is 25 mol % or more based on all repeating units in the resin (P):

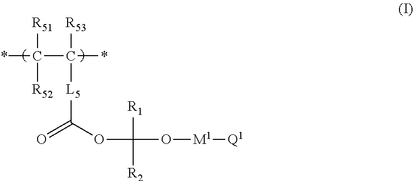

wherein each of R₅₁, R₅₂ and R₅₃ independently represents a hydrogen atom, an alkyl group, a cycloalkyl group, a halogen atom, a cyano group or an alkoxycarbonyl group, R₅₂ may combine with L₅ to form a ring, and in this case, R₅₂ represents an alkylene group;

L₅ represents a single bond or a divalent linking group, and in the case of forming a ring with R₅₂, L₅ represents a trivalent linking group;

R₁ represents a hydrogen atom or an alkyl group;

R₂ represents a hydrogen atom, an alkyl group, a cycloalkyl group, an aryl group, an aralkyl group, an alkoxy group, an acyl group or a heterocyclic group;

M¹ represents a single bond or a divalent linking group, and Q¹, M¹ and R₂ may combine with each other to form a ring;

Q¹ represents an alkyl group, a cycloalkyl group, an aryl group or a heterocyclic group; and

when M¹ is a divalent linking group, Q¹ may combine with M¹ through a single bond or another linking group to form a ring.

According to the pattern forming method of the present invention, in the formation of an ultrafine pattern (for example, the line width or space width is of the order of several tens of nm), a line pattern with small line width roughness (LWR) can be formed at high resolution and high sensitivity and an isolated pattern can be formed at high resolution. The reason therefor is not clearly known but is presumed as follows.

First, in the exposed area of a resist film obtained from the actinic ray-sensitive or radiation-sensitive resin composition of the present invention, an acid generated from an acid generator and a repeating unit represented by formula (I) in the resin (P) are reacted and the repeating unit generates a carboxyl group, whereby the polarity of the resin (P) is increased and the solubility for an organic solvent-containing developer is decreased.

Subsequently, the resist film is developed by using an organic solvent-containing developer, as a result, the unexposed area is removed and a pattern is formed.

Here, in the repeating unit represented by formula (I) contained in not less than a given amount (that is, 25 mol % or more) in the resin (P), the structure where a hydrogen atom in a carboxyl group is protected by a group represented by —C(R₁)(R₂)—O-M¹-Q¹ has a very high reactivity of acid-induced decomposition as compared with a structure where a hydrogen atom in a carboxyl group is protected by a tertiary alkyl group. This is considered to enable achieving enhancement of sensitivity and resolution and reduction of LWR in the formation of an ultrafine pattern (for example, the line width or space width is 50 nm or less) (typically, a 1:1 line-and-space pattern or an isolated space pattern).

On the other hand, it is very difficult to form particularly an ultrafine (for example, the space width is 50 nm or less) isolated space pattern by a positive image forming method using an alkali developer. This is because in the case of forming an isolated space pattern by a positive image forming method, the exposed area works out to a region in which a space part is formed, but an ultrafine region is optically very difficult to be resolved by exposure.

### (1) Film Formation

The resist film of the present invention is a film formed of the above-described actinic ray-sensitive or radiation-sensitive resin composition.

More specifically, respective components described later of the actinic ray-sensitive or radiation-sensitive resin composition are dissolved in a solvent, and the solution is filtered through a filter, if desired, and then coated on a support (substrate), whereby the resist film can be formed. The filter is preferably a polytetrafluoroethylene-, polyethylene- or nylon-made filter having a pore size of 0.1 μm or less, more preferably 0.05 μm or less, still more preferably 0.03 μm or less.

The composition is coated on such a substrate as used in the production of an integrated circuit device (for example, a silicon- or silicon dioxide-coated substrate) by an appropriate coating method such as spin coater and then dried to form a photosensitive film. In the drying stage, heating (prebaking) is preferably performed.

The film thickness is not particularly limited but is preferably adjusted to a range of 10 to 500 nm, more preferably from 30 to 120 nm, still more preferably from 30 to 80 nm. In the case of coating the actinic ray-sensitive or radiation-sensitive resin composition by a spinner, the rotation speed of the spinner is usually from 500 to 3,000 rpm, preferably from 800 to 2,000 rpm, more preferably from 1,000 to 1,500 rpm.

The heating (prebaking) is preferably performed at a temperature of 60 to 200° C., more preferably at 80 to 150° C., still more preferably at 90 to 140° C.

The heating (prebaking) time is not particularly limited but is preferably from 30 to 300 seconds, more preferably from 30 to 180 seconds, still more preferably from 30 to 90 seconds.

The heating may be performed by means of a device usually attached to an exposure/developing machine or may be also performed using a hot plate or the like.

If desired, a commercially available inorganic or organic antireflection film may be used. Also, an antireflection film may be used by coating it as an underlying layer of the actinic ray-sensitive or radiation-sensitive resin composition. The antireflection film which can be used may be either an inorganic film type such as titanium, titanium dioxide, titanium nitride, chromium oxide, carbon and amorphous silicon, or an organic film type composed of a light absorber and a polymer material. Furthermore, a commercially available organic antireflection film such as DUV30 Series and DUV-40 Series produced by Brewer Science, Inc., or AR-2, AR-3 and AR-5 produced by Shipley Co., Ltd., can be used as the organic antireflection film

### (2) Exposure

The exposure is performed using an actinic ray or radiation. The actinic ray or radiation includes, for example, infrared light, visible light, ultraviolet light, far ultraviolet light, X-ray, and electron beam. An actinic ray or radiation having, for example, a wavelength of 250 nm or less, particularly 220 nm or less, is preferred. Examples of such an actinic ray or radiation include KrF excimer laser (248 nm), ArF excimer laser (193 nm), F₂ excimer laser (157 nm), X-ray, and electron beam. The actinic ray or radiation is preferably, for example, KrF excimer laser, ArF excimer laser (193 nm), electron beam, X-ray or EUV light, more preferably ArF excimer laser (193 nm), electron beam, X-ray or EUV light.

### (3) Baking

After the exposure, baking (heating) is preferably performed before performing development.

The heating is preferably performed at a temperature of 60 to 150° C., more preferably at 80 to 150° C., still more preferably at 90 to 140° C.

The heating time is not particularly limited but is preferably from 30 to 300 seconds, more preferably from 30 to 180 seconds, still more preferably from 30 to 90 seconds.

The heating may be performed by means of a device usually attached to an exposure/developing machine or may be also performed using a hot plate or the like.

The reaction of the exposed area is accelerated by the baking and in turn, the sensitivity or pattern profile is improved. It is also preferred to contain a heating step (post-baking) after the rinsing step. The heating temperature and the heating time are as described above. By the baking, the developer and rinsing solution remaining between patterns and in the inside of the pattern are removed.

### (4) Development

In the present invention, development is performed using a developer containing an organic solvent.

Developer:

The vapor pressure of the developer (in the case of a mixed solvent, the vapor pressure as a whole) is, at 20° C., preferably 5 kPa or less, more preferably 3 kPa or less, still more preferably 2 kPa or less. By setting the vapor pressure of the organic solvent to 5 kPa or less, evaporation of the developer on a substrate or in a development cup is suppressed and the temperature uniformity in the wafer plane is enhanced, as a result, the dimensional uniformity in the wafer plane is improved.

As the organic solvent used for the developer, various organic solvents may be widely used but, for example, a solvent such as ester-based solvent, ketone-based solvent, alcohol-based solvent, amide-based solvent, ether-based solvent and hydrocarbon-based solvent may be used.

In the present invention, the ester-based solvent is a solvent having an ester group in the molecule; the ketone-based solvent is a solvent having a ketone group in the molecule; the alcohol-based solvent is a solvent having an alcoholic hydroxyl group in the molecule; the amide-based solvent is a solvent having an amide group in the molecule; and the ether-based solvent is a solvent having an ether bond in the molecule. Some of these solvents have a plurality of kinds of the above-described functional groups per molecule, and in such a case, the solvent comes under all of solvent species containing the functional group that is contained in the solvent. For example, diethylene glycol monomethyl ether comes under both of the alcohol-based solvent and the ether-based solvent in the categories above. Also, the hydrocarbon-based solvent means a hydrocarbon solvent not having a substituent.

Above all, a developer containing at least one kind of a solvent selected from a ketone-based solvent, an ester-based solvent, an alcohol-based solvent and an ether-based solvent is preferred.

Examples of the ester-based solvent include methyl acetate, ethyl acetate, butyl acetate, pentyl acetate, isopropyl acetate, amyl acetate, isoamyl acetate, ethyl methoxyacetate, ethyl ethoxyacetate, propylene glycol monomethyl ether acetate (PGMEA; another name: 1-methoxy-2-acetoxypropane), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylene carbonate, and γ-butyrolactone.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, n-decanol and 3-methoxy-1-butanol; a glycol-based solvent such as ethylene glycol, diethylene glycol and triethylene glycol; and a hydroxyl group-containing glycol ether-based solvent such as ethylene glycol monomethyl ether, propylene glycol monomethyl ether (PGME; another name: 1-methoxy-2-propanol), diethylene glycol monomethyl ether, triethylene glycol monoethyl ether, methoxymethyl butanol, ethylene glycol monoethyl ether, ethylene glycol monopropyl ether, ethylene glycol monobutyl ether, propylene glycol monoethyl ether, propylene glycol monopropyl ether, propylene glycol monobutyl ether and propylene glycol monophenyl ether. Among these, a glycol ether-based solvent is preferably used.

Examples of the ether-based solvent include, in addition to the hydroxyl group-containing glycol ether-based solvents above, a hydroxyl group-free glycol ether-based solvent such as propylene glycol dimethyl ether, propylene glycol diethyl ether, diethylene glycol dimethyl ether and diethylene glycol diethyl ether; an aromatic ether solvent such as anisole and phenetole; dioxane; tetrahydrofuran; tetrahydropyrane; perfluoro-2-butyltetrahydrofuran; perfluorotetrahydrofuran; and 1,4-dioxane. A glycol ether-based solvent or an aromatic ether solvent such as anisole is preferably used.

Examples of the amide-based solvent which can be used include N-methyl-2-pyrrolidone, N,N-dimethylacetamide, N,N-dimethylformamide, hexamethylphosphoric triamide and 1,3-dimethyl-2-imidazolidinone.

Examples of the hydrocarbon-based solvent include an aliphatic hydrocarbon-based solvent such as pentane, hexane, octane, decane, 2,2,4-trimethylpentane, 2,2,3-trimethylhexane, perfluorohexane and perfluoroheptane, and an aromatic hydrocarbon-based solvent such as toluene, xylene, ethylbenzene, propylbenzene, 1-methylpropylbenzene, 2-methylpropylbenzene, dimethylbenzene, diethylbenzene, ethylmethylbenzene, trimethylbenzene, ethyldimethylbenzene and dipropylbenzene. Among these, an aromatic hydrocarbon-based solvent is preferred.

A plurality of these solvents may be mixed, or the solvent may be mixed with a solvent other than those described above or with water and used. However, in order to sufficiently bring out the effects of the present invention, the percentage of water content in the entire developer is preferably less than 10 mass %, and it is more preferred to contain substantially no water. (In this specification, mass ratio is equal to weight ratio.)

The concentration of the organic solvent (in the case of mixing a plurality of kinds of organic solvents, the total concentration) in the developer is preferably 50 mass % or more, more preferably 70 mass % or more, still more preferably 90 mass % or more. Above all, the developer is preferably composed of substantially only an organic solvent. The expression “composed of substantially only an organic solvent” encompasses a case containing a slight amount of a surfactant, an antioxidant, a stabilizer, a defoaming agent or the like.

Among the solvents above, it is more preferred to contain one or more selected from the group consisting of butyl acetate, pentyl acetate, isopentyl acetate, propylene glycol monomethyl ether acetate and anisole.

The organic solvent used as the developer may be suitably an ester-based solvent.

The ester-based solvent used here is preferably a solvent represented by formula (S1) described below or a solvent represented by formula (S2) described below, more preferably a solvent represented by formula (S1), still more preferably an alkyl acetate, and most preferably butyl acetate, pentyl acetate or isopentyl acetate.

R—C(═O)—O—R′ Formula (S1)

In formula (S1), each of R and R′ independently represents a hydrogen atom, an alkyl group, a cycloalkyl group, an alkoxyl group, an alkoxycarbonyl group, a carboxyl group, a hydroxyl group, a cyano group or a halogen atom. R and R′ may combine with each other to form a ring.

The carbon number of the alkyl group, alkoxy group and alkoxycarbonyl group of R and R′ is preferably from 1 to 15, and the carbon number of the cycloalkyl group is preferably from 3 to 15.

Each of R and R′ is preferably a hydrogen atom or an alkyl group, and the alkyl group, cycloalkyl group, alkoxyl group and alkoxycarbonyl group of R and R′ and the ring formed by combining R and R′ with each other may be substituted with a hydroxyl group, a carbonyl group-containing group (such as acyl group, aldehyde group and alkoxycarbonyl group), a cyano group or the like.

Examples of the solvent represented by formula (S1) include methyl acetate, butyl acetate, ethyl acetate, isopropyl acetate, amyl acetate, isoamyl acetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, and ethyl 2-hydroxypropionate.

Among these, a solvent where R and R′ are an unsubstituted alkyl group is preferred.

The solvent represented by formula (S1) is preferably an alkyl acetate, more preferably butyl acetate, pentyl acetate or isopentyl acetate.

The solvent represented by formula (S1) may be used in combination with one or more other organic solvents. In this case, the combined solvent is not particularly limited as long as it can be mixed with the solvent represented by formula (S1) without causing separation, and the solvents represented by formula (S1) may be used in combination or the solvent represented by formula (S1) may be used by mixing it with a solvent selected from other ester-based, ketone-based, alcohol-based, amide-based, ether-based and hydrocarbon-based solvents. As for the combined solvent, one or more kinds of solvents may be used, but from the standpoint of obtaining a stable performance, it is preferred to use one kind of a solvent. In the case where one kind of a combined solvent is mixed and used, the mixing ratio between the solvent represented by formula (S1) and the combined solvent is, in mass ratio, usually from 20:80 to 99:1, preferably from 50:50 to 97:3, more preferably from 60:40 to 95:5, and most preferably from 60:40 to 90:10.

R″—C(═O)—O—R′″—O—R″″ Formula (S2)

In formula (S2), each of R″ and R″″ independently represents a hydrogen atom, an alkyl group, a cycloalkyl group, an alkoxyl group, an alkoxycarbonyl group, a carboxyl group, a hydroxyl group, a cyano group or a halogen atom, and R″ and R″″ may combine with each other to form a ring.

Each of R″ and R″″ is preferably a hydrogen atom or an alkyl group. The carbon number of the alkyl group, alkoxyl group and alkoxycarbonyl group of R″ and R″″ is preferably from 1 to 15, and the carbon number of the cycloalkyl group is preferably from 3 to 15.

R′″ represents an alkylene group or a cycloalkylene group. R′″ is preferably an alkylene group. The carbon number of the alkylene group of R′″ is preferably from 1 to 10, and the carbon number of the cycloalkylene group of R′″ is preferably from 3 to 10.

The alkyl group, cycloalkyl group, alkoxyl group and alkoxycarbonyl group of R″ and R″″, the alkylene group and cycloalkylene group of R′″, and the ring formed by combining R″ and R″″ with each other may be substituted with a hydroxyl group, a carbonyl group-containing group (such as acyl group, aldehyde group and alkoxycarbonyl group), a cyano group or the like.

In formula (S2), the alkylene group of R′″ may have an ether bond in the alkylene chain.

Examples of the solvent represented by formula (S2) include propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, propylene glycol monoethyl ether acetate, propylene glycol monopropyl ether acetate, methyl-3-methoxypropionate, ethyl-3-methoxypropionate, ethyl-3-ethoxypropionate, propyl-3-methoxypropionate, ethyl methoxyacetate, ethyl ethoxyacetate, 2-methoxybutyl acetate, 3-methoxybutyl acetate, 4-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, and 4-methyl-4-methoxypentyl acetate, with propylene glycol monomethyl ether acetate being preferred.

Among others, a solvent where R″ and R″″ are an unsubstituted alkyl group and R′″ is an unsubstituted alkylene group is preferred, a solvent where R″ and R″″ are either a methyl group or an ethyl group is more preferred, and a solvent where R″ and R″″ are a methyl group is still more preferred.

The solvent represented by formula (S2) may be used in combination with one or more other organic solvents. In this case, the combined solvent is not particularly limited as long as it can be mixed with the solvent represented by formula (S2) without causing separation, and the solvents represented by formula (S2) may be used in combination or the solvent represented by formula (S2) may be used by mixing it with a solvent selected from other ester-based, ketone-based, alcohol-based, amide-based, ether-based and hydrocarbon-based solvents. As for the combined solvent, one or more kinds of solvents may be used, but from the standpoint of obtaining a stable performance, it is preferred to use one kind of a solvent. In the case where one kind of a combined solvent is mixed and used, the mixing ratio between the solvent represented by formula (S2) and the combined solvent is, in mass ratio, usually from 20:80 to 99:1, preferably from 50:50 to 97:3, more preferably from 60:40 to 95:5, and most preferably from 60:40 to 90:10.

The organic solvent used as the developer may be also suitably an ether-based solvent.

The ether-based solvent which can be used includes the ether-based solvents described above. Among these, an ether-based solvent containing one or more aromatic rings is preferred, a solvent represented by the following formula (S3) is more preferred, and anisole is most preferred.

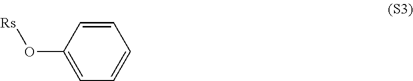

In formula (S3), Rs represents an alkyl group. The alkyl group is preferably an alkyl group having a carbon number of 1 to 4, more preferably a methyl group or an ethyl group, and most preferably a methyl group.

In the present invention, the percentage of water content in the developer is usually 10 mass % or less, preferably 5 mass % or less, more preferably 1 mass % or less, and it is most preferred to contain substantially no water.

Surfactant:

Into the developer containing an organic solvent, an appropriate amount of a surfactant can be incorporated, if desired.

As the surfactant, the same as the later-described surfactant used in the actinic ray-sensitive or radiation-sensitive resin composition may be used.

The amount of the surfactant used is usually from 0.001 to 5 mass %, preferably from 0.005 to 2 mass %, more preferably from 0.01 to 0.5 mass %, based on the total amount of the developer.

Basic Compound

The developer for use in the present invention may contain a basic compound. Specific examples and preferred examples of the basic compound which can be contained in the developer for use in the present invention are the same as those of the later-described basic compound which can be contained in the actinic ray-sensitive or radiation-sensitive resin composition.

In the pattern forming method of the present invention, a step of performing development by using an aqueous alkali solution (alkali development step) may be used in combination, in addition to the step of performing development by using an organic solvent-containing developer (organic solvent development step). Thanks to this combination, a finer pattern can be formed.

In the present invention, the portion of low exposure intensity is removed in the organic solvent development step, and by further performing the alkali development step, the portion of high exposure intensity is also removed. By virtue of the multiple development process of performing development a plurality of times in this way, a pattern can be formed by keeping only the region of intermediate exposure intensity from being dissolved, so that a finer pattern than usual can be formed (the same mechanism as in [0077] of JP-A-2008-292975).

In the pattern forming method of the present invention, the order of the alkali development step and the organic development step is not particularly limited, but the alkali development is preferably performed before the organic solvent development step.

Developing Method:

As the developing method, for example, a method of dipping the substrate in a bath filled with the developer for a fixed time (dipping method), a method of raising the developer on the substrate surface by the effect of a surface tension and keeping it still for a fixed time, thereby performing the development (puddle method), a method of spraying the developer on the substrate surface (spraying method), and a method of continuously ejecting the developer on the substrate spinning at a constant speed while scanning the developer ejecting nozzle at a constant rate (dynamic dispense method) may be applied.

Also, after the step of performing development, a step of stopping the development while replacing the developer with another solvent may be practiced.

The development time is not particularly limited as long as it is long enough to sufficiently dissolve the resin of the unexposed area, and the development time is usually from 10 to 300 seconds, preferably from 20 to 120 seconds.

The temperature of the developer is preferably from 0 to 50° C., more preferably from 15 to 35° C.

### (5) Rinsing

The pattern forming method of the present invention may contain (5) a step of rinsing the film by using a rinsing solution containing an organic solvent, after the development step (4). However, it is preferable not to contain a rinsing step from the standpoint of throughput, used amount of the rinsing solution and the like.

Rinsing Solution:

The vapor pressure of the rinsing solution (in the case of a mixed solvent, the vapor pressure as a whole) used after development is, at 20° C., preferably from 0.05 to 5 kPa, more preferably from 0.1 to 5 kPa, and most preferably from 0.12 to 3 kPa. By setting the vapor pressure of the rinsing solution to from 0.05 to 5 kPa, the temperature uniformity in the wafer plane is enhanced and swelling ascribable to permeation of the rinsing solution is suppressed, as a result, the dimensional uniformity in the wafer plane is improved.

As the rinsing solution, various organic solvents may be used, but it is preferred to use a rinsing solution containing at least one kind of an organic solvent selected from a hydrocarbon-based solvent, a ketone-based solvent, an ester-based solvent, an alcohol-based solvent, an amide-based solvent and an ether-based solvent, or water.

More preferably, a step of washing the film by using a rinsing solution containing at least one kind of an organic solvent selected from a ketone-based solvent, an ester-based solvent, an alcohol-based solvent, an amide-based solvent and a hydrocarbon-based solvent is preformed after development. Still more preferably, a step of washing the film by using a rinsing solution containing an alcohol-based solvent or a hydrocarbon-based solvent is preformed after development.

Among others, a rinsing solution containing at least one or more members selected from the group consisting of a monohydric alcohol-based solvent and a hydrocarbon-based solvent is preferably used.

The monohydric alcohol used in the rinsing step after development includes a linear, branched or cyclic monohydric alcohol, and specific examples of the monohydric alcohol which can be used include 1-butanol, 2-butanol, 3-methyl-1-butanol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 3-methyl-3-pentanol, 4-methyl-2-pentanol, 4-methyl-3-pentanol, cyclohexanol, 5-methyl-2-hexanol, 4-methyl-2-hexanol, 4,5-dimethyl-2-hexanol, 6-methyl-2-heptanol, 7-methyl-2-octanol, 8-methyl-2-nonanol, and 9-methyl-2-decanol. Of these, 1-hexanol, 2-hexanol, 1-pentanol, 3-methyl-1-butanol, 3-methyl-2-pentanol, 3-methyl-3-pentanol, 4-methyl-2-pentanol and 4-methyl-3-pentanol are preferred, and 1-hexanol and 4-methyl-2-pentanol are most preferred.

The hydrocarbon-based solvent includes an aromatic hydrocarbon-based solvent such as toluene and xylene, and an aliphatic hydrocarbon-based solvent such as octane and decane.

The rinsing solution preferably contains one or more members selected from 1-hexanol, 4-methyl-2-pentanol and decane.

As for these components, a plurality of components may be mixed, or the component may be used by mixing it with an organic solvent other than those described above. The above-described solvent may be mixed with water, but the percentage of water content in the rinsing solution is usually 60 mass % or less, preferably 30 mass % or less, more preferably 10 mass % or less, and most preferably 5 mass % or less. By setting the percentage of water content to 60 mass % or less, good rinsing characteristics can be obtained.

The rinsing solution may be also used after incorporating thereinto an appropriate amount of a surfactant.

As the surfactant, the same as the later-described surfactant used in the actinic ray-sensitive or radiation-sensitive resin composition may be used, and the amount used thereof is usually from 0.001 to 5 mass %, preferably from 0.005 to 2 mass %, more preferably from 0.01 to 0.5 mass %, based on the total amount of the rinsing solution.

Rinsing Method:

In the rinsing step, the developed wafer is washed using the above-described rinsing solution containing an organic solvent.

The method for washing treatment is not particularly limited but, for example, a method of continuously ejecting the rinsing solution on the substrate spinning at a constant speed (spin ejection method), a method of dipping the substrate in a bath filled with the rinsing solution for a fixed time (dipping method), and a method of spraying the rinsing solution on the substrate surface (spraying method) may be applied. Among others, it is preferred to perform the washing treatment by the spin ejection method and after the washing, remove the rinsing solution from the substrate surface by spinning the substrate at a rotation speed of 2,000 to 4,000 rpm.

The rinsing time is not particularly limited but is usually from 10 to 300 seconds, preferably from 10 to 180 seconds, and most preferably from 20 to 120 seconds.

The temperature of the rinsing solution is preferably from 0 to 50° C., more preferably from 15 to 35° C.

After the development or rinsing, a treatment for removing the developer or rinsing solution adhering on the pattern with a supercritical fluid may be performed.

Furthermore, after the development, rinsing or treatment with a supercritical fluid, a heating treatment for removing the solvent remaining in the pattern may be performed. The heating temperature is not particularly limited as long as a good resist pattern can be obtained, but the heating temperature is usually from 40 to 160° C., preferably from 50 to 150° C., and most preferably from 50 to 110° C. The heating time is not particularly limited as long as a good resist pattern can be obtained, but the heating time is usually from 15 to 300 seconds, preferably from 15 to 180 seconds.

Alkali Development:

The pattern forming method of the present invention may further include a step of performing development by using an aqueous alkali solution to form a resist pattern (alkali development step), and by this development, a finer pattern can be formed.

In the present invention, the portion of low exposure intensity is removed in the organic solvent development step (4), and by further performing the alkali development step, the portion of high exposure intensity is also removed. By virtue of the multiple development process of performing development a plurality of times in this way, a pattern can be formed by keeping only the region of intermediate exposure intensity from being dissolved, so that a finer pattern than usual can be formed (the same mechanism as disclosed in [0077] of JP-A-2008-292975).

The alkali development may be performed either before or after the step (4) of performing the development by using a developer containing an inorganic solvent but is preferably performed before the organic solvent development step (4).

Examples of the aqueous alkali solution which can be used for alkali development include an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, or cyclic amines such as pyrrole and piperidine.

The alkaline aqueous solution above may be also used after adding thereto alcohols and a surfactant each in an appropriate amount.

The alkali concentration of the alkali developer is usually from 0.1 to 20 mass %.

The pH of the alkali developer is usually from 10.0 to 15.0.

In particular, an aqueous solution of 2.38 mass % tetramethylammonium hydroxide is preferred.

The alkali development time is not particularly limited and is usually from 10 to 300 seconds, preferably from 20 to 120 seconds.

The temperature of the alkali developer is preferably from 0 to 50° C., more preferably from 15 to 35° C.

After the development with an aqueous alkali solution, a rinsing treatment may be performed. The rinsing solution in the rinsing treatment is preferably pure water, and the rinsing solution may be also used after adding thereto an appropriate amount of a surfactant.

Moreover, after the development or rinsing, a heating treatment for removing water remaining in the pattern may be performed.

Furthermore, a treatment for removing the remaining developer or rinsing solution by heating may be performed. The heating temperature is not particularly limited as long as a good resist pattern can be obtained, but the heating temperature is usually from 40 to 160° C., preferably from 50 to 150° C., and most preferably from 50 to 110° C. The heating time is not particularly limited as long as a good resist pattern can be obtained, but the heating time is usually from 15 to 300 seconds, preferably from 15 to 180 seconds.

With respect to the film formed from the resist composition of the present invention, the exposure may be also performed by filling a liquid (immersion medium) having a refractive index higher than that of air between the film and a lens at the irradiation with an actinic ray or radiation (immersion exposure). By this exposure, the resolution can be enhanced. The immersion medium used may be any liquid as long as it has a refractive index higher than that of air, but pure water is preferred.

The immersion liquid used in the immersion exposure is described below.

The immersion liquid is preferably a liquid being transparent to light at the exposure wavelength and having as small a temperature coefficient of refractive index as possible so as to minimize the distortion of an optical image projected on the resist film, and water is preferably used in view of easy availability and easy handleability in addition to the above-described aspects.

Furthermore, a medium having a refractive index of 1.5 or more can be also used from the standpoint that the refractive index can be more enhanced. This medium may be either an aqueous solution or an organic solvent.

In the case of using water as the immersion liquid, for the purpose of decreasing the surface tension of water and increasing the surface activity, an additive (liquid) which does not dissolve the resist film on a wafer and at the same time, gives only a negligible effect on the optical coat at the undersurface of the lens element, may be added in a small ratio. The additive is preferably an aliphatic alcohol having a refractive index nearly equal to that of water, and specific examples thereof include methyl alcohol, ethyl alcohol and isopropyl alcohol. By virtue of adding an alcohol having a refractive index nearly equal to that of water, even when the alcohol component in water is evaporated and its content concentration is changed, the change in the refractive index of the entire liquid can be advantageously made very small. On the other hand, if an impurity greatly differing in the refractive index from water is mingled, this incurs distortion of the optical image projected on the resist film. Therefore, the water used is preferably distilled water. Pure water obtained by further filtering the distilled water through an ion exchange filter or the like may be also used.

The electrical resistance of water is preferably 18.3 MΩcm or more, and TOC (total organic carbon) is preferably 20 ppb or less. Also, the water is preferably subjected to a deaeration treatment.

The lithography performance can be enhanced by elevating the refractive index of the immersion liquid. From such a standpoint, an additive for elevating the refractive index may be added to water, or heavy water (D₂O) may be used in place of water.

In order to prevent the film from directly contacting with the immersion liquid, a film (hereinafter, sometimes referred to as a “topcoat”) sparingly soluble in the immersion liquid may be provided between the film formed of the composition of the present invention and the immersion liquid. The functions required of the topcoat are suitability for coating as an overlayer of the composition film and sparing solubility in the immersion liquid. The topcoat is preferably unmixable with the composition film and capable of being uniformly coated as an overlayer of the composition film.

Specific examples of the topcoat include a hydrocarbon polymer, an acrylic acid ester polymer, a polymethacrylic acid, a polyacrylic acid, a polyvinyl ether, a silicon-containing polymer, and a fluorine-containing polymer. If an impurity is dissolved out into the immersion liquid from the topcoat, the optical lens is contaminated. In this viewpoint, the amount of residual monomer components of the polymer contained in the topcoat is preferably smaller.

On peeling off the topcoat, a developer may be used or a releasing agent may be separately used. The releasing agent is preferably a solvent hardly permeating the film. From the standpoint that the peeling step can be performed simultaneously with the development step of the film, the topcoat is preferably peelable with an organic solvent-containing developer.

With no difference in the refractive index between the topcoat and the immersion liquid, the resolution is enhanced. In the case of using water as the immersion liquid, the topcoat preferably has a refractive index close to that of the immersion liquid. From the standpoint of having a refractive index close to that of the immersion liquid, the topcoat preferably contains a fluorine atom. Also, in view of transparency and refractive index, the topcoat is preferably a thin film.

The topcoat is preferably unmixable with the film and further unmixable with the immersion liquid. From this standpoint, when the immersion liquid is water, the solvent used for the topcoat is preferably a medium that is sparingly soluble in the solvent used for the composition of the present invention and at the same time, is insoluble in water. In the case where the immersion liquid is an organic solvent, the topcoat may be either water-soluble or water-insoluble.

On the other hand, when performing EUV exposure or EB exposure, for the purpose of outgas inhibition or blob defect suppression or for preventing, for example, worsening of the collapse performance resulting from improvement of the reverse taper profile or worsening of LWR due to surface roughening, a topcoat layer may be formed on the resist film formed of the actinic ray-sensitive or radiation-sensitive resin composition of the present invention. The topcoat composition used for formation of the topcoat layer is described below.

In the topcoat composition for use in the present invention, the solvent is preferably water or an organic solvent, more preferably water or an alcohol-based solvent.

In the case where the solvent is an organic solvent, a solvent incapable of dissolving the resist film is preferred. As the solvent which can be used, it is preferred to use an alcohol-based solvent, a fluorine-based solvent or a hydrocarbon-based solvent, and it is more preferred to use a fluorine-free alcohol-based solvent. The alcohol-based solvent is, in view of coatability, preferably a primary alcohol, more preferably a primary alcohol having a carbon number of 4 to 8. As the primary alcohol having a carbon number of 4 to 8, a linear, branched or cyclic alcohol may be used, but a linear or branched alcohol is preferred. Specific examples thereof include 1-butanol, 1-hexanol, 1-pentanol, and 3-methyl-1-butanol.

In the case where the solvent of the topcoat composition for use in the present invention is water, an alcohol-based solvent or the like, the composition preferably contains a water-soluble resin. It is considered that the uniformity of solubility in the developer can be more enhanced by containing a water-soluble resin. Preferred examples of the water-soluble resin include polyacrylic acid, polymethacrylic acid, polyhydroxystyrene, polyvinylpyrrolidone, polyvinyl alcohol, polyvinyl ether, polyvinyl acetal, polyacrylimide, polyethylene glycol, polyethylene oxide, polyethyleneimine, polyester polyol, polyether polyol, and polysaccharides. Among these, polyacrylic acid, polymethacrylic acid, polyhydroxystyrene, polyvinylpyrrolidone and polyvinyl alcohol are preferred. Incidentally, the water-soluble resin is not limited only to a homopolymer and may be a copolymer, for example, may be a copolymer having a monomer corresponding to the repeating unit of the homopolymer described above and another monomer unit. Specifically, an acrylic acid-methacrylic acid copolymer, an acrylic acid-hydroxystyrene copolymer, and the like may be also used in the present invention.

As the resin for the topcoat composition, a resin having an acidic group described in JP-A-2009-134177 and JP-A-2009-91798 may be also preferably used.

The weight average molecular weight of the water-soluble resin is not particularly limited but is preferably from 2,000 to 1,000,000, more preferably from 5,000 to 500,000, still more preferably from 10,000 to 100,000. The weight average molecular weight of the resin as used herein indicates a molecular weight in terms of polystyrene measured by GPC (carrier: THF or N-methyl-2-pyrrolidone (NMP)).

The pH of the topcoat composition is not particularly limited but is preferably from 0 to 10, more preferably from 0 to 8, still more preferably from 1 to 7.

In the case where the solvent of the topcoat composition is an organic solvent, the topcoat composition may contain a hydrophobic resin such as the hydrophobic resin (HR) described above in the paragraph of an actinic ray-sensitive or radiation-sensitive resin composition. As the hydrophobic resin, it is also preferred to use a hydrophobic resin described in JP-A-2008-209889.

The concentration of the resin in the topcoat composition is preferably from 0.1 to 10 mass %, more preferably from 0.2 to 5 mass %, still more preferably from 0.3 to 3 mass %.

The topcoat material may contain a component other than the resin, but the proportion of the resin in the solid content of the topcoat composition is preferably form 80 to 100 mass %, more preferably from 90 to 100 mass %, still more preferably from 95 to 100 mass %.

The solid content concentration of the topcoat composition for use in the present invention is preferably from 0.1 to 10 mass %, more preferably from 0.2 to 6 mass %, still more preferably from 0.3 to 5 mass %. By adjusting the solid content concentration to fall in the range above, the topcoat composition can be uniformly coated on the resist film.

Examples of the component other than the resin, which can be added to the topcoat material, include a surfactant, a photoacid generator, and a basic compound. Specific examples of the photoacid generator and basic compound include the same compounds as those of the above-described compound capable of generating an acid upon irradiation with an actinic ray or radiation and the basic compound.

In the case of using a surfactant, the amount of the surfactant used is preferably from 0.0001 to 2 mass %, more preferably from 0.001 to 1 mass %, based on the total amount of the topcoat composition.

Addition of a surfactant to the topcoat composition makes it possible to enhance the coatability when coating the topcoat composition. The surfactant include nonionic, anionic, cationic and amphoteric surfactants.

Examples of the nonionic surfactant which can be used include Plufarac Series produced by BASF; ELEBASE Series, Finesurf Series, and Blaunon Series produced by Aoki Oil Industrial Co., Ltd.; Adeka Pluronic P-103 produced by Asahi Denka Co., Ltd.; Emulgen Series, Amiet Series, Aminon PK-02S, Emanon CH-25, and Rheodol Series produced by Kao Corporation; Surflon S-141 produced by AGC Seimi Chemical Co., Ltd.); Noigen Series produced by Daiichi Kogyo Seiyaku Co., Ltd.; Newcalgen Series produced by Takemoto Oil & Fat Co., Ltd.; DYNOL 604, EnviroGem AD01, Olfine EXP Series, and Surfynol Series produced by Nisshin Chemical Industry Co., Ltd.; and Ftergent 300 produced by Ryoko Chemical Co., Ltd.

Examples of the anionic surfactant which can be used include Emal 20T and Poiz 532A produced by Kao Corporation; Phosphanol ML-200 produced by Toho Chemical Industry Co., Ltd.; EMULSOGEN Series produced by Clariant Japan K.K.; Surflon S-111N and Surflon S-211 produced by AGC Seimi Chemical Co., Ltd.; Plysurf Series produced by Dai-ichi Kogyo Seiyaku Co., Ltd.; Pionin Series produced by Takemoto Oil & Fat Co., Ltd.; Olfine PD-201 and Olfine PD-202 produced by Nisshin Chemical Industry Co., Ltd.; AKYPO RLM45 and ECT-3 produced by Nihon Surfactant Kogyo K.K.; and Lipon produced by Lion Corporation.

Examples of the cationic surfactant which can be used include Acetamin 24 and Acetamin 86 produced by Kao Corporation.

Examples of the amphoteric surfactant which can be used include Surflon S-131 produced by AGC Seimi Chemical Co., Ltd.; and Enagicol C-40H and Lipomin LA produced by Kao Corporation.

Also, these surfactants may be mixed and used.

In the pattern forming method of the present invention, a resist film can be formed on a substrate by using the actinic ray-sensitive or radiation-sensitive resin composition, and a topcoat layer can be formed on the resist film by using the topcoat composition. The thickness of the resist film is preferably from 10 to 100 nm, and the thickness of the topcoat layer is preferably from 10 to 200 nm, more preferably from 20 to 100 nm, still more preferably from 40 to 80 nm.

The method for coating the actinic ray-sensitive or radiation-sensitive resin composition on a substrate is preferably spin coating, and the rotation speed thereof is preferably from 1,000 to 3,000 rpm.

For example, the actinic ray-sensitive or radiation-sensitive resin composition is coated on such a substrate (e.g., silicon/silicon dioxide-coated substrate) as used in the production of a precision integrated circuit device by an appropriate coating method such as spinner and coater and then dried to form a resist film. Incidentally, a known antireflection film may be previously provided by coating. Also, the resist film is preferably dried before forming a topcoat layer.

On the resist film obtained, a topcoat composition is coated by the same method as the resist film forming method and dried, whereby a topcoat layer can be formed.

The resist film having thereon a topcoat layer is irradiated with an electron beam (EB), an X-ray or EUV light usually through a mask, then preferably baked (heated), and further subjected to development, whereby a good pattern can be obtained.

### [1] Actinic Ray-Sensitive or Radiation-Sensitive Resin Composition

The actinic ray-sensitive or radiation-sensitive resin composition which can be used in the present invention is described below.

The actinic ray-sensitive or radiation-sensitive resin composition according to the present invention is used for negative development (development where the solubility for developer is decreased upon exposure and while the exposed area remains as a pattern, the unexposed area is removed). That is, the actinic ray-sensitive or radiation-sensitive resin composition according to the present invention can be an actinic ray-sensitive or radiation-sensitive resin composition for organic solvent development, which is used for development using an organic solvent-containing developer. The term “for organic solvent development” as used herein means usage where the composition is subjected to at least a step of performing development by using an organic solvent-containing developer.

In this way, the present invention also relates to an actinic ray-sensitive or radiation-sensitive resin composition for use in the above-described pattern forming method of the present invention.

The actinic ray-sensitive or radiation-sensitive resin composition of the present invention is typically a resist composition and is preferably a negative resist composition (that is, a resist composition for organic solvent development), because particularly high effects can be obtained. Also, the composition according to the present invention is typically a chemical amplification resist composition.

The actinic ray-sensitive or radiation-sensitive resin composition of the present invention contains (P) a resin having a repeating unit represented by the following formula (I) (hereinafter, sometimes referred to as “repeating unit (a)”):

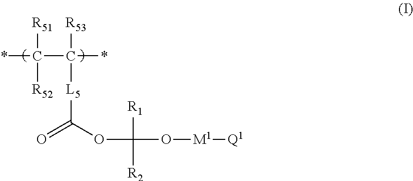

In formula (I), each of R₅₁, R₅₂ and R₅₃ independently represents a hydrogen atom, an alkyl group, a cycloalkyl group, a halogen atom, a cyano group or an alkoxycarbonyl group, R₅₂ may combine with L₅ to form a ring, and in this case, R₅₂ represents an alkylene group.

L₅ represents a single bond or a divalent linking group, and in the case of forming a ring with R₅₂, L₅ represents a trivalent linking group.

R₁ represents a hydrogen atom or an alkyl group.

R₂ represents a hydrogen atom, an alkyl group, a cycloalkyl group, an aryl group, an aralkyl group, an alkoxy group, an acyl group or a heterocyclic group.

M¹ represents a single bond or a divalent linking group.

Q¹ represents an alkyl group, a cycloalkyl group, an aryl group or a heterocyclic group, and Q¹, M¹ and R₂ may combine with each other to form a ring.

When M¹ is a divalent linking group, Q¹ may combine with M¹ through a single bond or another linking group to form a ring.

### [1] Resin (P)

The resin (P) has an acid-decomposable repeating unit. In turn, the resin (P) is a resin capable of reducing the solubility for an organic solvent-containing developer by an action of an acid. The acid-decomposable repeating unit is, for example, a repeating unit having, on either one or both of the main chain and the side chain of the resin, a group capable of decomposing by the action of an acid to produce a polar group (hereinafter sometimes referred to as “acid-decomposable group”). Thanks to this repeating unit, the affinity of the resin (P) for an organic solvent-containing developer is reduced by the action of an acid, and insolubilization or difficult solubilization (negative conversion) proceeds. More specifically, the resin (P) has, as the acid-decomposable repeating unit, a repeating unit represented by the following formula (I) which is caused to generate a carbonyl group by the action of an acid:

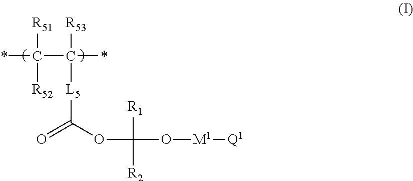

In formula (I), each of R₅₁, R₅₂ and R₅₃ independently represents a hydrogen atom, an alkyl group, a cycloalkyl group, a halogen atom, a cyano group or an alkoxycarbonyl group, R₅₂ may combine with L₅ to form a ring, and in this case, R₅₂ represents an alkylene group.

L₅ represents a single bond or a divalent linking group, and in the case of forming a ring with R₅₂, L₅ represents a trivalent linking group.

R₁ represents a hydrogen atom or an alkyl group.

R₂ represents a hydrogen atom, an alkyl group, a cycloalkyl group, an aryl group, an aralkyl group, an alkoxy group, an acyl group or a heterocyclic group.

M¹ represents a single bond or a divalent linking group.

Q¹ represents an alkyl group, a cycloalkyl group, an aryl group or a heterocyclic group, and Q¹ and R₂ may combine with each other to form a ring.

When M¹ is a divalent linking group, Q¹ may combine with M¹ through a single bond or another linking group to form a ring.

The alkyl group of R₅₁ to R₅₃ in formula (I) is preferably an alkyl group having a carbon number of 20 or less, such as methyl group, ethyl group, propyl group, isopropyl group, n-butyl group, sec-butyl group, hexyl group, 2-ethylhexyl group, octyl group and dodecyl group, which may have a substituent, more preferably an alkyl group having a carbon number of 8 or less, still more preferably an alkyl group having a carbon number of 3 or less.

As the alkyl group contained in the alkoxycarbonyl group, the same as the alkyl group in R₁₁ to R₁₃ is preferred.

The cycloalkyl group may be either monocyclic or polycyclic and is preferably a monocyclic cycloalkyl group having a carbon number of 3 to 8, such as cyclopropyl group, cyclopentyl group and cyclohexyl group, which may have a substituent.

The halogen atom includes fluorine atom, chlorine atom, bromine atom and iodine atom, with fluorine atom being preferred.

Preferred examples of the substituent on the groups above include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The carbon number of the substituent is preferably 8 or less.

In the case where R₅₂ is an alkylene group and forms a ring with L₁₁, the alkylene group is preferably an alkylene group having a carbon number of 1 to 8, such as methylene group, ethylene group, propylene group, butylene group, hexylene group and octylene group, more preferably an alkylene group having a carbon number of 1 to 4, still more preferably an alkylene group having a carbon number of 1 or 2. The ring formed by combining R₅₂ and L₁₁ is preferably a 5- or 6-membered ring.

In formula (I), each of R₅₁ and R₅₃ is preferably a hydrogen atom, an alkyl group or a halogen atom, more preferably a hydrogen atom, a methyl group, an ethyl group, a trifluoromethyl group (—CF₃), a hydroxymethyl group (—CH₂—OH), a chloromethyl group (—CH₂—Cl) or a fluorine atom (—F). R₅₂ is preferably a hydrogen atom, an alkyl group, a halogen atom or an alkylene group (forms a ring with L₅), more preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forms a ring with L₅) or an ethylene group (forms a ring with L₅).

In formula (I), the alkyl group of R₁ is preferably an alkyl group having a carbon number of 1 to 10, more preferably an alkyl group having a carbon number of 1 to 5, still more preferably an alkyl group having a carbon number of 1 to 3, yet still more preferably an alkyl group having a carbon number of 1 or 2 (that is, a methyl group or an ethyl group). Specific examples of the alkyl group of R₁ include a methyl group, an ethyl group, an n-propyl group, an isopropyl group, an n-butyl group, an isobutyl group, a sec-butyl group, and a tert-butyl group.

R₁ is preferably a hydrogen atom or an alkyl group having a carbon number of 1 to 5, more preferably a hydrogen atom or an alkyl group having a carbon number of 1 to 3, still more preferably a hydrogen atom, a methyl group or an ethyl group, yet still more preferably a hydrogen atom.

Examples of the divalent linking group represented by L₅ include an alkylene group, a divalent aromatic ring group, —COO-L₁-, —O-L₁-, and a group formed by combining two or more of these groups. Here, L₁ represents an alkylene group, a cycloalkylene group, a divalent aromatic ring group, or a group formed by combining an alkylene group and a divalent aromatic ring group.

The divalent aromatic ring group is preferably a 1,4-phenylene group, a 1,3-phenylene group, a 1,2-phenylene group or a 1,4-naphthylene group, more preferably a 1,4-phenylene group.

L₅ is preferably a single bond, a group represented by —COO-L₁-, or a group represented by -L₂-O—CH₂—, more preferably a single bond. Here, L₂ represents a divalent aromatic ring group.

The cycloalkylene group of L₁ may have an ester bond and form a lactone ring, and L₁ is preferably an alkylene group having a carbon number of 1 to 15, which may contain a heteroatom or a carbonyl bond, more preferably an alkylene group which may contain a heteroatom, still more preferably a methylene group, an ethylene group or a propylene group.

L₂ is preferably an arylene group (preferably having a carbon number of 1 to 10), more preferably a 1,4-phenylene group, a 1,3-phenylene group or a 1,2-phenylene group, still more preferably a 1,4-phenylene group or a 1,3-phenylene group.

In the case where L₅ combines with R₅₂ to form a ring, preferred examples of the trivalent linking group represented by L₅ include groups formed by removing one arbitrary hydrogen atom from specific examples above of the divalent linking group represented by L₅.

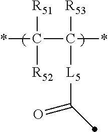

Specific examples of the partial structure (main chain moiety structure) represented by formula (1-1) in the repeating unit represented by formula (I) are illustrated below, but the present invention is not limited thereto.

In formulae, “•” indicates a bond connected to the oxygen atom of the acetal structure in formula (I).

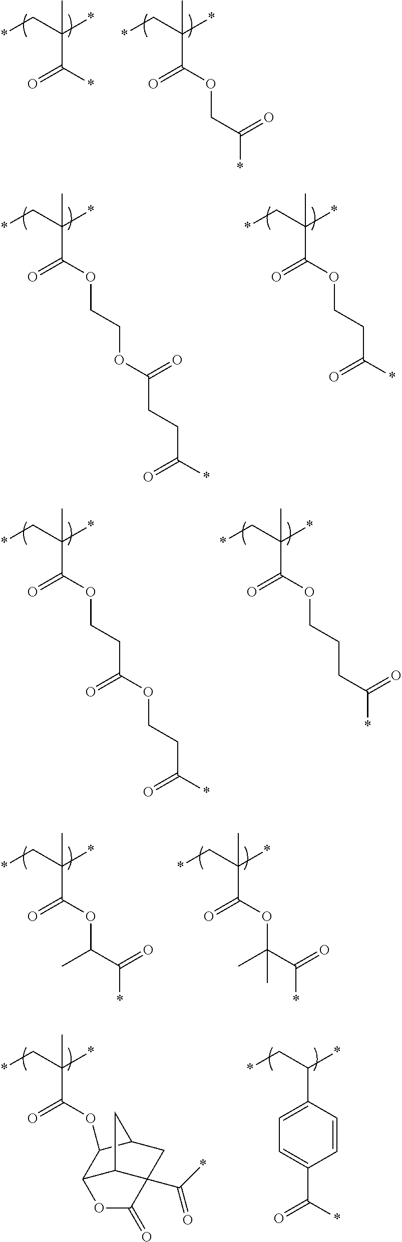

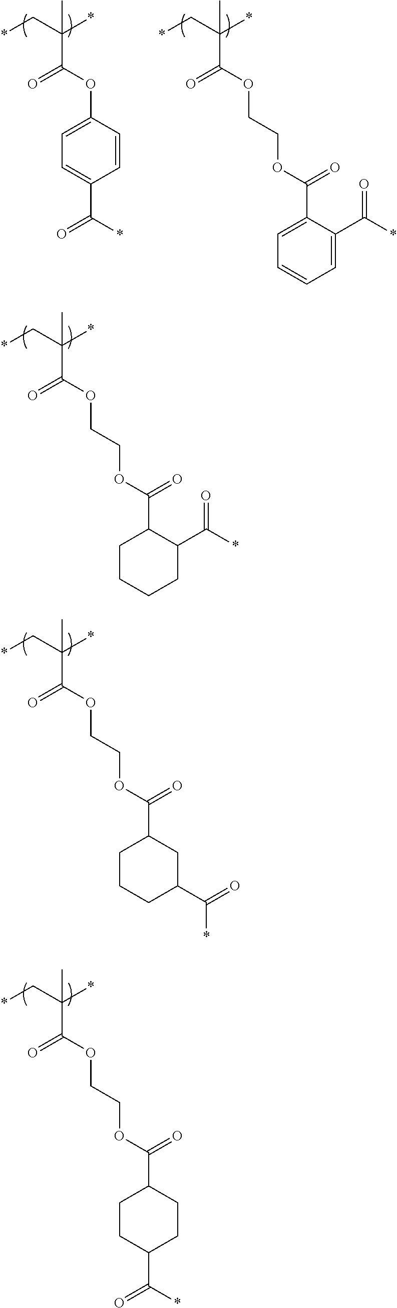

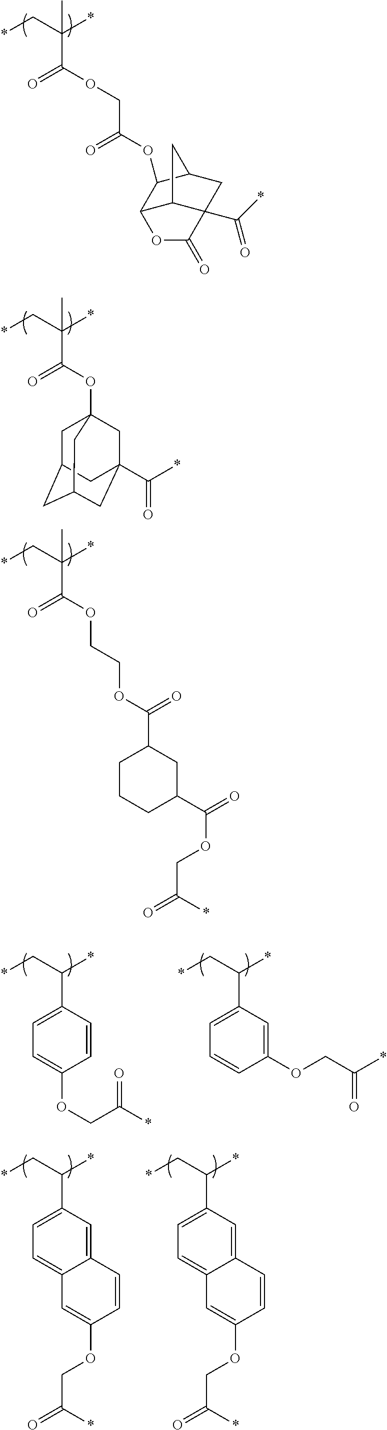

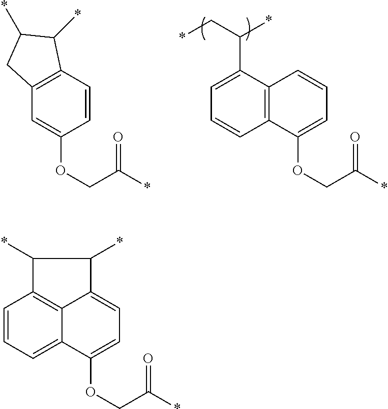

R₂ represents a hydrogen atom, an alkyl group, a cycloalkyl group, an aryl group, an aralkyl group, an alkoxy group, an acyl group or a heterocyclic group. From the standpoint of reducing the residual film ratio of the resin (P), the carbon number of R₂ is preferably 15 or less.

The alkyl group of R₂ is preferably an alkyl group having a carbon number of 1 to 15, more preferably an alkyl group having a carbon number of 1 to 10, still more preferably an alkyl group having a carbon number of 1 to 6. Specific examples of the alkyl group of R₂ include a methyl group, an ethyl group, a propyl group, an isopropyl group, an n-butyl group, a sec-butyl group, a tert-butyl group, a neopentyl group, a hexyl group, a 2-ethylhexyl group, an octyl group, and a dodecyl group. The alkyl group of R₂ is preferably a methyl group, an ethyl group, a propyl group, an isopropyl group or a tert-butyl group.

The cycloalkyl group of R₂ may be monocyclic or polycyclic and is preferably a cycloalkyl group having a carbon number of 3 to 15, more preferably a cycloalkyl group having a carbon number of 3 to 10, still more preferably a cycloalkyl group having a carbon number of 3 to 6. Specific examples of the cycloalkyl group of R₂ include a cyclopropyl group, a cyclobutyl group, a cyclopentyl group, a cyclohexyl group, a cycloheptyl group, a cyclooctyl group, a decahydronaphthyl group, a cyclodecyl group, a 1-adamantyl group, a 2-adamantyl group, a 1-norbornyl group, and a 2-norbornyl group. The cycloalkyl group of R₂ is preferably a cyclopropyl group, a cyclopentyl group or a cyclohexyl group.

The aryl group of R₂ is preferably an aryl group having a carbon number of 6 to 15, more preferably an aryl group having a carbon number of 6 to 12, and encompasses a structure where a plurality of aromatic rings are connected to each other through a single bond (such as biphenyl group and terphenyl group). Specific examples of the aryl group of R₂ include a phenyl group, a naphthyl group, an anthranyl group, a biphenyl group, and a terphenyl group. The aryl group of R₂ is preferably a phenyl group, a naphthyl group or a biphenyl group.

The aralkyl group of R₂ is preferably an aralkyl group having a carbon number of 6 to 20, more preferably an aralkyl group having a carbon number of 7 to 12. Specific examples of the aralkyl group of R₂ include a benzyl group, a phenethyl group, a naphthylmethyl group, an a naphthylethyl group.

Examples of the alkyl group moiety of the alkoxy group of R₂ include those recited above for the alkyl group of R₂. This alkoxy group is preferably a methoxy group, an ethoxy group, an n-propoxy group or an n-butoxy group.

The acyl group of R₂ includes, for example, a linear or branched acyl group having a carbon number of 2 to 12, such as acetyl group, propionyl group, n-butanoyl group, i-butanoyl group, n-heptanoyl group, 2-methylbutanoyl group, 1-methylbutanoyl group and tert-heptanoyl group.

The heterocyclic group of R₂ is preferably a heterocyclic group having a carbon number of 6 to 20, more preferably a heterocyclic group having a carbon number of 6 to 12. Specific examples of the heterocyclic group of R₂ include a pyridyl group, a pyrazyl group, a tetrahydrofuranyl group, a tetrahydropyranyl group, a tetrahydrothiophene group, a piperidyl group, a piperazyl group, a furanyl group, a pyranyl group, and a chromanyl group.

The alkyl group as R₁ and the alkyl group, cycloalkyl group, aryl group, aralkyl group, alkoxy group, acyl group and heterocyclic group as R₂ may further have a substituent.

Examples of the substituent which the alkyl group as R₁ and R₂ may further have include a cycloalkyl group, an aryl group, an amino group, an amido group, a ureido group, a urethane group, a hydroxy group, a carboxy group, a halogen atom, an alkoxy group, an aralkyloxy group, a thioether group, an acyl group, an acyloxy group, an alkoxycarbonyl group, a cyano group, and a nitro group.

Examples of the substituent which the cycloalkyl group as R₂ may further have include an alkyl group and the groups described above as specific examples of the substituent which the alkyl group may further have.

Incidentally, each of the carbon number of the alkyl group and the carbon number of the substituent which the cycloalkyl group may further have is preferably from 1 to 8.

Examples of the substituent which the aryl group, aralkyl group and heterocyclic group as R₂ may further have include a nitro group, a halogen atom such as fluorine atom, a carboxyl group, a hydroxyl group, an amino group, a cyano group, an alkyl group (preferably having a carbon number of 1 to 15), an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), and an alkoxycarbonyloxy group (preferably having a carbon number of 2 to 7).

R₂ is described in more detail.

In formula (I), R₂ is more preferably a hydrogen atom or a group represented by —(CH₂)ₙ₁—C(R²¹)(R²²)(R²³).

In the formula above, each of R²¹ to R²³ independently represents a hydrogen atom, an alkyl group, a cycloalkyl group, an aryl group, an aralkyl group or a heterocyclic group, and each of at least two members of R²¹ to R²³ independently represents an alkyl group, a cycloalkyl group, an aryl group, an aralkyl group or a heterocyclic group

At least two members of R²¹ to R²³ may combine with each other to form a ring.

n1 represents an integer of 0 to 6.)

When R₂ in formula (I) is a group represented by —(CH₂)ₙ₁—C(R²¹)(R²²)(R²³), the bulkiness is increased and the glass transition temperature (Tg) of the resin (P) becomes higher. As a result, the dissolution contrast of the resin (P) can be more improved, and the resolution can be more enhanced.

Specific examples and preferred examples of the alkyl group of R²¹ to R²³ are the same as specific examples and preferred examples of the alkyl group described above for R₂.

As described above, each of at least two members of R²¹ to R²³ independently represents an alkyl group, a cycloalkyl group, an aryl group, an aralkyl group or a heterocyclic group, and it is preferred that all of R²¹ to R²³ represent an alkyl group, a cycloalkyl group, an aryl group, an aralkyl group or a heterocyclic group.

Specific examples and preferred examples of the cycloalkyl group of R²¹ to R²³ are the same as specific examples and preferred examples of the cycloalkyl group described above for R₂.

Specific examples and preferred examples of the aryl group of R²¹ to R²³ are the same as specific examples and preferred examples of the aryl group described above for R₂.

Specific examples and preferred examples of the aralkyl group of R²¹ to R²³ are the same as specific examples and preferred examples of the aralkyl group described above for R₂.

Specific examples and preferred examples of the heterocyclic group of R²¹ to R²³ are the same as specific examples and preferred examples of the heterocyclic group described above for R₂.

The alkyl group, cycloalkyl group, aryl group, aralkyl group and heterocyclic group as R²¹ to R²³ may further have a substituent.

Specific examples of the substituent which the alkyl group as R²¹ to R²³ may further have are the same as specific examples of the substituent which the alkyl group of R₂ may further have.

Specific examples of the substituent which the cycloalkyl group as R²¹ to R²³ may further have include an alkyl group and the groups described above as specific examples of the substituent which the alkyl group may further have.

Each of the carbon number of the alkyl group and the carbon number of the substituent which the cycloalkyl group may further have is preferably from 1 to 8.

When R²¹ to R²³ are an alkyl group or a cycloalkyl group, preferably, all of R²¹ to R²³ are an alkyl group or all of R²¹ to R²³ are a cycloalkyl group; more preferably, all of R²¹ to R²³ are an alkyl group; and most preferably, all of R²¹ to R²³ are a methyl group.

Specific examples and preferred examples of the substituent which the aryl group, aralkyl group and heterocyclic group as R²¹ to R²³ may further have are the same as specific examples and preferred examples of the substituent which the aryl group, aralkyl group and heterocyclic group as R₂ may further have.

At least two of R²¹ to R²³ may form a ring together.

In the case where at least two of R²¹ to R²³ combine with each other to form a ring, examples of the ring formed include a cyclopentane ring, a cyclohexane ring, an adamantane ring, a norbornene ring, and a norbornane ring. These rings may have a substituent, and examples of the substituent which the ring may have include an alkyl group and the groups described above as specific examples of the substituent which the alkyl group may further have.

In the case where all of R²¹ to R²³ combine with each other to form a ring, examples of the ring formed include an adamantane ring, a norbornane ring, a norbornene ring, a bicyclo[2,2,2]octane ring, and a bicyclo[3,1,1]heptane ring. Among these, an adamantane ring is preferred. These rings may have a substituent, and examples of the substituent which the ring may have include an alkyl group and the groups described above as specific examples of the substituent which the alkyl group may further have.

From the standpoint that the compound (P) can have a high glass transition temperature and the resolution can be enhanced, it is preferred that each of R²¹ to R²³ is independently an alkyl group.

The carbon number of the group represented by —(CH₂)ₙ₁—C(R²¹)(R²²)(R²³) in formula (I) is preferably 15 or less and by satisfying this condition, the resist film obtained can have sufficient affinity for the developer and the exposed area can be more unfailingly removed by the developer (that is, adequate developability can be obtained).

From the standpoint of more raising the glass transition temperature of the resin, n1 preferably represents an integer of 0 to 6, more preferably 0 or 1. In terms of achieving high sensitivity, n1 is more preferably 1, and in terms of improving the resolution/isolated space resolution, n1 is more preferably 0.

Specific examples of the group represented by —C(R²¹)(R²²)(R²³) in R² (preferably a group represented by —(CH₂)ₙ₁—C(R²¹)(R²²)(R²³)) are illustrated below, but the present invention is not limited thereto. In specific examples, * indicates a bond connected to a carbon atom to which R₁ in formula (I) is bonded, or a bond connected to the linking group represented by —(CH₂)ₙ₁— in R₂.

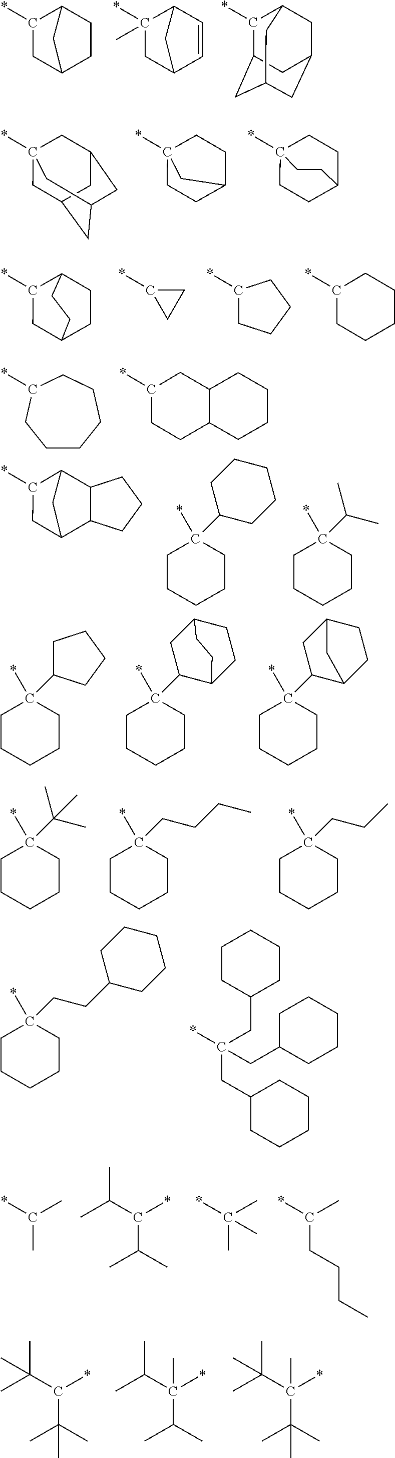

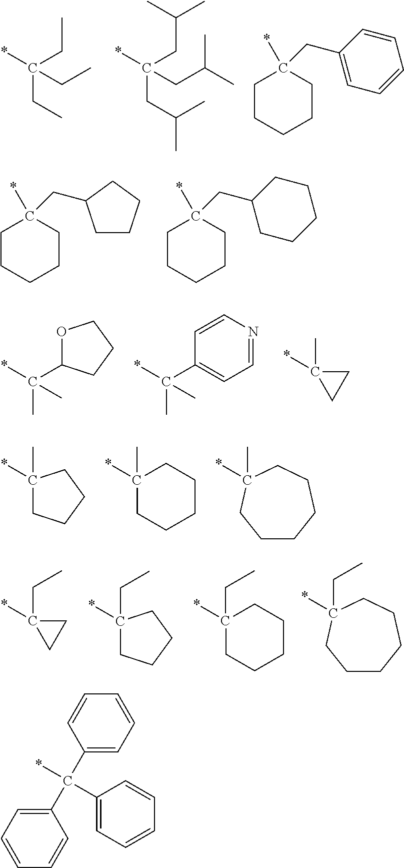

The divalent linking group as M¹ is, for example, an alkylene group (preferably an alkylene group having a carbon number of 1 to 8, such as methylene group, ethylene group, propylene group, butylene group, hexylene group or octylene group), a cycloalkylene group (preferably a cycloalkylene group having a carbon number of 3 to 15, such as cyclopentylene group or cyclohexylene group), —S—, —O—, —CO—, —CS—, —SO₂—, —N(R₀)—, or a combination of two or more thereof, and a linking group having a total carbon number of 20 or less is preferred. Here, R₀ is a hydrogen atom or an alkyl group (for example, an alkyl group having a carbon number of 1 to 8, and specific examples thereof include a methyl group, an ethyl group, a propyl group, an n-butyl group, a sec-butyl group, a hexyl group, and an octyl group).

M¹ is preferably a single bond, an alkylene group or a divalent linking group formed by a combination of an alkylene group and at least one of —O—, —CO—, —CS— and —N(R₀)—, more preferably a single bond, an alkylene group or a divalent linking group fixated by a combination of an alkylene group and —O—. Here, R₀ has the same meaning as R₀ above.

M¹ may further have a substituent, and examples of the substituent which M¹ may further have are the same as those of the substituent which the alkyl group of R²¹ above may have.

Specific examples and preferred examples of the alkyl group as Q¹ are the same, for example, as those described for the alkyl group of R²¹ above.

The cycloalkyl group as Q¹ may be monocyclic or polycyclic. The carbon number of the cycloalkyl group is preferably from 3 to 10. Examples of the cycloalkyl group include a cyclopropyl group, a cyclobutyl group, a cyclopentyl group, a cyclohexyl group, a cycloheptyl group, a cyclooctyl group, a 1-adamantyl group, a 2-adamantyl group, a 1-norbornyl group, a 2-norbornyl group, a bornyl group, an isobornyl group, a 4-tetracyclo[6.2.1.1^{3,6}.0^{2,7}]dodecyl group, a 8-tricyclo[5.2.1.0^{2,6}]decyl group, and a 2-bicyclo[2.2.1]heptyl group. Among these, a cyclopentyl group, a cyclohexyl group, a 2-adamantyl group, a 8-tricyclo[5.2.1.0^{2,6}]decyl group and a 2-bicyclo[2.2.1]heptyl group are preferred.

Specific examples and preferred examples of the aryl group as Q¹ are the same, for example, as those described for the aryl group of R²¹ above.

Specific examples and preferred examples of the heterocyclic group as Q¹ are the same, for example, as those described for the heterocyclic group of R²¹ above.

The alkyl group, cycloalkyl group, aryl group and heterocyclic group as Q¹ may have a substituent, and examples of the substituent include an alkyl group, a cycloalkyl group, a cyano group, a halogen atom, a hydroxyl group, an alkoxy group, a carboxyl group, and an alkoxycarbonyl group.

The group represented by -M¹-Q¹ is preferably an unsubstituted alkyl group, a cycloalkyl group-substituted alkyl group, a cycloalkyl group, an aralkyl group, an aryloxyalkyl group or a heterocyclic group. Specific examples and preferred examples of the unsubstituted alkyl group as the group represented by -M¹-Q¹, the “cycloalkyl group” and the cycloalkyl group in the “cycloalkyl group-substituted alkyl group” as the group represented by -M¹-Q¹, and the aryl group in the “aralkyl group (arylalkyl group)” and “aryloxyalkyl group” as the group represented by -M¹-Q¹ are the same as those described for the alkyl group, the cycloalkyl group and the aryl group of Q¹, respectively.

Specific examples and preferred examples of the alkyl moiety in the “cycloalkyl group-substituted alkyl group”, “aralkyl group (arylalkyl group)” and “aryloxyalkyl group” as the group represented by -M¹-Q¹ are the same as those described for the alkylene group of M¹.

Specific examples and preferred examples of the heterocyclic group as the group represented by -M¹-Q¹ are the same as those described for the heterocyclic group of

Specific examples of the group represented by -M¹-Q¹ include a methyl group, an ethyl group, an isopropyl group, a cyclopentyl group, a cyclohexyl group, a cyclohexylethyl group, a 2-adamantyl group, a 8-tricyclo[5.2.1.0^{2,6}]decyl group, a 2-bicyclo[2.2.1]heptyl group, a benzyl group, a 2-phenethyl group, and a 2-phenoxyethylene group.

Also, as described above, when M¹ is a divalent linking group, Q¹ may combine with M¹ through a single bond or another linking group to form a ring. The another linking group includes an alkylene group (preferably an alkylene group having a carbon number of 1 to 3), and the ring formed is preferably a 5- or 6-membered ring.

Q¹, M¹ and R₂ (particularly Q¹ and R₂) may combine with each other to form a ring, and the ring formed is preferably an oxygen-containing heterocyclic ring. The oxygen-containing heterocyclic ring structure may be monocyclic, polycyclic or spirocyclic and is preferably a monocyclic oxygen-containing heterocyclic structure, and the carbon number thereof is preferably 3 to 10, more preferably 4 or 5.

Specific examples of the group represented by -M¹-Q¹ are illustrated below, but the present invention is not limited thereto. In specific examples, * indicates a bond connected to the oxygen atom in formula (I), Me stands for a methyl group, Et stands for an ethyl group, and Pr stands for an n-propyl group.

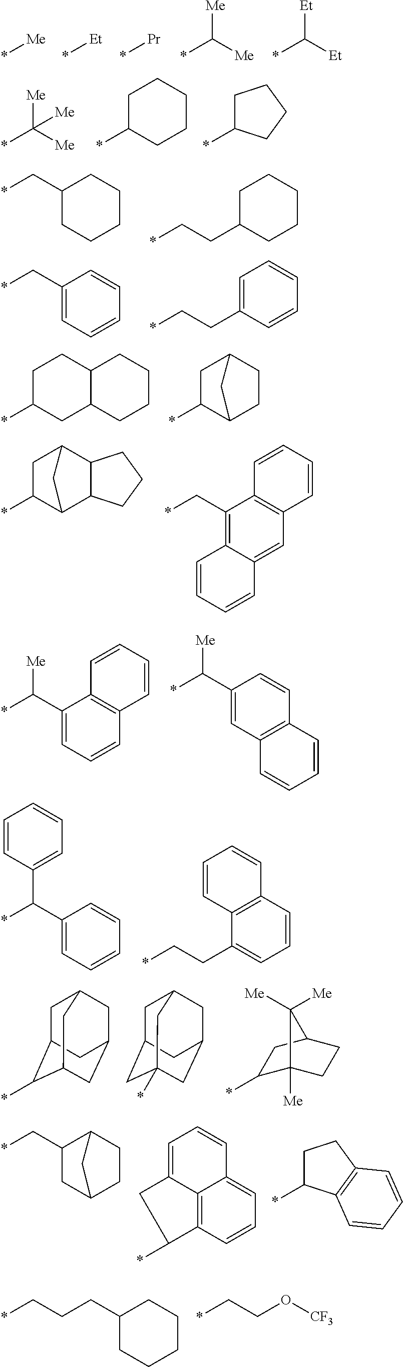

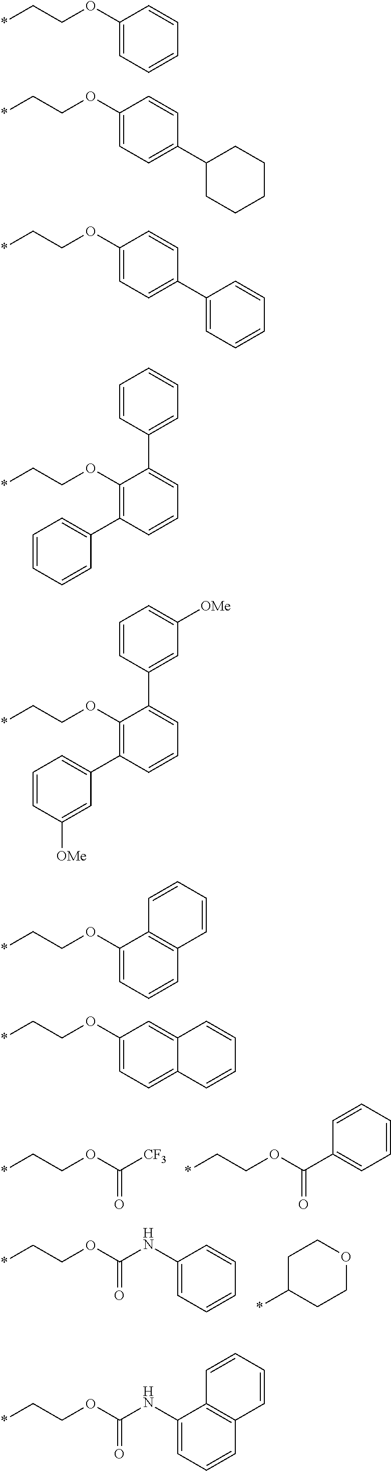

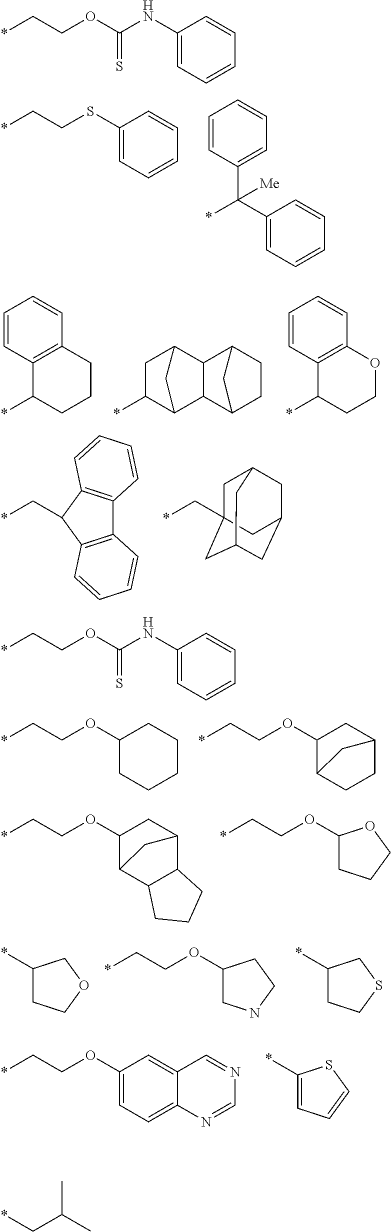

In the repeating unit represented by formula (I), specific examples of the ring formed when Q¹, M¹ and R₂ combine with each other to form a ring are illustrated below. * indicates a bond connected to the oxygen atom in formula (I). R₄ has the same meaning as R₁ in formula (I).

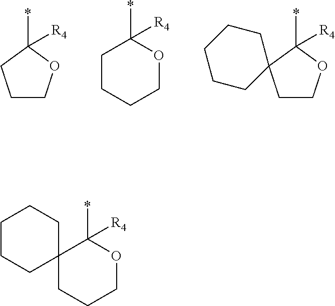

Specific examples of the portion except for the main chain moiety structure represented by formula (1-1), that is, the portion of an acetal structure-containing leaving group, in the repeating unit represented by formula (I) are illustrated blow, but the present invention is not limited thereto. In specific examples, * indicates a bond connected to the oxygen atom of an ester bond connected to L₅ in formula (I).

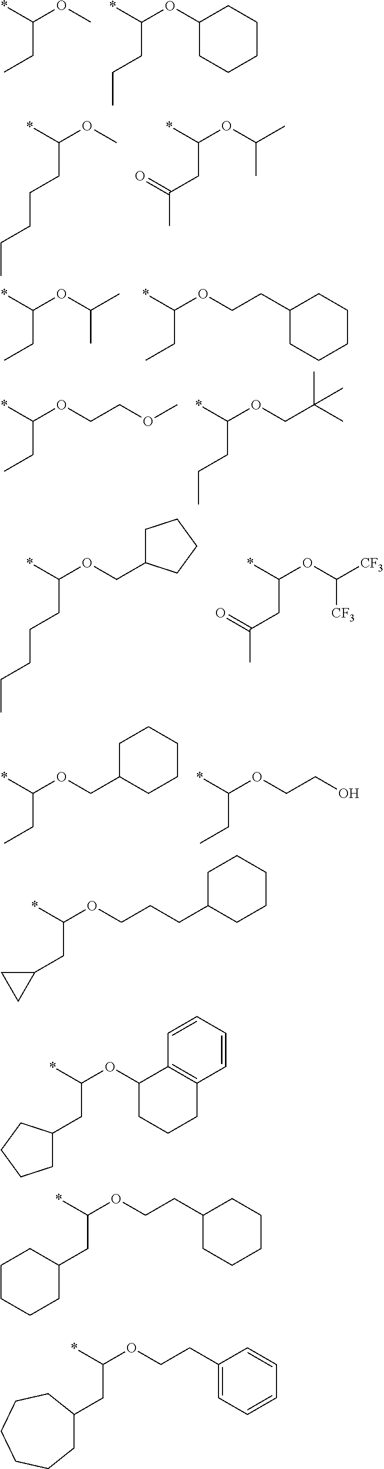

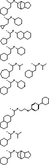

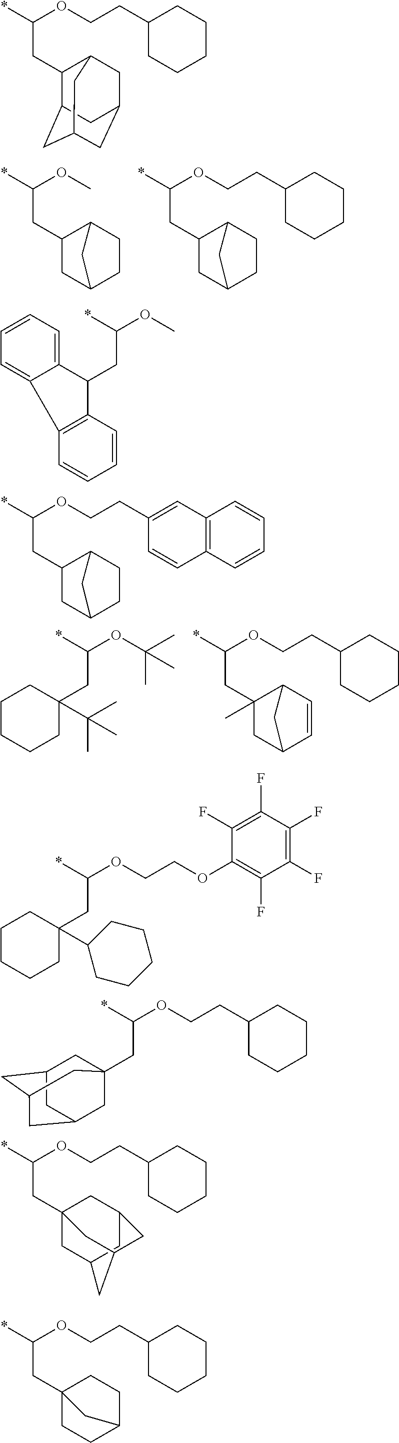

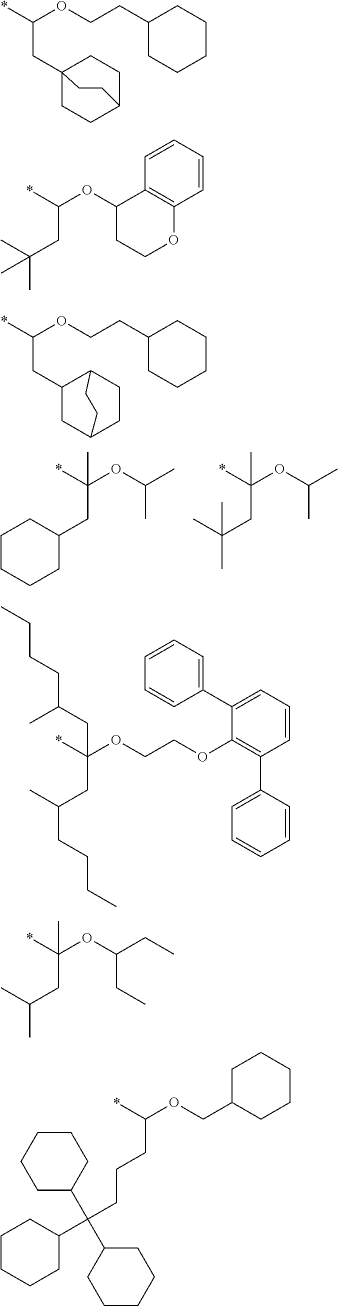

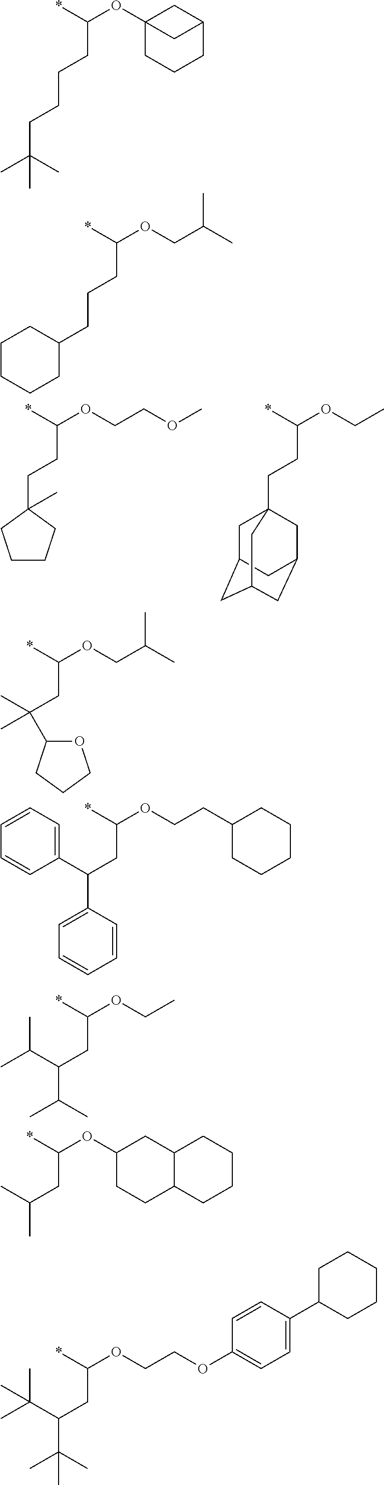

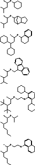

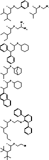

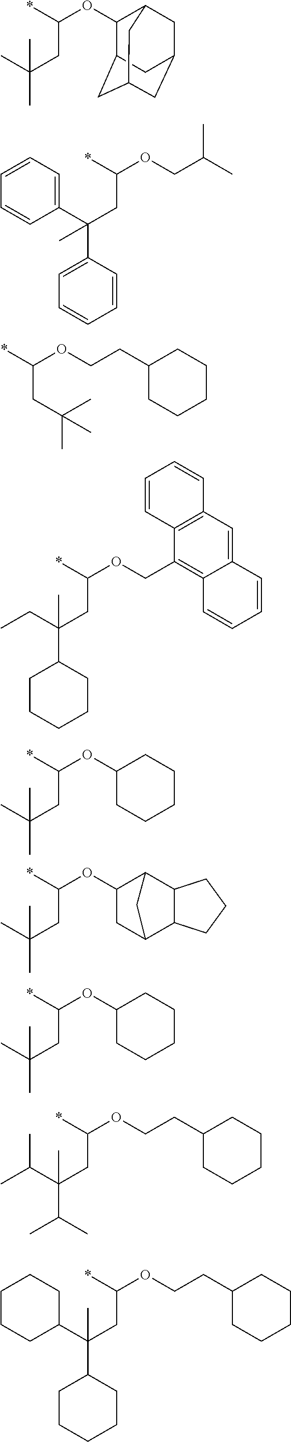

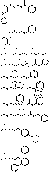

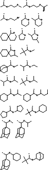

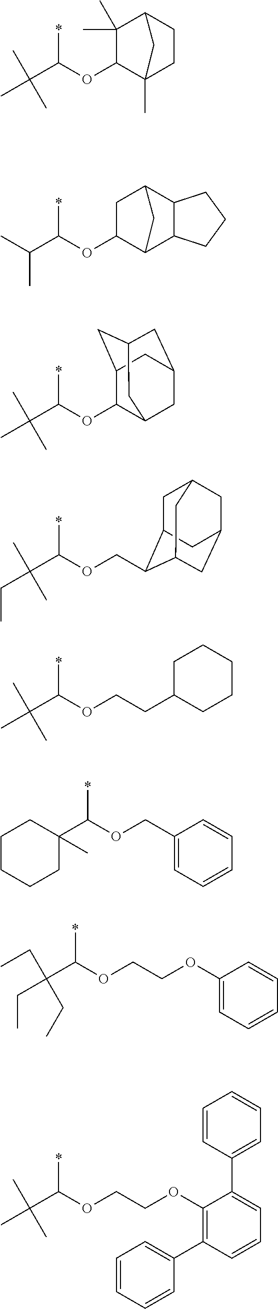

Specific examples of the repeating unit (a) represented by formula (I) are illustrated below, but the present invention is not limited thereto.

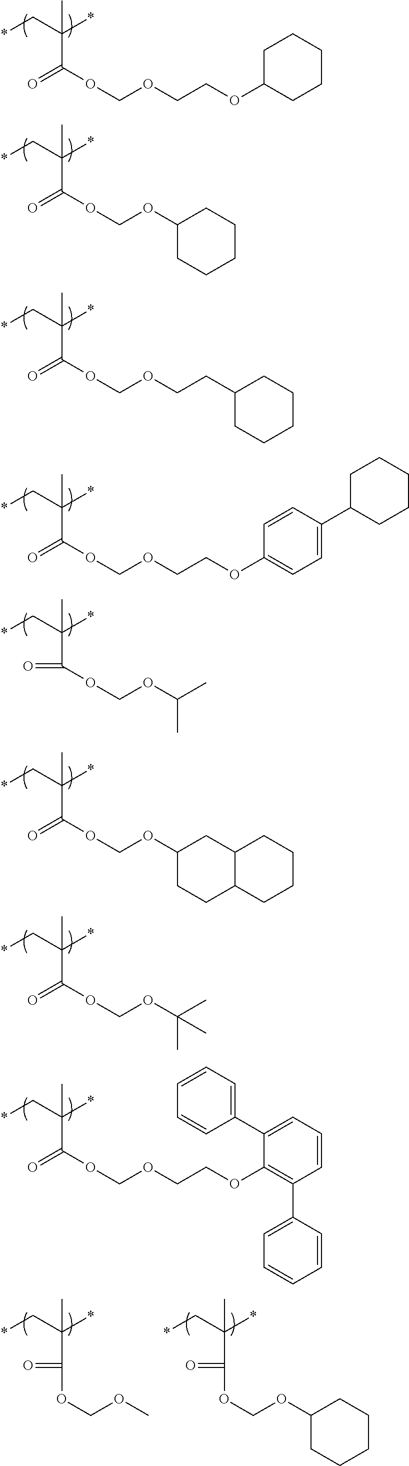

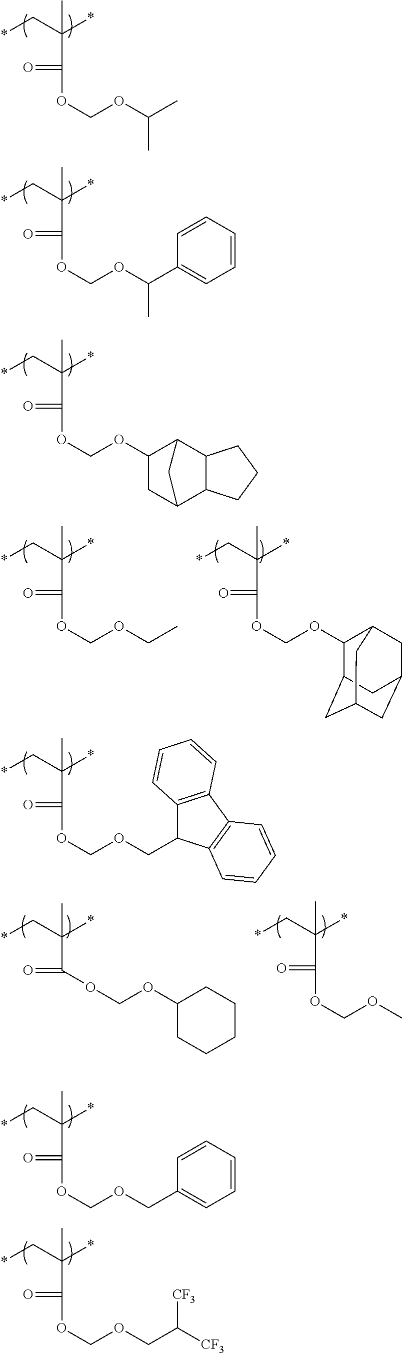

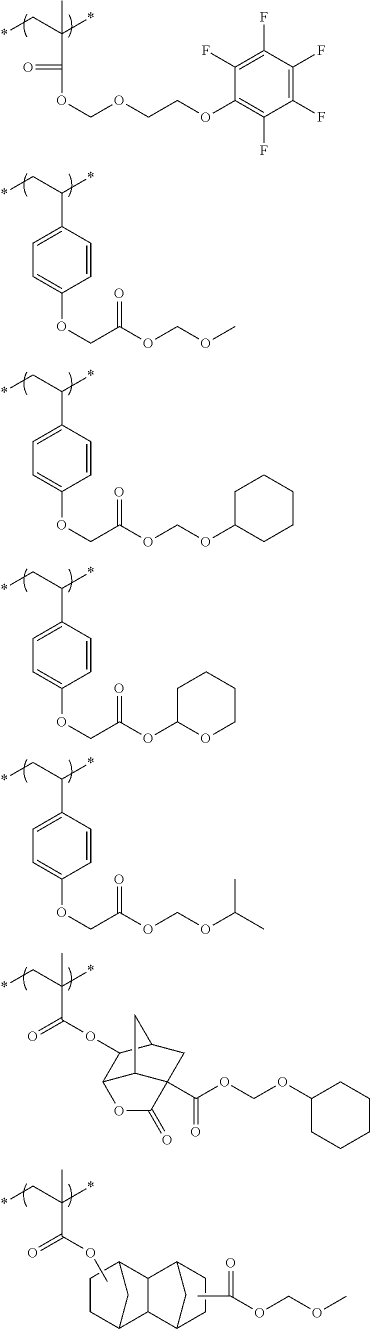

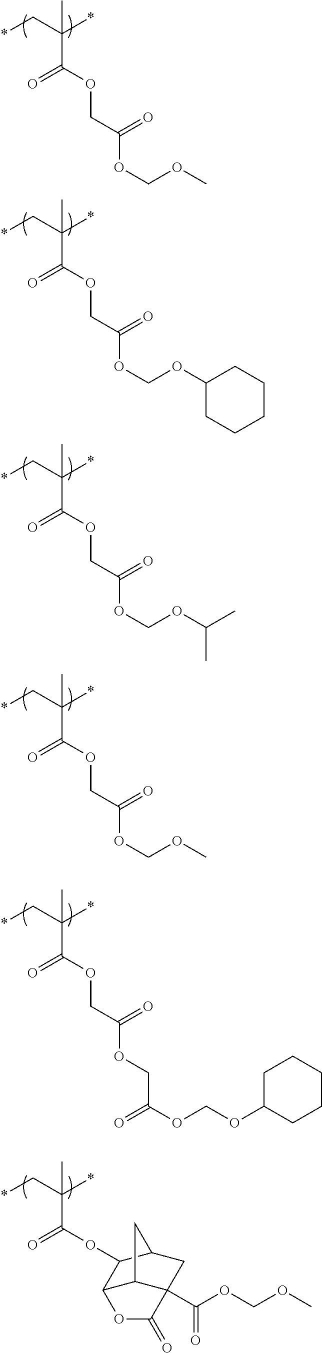

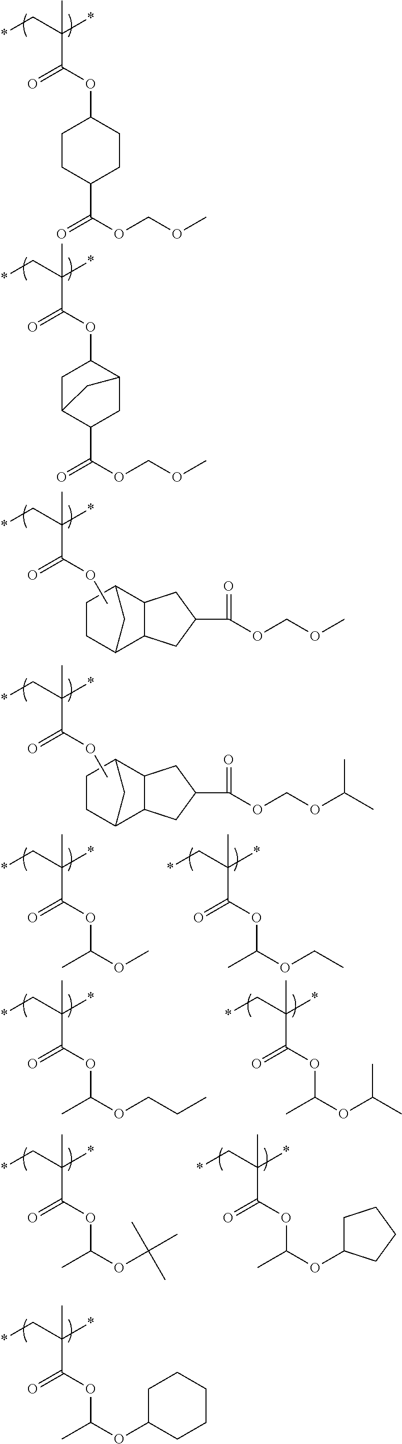

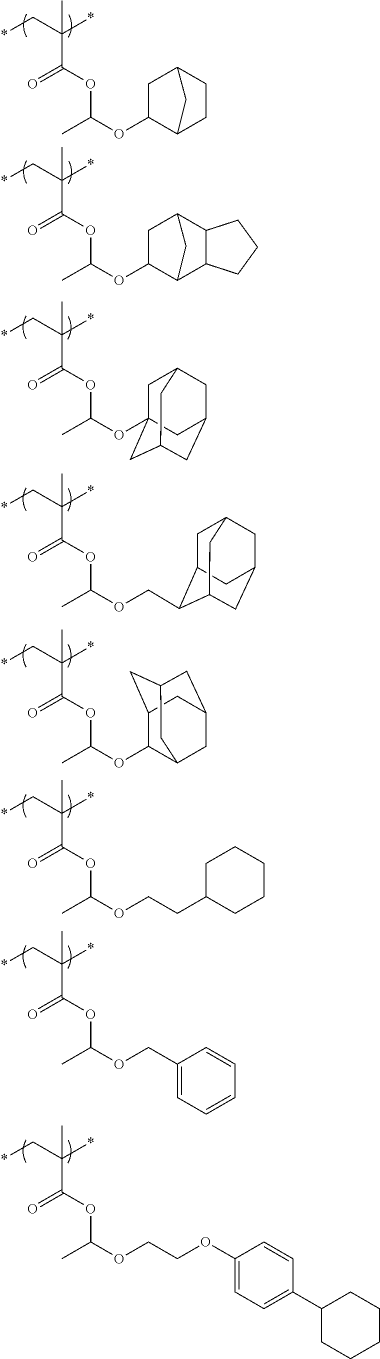

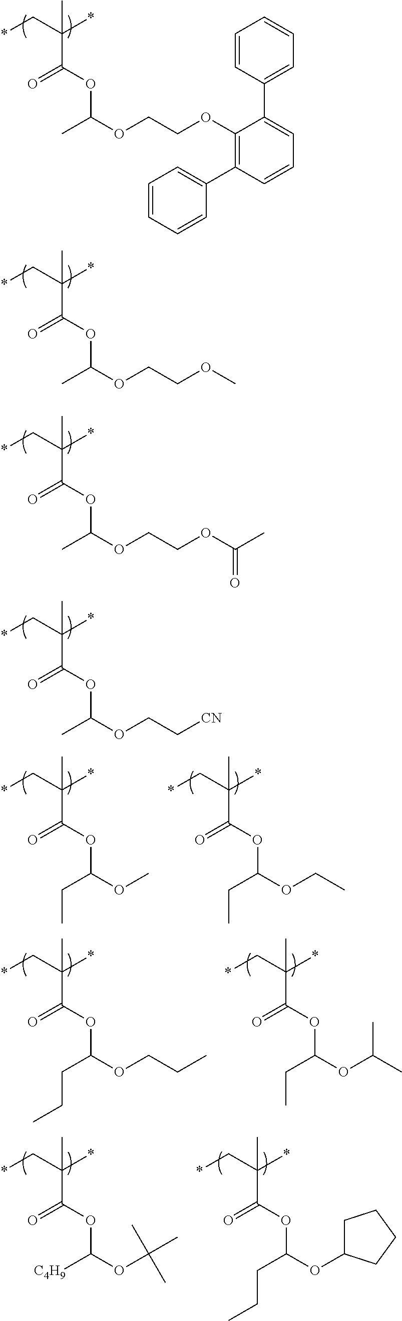

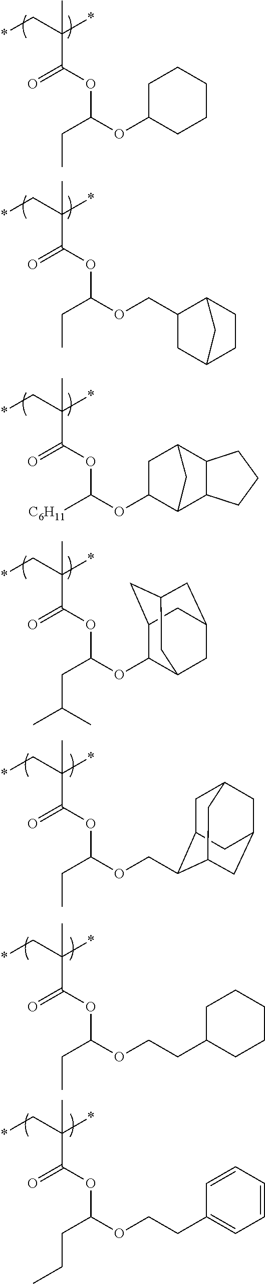

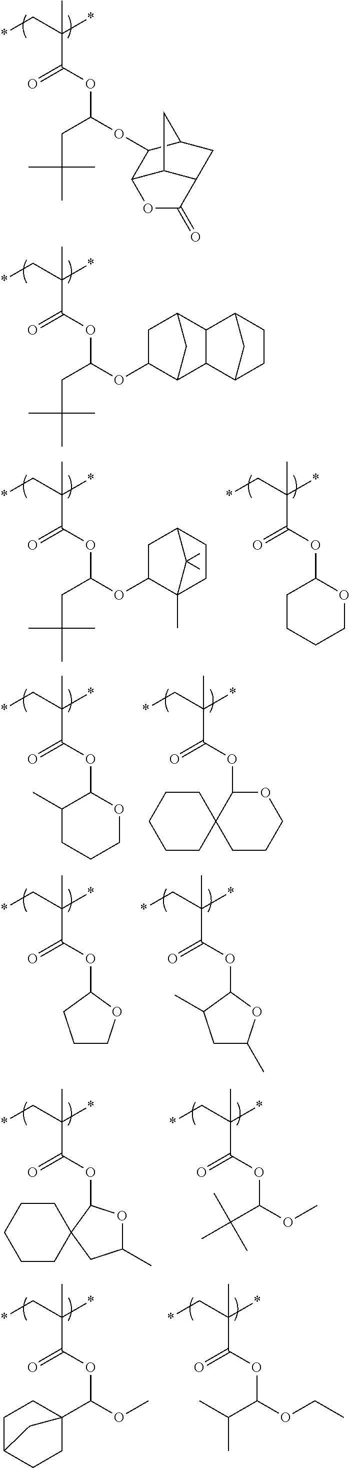

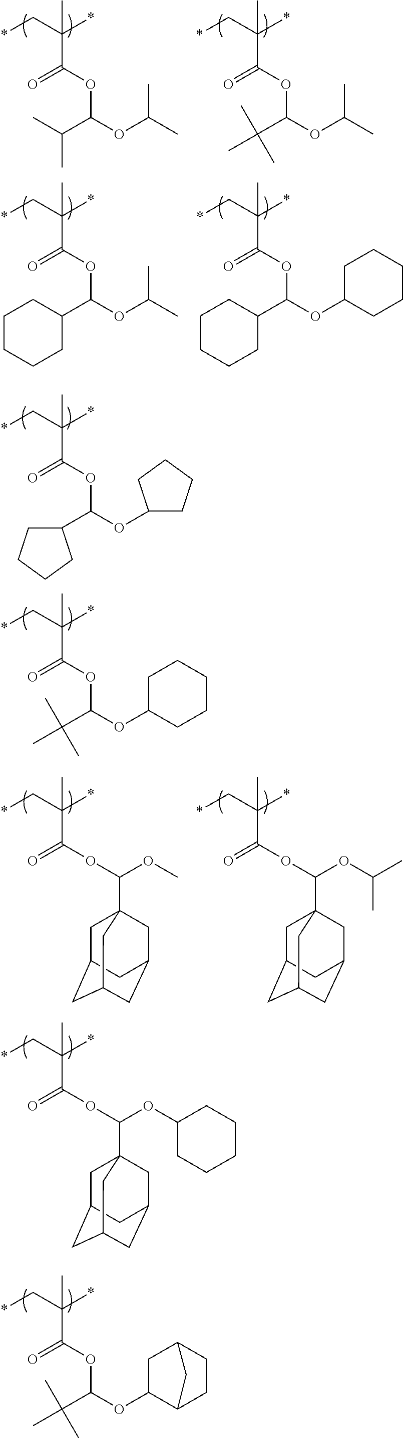

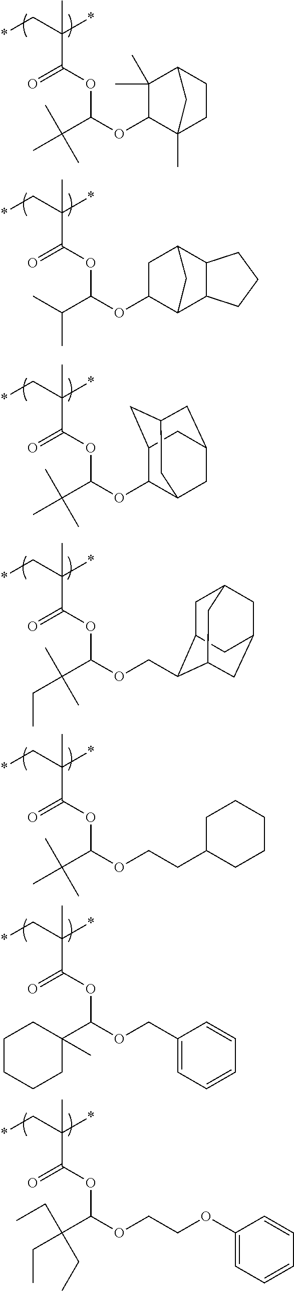

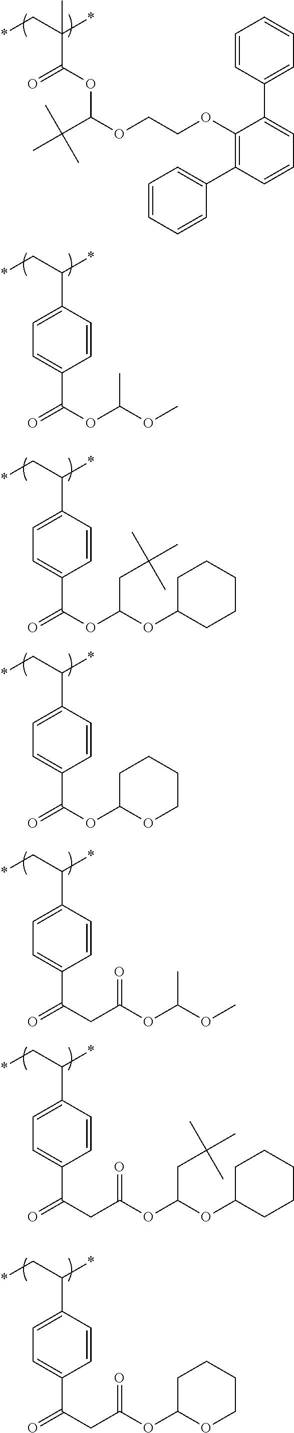

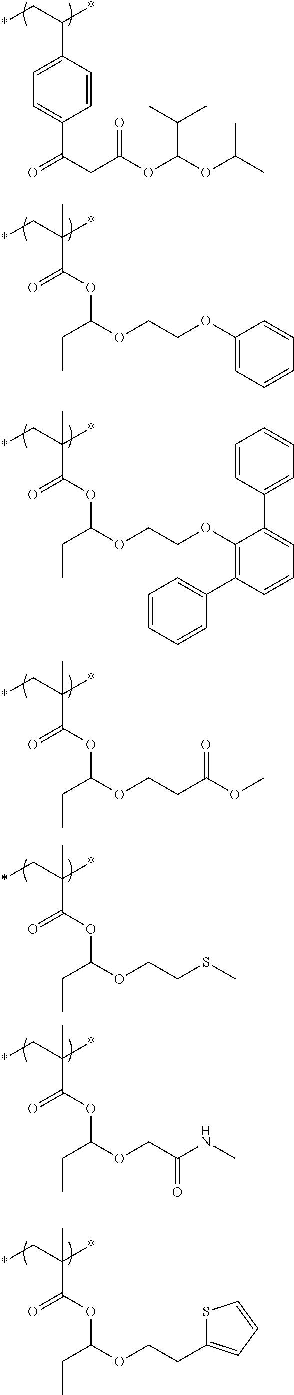

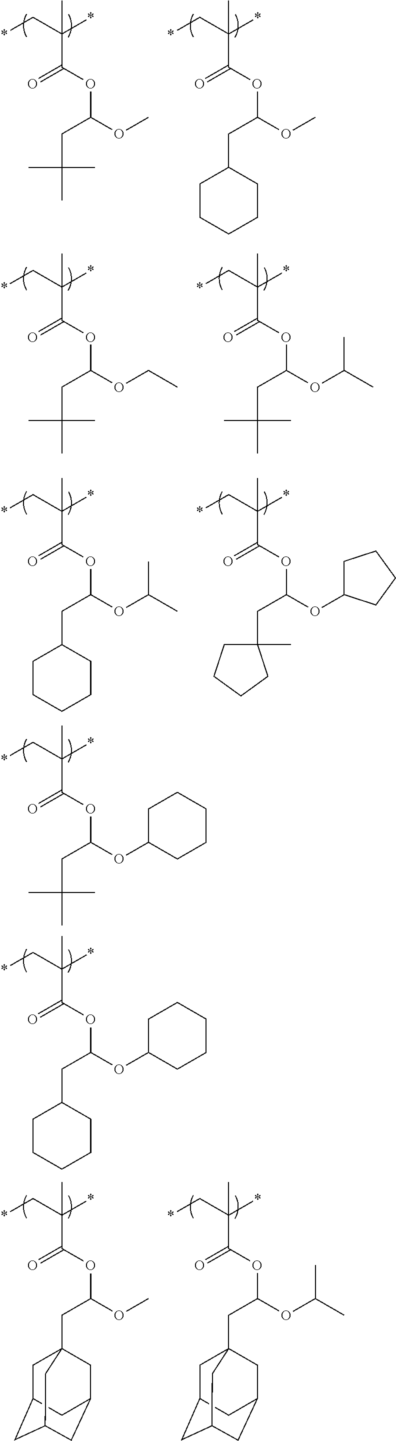

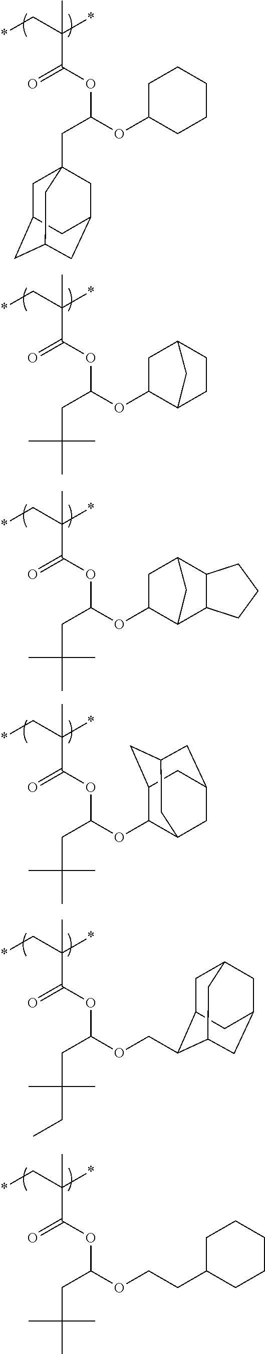

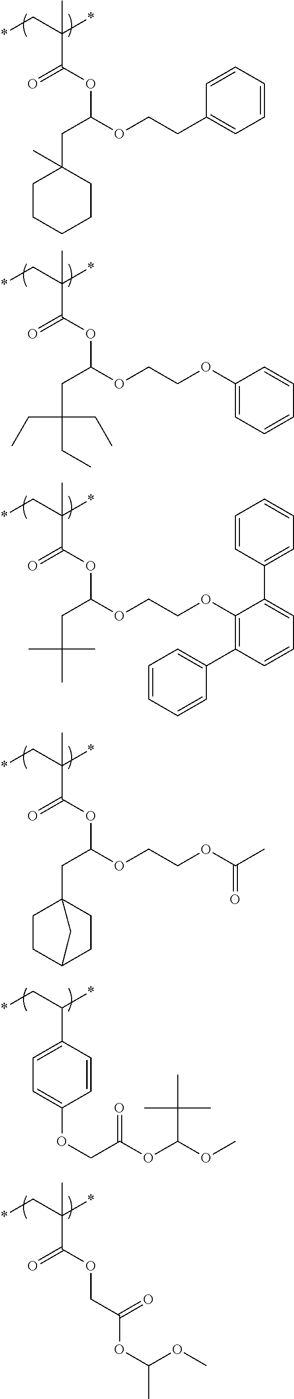

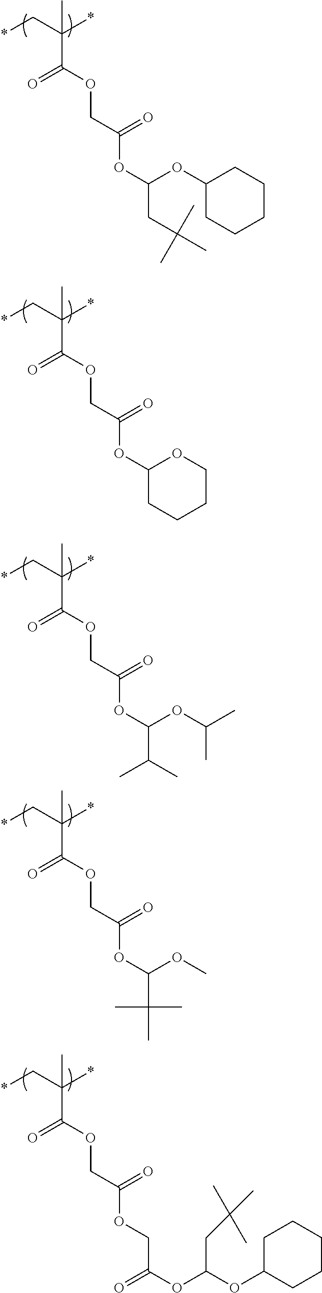

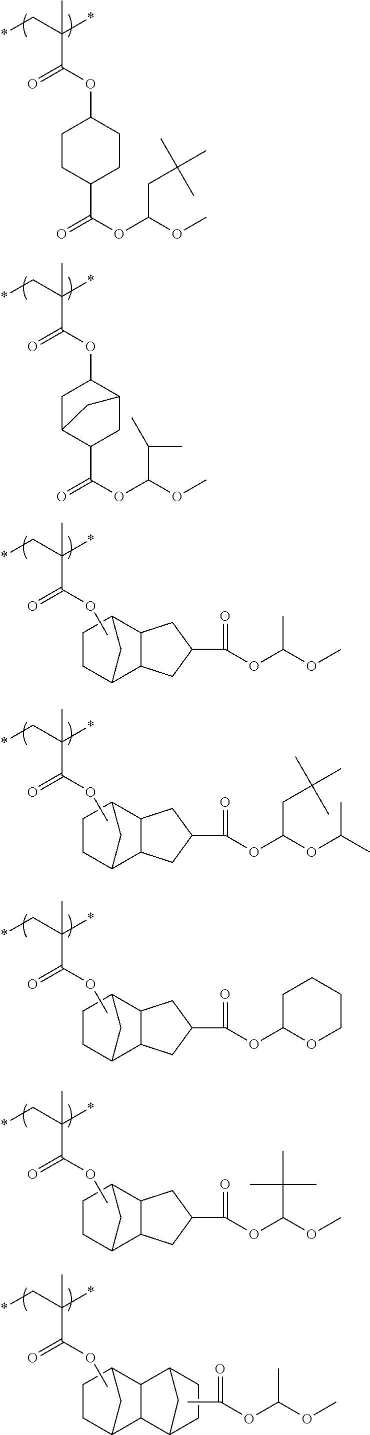

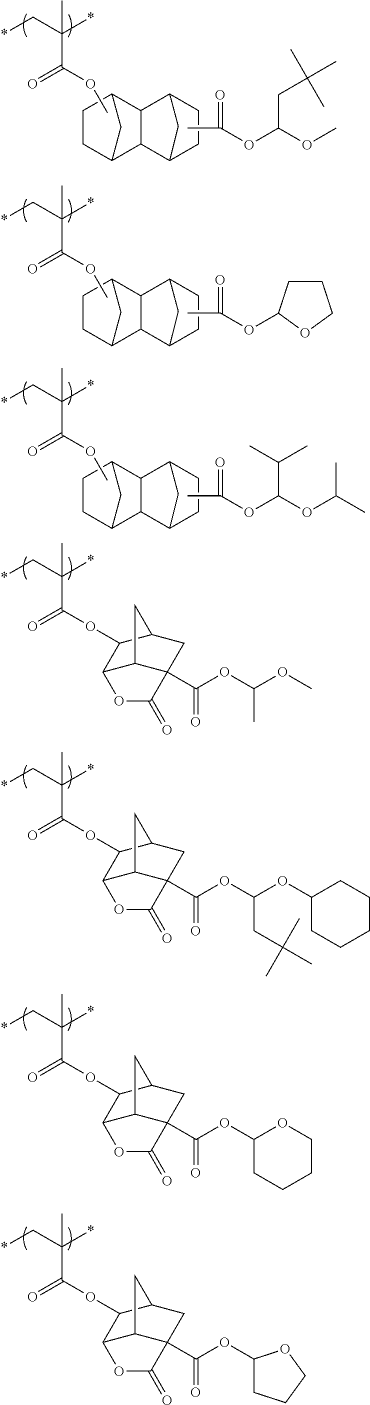

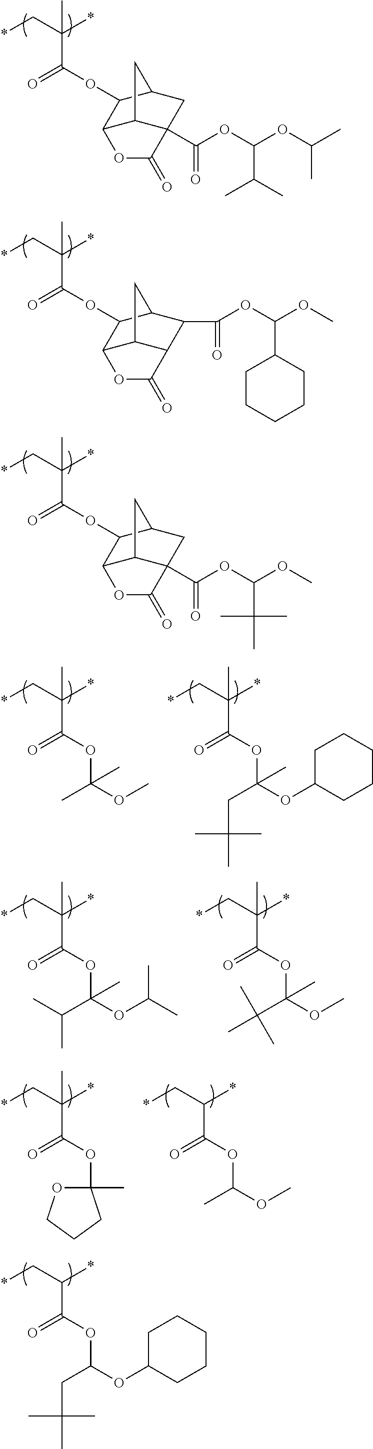

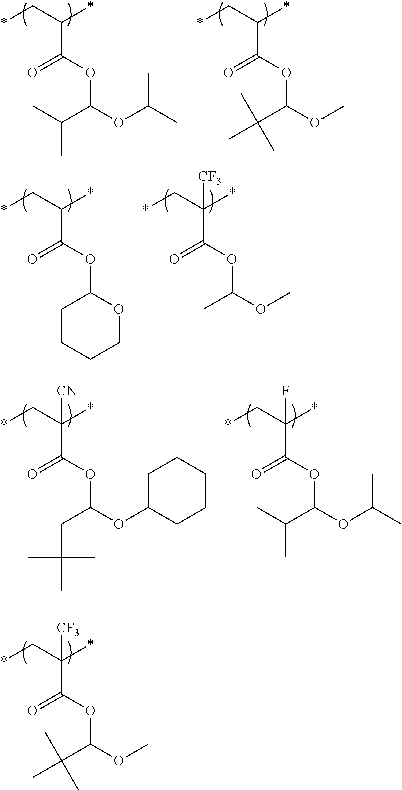

In the resin (P), as for the repeating unit represented by formula (I), one kind may be used, or two or more kinds may be used in combination.

The content of the repeating unit represented by formula (I) is 25 mol % or more, preferably from 25 to 100 mol %, more preferably from 30 to 80 mol %, still more preferably from 40 to 70 mol %, based on all repeating units in the resin (P). If the content of the repeating unit represented by formula (I) is less than 25 mol % based on all repeating units in the resin (P), the dissolution contrast of the resin (P) lowers, and the resolution is reduced.

From the standpoint of more unfailingly achieving the effects of the present invention, the resin (P) is preferably a resin containing a phenolic hydroxyl group-containing repeating unit represented by the following formula out of the later-described phenolic hydroxyl group-containing repeating units and a repeating unit represented by the following formula (1-2) or (1-3):

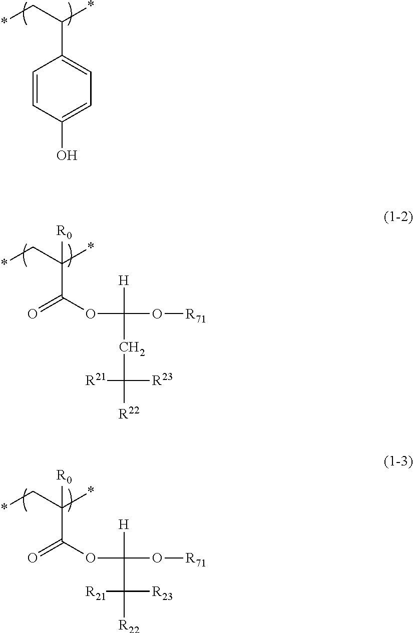

In formula (1-2), R₀ represents a hydrogen atom or a methyl group.

Each of R²¹ to R²³ independently represents a hydrogen atom, an alkyl group, a cycloalkyl group, an aryl group, an aralkyl group or a heterocyclic group, and each of at least two members of R²¹ to R²³ independently represents an alkyl group, a cycloalkyl group, an aryl group, an aralkyl group or a heterocyclic group.

At least two of R²¹ to R²³ may combine with each other to form a ring. However, R₇₁ represents an unsubstituted alkyl group, a cycloalkyl group-substituted alkyl group, a cycloalkyl group, an aralkyl group, an aryloxyalkyl group or a heterocyclic group.

Specific examples and preferred examples of each of the groups for R²¹ to R²³ are as described above.

The unsubstituted alkyl group, cycloalkyl group-substituted alkyl group, cycloalkyl group, aralkyl group, aryloxyalkyl group and heterocyclic group of R₇₁ are as described above for the group represented by -M¹-Q¹.

In formula (1-3), R₀, R²¹ to R²³ and R₇₁ have the same meanings as R₀, R²¹ to R²³ and R₇₁ in formula (1-2), and specific examples and preferred ranges thereof are also the same.

The resin (P) may contain a repeating unit having a phenolic hydroxyl group. The repeating unit having a phenolic hydroxyl group includes, for example, a repeating unit represented by the following formula (5) or (6), and a repeating unit represented by formula (5) is preferred.

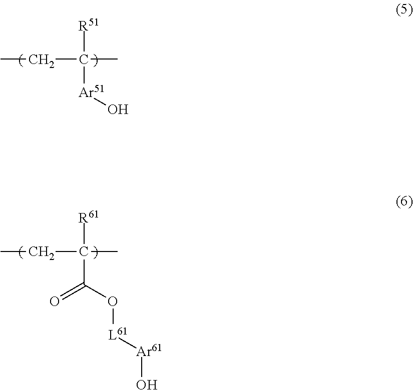

In formulae (5) and (6), each of R⁵¹ and R⁶¹ independently represents a hydrogen atom or a methyl group, and each of Ar⁵¹ and Ar⁶¹ independently represents an arylene group. L⁶¹ represents a single bond or an alkylene group.

R⁵¹ is preferably a hydrogen atom, and R⁶¹ is preferably a methyl group.

The arylene group represented by Ar⁵¹ and Ar⁶¹ may have a substituent. The arylene group is preferably an arylene group having a carbon number of 6 to 18, which may have a substituent, more preferably a phenylene or naphthylene group which may have a substituent, and most preferably a phenylene group which may have a substituent. Examples of the substituent which may be substituted on such a group include an alkyl group, a halogen atom, a hydroxyl group, an alkoxy group, a carboxyl group, and an alkoxycarbonyl group.

As described above, L⁶¹ represents a single bond or an alkylene group. The alkylene group is preferably an alkylene group having a carbon number of 1 to 8, more preferably an alkylene group having a carbon number of 1 to 4, and examples thereof include a methylene group, an ethylene group, a propylene group, a butylene group, a hexylene group and an octylene group, with a methylene group and an ethylene group being preferred.

Specific examples of the repeating unit represented by formula (5) are illustrated below, but the present invention is not limited thereto.

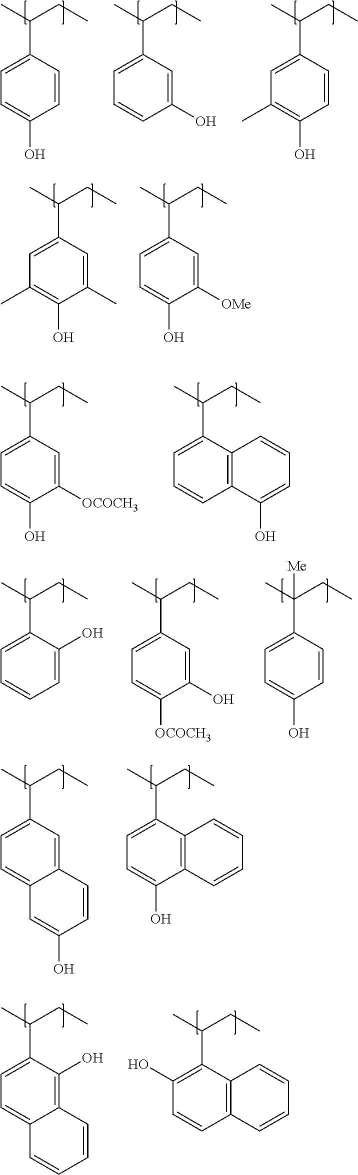

Specific examples of the repeating unit represented by formula (6) are illustrated below, but the present invention is not limited thereto.

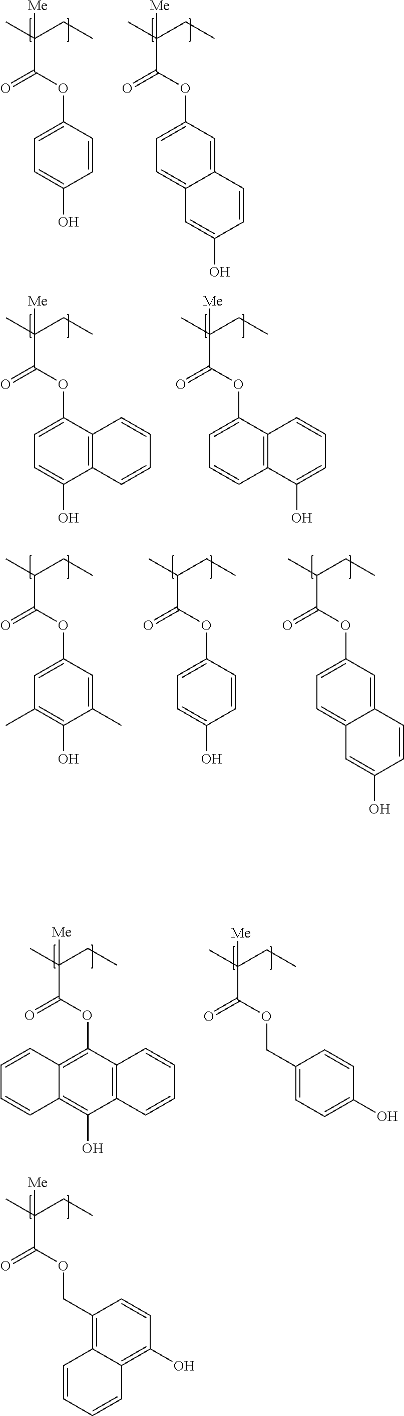

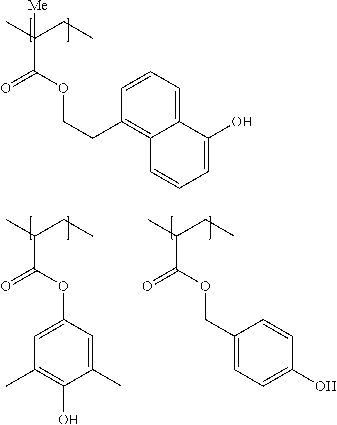

The resin (P) may or may not contain a repeating unit having a phenolic hydroxyl group, but in the case where the resin (P) contains a repeating unit having a phenolic hydroxyl group, the content of the repeating unit having a phenolic hydroxyl group (preferably the repeating unit represented by formula (5) or (6)) in the resin (P) is preferably from 10 to 70 mol %, more preferably from 15 to 65 mol %, still more preferably from 20 to 60 mol %, based on all repeating units in the resin (P).

The resin (P) may contain a repeating unit represented by the following formula (B):

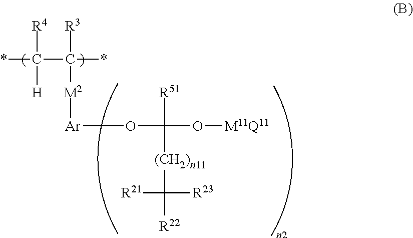

In formula (B), R⁵¹, R²¹, R²², R²³, M¹¹, Q¹¹ and n11 have the same meanings as R¹, R²¹, R²², R²³, M¹, Q¹ and n1 in formula (I), respectively, and each of at least two members of R²¹ to R²³ independently represents an alkyl group, a cycloalkyl group, an aryl group, an aralkyl group or a heterocyclic group.

At least two of R²¹ to R²³ may combine with each other to form a ring, provided that it is not allowed to form a ring by combining at least one of R²¹ to R²³ with M¹¹ or Q¹¹.

When M¹¹ is a divalent linking group, Q¹¹ may combine with M¹¹ through a single bond or another linking group to form a ring.

R³ represents a hydrogen atom or an alkyl group.

R⁴ represents a hydrogen atom or an alkyl group. R⁴ and M² or Ar may combine with each other to form a ring, and in this case, R⁴ represents an alkylene group.

M² represents a single bond or a divalent linking group and in the case of combining with R⁴ to form a ring, represents a trivalent linking group.

Ar represents an (n2+1)-valent aromatic ring group and in the case of combining with R⁴ to form a ring, represents an (n2+2)-valent aromatic ring group.

n2 represents an integer of 1 to 5.

When n2 is an integer of 2 or more, each of n2 groups in the parentheses may be the same as or different from every other group.

Specific examples and preferred examples of R⁵¹, R²¹, R²², R²³, M¹¹, Q¹¹ and n11 are the same as those described for R¹, R²¹, R²², R²³, M¹, Q¹ and n1 in formula (I).

The alkyl group of R³ and R⁴ may have a substituent (preferably a fluorine atom) and is preferably an alkyl group having a carbon number of 1 to 5, more preferably an alkyl group having a carbon number of 1 to 3, still more preferably a methyl group or a trifluoromethyl group.

Each of R³ and R⁴ is independently preferably a hydrogen atom, a methyl group or a trifluoromethyl group, more preferably a hydrogen atom.

At least either one of R³ and R⁴ is preferably a hydrogen atom, and it is more preferred that both are a hydrogen atom.

The alkylene group of R⁴ when R⁴ and M² or Ar combine with each other to form a ring is preferably an alkylene group having a carbon number of 1 to 3, more preferably an alkylene group having a carbon number of 1 or 2.

The divalent linking group as M² is preferably an alkylene group, —O—, —CO—, —N(R₀)—, or a group formed by combining two or more thereof. R₀ in —N(R₀)— is a hydrogen atom or an alkyl group (for example, an alkyl group having a carbon number of 1 to 8, and specific examples thereof include a methyl group, an ethyl group, a propyl group, an n-butyl group, a sec-butyl group, a hexyl group, and an octyl group).

Specific examples of the divalent linking group include —COO—, —COOCH₂—, —COO—CH₂—CH₂—, —O—, and —CONH—.

M² is preferably a single bond or —COO—.

Ar represents an (n2+1)-valent aromatic ring group. The divalent aromatic ring group when n2 is 1 may have a substituent, and preferred examples of the aromatic ring group include an arylene group having a carbon number of 6 to 18 (more preferably a carbon number of 6 to 10) such as phenylene group, tolylene group and naphthylene group, and a divalent aromatic ring group containing a heterocyclic ring such as thiophene, furan, pyrrole, benzothiophene, benzofuran, benzopyrrole, triazine, imidazole, benzimidazole, triazole, thiadiazole and thiazole.

Specific preferred examples of the (n2+1)-valent aromatic ring group when n2 is an integer of 2 or more include groups formed by removing arbitrary (n2−1) hydrogen atoms from the above-described specific examples of the divalent aromatic ring group.

Specific preferred examples of the (n2+2)-valent aromatic ring group as Ar when Ar combines with R⁴ to form a ring include groups formed by removing arbitrary n2 hydrogen atoms from the above-described specific examples of the divalent aromatic ring group.

Specific examples of the substituent which the alkylene group of R⁴ and M² may have include a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group.

Specific examples of the substituent which each group of Ar may have include the above-described specific examples of the substituent which the alkyl group and the alkylene group of R⁴ and M² may have.

The carbon number of the substituent which the alkylene group of R⁴ and M² may have and the carbon number of the substituent which each group of Ar may have are preferably 8 or less.

n2 is preferably an integer of 1 to 3, more preferably 1.

Specific examples of the repeating unit represented by formula (B) are illustrated below, but the present invention is not limited thereto. In the following specific examples, * in the group represented by P indicates a bond connected to the oxygen atom in a phenolic hydroxyl group.

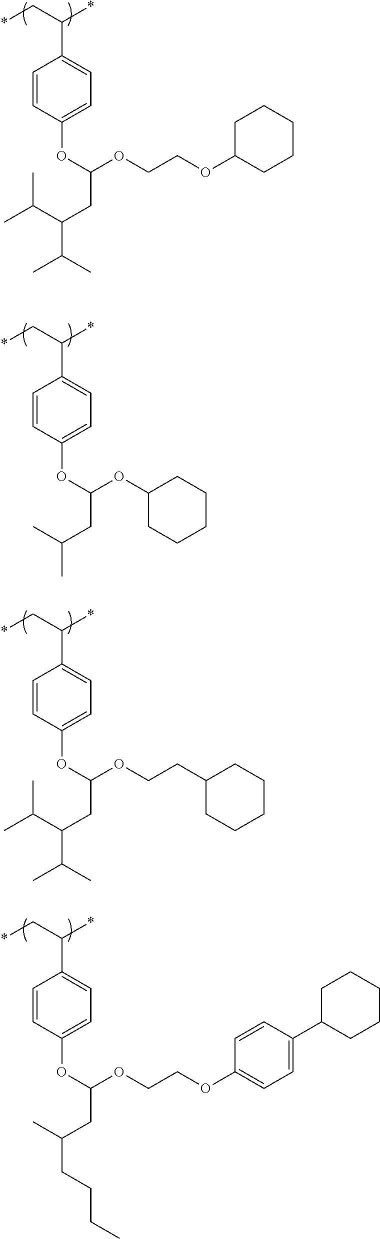

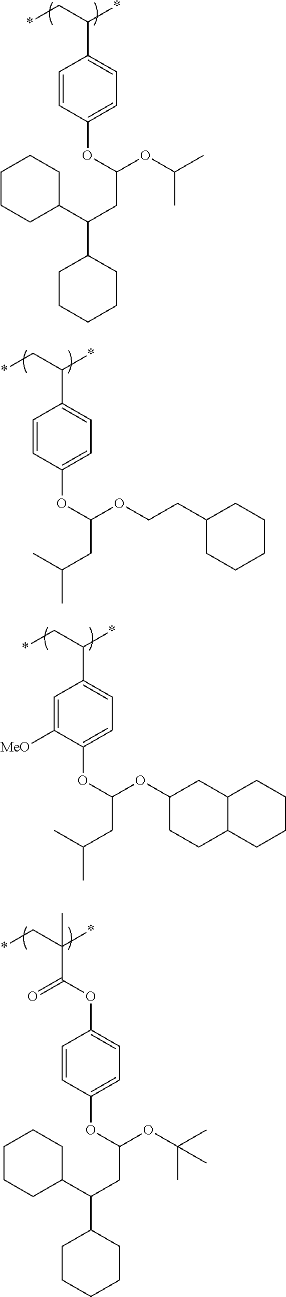

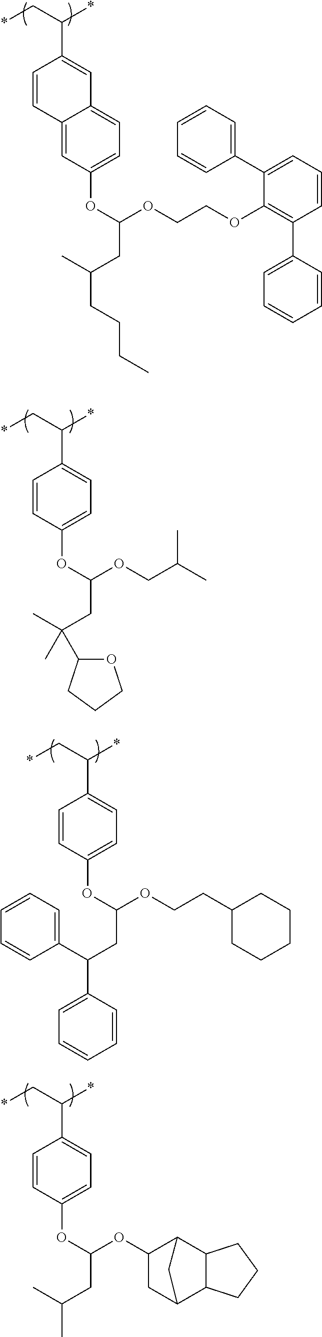

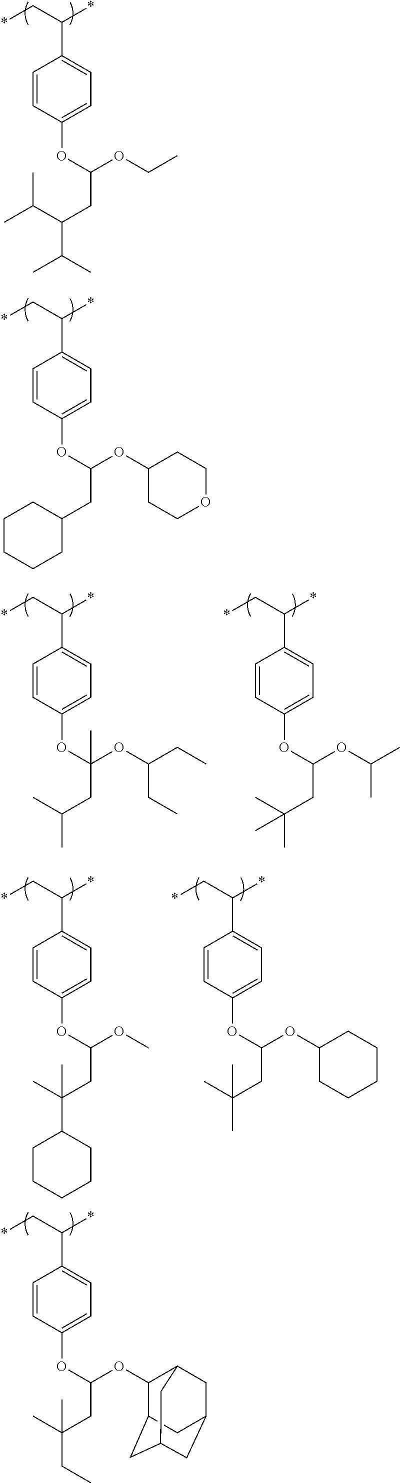

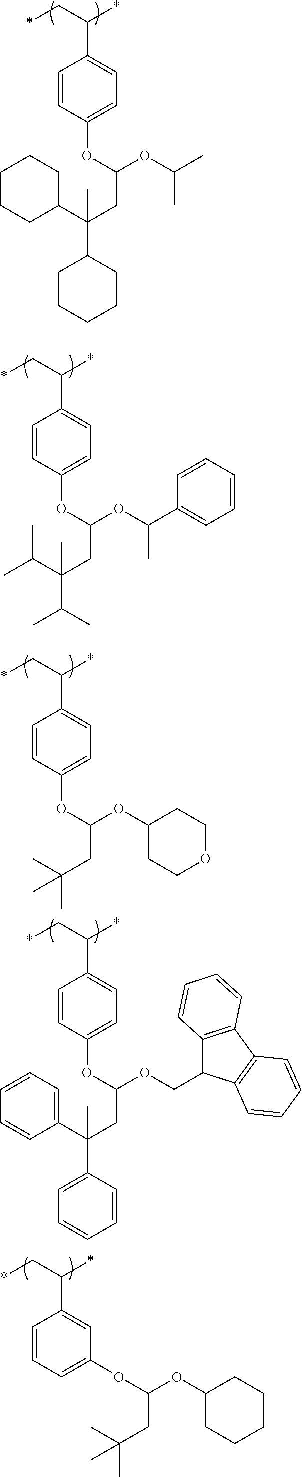

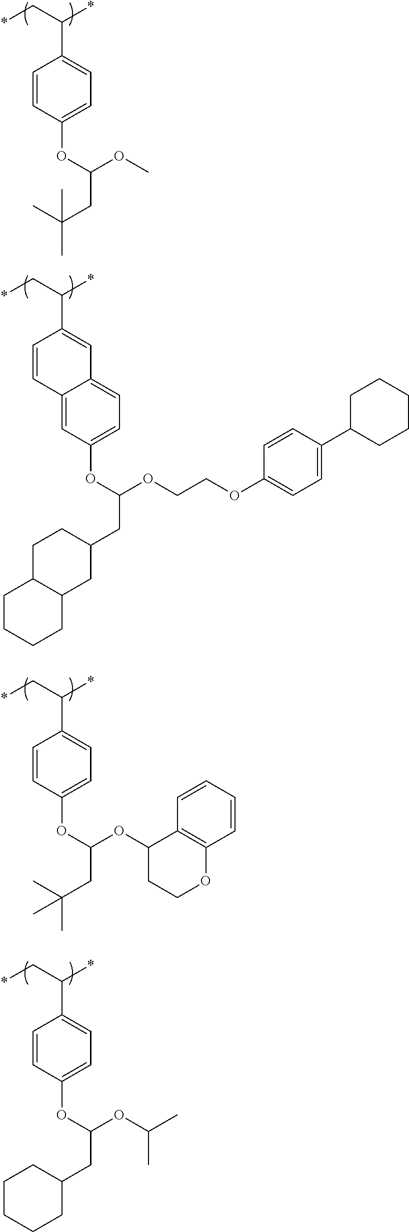

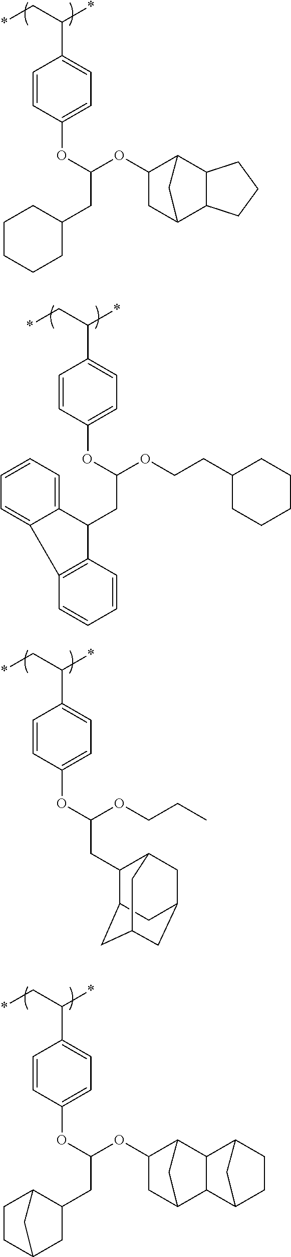

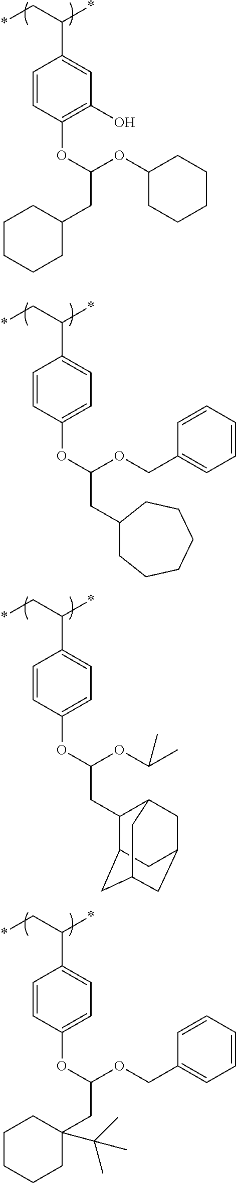

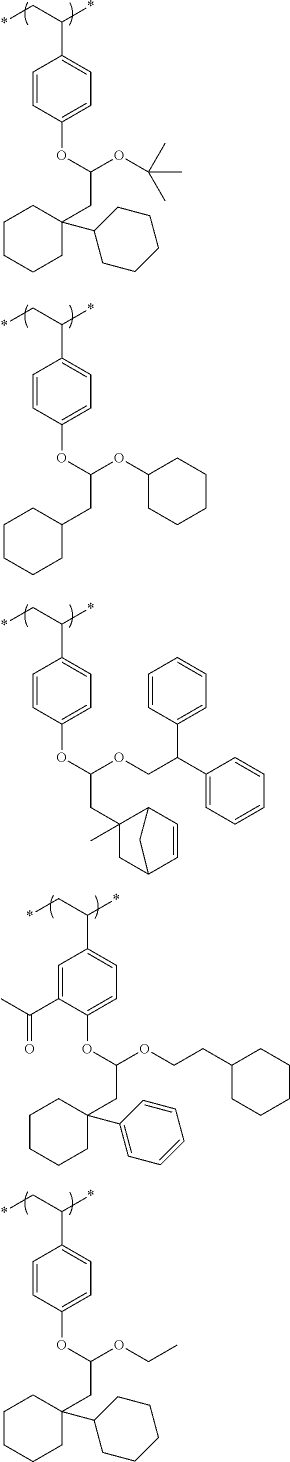

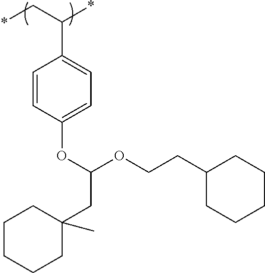

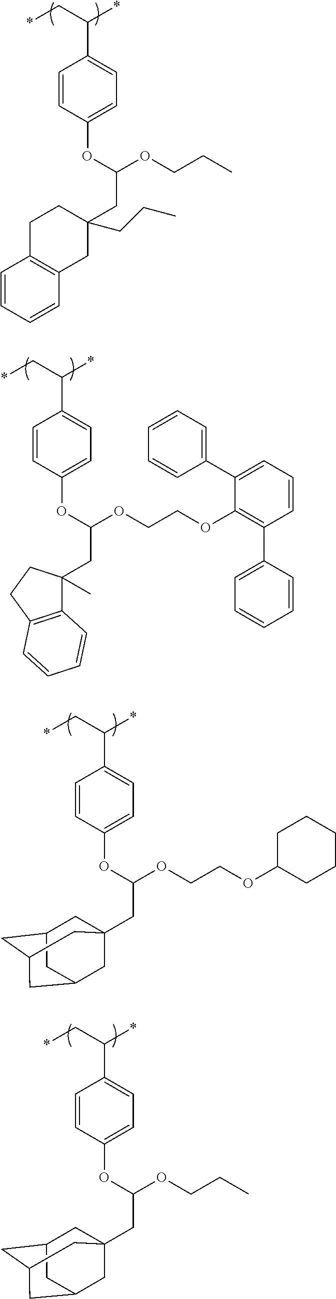

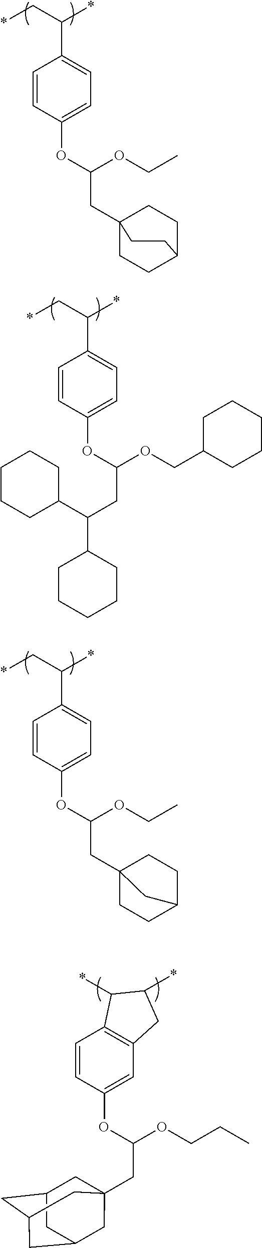

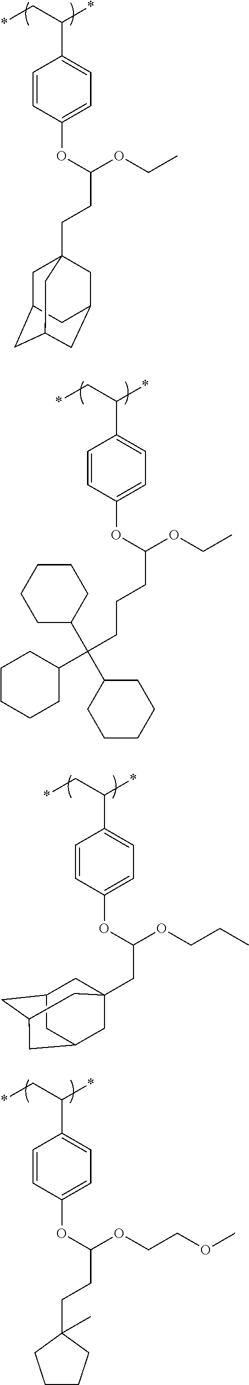

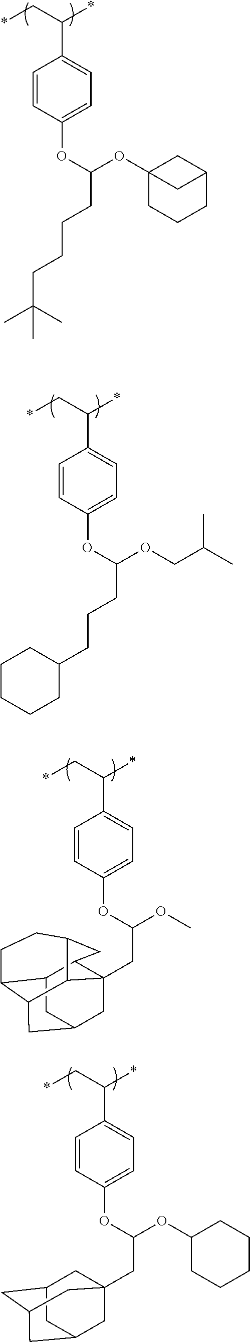

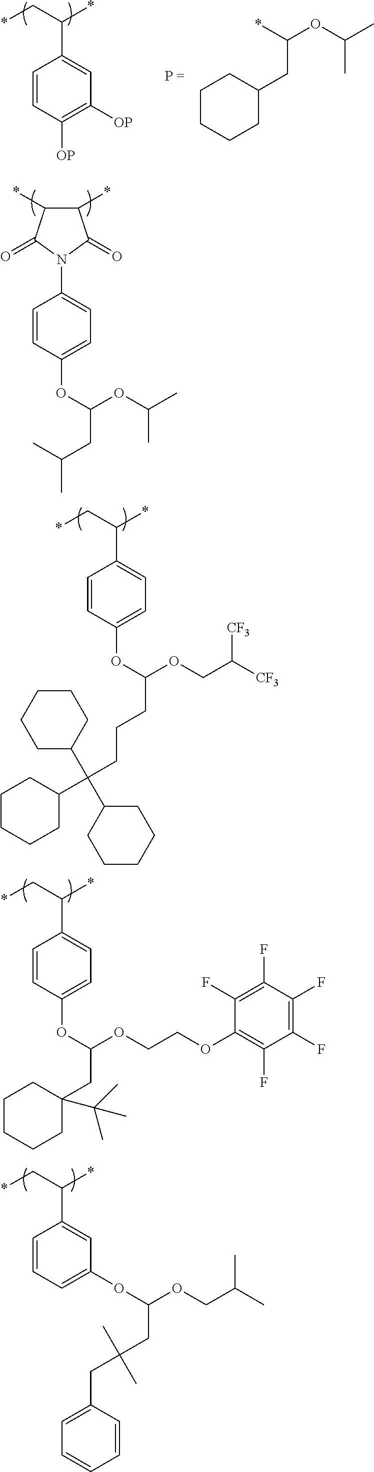

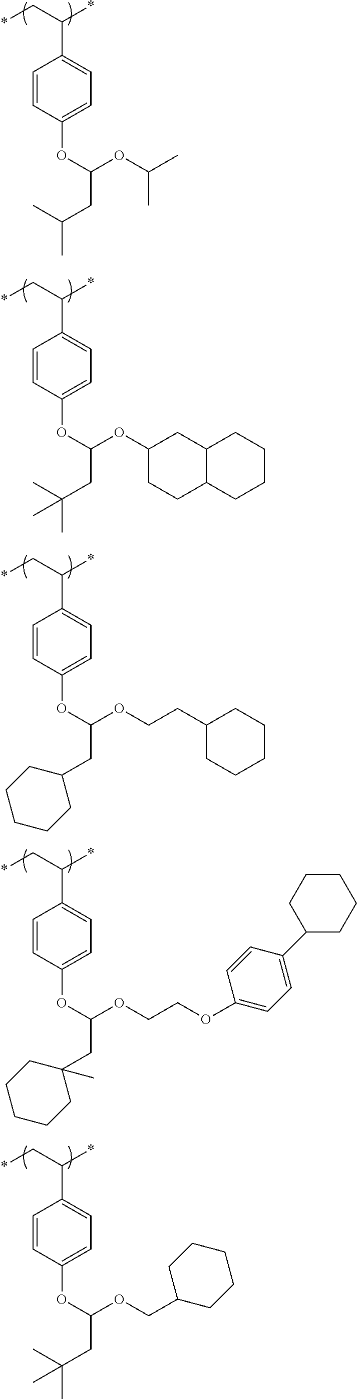

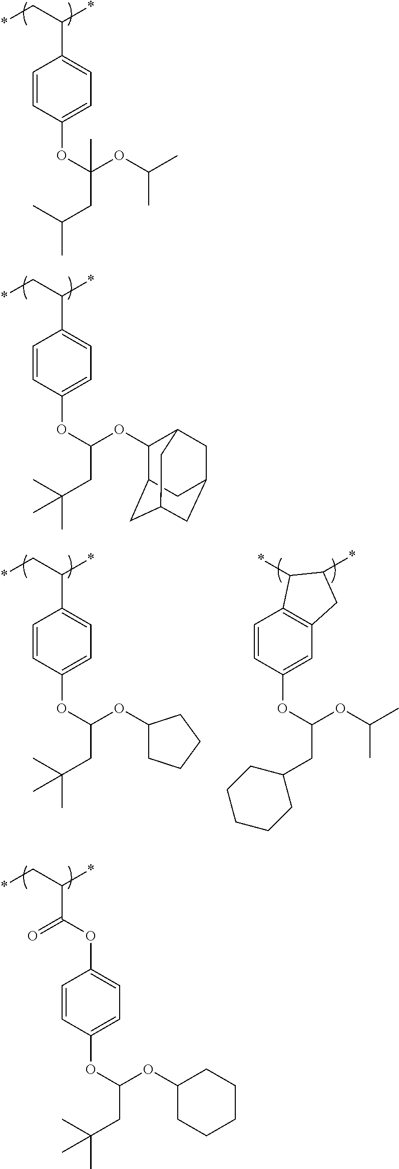

As for the repeating unit represented by formula (B), one repeating may be used or two or more repeating units may be used in combination, but it is preferred to use one repeating unit.

The resin (P) may or may not contain a repeating unit represented by formula (B), but in the case where the resin (P) contains a repeating unit represented by formula (B), the content of the repeating unit represented by formula (B) in the resin (P) is preferably from 1 to 40 mol %, more preferably from 3 to 30 mol %, still more preferably from 5 to 20 mol %, based on all repeating units in the resin (P).

The resin (P) may contain a repeating unit represented by the following formula (C):

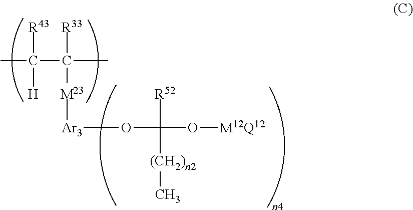

In formula (C), R⁵² represents a hydrogen atom or an alkyl group.

R³³ represents a hydrogen atom or an alkyl group.

R⁴³ represents a hydrogen atom or an alkyl group. R⁴³ and M²³ or Ar₃ may combine with each other to form a ring, and in this case, R⁴³ represents an alkylene group.

M²³ represents a single bond or a divalent linking group and in the case of combining with R⁴³ to form a ring, represents a trivalent linking group.

Ar₃ represents an (n4+1)-valent aromatic ring group and in the case of combining with R⁴³ to form a ring, represents an (n4+2)-valent aromatic ring group.

M¹² represents a single bond or a divalent linking group.

Q¹² represents an alkyl group, a cycloalkyl group, an aryl group or a heterocyclic group.

When M¹² is a divalent linking group, Q¹² may combine with M¹² through a single bond or another linking group to form a ring.

n2 represents an integer of 0 or more.

n4 represents an integer of 1 or more.

Specific examples and preferred ranges of Ar₃, M²³, R³³ and R⁴³ are the same as those described for Ar, M², R³ and R⁴ in formula (B).

Specific examples and preferred ranges of R⁵², M¹², Q¹² and n4 are the same as those described for R⁵¹, M¹¹, Q¹¹ and n2 in formula (B).

n2 is preferably an integer of 0 to 5, more preferably an integer of 0 to 1, still more preferably 0.

Specific examples of the repeating unit represented by formula (C) are illustrated below, but the present invention is not limited thereto.

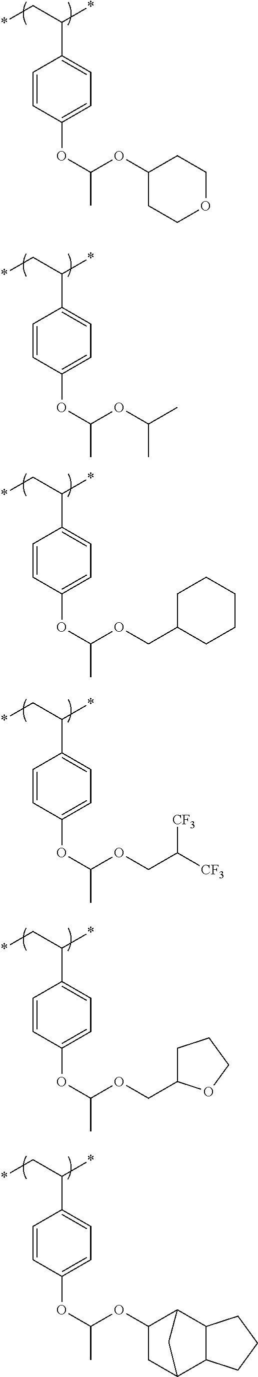

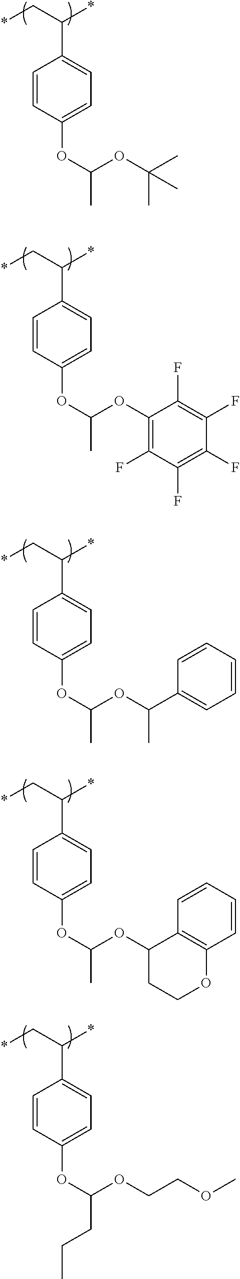

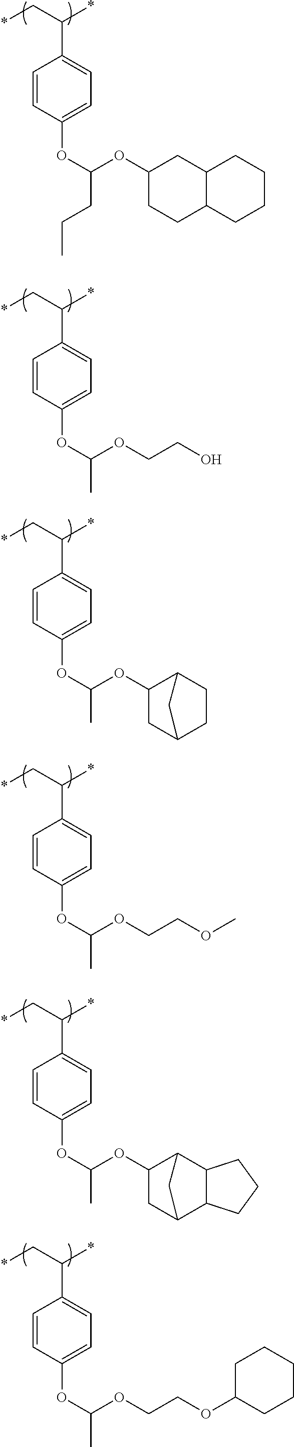

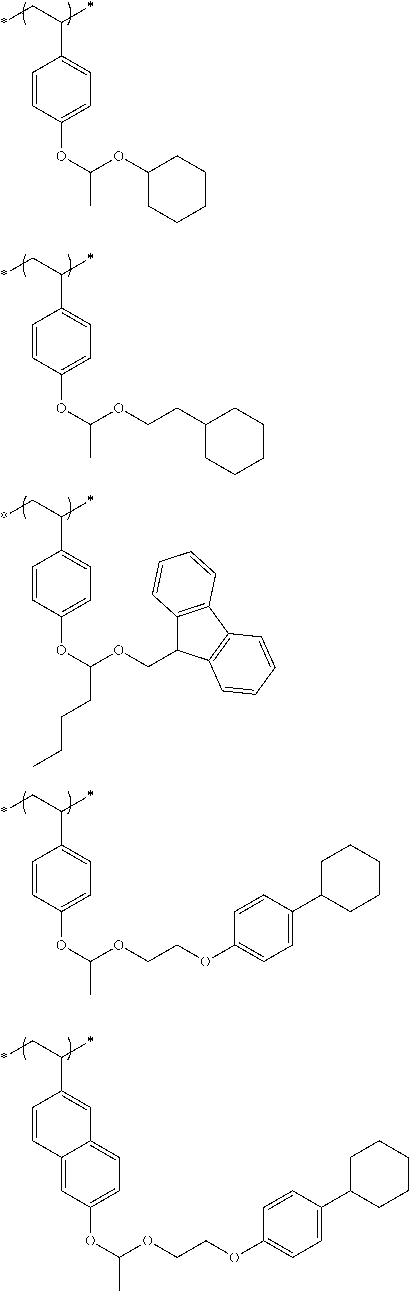

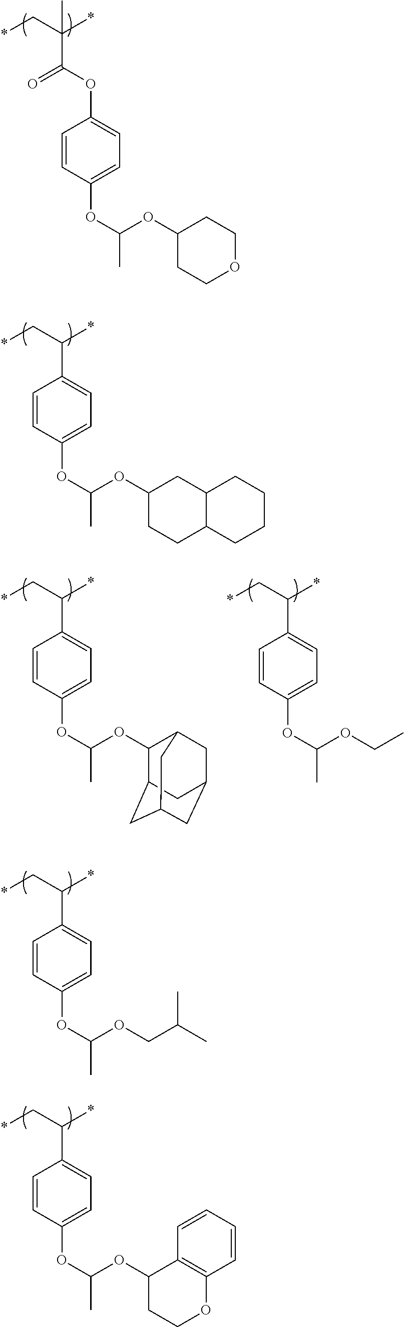

The resin (P) may or may not contain a repeating unit represented by formula (C), but in the case where the resin (P) for use in the present invention contains a repeating unit represented by formula (C), the repeating unit represented by formula (C) is preferably present in a ratio of 1 to 40 mol %, more preferably from 3 to 30 mol %, still more preferably from 5 to 20 mol %, based on all repeating units in the resin (P).

The resin (P) may contain a repeating unit represented by the following formula (D):

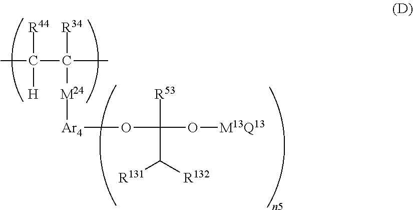

In formula (D), R⁵³ represents a hydrogen atom or an alkyl group.

Each of R¹³¹ and R¹³² independently represents an alkyl group, a cycloalkyl group, an aryl group, an aralkyl group or a heterocyclic group, and R¹³¹ and R¹³² may combine with each other to form a ring.

R³⁴ represents a hydrogen atom or an alkyl group.

R⁴⁴ represents a hydrogen atom or an alkyl group. R⁴⁴ and M²⁴ or Ar₄ may combine with each other to form a ring, and in this case, R⁴⁴ represents an alkylene group.

M²⁴ represents a single bond or a divalent linking group and in the case of combining with R⁴⁴ to form a ring, represents a trivalent linking group.

Ar₄ represents an (n5+1)-valent aromatic ring group and in the case of combining with R⁴⁴ to form a ring, represents an (n5+2)-valent aromatic ring group.

M¹³ represents a single bond or a divalent linking group.

Q¹³ represents an alkyl group, a cycloalkyl group, an aryl group or a heterocyclic group.

When M¹³ is a divalent linking group, Q¹³ may combine with M¹³ through a single bond or another linking group to form a ring.

n5 represents an integer of 1 or more.

Specific examples and preferred ranges of Ar₄, M²⁴, R³⁴ and R⁴⁴ are the same as those described for Ar, M², R³ and R⁴ in formula (B).

Specific examples and preferred ranges of R⁵³, R¹³¹, R¹³², M¹³, Q¹³ and n5 are the same as those described for R⁵¹, R²¹ to R²³, M¹¹, Q¹¹ and n2 in formula (B).

Specific examples of the repeating unit represented by formula (D) are illustrated below, but the present invention is not limited thereto.

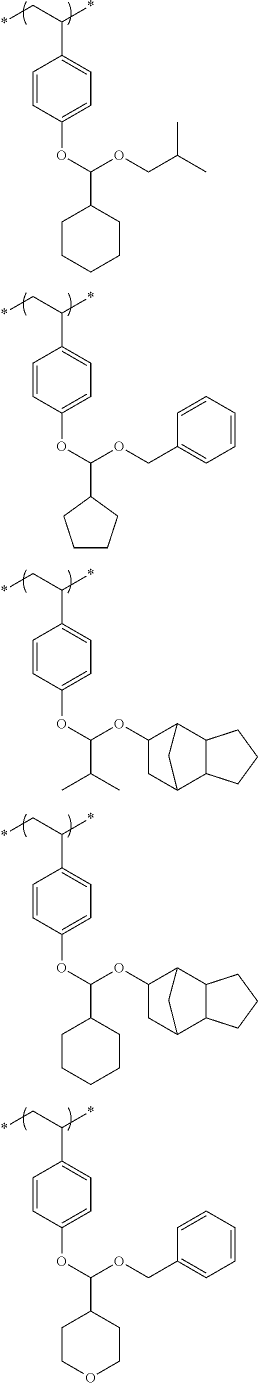

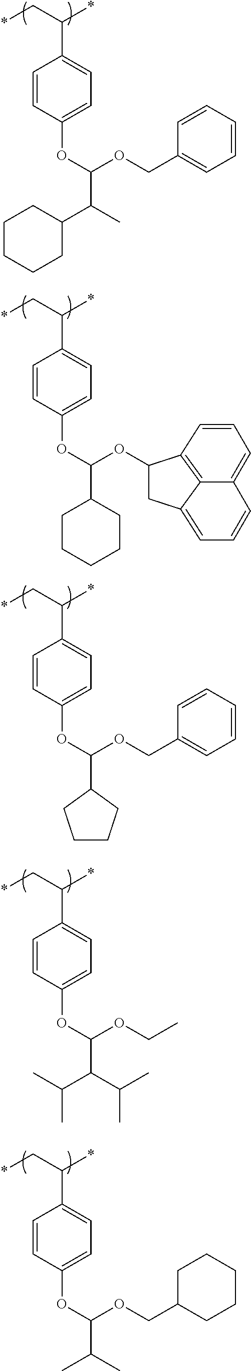

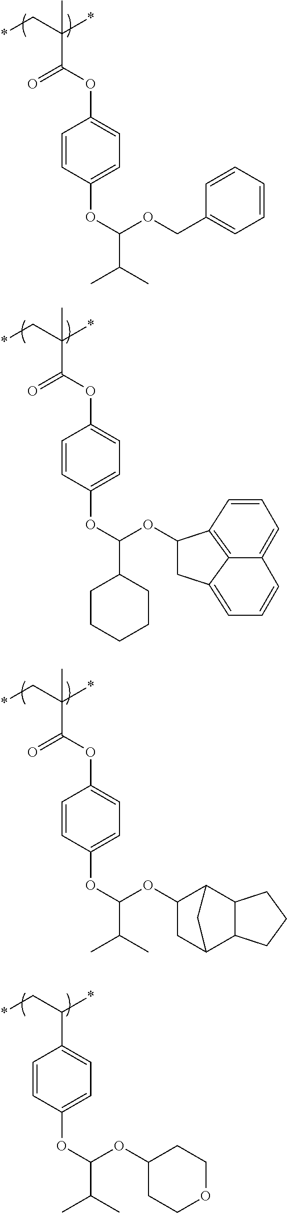

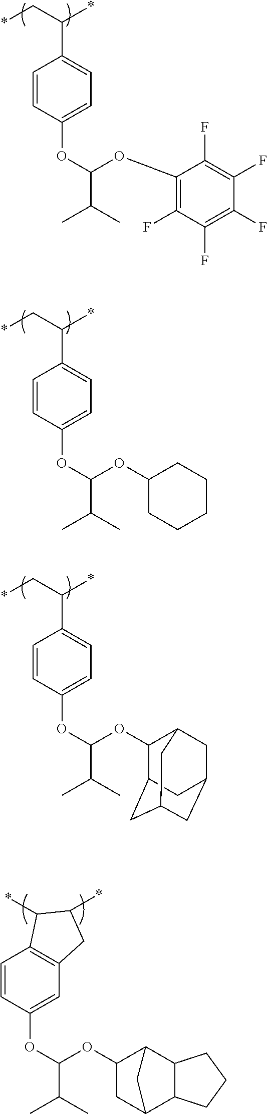

The resin (P) may or may not contain a repeating unit represented by formula (D), but in the case where the resin (P) contains a repeating unit represented by formula (D), the repeating unit represented by formula (D) is preferably present in a ratio of 1 to 40 mol %, more preferably from 3 to 30 mol %, still more preferably from 5 to 20 mol %, based on all repeating units in the resin (P).

The resin (P) may contain a repeating unit represented by the following formula (E):

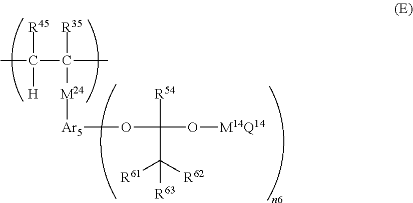

In formula (E), R⁵⁴ represents a hydrogen atom or an alkyl group.

Each of R⁶¹ to R⁶³ independently represents an organic group where the atom bonded to C in —C(R⁶¹)(R⁶²)(R⁶³) is a carbon atom. At least two of R⁶¹, R⁶² and R⁶³ may combine with each other to form a ring.

R³⁵ represents a hydrogen atom or an alkyl group.

R⁴⁵ represents a hydrogen atom or an alkyl group. R⁴⁵ and M²⁴ or Ar₅ may combine with each other to form a ring, and in this case, R⁴⁵ represents an alkylene group.

M²⁴ represents a single bond or a divalent linking group and in the case of combining with R⁴⁵ to form a ring, represents a trivalent linking group.

Ar₅ represents an (n6+1)-valent aromatic ring group and in the case of combining with R⁴⁵ to form a ring, represents an (n6+2)-valent aromatic ring group.

M¹⁴ represents a single bond or a divalent linking group.

Q¹⁴ represents an alkyl group, a cycloalkyl group, an aryl group or a heterocyclic group.

n6 represents an integer of 1 or more.

Specific examples and preferred ranges of Ar₅, M²⁴, R³⁵ and R⁴⁵ are the same as those described for Ar, M², R³ and R⁴ in formula (B).

Specific examples and preferred ranges of R⁵⁴ and n6 are the same as those described for R⁵¹ and n2 in formula (B).

As described above, each of R⁶¹, R⁶² and R⁶³ independently represents an organic group. Here, the organic group is a group containing at least one carbon atom, where one of) carbon atoms contained is bonded to C in the —C(R⁶¹)(R⁶²)(R⁶³) group.

The total number of carbon atoms contained in the organic group represented by R⁶¹, R⁶² and R⁶³ is 4 or more, preferably from 6 to 20, still more preferably from 6 to 10.

The organic group represented by R⁶¹, R⁶² and R⁶³ is preferably an organic group containing a carbon-hydrogen bond moiety, and in the case of containing two or more carbon atoms, the organic group may be a saturated organic group where the carbon-carbon bond is composed of only a single bond, or an unsaturated organic group where the carbon-carbon bond contains a moiety composed of a double bond or a triple bond. Also, the organic group contain a heteroatom such as oxygen atom, nitrogen atom and sulfur atom.

Examples of R⁶¹, R⁶² and R⁶³ include an alkyl group, a cycloalkyl group, an aryl group, an aralkyl group, and a heterocyclic group connected through a carbon atom. The heterocyclic group connected through a carbon atom may be aromatic or non-aromatic.

In one embodiment, the carbon number of the alkyl group is preferably 20 or less, more preferably 8 or less. Examples of the alkyl group include a methyl group, an ethyl group, a propyl group, an isopropyl group, an n-butyl group, a sec-butyl group, a tert-butyl group, a hexyl group, a 2-ethylhexyl group, an octyl group, and a dodecyl group. Among these, a methyl group, an ethyl group, a propyl group, an isopropyl group and a tert-butyl group are preferred.

The cycloalkyl group may be monocyclic or polycyclic. The carbon number of the cycloalkyl group is preferably from 3 to 10. Examples of the cycloalkyl group include a cyclopropyl group, a cyclobutyl group, a cyclopentyl group, a cyclohexyl group, a cycloheptyl group, a cyclooctyl group, a 1-adamantyl group, a 2-adamantyl group, a 1-norbornyl group, and a 2-norbornyl group. Among these, a cyclopentyl group and a cyclohexyl group are preferred.

The aryl group encompasses a structure where a plurality of aromatic rings are connected to each other through a single bond (such as biphenyl group and terphenyl group). The carbon number of the aryl group is preferably from 4 to 20, more preferably from 6 to 14. Examples of the aryl group include a phenyl group, a naphthyl group, an anthranyl group, a biphenyl group, and a terphenyl group. Among these, a phenyl group, a naphthyl group and a biphenyl group are preferred.

The carbon number of the aralkyl group is from 6 to 20, more preferably from 7 to 12. Examples of the aralkyl group include a benzyl group, a phenethyl group, a naphthylmethyl group, and a naphthylethyl group.

The alkyl group, cycloalkyl group, aryl group and aralkyl group may further have a substituent.

Examples of the substituent which the alkyl group may further have include a cycloalkyl group, an aryl group, an amino group, an amido group, a ureido group, a urethane group, a hydroxyl group, a carboxy group, a halogen atom, an alkoxy group, an aralkyloxy group, a thioether group, an acyl group, an acyloxy group, an alkoxycarbonyl group, a cyano group, and a nitro group.

Examples of the substituent which the cycloalkyl group may further have include an alkyl group and the groups described above as specific examples of the substituent which the alkyl group may further have.

The carbon number of the substituent which the alkyl group and cycloalkyl group may further have is preferably 8 or less.

Examples of the substituent which the aryl group and aralkyl group may further have include a nitro group, a halogen atom such as fluorine atom, a carboxyl group, a hydroxyl group, an amino group, a cyano group, an alkyl group (preferably having a carbon number of 1 to 15), an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), and an alkoxycarbonyloxy group (preferably having a carbon number of 2 to 7).

The “connected through a carbon atom” in the heterocyclic group connected through a carbon atom means that the atom bonded to C in —(CR⁶¹R⁶²R⁶³) is a carbon atom. The heterocyclic group may be an aromatic ring or a non-aromatic group, and the carbon number thereof is preferably from 2 to 20, more preferably from 4 to 14. Examples of the heterocyclic group connected through a carbon atom include a pyrrolyl group, a pyridyl group, a pyrimidyl group, a furanyl group, a thienyl group, a tetrahydrofuranyl group, a tetrahydropyranyl group, a tetrahydrothienyl group, a pyrrolidinyl group, and a morpholinyl group.

At least two of R⁶¹, R⁶² and R⁶³ may combine with each other to form a ring. Here, in the case where two of R⁶¹, R⁶² and R⁶³ combine with each other to form a ring, examples of the ring formed include a cyclopentane ring, a cyclohexane ring, an adamantane ring, a norbornene ring, and a norbornene ring. These may have a substituent, and examples of the substituent which the ring may have include an alkyl group and the groups described above as specific examples of the substituent which the alkyl group may further have. In the case where all of R⁶¹, R⁶² and R⁶³ combine with each other to form a ring, examples of the ring formed include an adamantane ring, a norbornane ring, a norbornene ring, a bicyclo[2,2,2]octane ring, and a bicyclo[3,1,1]heptane ring. Among these, an adamantane ring is preferred. These may have a substituent, and examples of the substituent which the ring may have include an alkyl group and the groups described above as specific examples of the substituent which the alkyl group may further have.

From the standpoint of enhancing the dry etching resistance and raising the glass transition temperature of the compound (P), preferably, at least one of R⁶¹, R⁶² and R⁶³ has one cyclic structure; more preferably, at least two of R⁶¹, R⁶² and R⁶³ combine with each other to form a ring; still more preferably, all of R⁶¹, R⁶² and R⁶³ combine with each other to form a ring.

The divalent linking group as M¹⁴ is, for example, an alkylene group (preferably an alkylene group having a carbon number of 1 to 8, such as methylene group, ethylene group, propylene group, butylene group, hexylene group or octylene group), a cycloalkylene group (preferably a cycloalkylene group having a carbon number of 3 to 15, such as cyclopentylene group or cyclohexylene group), —S—, —O—, —CO—, —CS—, —SO₂—, —N(R⁰—, or a combination of two or more thereof, and a linking group having a total carbon number of 20 or less is preferred. Here, R⁰ is a hydrogen atom or an alkyl group (for example, an alkyl group having a carbon number of 1 to 8, and specific examples thereof include a methyl group, an ethyl group, a propyl group, an n-butyl group, a sec-butyl group, a hexyl group, and an octyl group).

M¹⁴ is preferably a single bond, an alkylene group or a divalent linking group formed by a combination of an alkylene group and at least one of —O—, —CO—, —CS— and —N(R⁰—, more preferably a single bond, an alkylene group or a divalent linking group formed by a combination of an alkylene group and —O—. Here, R⁰ has the same meaning as R⁰ above.

M¹⁴ may further have a substituent, and examples of the substituent which M¹⁴ may further have are the same as those of the substituent which the alkyl group of R⁶¹ above may have.

Examples of the alkyl group as Q¹⁴ are the same as those of the alkyl group of R⁶¹ above. The cycloalkyl group as Q¹⁴ may be monocyclic or polycyclic. The carbon number of the cycloalkyl group is preferably from 3 to 10. Examples of the cycloalkyl group include a cyclopropyl group, a cyclobutyl group, a cyclopentyl group, a cyclohexyl group, a cycloheptyl group, a cyclooctyl group, a 1-adamantyl group, a 2-adamantyl group, a 1-norbornyl group, a 2-norbornyl group, a bornyl group, an isobornyl group, a 4-tetracyclo[6.2.1.1^{3,6}.0^{2,7}]dodecyl group, a 8-tricyclo[5.2.1.0^{2,6}]decyl group, and a 2-bicyclo[2.2.1]heptyl group. Among these, a cyclopentyl group, a cyclohexyl group, a 2-adamantyl group, a 8-tricyclo[5.2.1.0^{2,6}]decyl group and a 2-bicyclo[2.2.1]heptyl group are preferred.

Examples of the aryl group as Q¹⁴ are the same as those of the aryl group of R⁶¹ above, and the carbon number of the aryl group is preferably from 3 to 18.

The heterocyclic ring as Q¹⁴ is preferably a heterocyclic group having a carbon number of 6 to 20, more preferably a heterocyclic group having a carbon number of 6 to 12. Specific examples of the heterocyclic group of R²¹ to R²³ include a pyridyl group, a pyrazyl group, a tetrahydropyranyl group, a tetrahydropyranyl group, a tetrahydrothiophene group, a piperidyl group, a piperazyl group, a furanyl group, a pyranyl group, a chromanyl group, and a benzofuranyl group.

The cycloalkyl group and aryl group as Q¹⁴ may have a substituent, and examples of the substituent include an alkyl group, a cycloalkyl group, a cyano group, a halogen atom, a hydroxyl group, an alkoxy group, a carboxyl group, and an alkoxycarbonyl group.

The (-M¹⁴-Q¹⁴) is preferably, for example, an alkyl group, a cycloalkyl group-substituted alkyl group, a cycloalkyl group, an aralkyl group, or an aryloxyalkyl group. Specific examples thereof include a methyl group, an ethyl group, an isopropyl group, a cyclopentyl group, a cyclohexyl group, a cyclohexylethyl group, a 2-adamantyl group, a 8-tricyclo[5.2.1.0^{2,6}]decyl group, a 2-bicyclo[2.2.1]heptyl group, a benzyl group, a 2-phenethyl group, and a 2-phenoxyethyl group.

Specific examples of the repeating unit represented by formula (E) are illustrated below, but the present invention is not limited thereto.

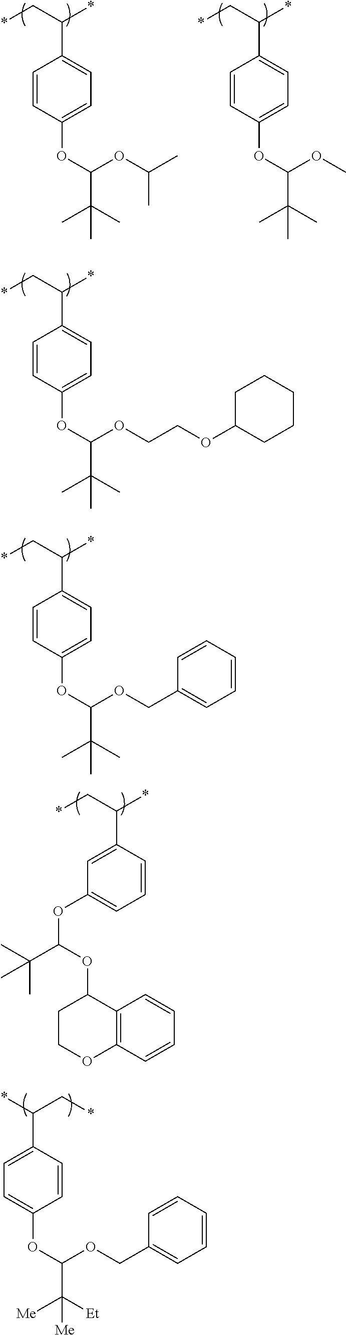

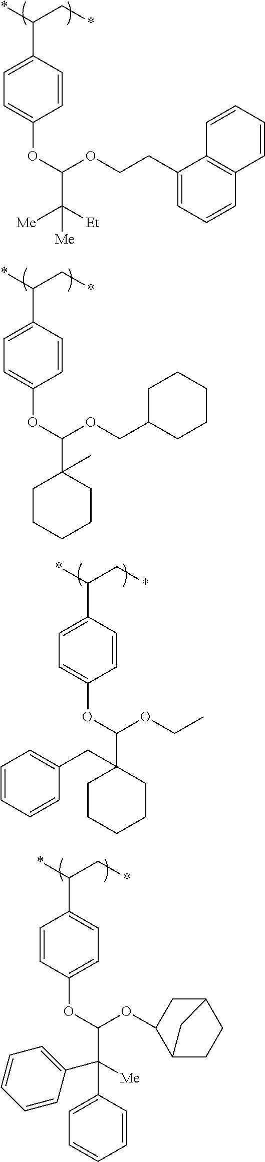

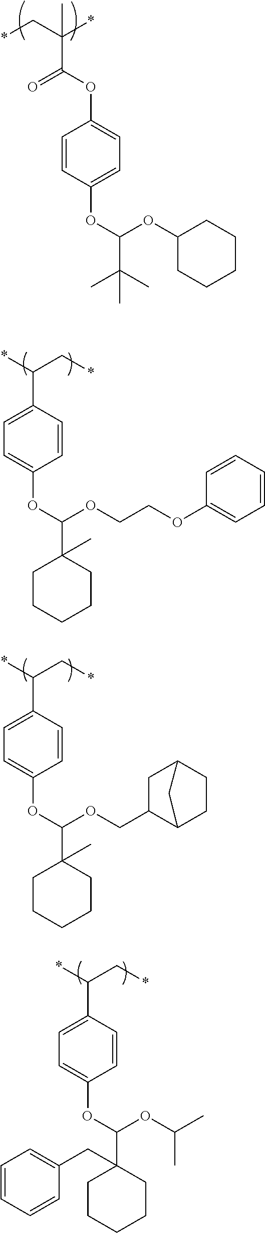

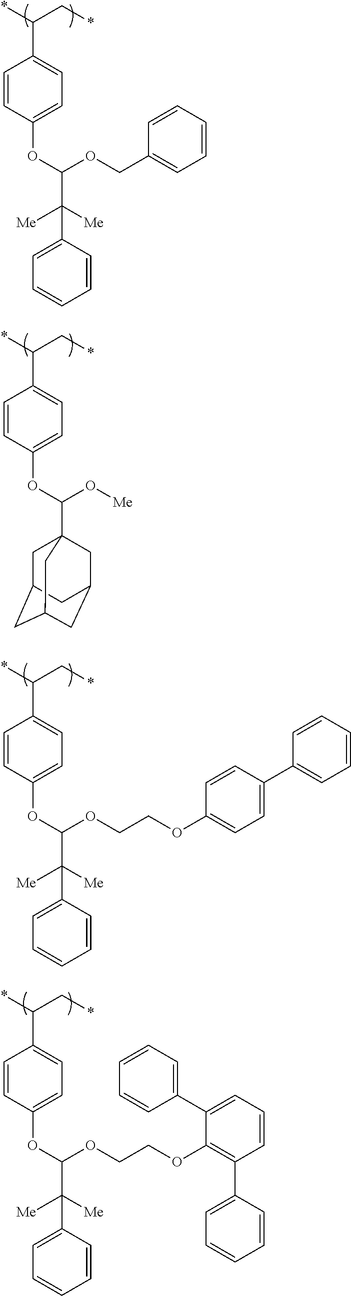

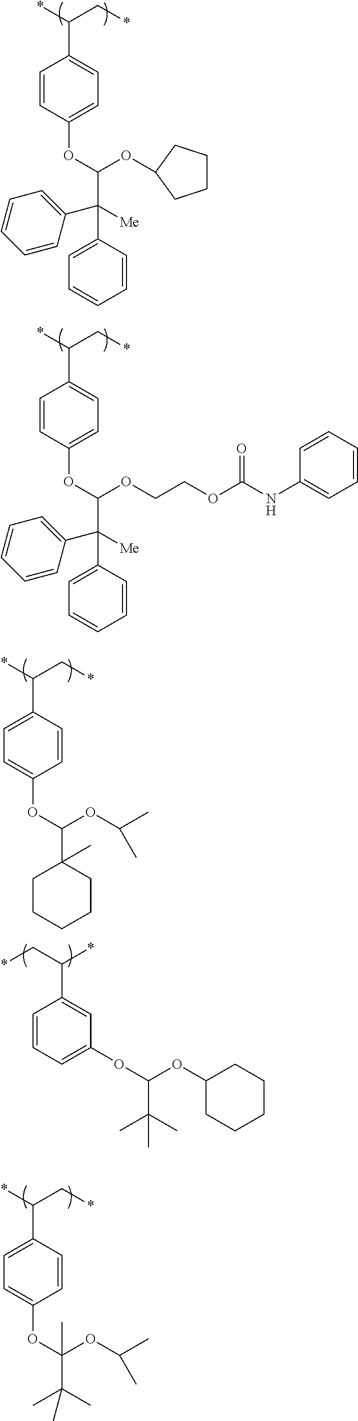

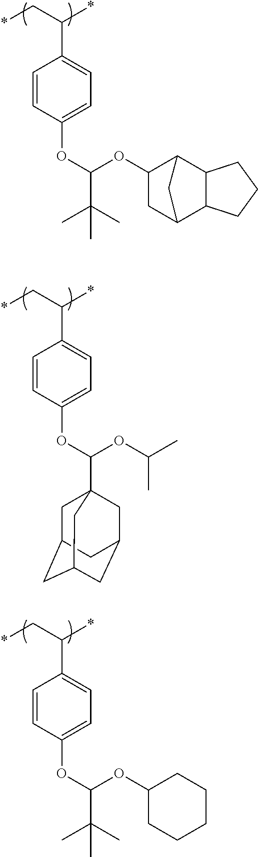

The resin (P) may or may not contain a repeating unit represented by formula (E), but in the case where the resin (P) for use in the present invention contains a repeating unit represented by formula (E), the repeating unit represented by formula (E) is preferably present in a ratio of 1 to 40 mol %, more preferably from 3 to 30 mol %, still more preferably from 5 to 20 mol %, based on all repeating units in the resin (P).

The resin (P) may further contain a repeating unit represented by the following formula (4):

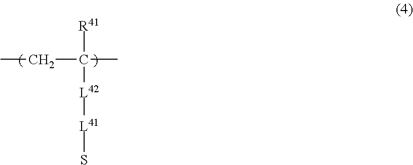

R⁴¹ represents a hydrogen atom or a methyl group. L⁴¹ represents a single bond or a divalent linking group. L⁴² represents a divalent linking group. S represents a structural moiety capable of decomposing upon irradiation with an actinic ray or radiation to generate an acid on the side chain

Specific examples of the repeating unit represented by formula (4) are illustrated below, but the present invention is not limited thereto.

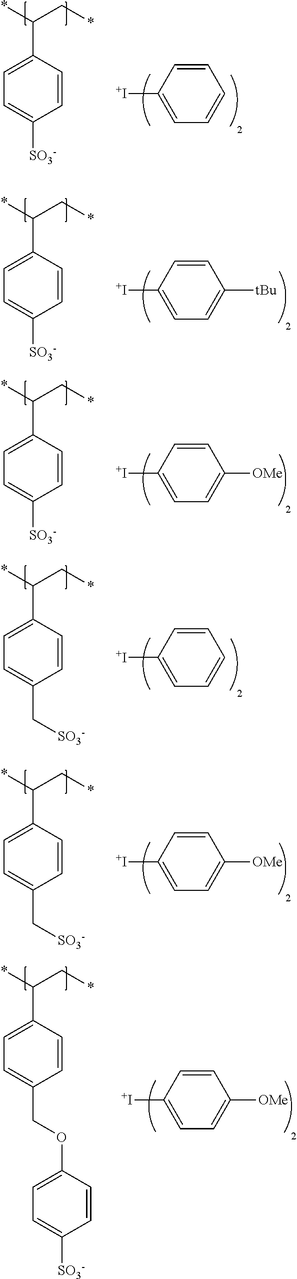

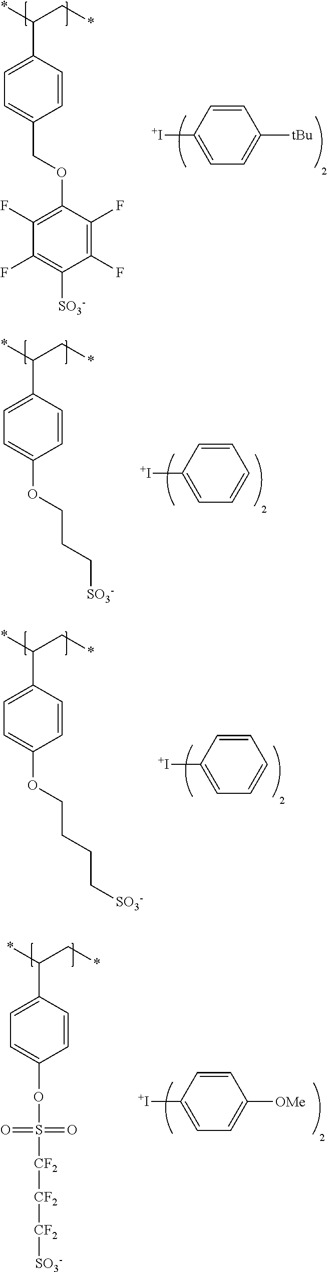

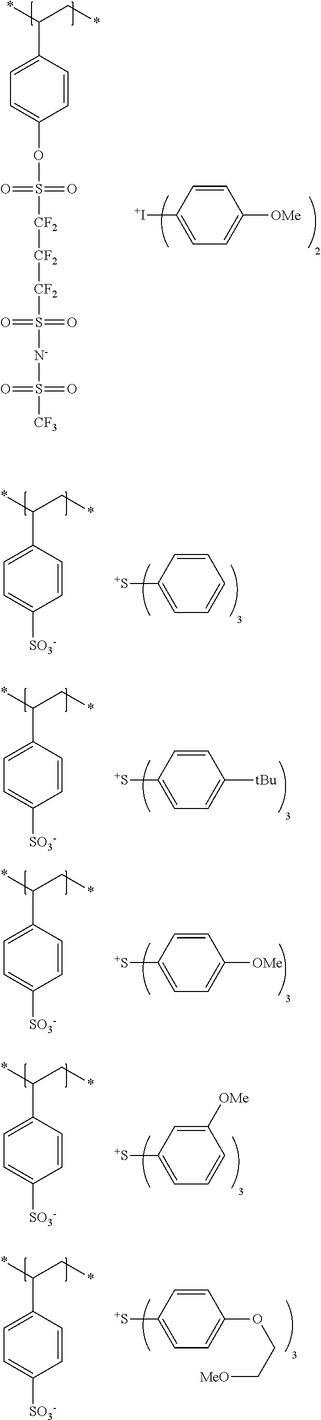

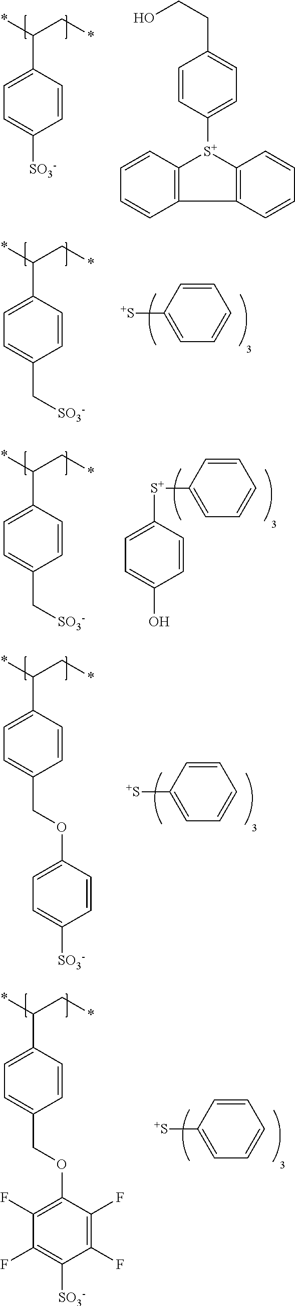

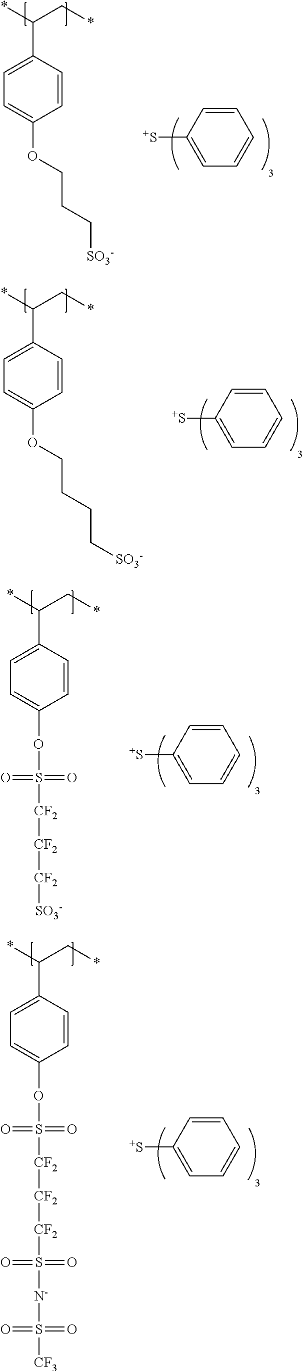

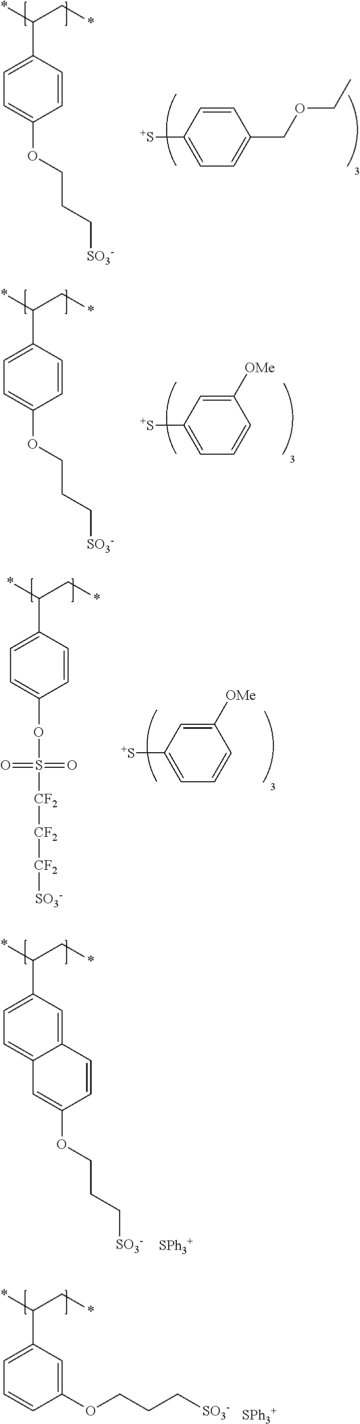

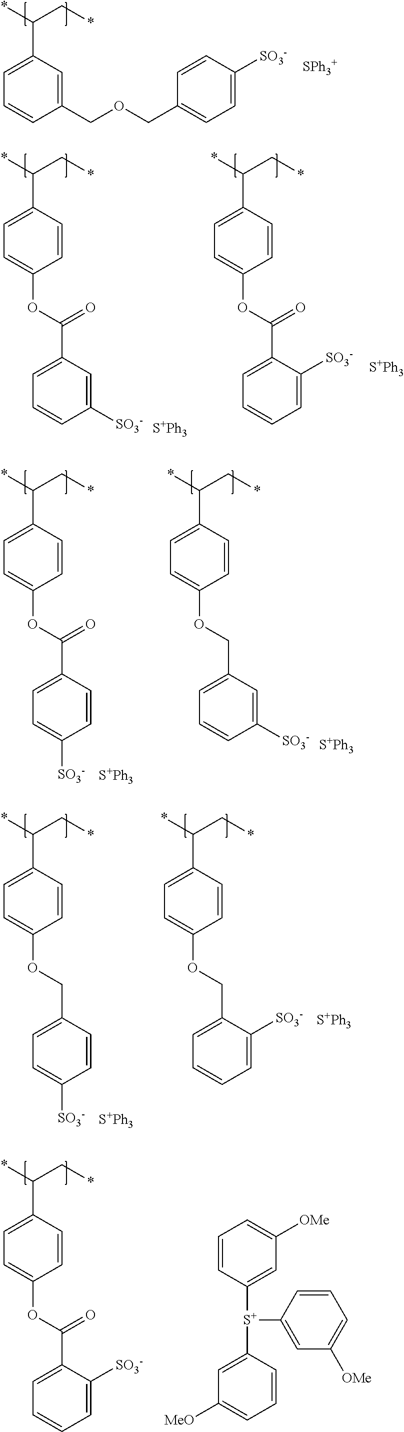

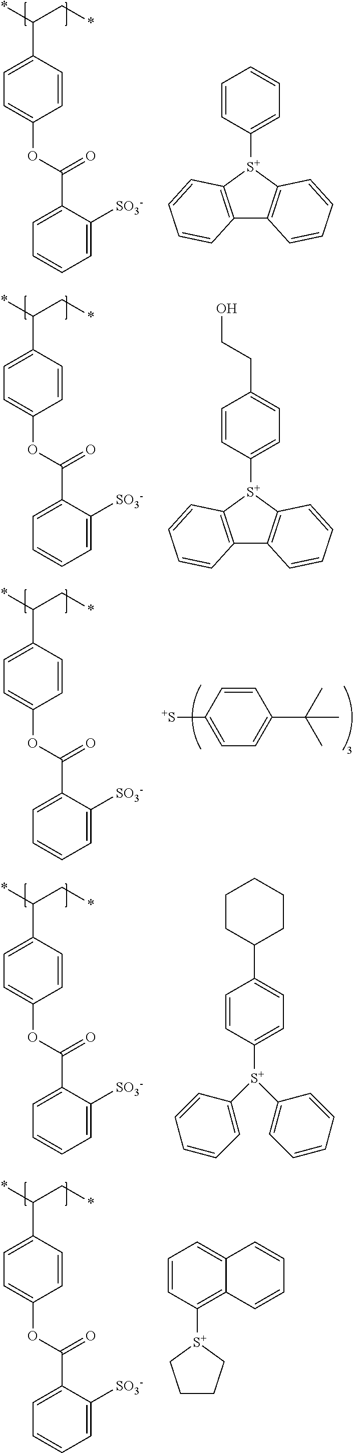

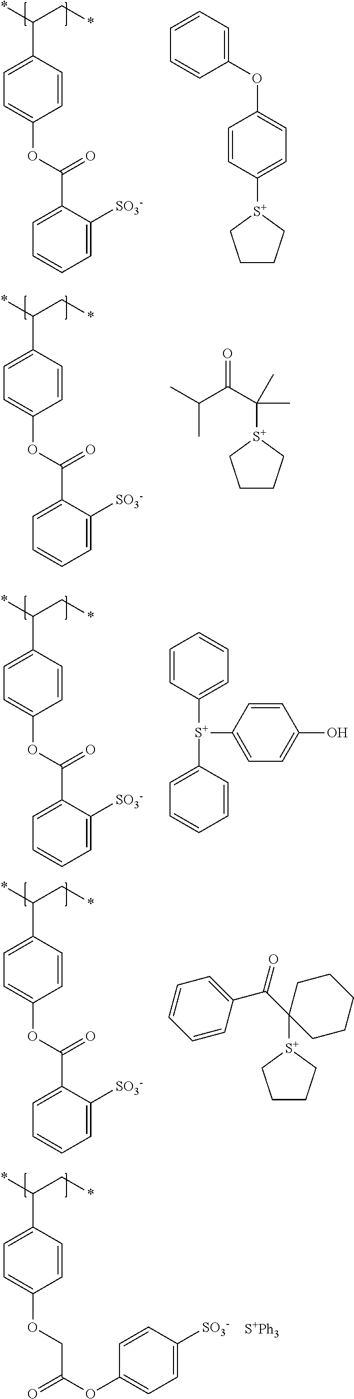

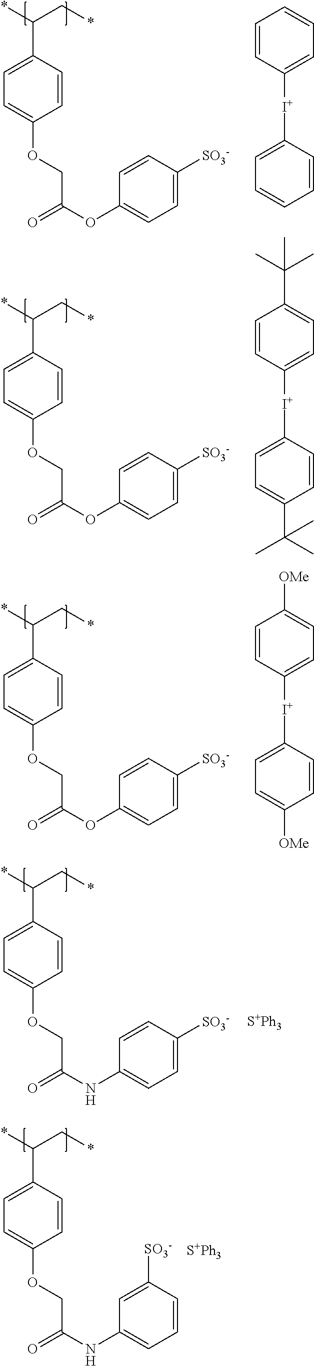

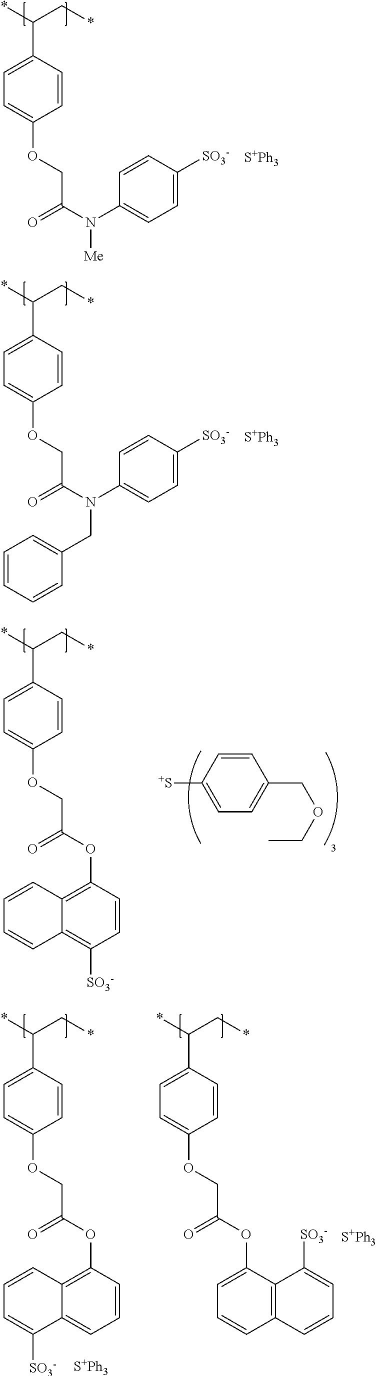

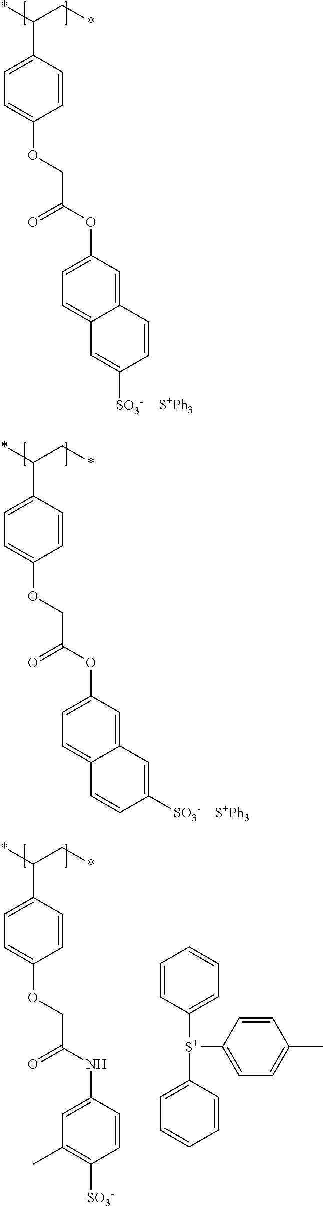

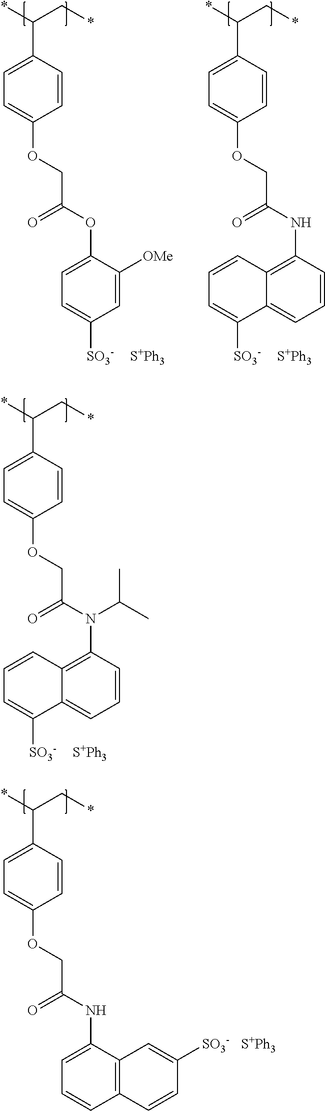

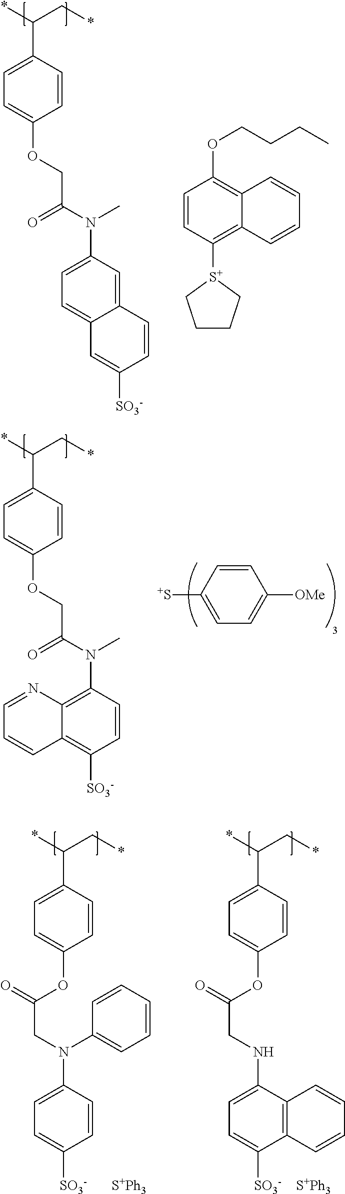

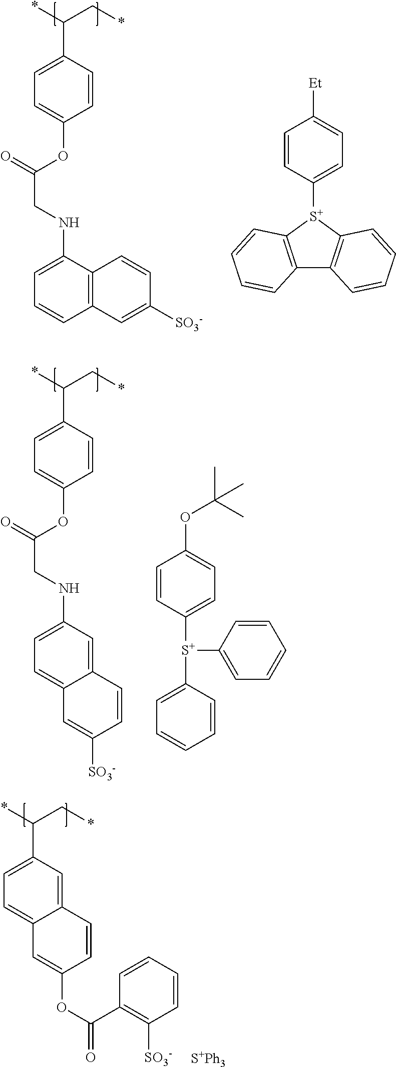

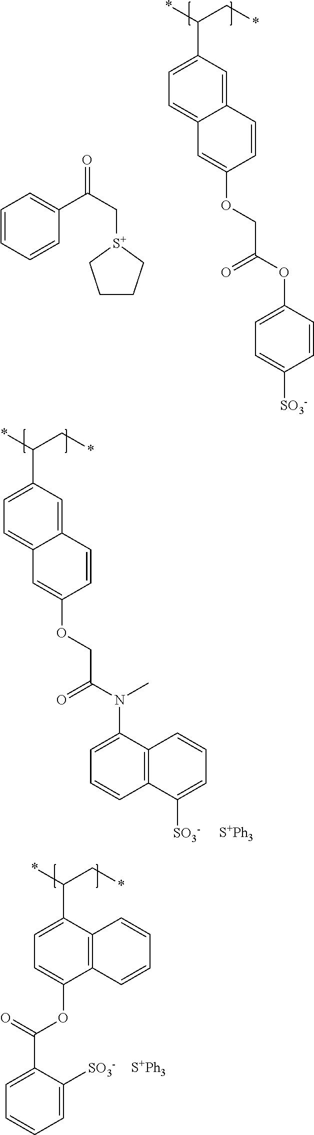

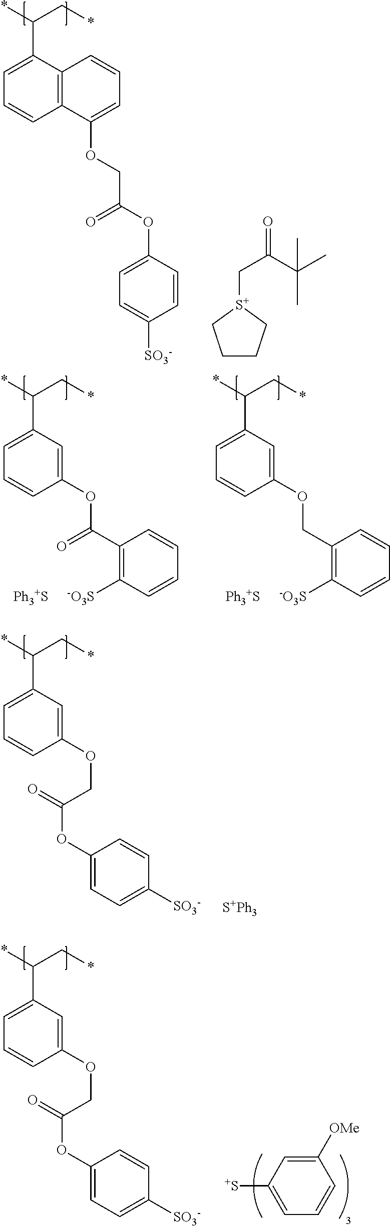

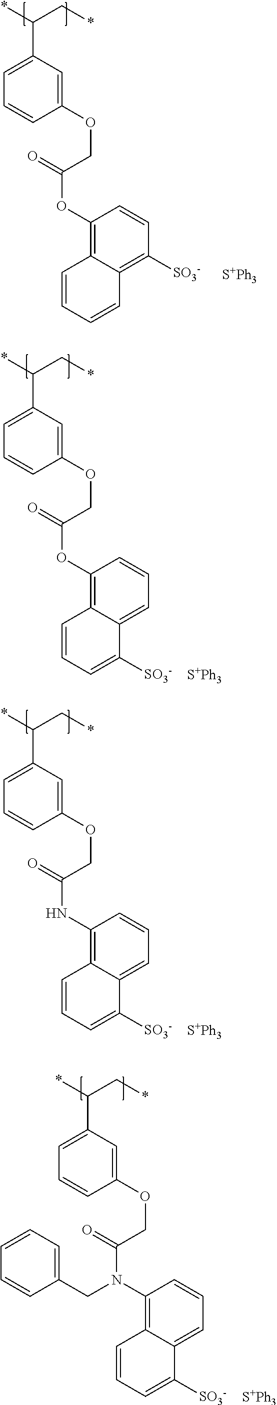

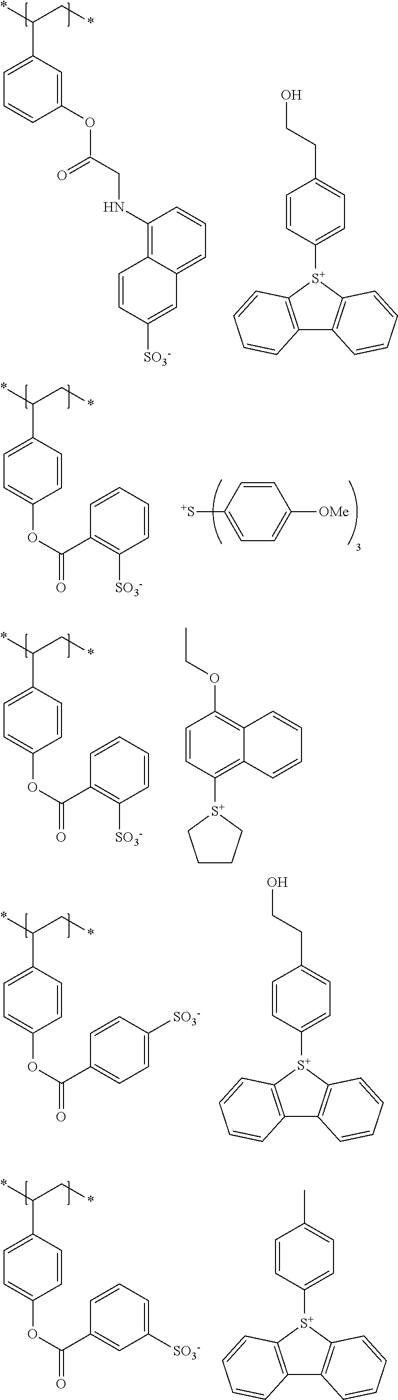

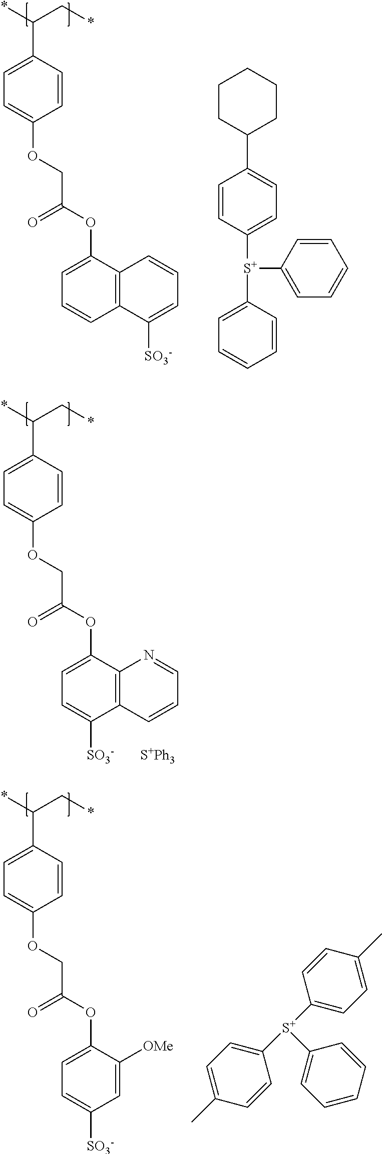

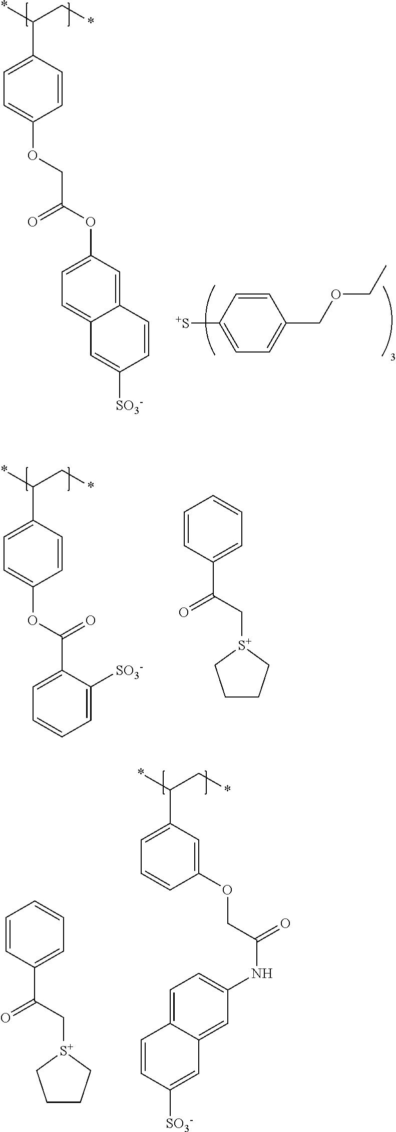

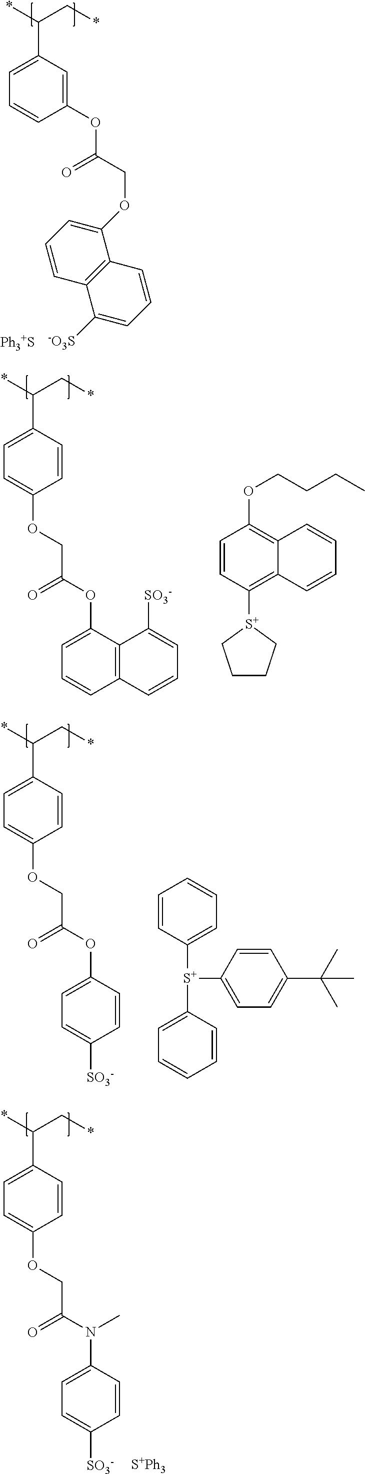

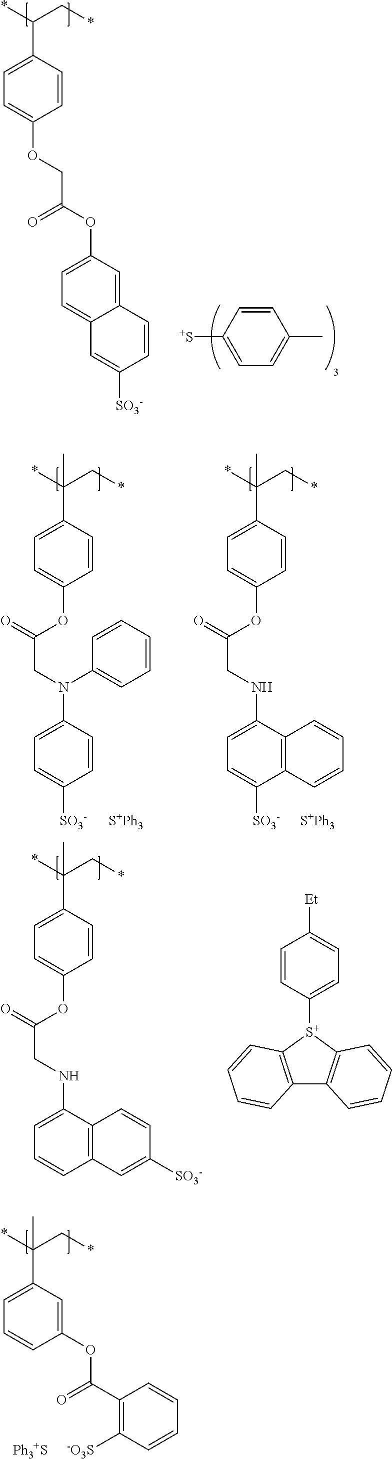

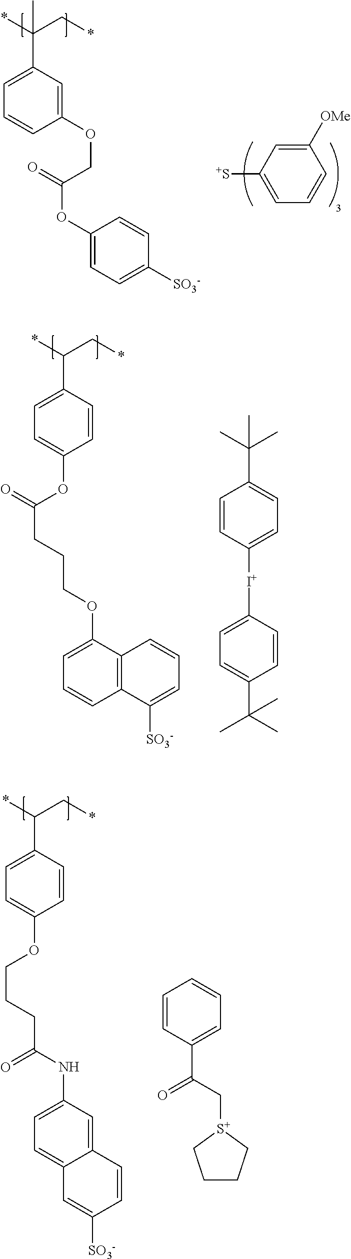

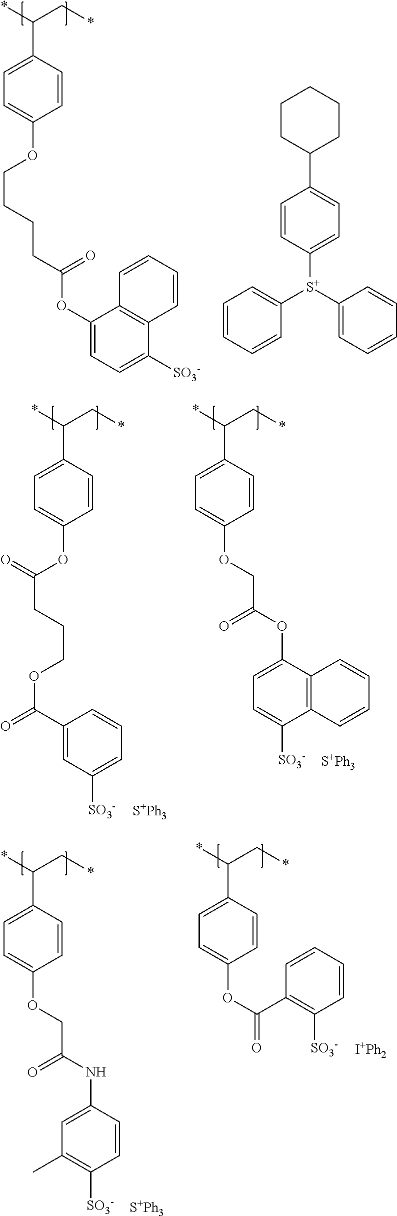

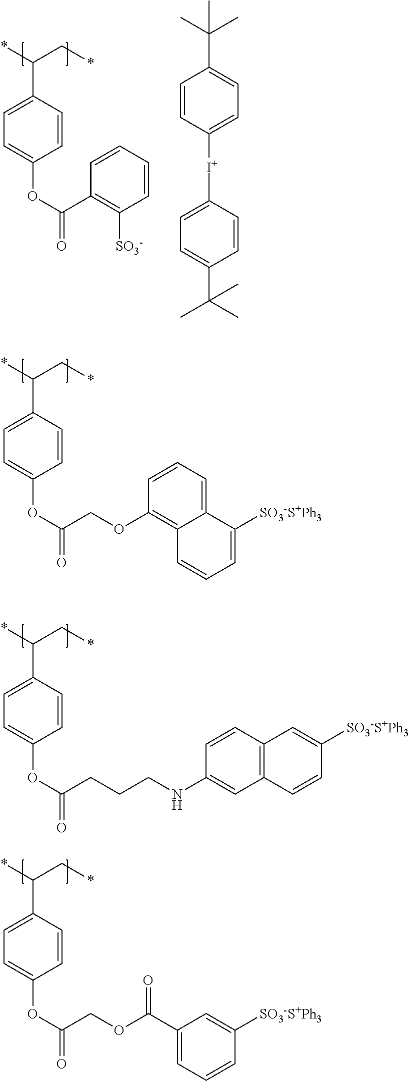

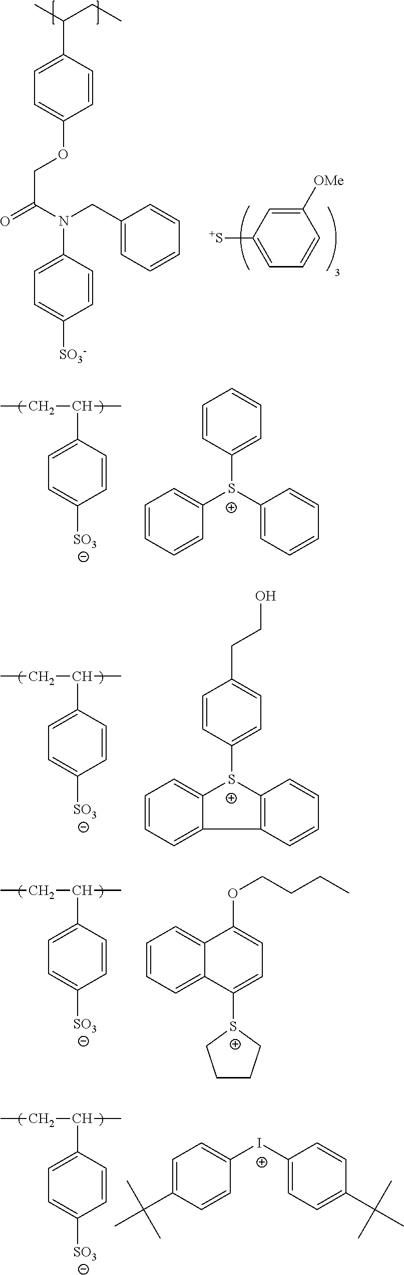

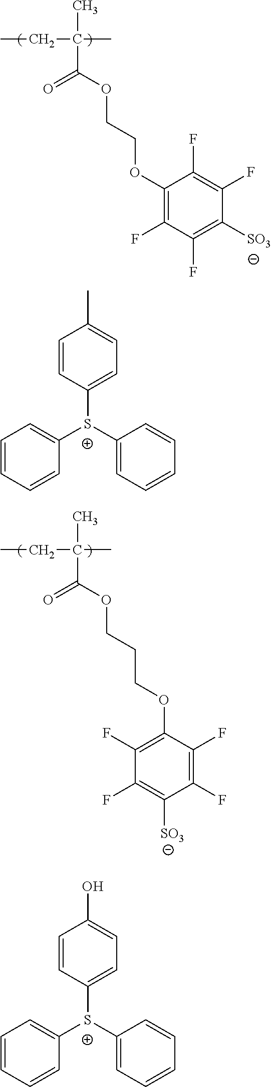

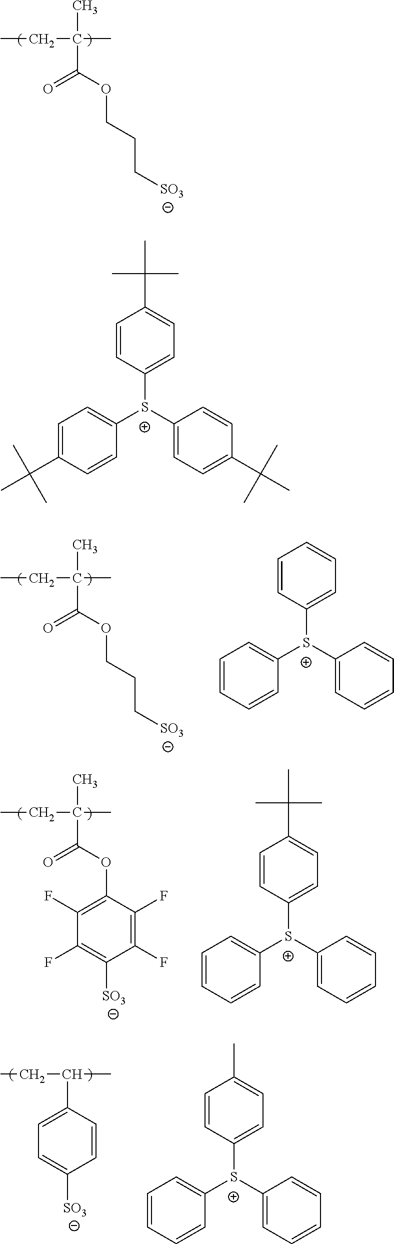

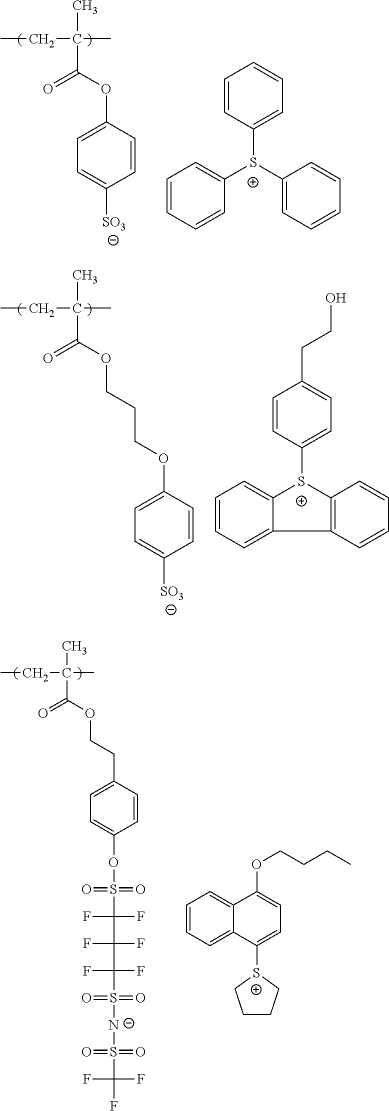

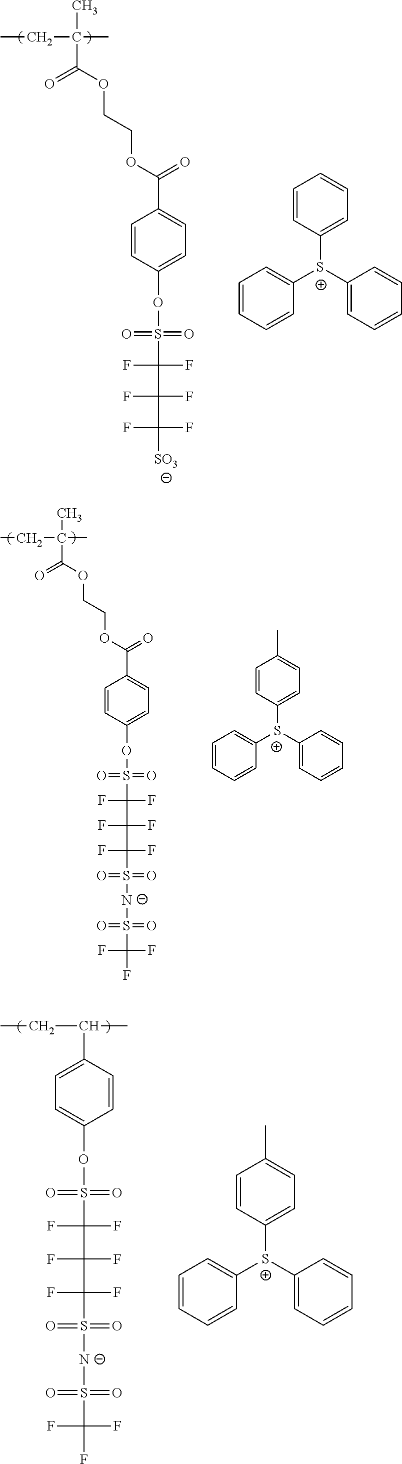

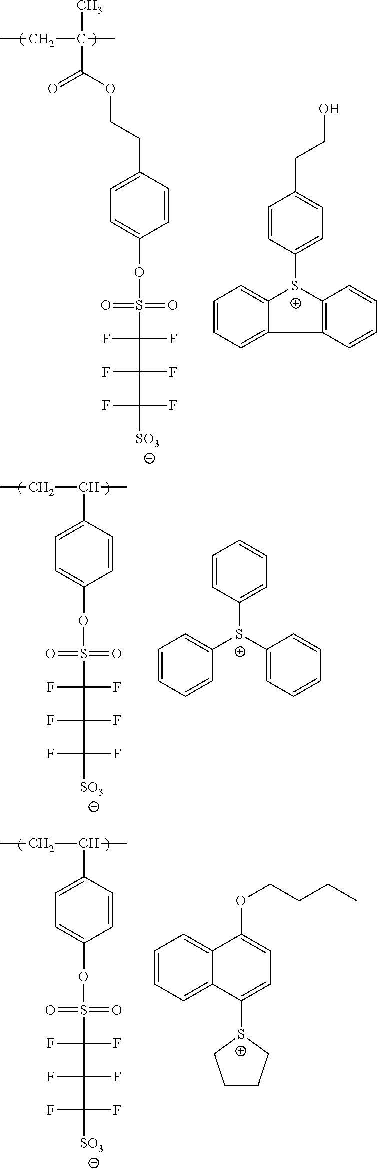

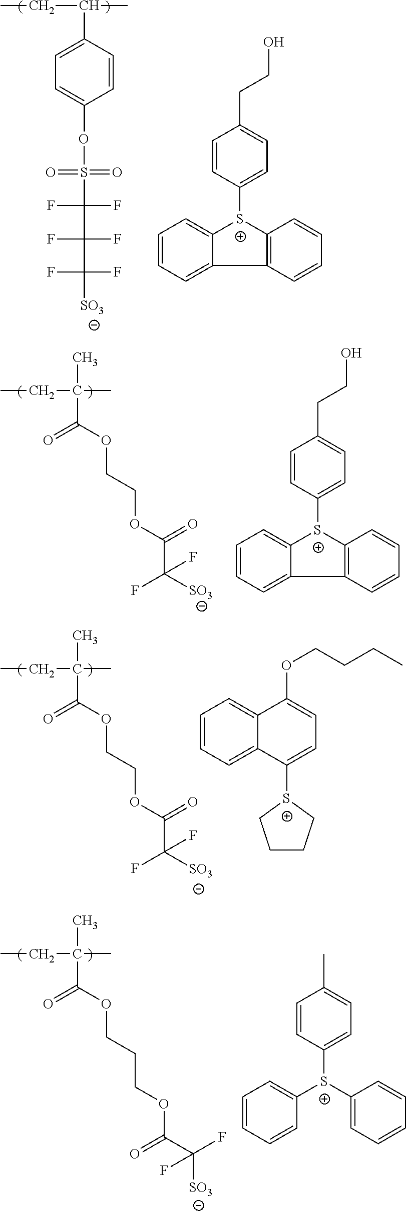

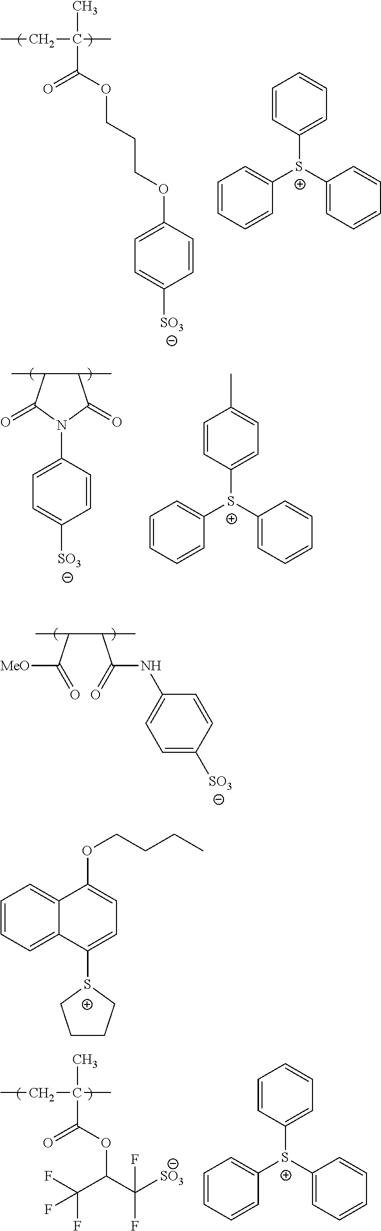

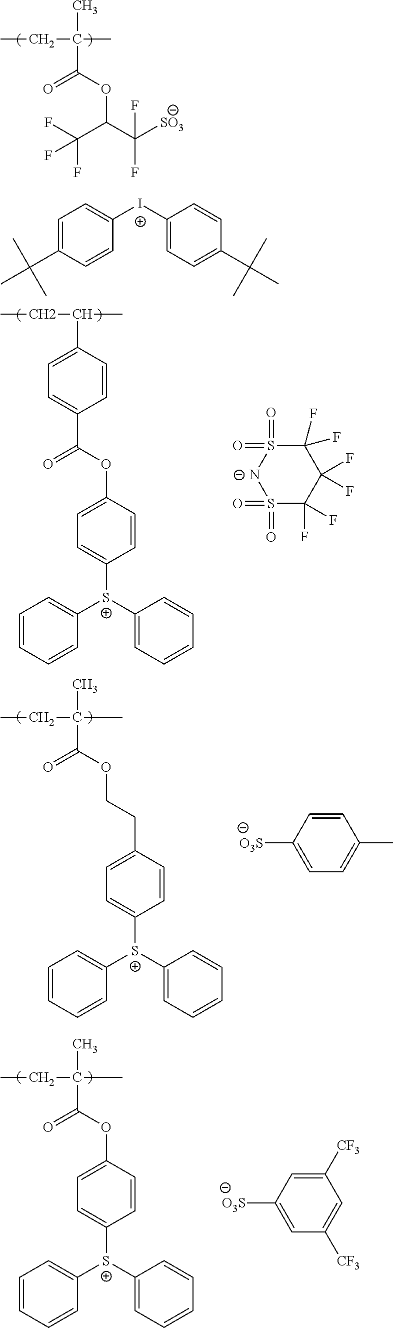

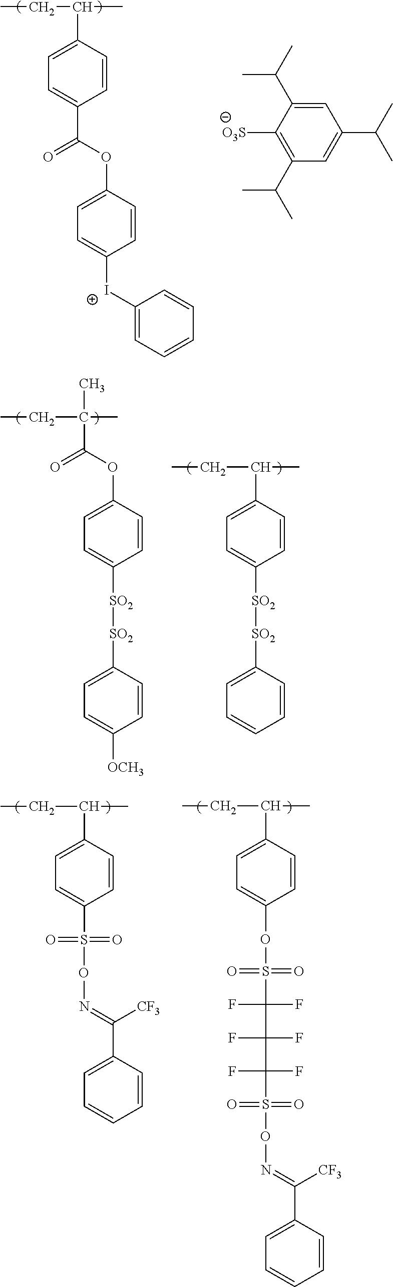

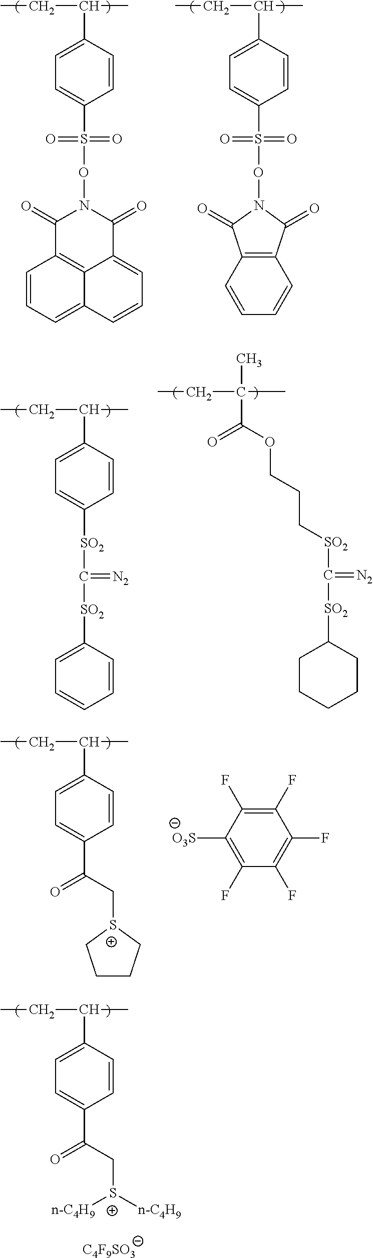

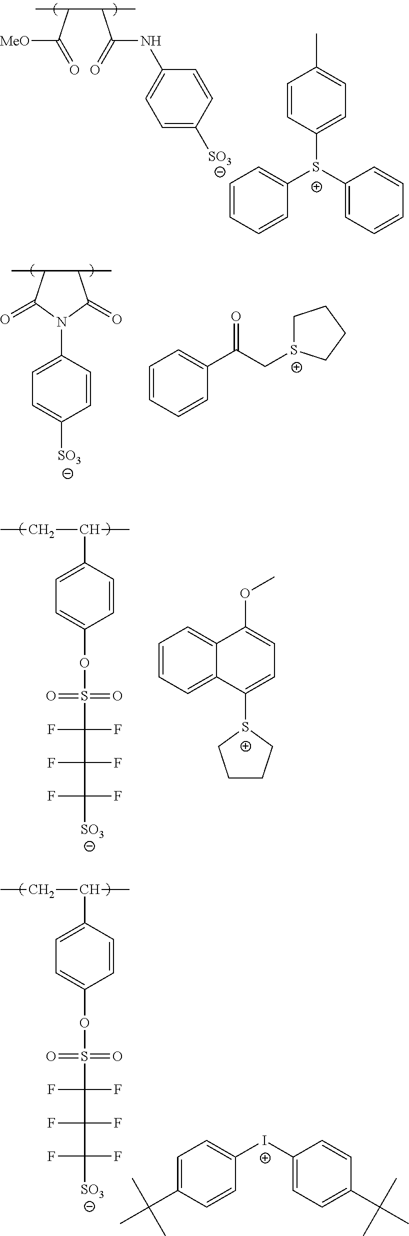

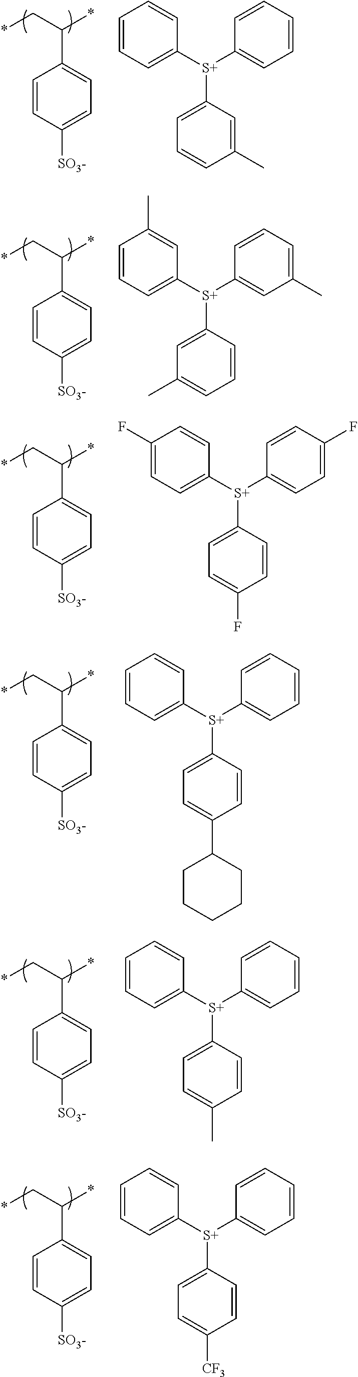

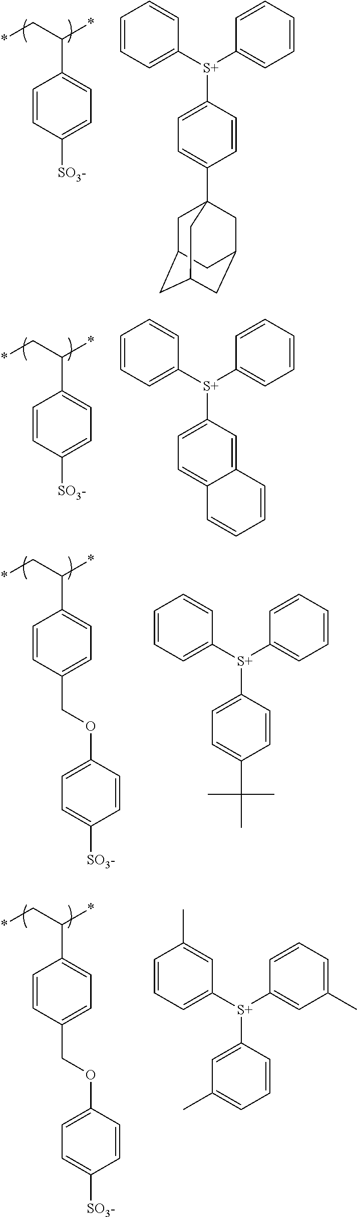

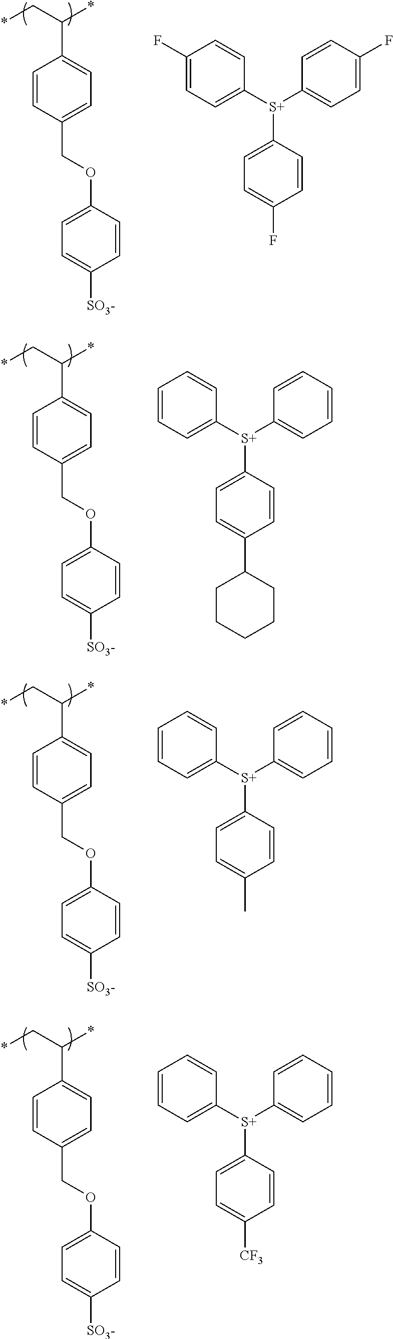

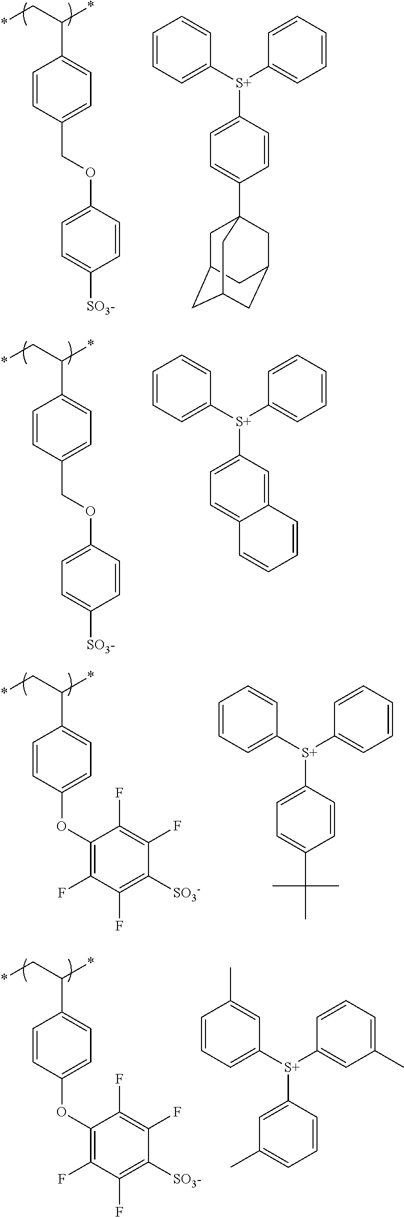

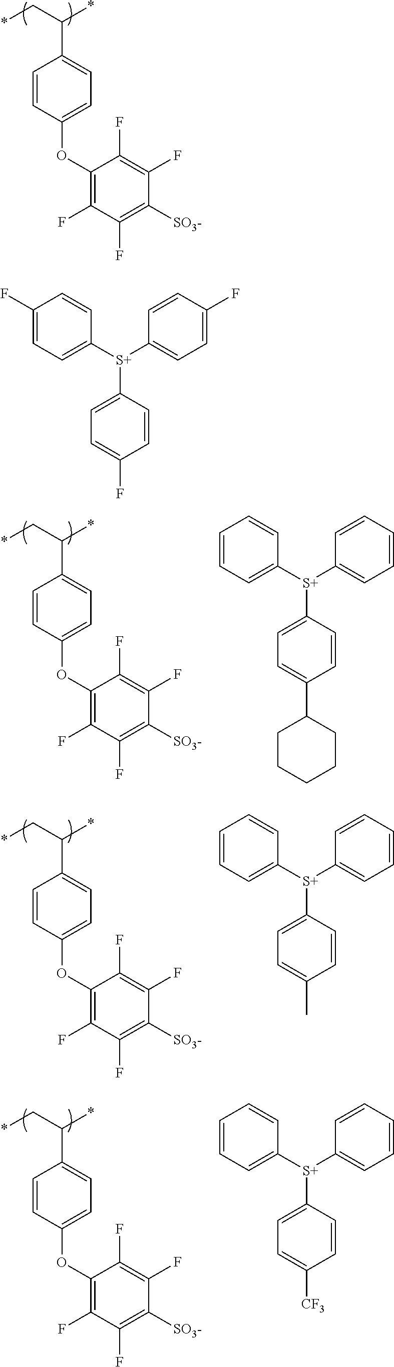

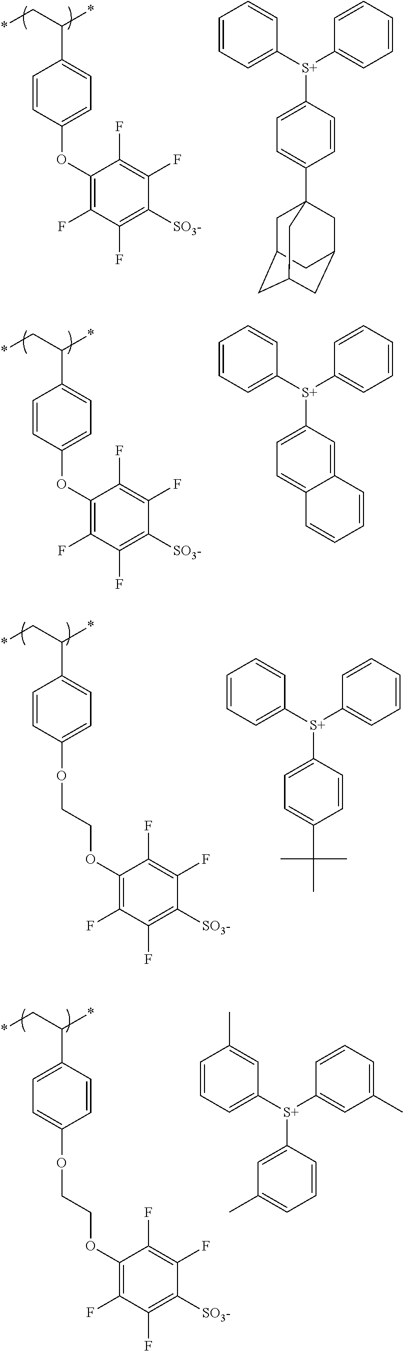

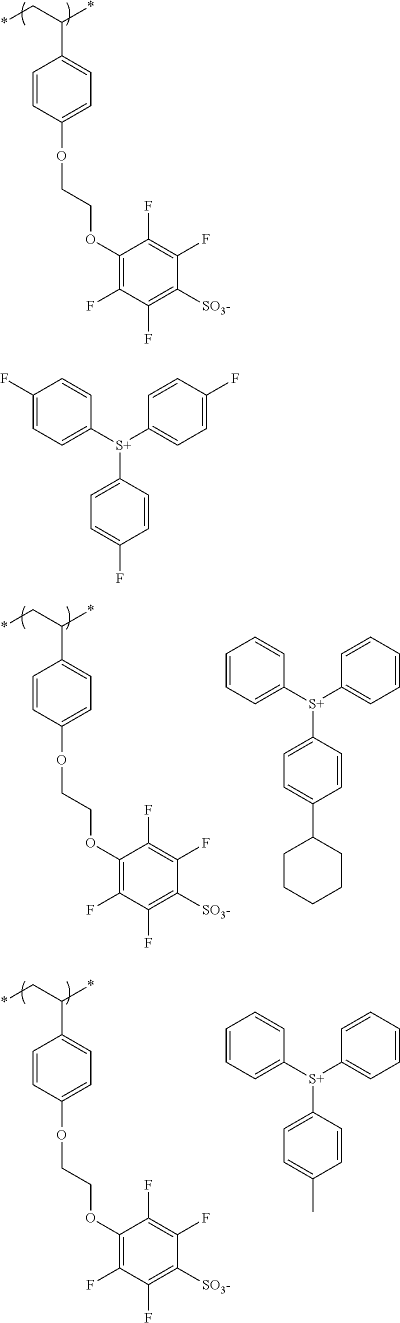

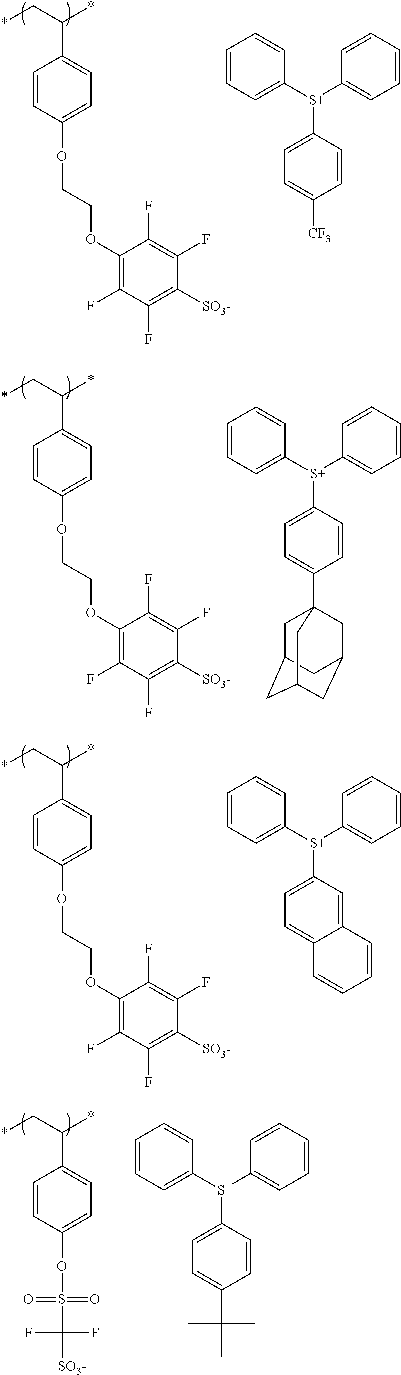

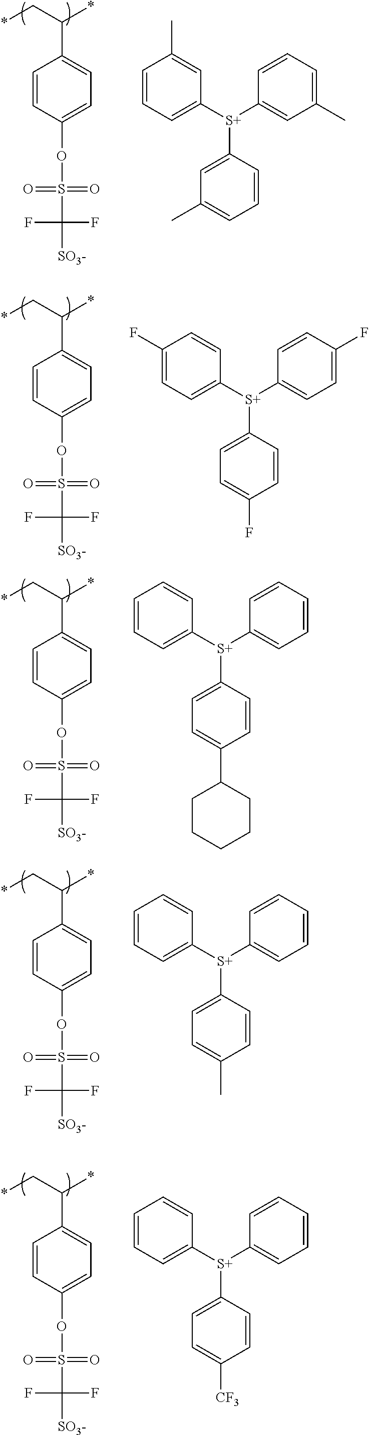

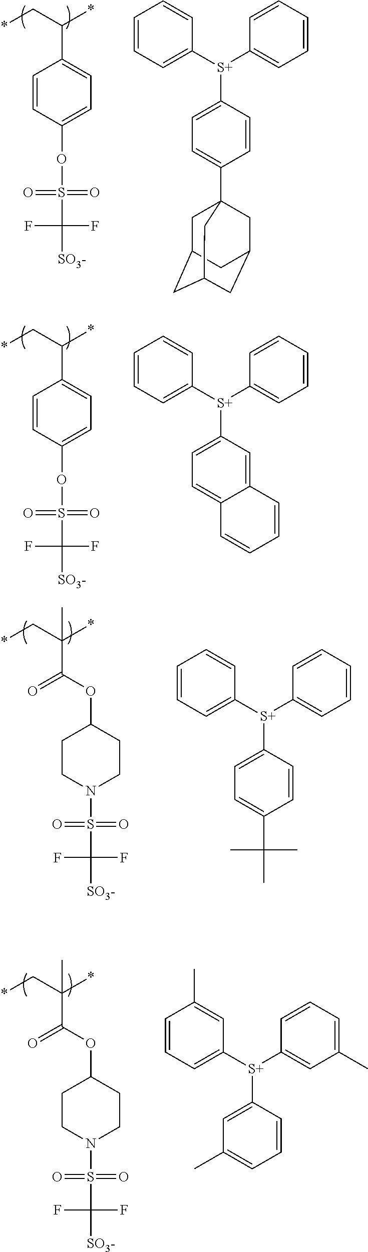

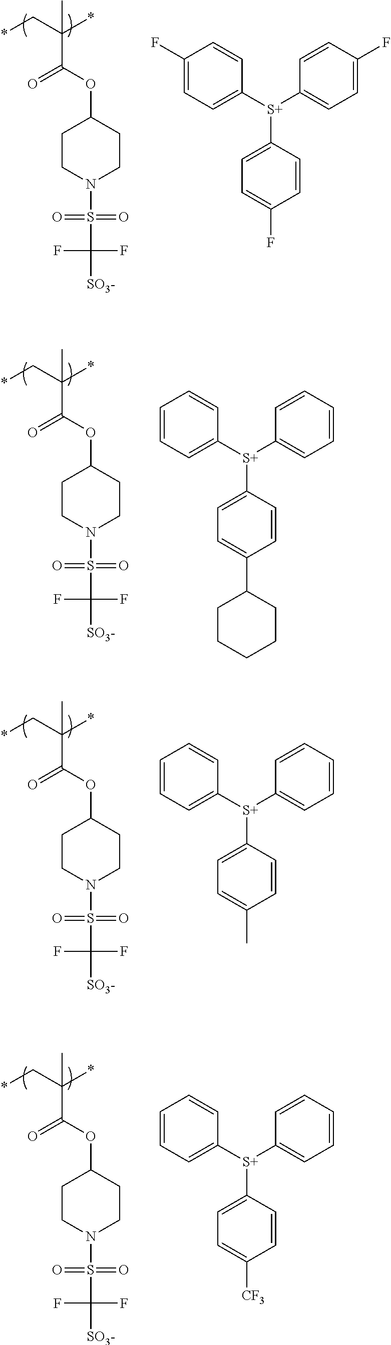

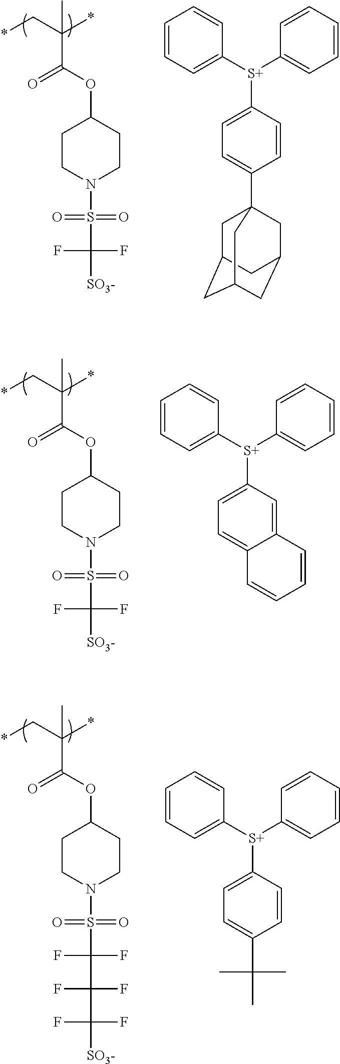

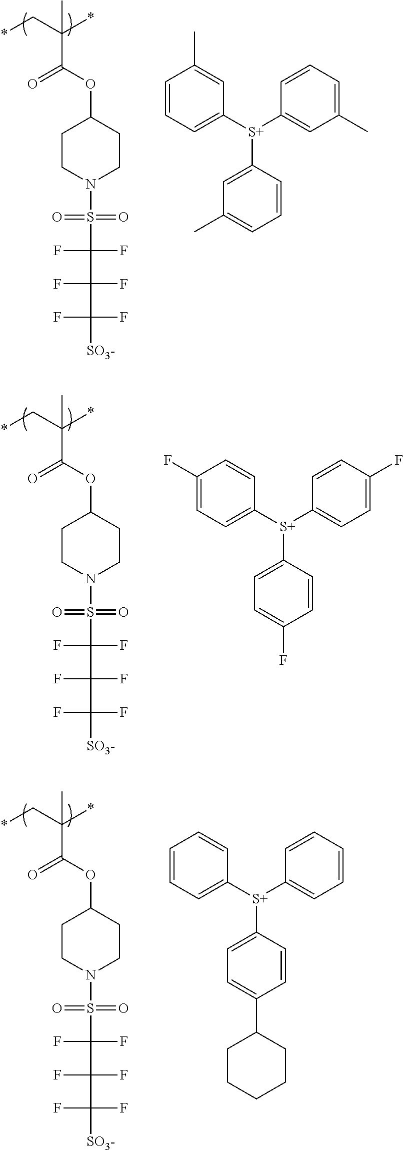

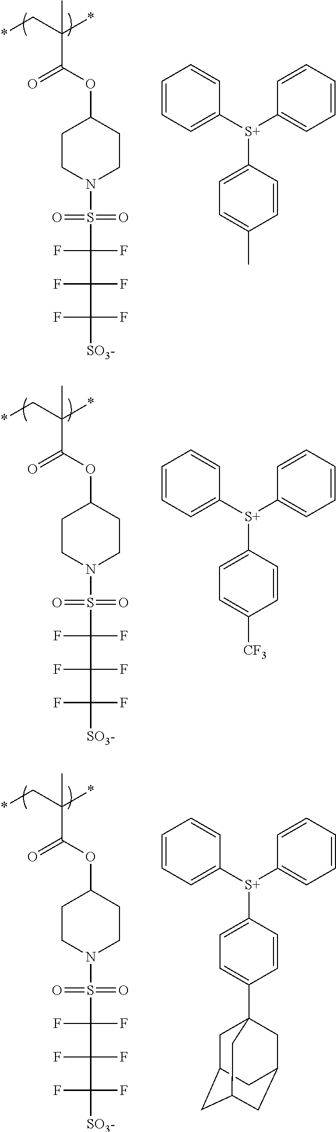

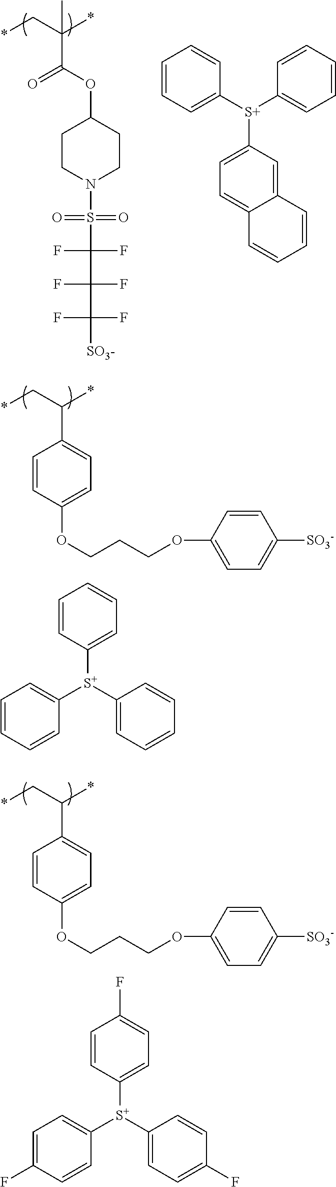

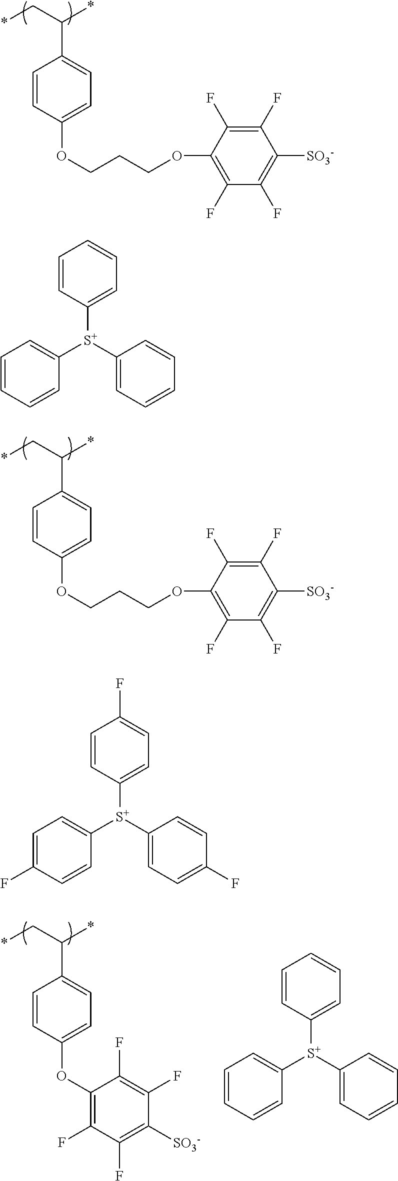

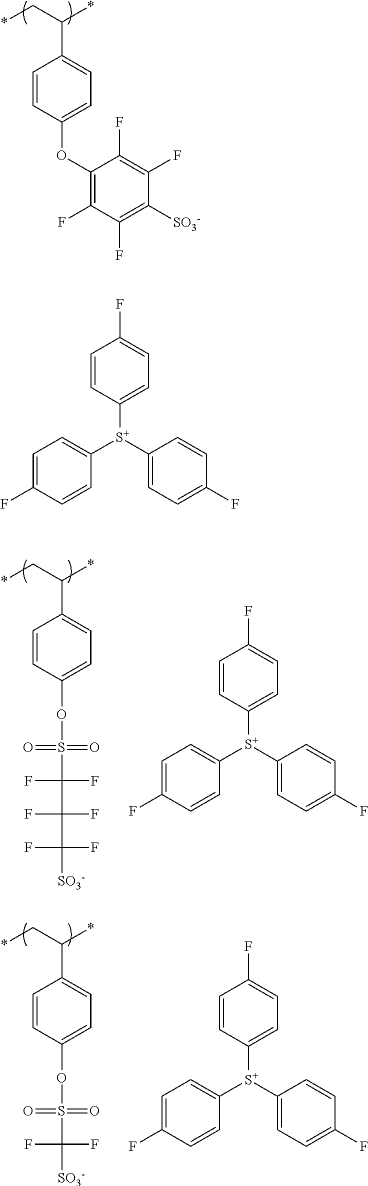

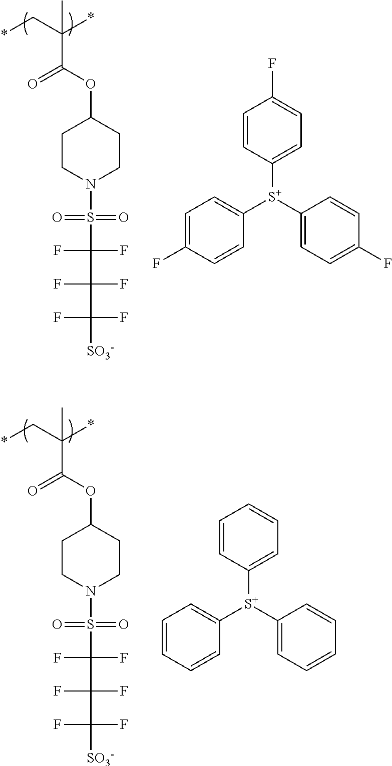

The content of the repeating unit represented by formula (4) in the resin (P) is preferably from 1 to 40 mol %, more preferably from 2 to 30 mol %, still more preferably from to 25 mol %, based on all repeating units in the resin (P).

It is also preferred that the resin (P) further contains the following repeating units as other repeating units.

### (a) Repeating Unit Having a Polar Group

The resin (P) preferably contains (a) a repeating unit having a polar group. By containing the repeating unit (a), for example, the sensitivity of the composition containing the resin can be more enhanced. The repeating unit (a) is preferably a non-acid-decomposable repeating unit (that is, has no acid-decomposable group).

The “polar group” which can be contained in the repeating unit (a) includes, for example, the following (1) to (4). In the following, the “electronegativity” means a Pauling's value.

(1) A functional group containing a structure where an oxygen atom and an atom with the electronegativity difference from oxygen atom being 1.1 or more are bonded through a single bond

Examples of this polar group include a group containing a structure represented by O—H, such as hydroxy group.

(2) A functional group containing a structure where a nitrogen atom and an atom with the electronegativity difference from nitrogen atom being 0.6 or more are bonded through a single bond

Examples of this polar group include a group containing a structure represented by N—H, such as amino group.

(3) A functional group containing a structure where two atoms differing in the electronegativity by 0.5 or more are bonded through a double bond or a triple bond

Examples of this polar group include a group containing a structure represented by C≡N, C═O, N═O, S═O or C═N.

(4) A functional group having an ionic moiety

Examples of this polar group include a group having a moiety represented by N⁺ or S⁺.

Specific examples of the partial structure which can be contained in the “polar group” are illustrated below.

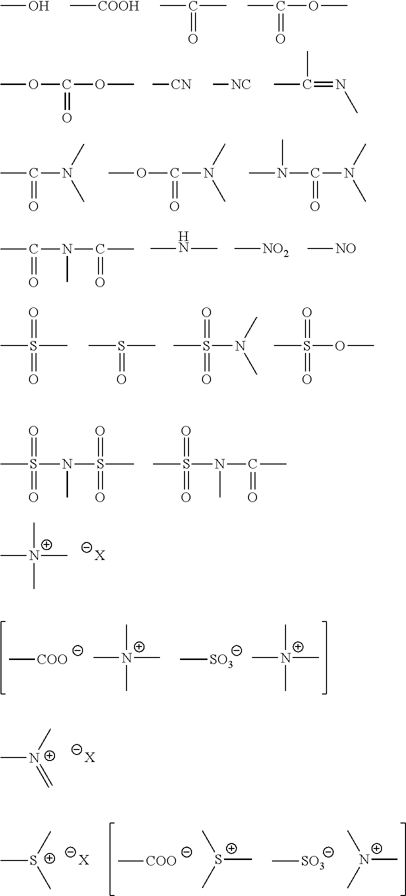

The polar group is preferably selected from a hydroxyl group, a cyano group, a lactone group, a sultone group, a carboxylic acid group, a sulfonic acid group, an amide group, a sulfonamide group, an ammonium group, a sulfonium group, a carbonate group (—O—CO—O—) (for example, a cyclic carbonic acid ester structure), and a group formed by combining two or more thereof, more preferably an alcoholic hydroxy group, a cyano group, a lactone group, a sultone group or a cyanolactone structure-containing group.

When a repeating unit having an alcoholic hydroxy group is further incorporated into the resin, the exposure latitude (EL) of a composition containing the resin can be more enhanced.

When a repeating unit having a cyano group is further incorporated into the resin, the sensitivity of a composition containing the resin can be more enhanced.

When a repeating unit having a lactone group is further incorporated into the resin, the dissolution contrast for an organic solvent-containing developer can be more enhanced. Also, a composition containing the resin can be more improved in the dry etching resistance, coatability and adherence to substrate.

When a repeating unit having a group containing a cyano group-containing lactone structure is further incorporated into the resin, the dissolution contrast for an organic solvent-containing developer can be more enhanced. Also, a composition containing the resin can be more improved in the sensitivity, dry etching resistance, coatability and adherence to substrate. In addition, functions attributable to a cyano group and a lactone group, respectively, can be undertaken by a single repeating unit and the latitude in designing the resin can be more broadened.

In the case where the polar group contained in the repeating unit (a) is an alcoholic hydroxyl group, the repeating unit is preferably represented by at least one of the following formulae (I-1H) to (I-10H), more preferably represented by at least one of the following formulae (I-1H) to (I-3H), still more preferably represented by the following formula (I-1H).

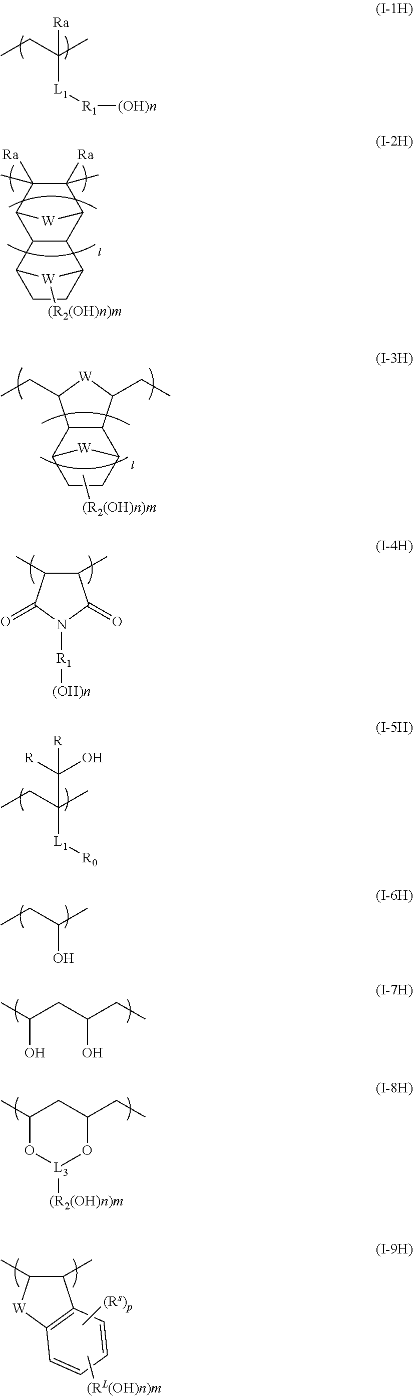

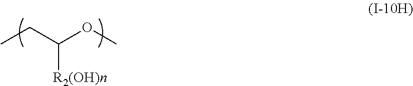

In the formulae, each Ra independently represents a hydrogen atom, an alkyl group or a group represented by —CH₂—O—Ra₂, wherein Ra₂ represents a hydrogen atom, an alkyl group or an acyl group.

R₁ represents an (n+1)-valent organic group.

R₂ represents, when m≧2, each independently represents, a single bond or an (n+1)-valent organic group.

W represents a methylene group, an oxygen atom or a sulfur atom,

n and m represent an integer of 1 or more. Incidentally, in the case where R₂ in formula (I-2), (I-3) or (I-8) represents a single bond, n is 1.

l represents an integer of 0 or more.

L₁ represents a linking group represented by —COO—, —COO—, —CONH—, —O—, —Ar—, —SO₃— or —SO₂NH—, wherein Ar represents a divalent aromatic ring group.

Each R independently represents a hydrogen atom or an alkyl group.

R₀ represents a hydrogen atom or an organic group.

L₃ represents an (m+2)-valent linking group.

R^{L} represents, when m≧2, each independently represents, an (n+1)-valent linking group.

R^{S} represents, when p≧2, each independently represents, a substituent, and when p≧2, the plurality of R^{S} may combine with each other to form a ring.

p represents an integer of 0 to 3.

Ra represents a hydrogen atom, an alkyl group or a group represented by —CH₂—O—Ra₂. Ra is preferably a hydrogen atom or an alkyl group having a carbon number of 1 to 10, more preferably a hydrogen atom or a methyl group.

W represents a methylene group, an oxygen atom or a sulfur atom. W is preferably a methylene group or an oxygen atom.

R₁ represents an (n+1)-valent organic group. R₁ is preferably a non-aromatic hydrocarbon group. In this case, R₁ may be a chain hydrocarbon group or an alicyclic hydrocarbon group. R₁ is more preferably an alicyclic hydrocarbon group.

R₂ represents a single bond or an (n+1)-valent organic group. R₂ is preferably a single bond or a non-aromatic hydrocarbon group. In this case, R₂ may be a chain hydrocarbon group or an alicyclic hydrocarbon group.

In the case where R₁ and/or R₂ are a chain hydrocarbon group, the chain hydrocarbon group may be a linear or branched-chain hydrocarbon group. The carbon number of the chain hydrocarbon group is preferably from 1 to 8. For example, when R₁ and/or R₂ are an alkylene group, R₁ and/or R₂ are preferably a methylene group, an ethylene group, an n-propylene group, an isopropylene group, an n-butylene group, an isobutylene group or a sec-butylene group.

In the case where R₁ and/or R₂ are an alicyclic hydrocarbon group, the alicyclic hydrocarbon group may be monocyclic or polycyclic. The alicylcic hydrocarbon group has, for example, a monocyclo, bicyclo, tricyclo or tetracyclo structure. The carbon number of the alicyclic hydrocarbon group is usually 5 or more, preferably from 6 to 30, more preferably from 7 to 25.

The alicyclic hydrocarbon group includes, for example, those having a partial structure illustrated below. Each of these partial structures may have a substituent. Also, in each of these partial structures, the methylene group (—CH₂—) may be substituted with an oxygen atom (—O—), a sulfur atom (—S—), a carbonyl group [—C(═O)—], a sulfonyl group [—S(═O)₂—], a sulfinyl group [—S(═O)—] or an imino group [—N(R)—] (wherein R is a hydrogen atom or an alkyl group).

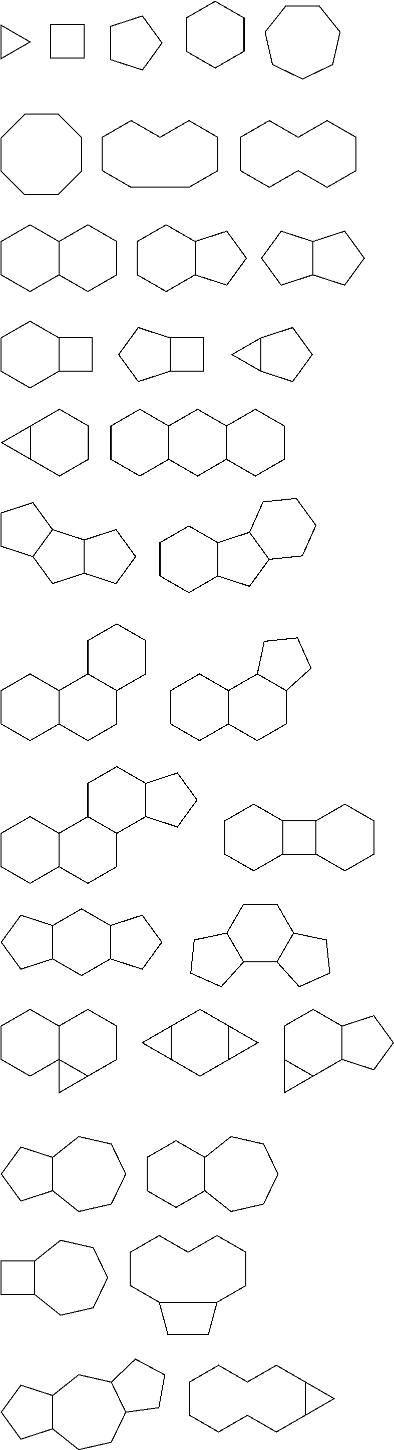

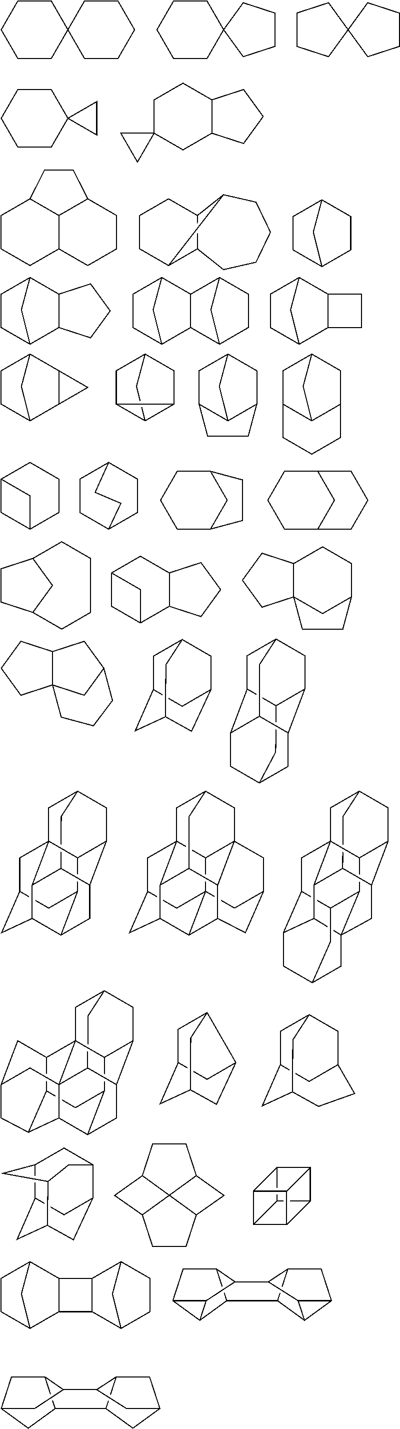

For example, when R₁ and/or R₂ are a cycloalkylene group, R₁ and/or R₂ are preferably an adamantylene group, a noradamantylene group, a decahydronaphthylene group, a tricyclodecanylene group, a tetracyclododecanylene group, a norbornylene group, a cyclopentylene group, a cyclohexylene group, a cycloheptylene group, a cyclooctylene group, a cyclodecanylene group or a cyclododecanylene group, more preferably an adamantylene group, a norbornylene group, a cyclohexylene group, a cyclopentylene group, a tetracyclododecanylene group or a tricyclodecanylene group.

The non-aromatic hydrocarbon group of R₁ and/or R₂ may have a substituent. Examples of this substituent include an alkyl group having a carbon number of 1 to 4, a halogen atom, a hydroxy group, an alkoxy group having a carbon number of 1 to 4, a carboxy group, and an alkoxycarbonyl group having a carbon number of 2 to 6. These alkyl group, alkoxy group and alkoxycarbonyl group may further have a substituent, and examples of the substituent include a hydroxy group, a halogen atom, and an alkoxy group.

L₁ represents a linking group represented by —COO—, —COO—, —CONH—, —O—, —Ar—, —SO₃— or —SO₂NH—, wherein Ar represents a divalent aromatic ring group. L₁ is preferably a linking group represented by —COO—, —CONH— or —Ar—, more preferably a linking group represented by —COO— or —CONH—.

R represents a hydrogen atom or an alkyl group. The alkyl group may be a linear alkyl group or a branched-chain alkyl group. The carbon number of this alkyl group is preferably from 1 to 6, more preferably from 1 to 3. R is preferably a hydrogen atom or a methyl group, more preferably a hydrogen atom.

R₀ represents a hydrogen atom or an organic group. Examples of the organic group include an alkyl group, a cycloalkyl group, an aryl group, an alkynyl group and an alkenyl group. R₀ is preferably a hydrogen atom or an alkyl group, more preferably a hydrogen atom or a methyl group.

L₃ represents an (m+2)-valent linking group. That is, L₃ represents a trivalent or higher valent linking group. Examples of such a linking group include corresponding groups in specific examples illustrated later.

R^{L} represents an (n+1)-valent linking group. That is, R^{L} represents a divalent or higher valent linking group. Examples of such a linking group include an alkylene group, a cycloalkylene group, and corresponding groups in specific examples illustrated later. R^{L} may combine with another R^{L} or with R^{S} to form a ring structure.

R^{S} represents a substituent. Examples of the substituent include an alkyl group, an alkenyl group, an alkynyl group, an aryl group, an alkoxy group, an acyloxy group, an alkoxycarbonyl group, and a halogen atom.

n is an integer of 1 or more. n is preferably an integer of 1 to 3, more preferably 1 or 2. Also, when n is an integer of 2 or more, the dissolution contrast for an organic solvent-containing developer can be more enhanced and in turn, the limiting resolution and roughness characteristics can be more improved.

m is an integer of 1 or more. m is preferably an integer of 1 to 3, more preferably 1 or 2.

l an integer of 0 or more. l is preferably 0 or 1.

p is an integer of 0 to 3.

When a repeating unit having a group capable of decomposing by the action of an acid to produce an alcoholic hydroxy group and a repeating unit represented by at least one formula selected from the group consisting of formulae (I-1H) to (I-10H) are used in combination, for example, thanks to suppression of acid diffusion by the alcoholic hydroxy group and increase in the sensitivity brought about by the group capable of decomposing by the action of an acid to produce an alcoholic hydroxy group, the exposure latitude (EL) can be improved without deteriorating other performances.

In the case of having an alcoholic hydroxy group, the content of this repeating unit is preferably from 1 to 60 mol %, more preferably from 3 to 50 mol %, still more preferably from 5 to 40 mol %, based on all repeating units in the resin (P).

Specific examples of the repeating unit represented by any one of formulae (I-1H) to (I-10H) are illustrated below. In specific examples, Ra has the same meaning as in formulae (I-1H) to (I-10H).

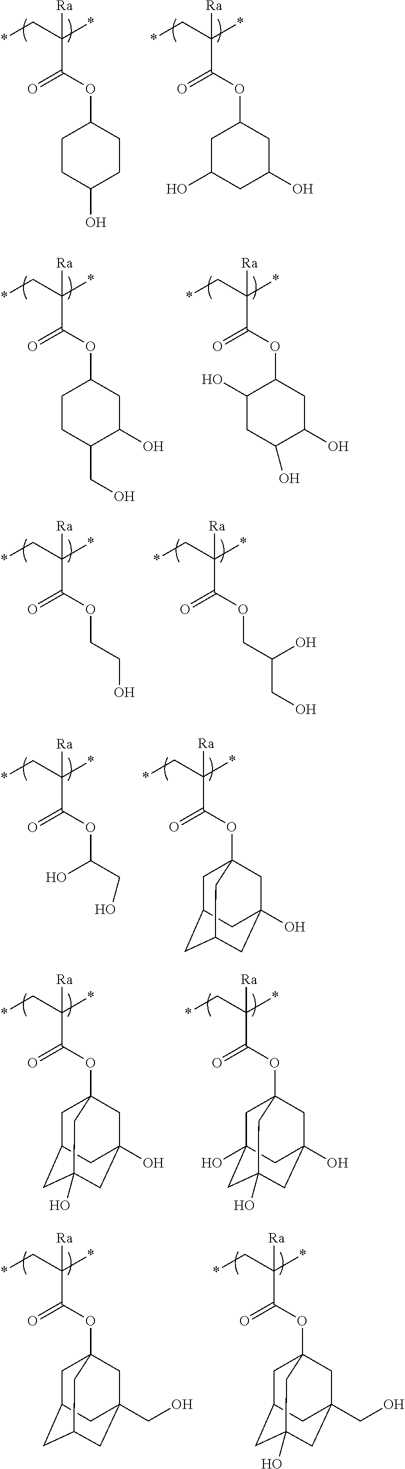

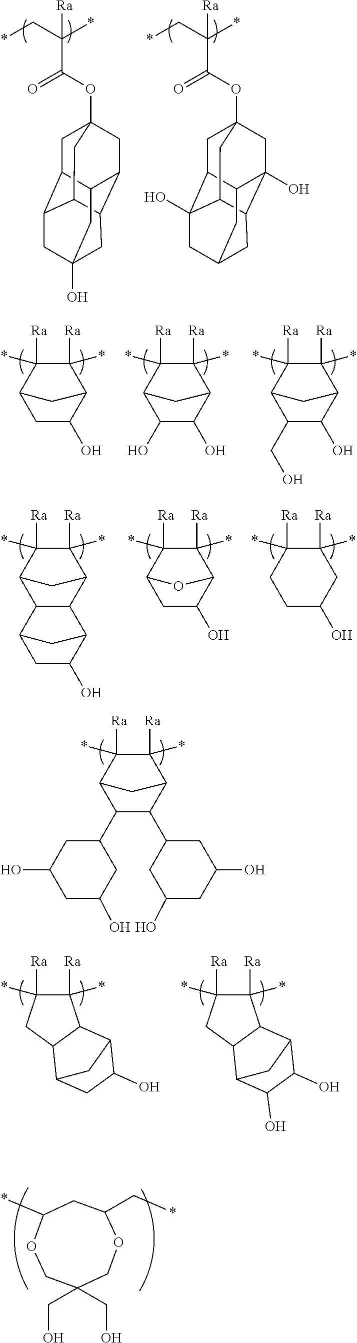

In the case where the polar group contained in the repeating unit (a) is an alcoholic hydroxy group or a cyano group, one preferred embodiment of the repeating unit is a repeating unit having an alicyclic hydrocarbon structure substituted with a hydroxyl group or a cyano group. At this time, the repeating unit preferably has no acid-decomposable group. The alicyclic hydrocarbon structure in the alicyclic hydrocarbon structure substituted with a hydroxyl group or a cyano group is preferably an adamantyl group, a diamantyl group or a norbornane group. The alicyclic hydrocarbon structure substituted with a hydroxyl group or a cyano group is preferably a partial structure represented by the following formulae (VIIa) to (VIIc). Thanks to this repeating unit, adherence to substrate and affinity for developer are enhanced.

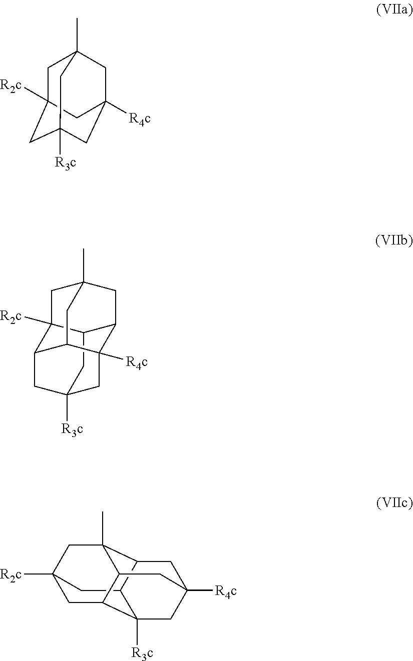

In formulae (VIIa) to (VIIc), each of R₂c to R₄c independently represents a hydrogen atom, a hydroxyl group or a cyano group, provided that at least one of R₂c to R₄c represents a hydroxyl group. A structure where one or two members of R₂c to R₄c are a hydroxyl group with the remaining being a hydrogen atom is preferred. In formula (VIIa), it is more preferred that two members of R₂c to R₄c are a hydroxyl group and the remaining is a hydrogen atom.

The repeating unit having a partial structure represented by formulae (VIIa) to (VIIc) includes repeating units represented by the following formulae (AIIa) to (AIIc):

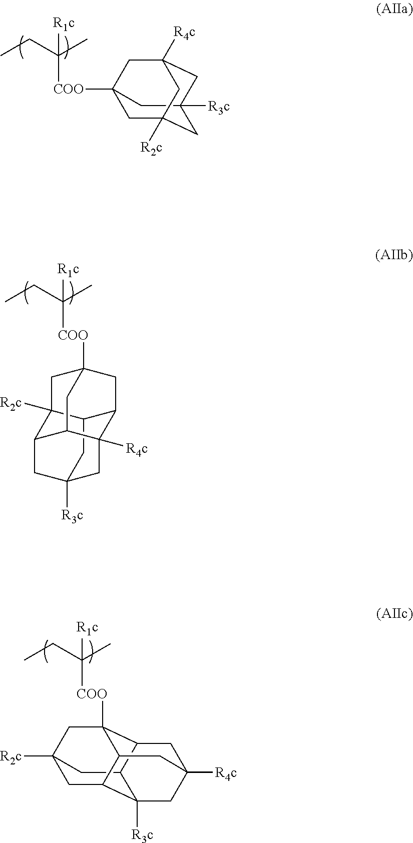

In formulae (AIIa) to (AIIc), R₁c represents a hydrogen atom, a methyl group, a trifluoromethyl group or a hydroxymethyl group.

R₂c to R₄c have the same meanings as R₂c to R₄c in formulae (VIIa) to (VIIc).

The resin (P) may or may not contain a repeating unit having a hydroxyl group or a cyano group, but in the case of containing a repeating unit having a hydroxyl group or a cyano group, the content thereof is preferably from 1 to 60 mol %, more preferably from 3 to 50 mol %, still more preferably from 5 to 40 mol %, based on all repeating units in the resin (P).

Specific examples of the repeating unit having a hydroxyl group or a cyano group are illustrated below, but the present invention is not limited thereto.

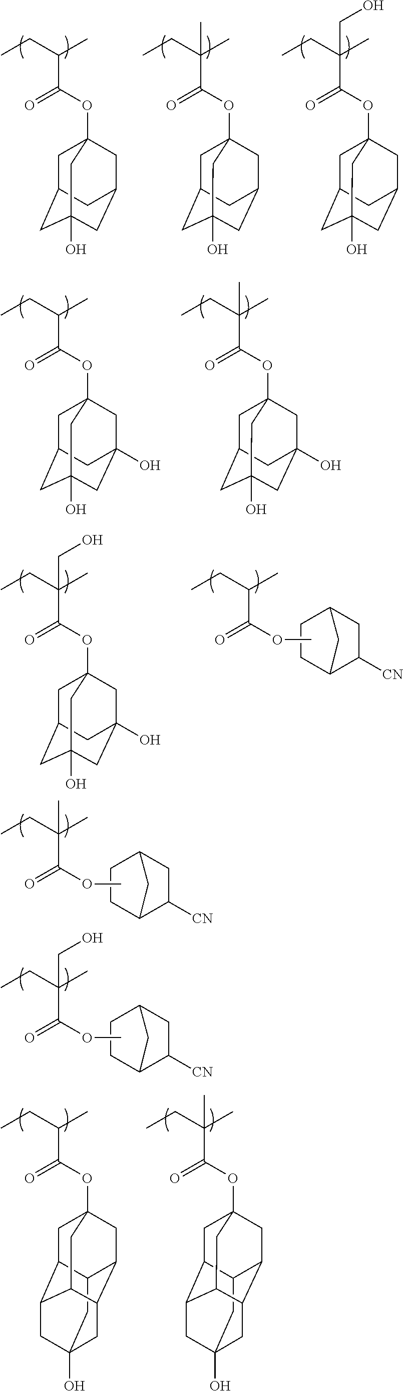

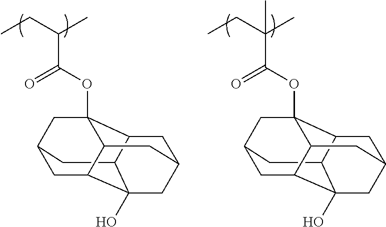

The repeating unit (a) may be a repeating unit having a lactone structure as the polar group.

The repeating unit having a lactone structure is preferably a repeating unit represented by the following formula (AII):

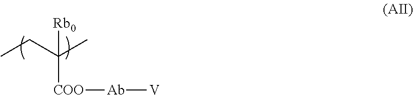

In formula (AII), Rb₀ represents a hydrogen atom, a halogen atom or an alkyl group (preferably having a carbon number of 1 to 4) which may have a substituent.

Preferred substituents which the alkyl group of Rb₀ may have include a hydroxyl group and a halogen atom. The halogen atom of Rb₀ includes a fluorine atom, a chlorine atom, a bromine atom and an iodine atom. Rb₀ is preferably a hydrogen atom, a methyl group, a hydroxymethyl group or a trifluoromethyl group, more preferably a hydrogen atom or a methyl group.

Ab represents a single bond, an alkylene group, a divalent linking group having a monocyclic or polycyclic cycloalkyl structure, an ether bond, an ester bond, a carbonyl group, or a divalent linking group formed by combining these. Ab is preferably a single bond or a divalent linking group represented by -Ab₁-CO₂—.

Ab₁ is a linear or branched alkylene group or a monocyclic or polycyclic cycloalkylene group and is preferably a methylene group, an ethylene group, a cyclohexylene group, an adamantylene group or a norbornylene group.

V represents a group having a lactone structure.

As the group having a lactone structure, any group may be used as long as it has a lactone structure, but a 5- to 7-membered ring lactone structure is preferred, and a 5- to 7-membered ring lactone structure to which another ring structure is fused to form a bicyclo or spiro structure is preferred. It is more preferred to contain a repeating unit having a lactone structure represented by any one of the following formulae (LC1-1) to (LC1-17). The lactone structure may be bonded directly to the main chain. Preferred lactone structures are (LC1-1), (LC1-4), (LC1-5), (LC1-6), (LC1-8), (LC1-13) and (LC1-14).

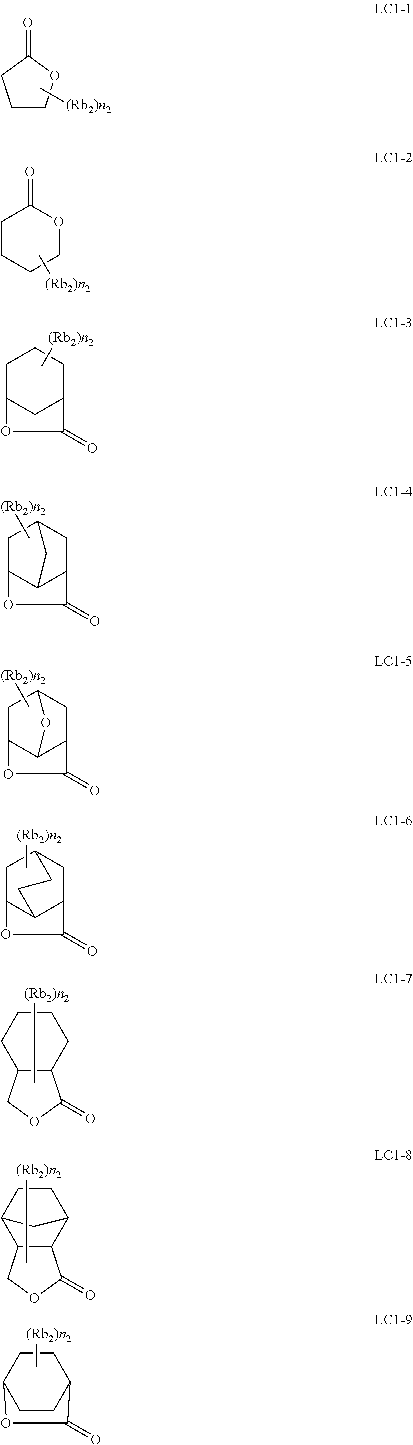

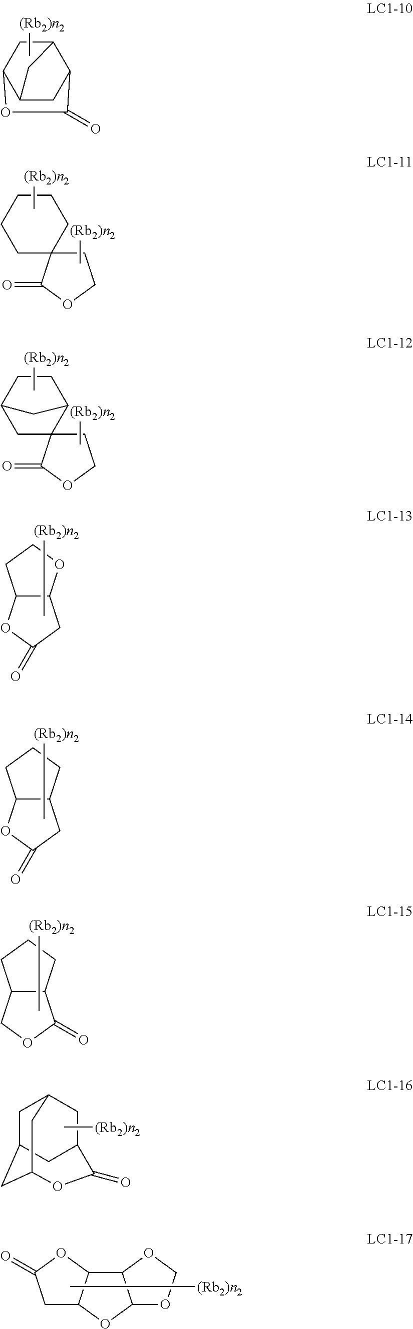

The lactone structure moiety may or may not have a substituent (Rb₂). Preferred examples of the substituent (Rb₂) include an alkyl group having a carbon number of 1 to 8, a monovalent cycloalkyl group having a carbon number of 4 to 7, an alkoxy group having a carbon number of 1 to 8, an alkoxycarbonyl group having a carbon number of 2 to 8, a carboxyl group, a halogen atom, a hydroxyl group, a cyano group, and an acid-decomposable group. Among these, an alkyl group having a carbon number of 1 to 4, a cyano group and an acid-decomposable group are more preferred. n₂ represents an integer of 0 to 4. When n₂ is 2 or more, each substituent (Rb₂) may be the same as or different from every other substituents (Rb₂) and also, the plurality of substituents (Rb₂) may combine with each other to form a ring.

The repeating unit having a lactone group usually has an optical isomer, and any optical isomer may be used. One optical isomer may be used alone, or a mixture of a plurality of optical isomers may be used. In the case of mainly using one optical isomer, the optical purity (ee) thereof is preferably 90% or more, more preferably 95% or more.

The resin (P) may or may not contain a repeating unit having a lactone structure, but in the case of containing a repeating unit having a lactone structure, the content of the repeating unit in the resin (P) is preferably from 1 to 70 mol %, more preferably from 3 to 65 mol %, still more preferably from 5 to 60 mol %, based on all repeating units.

Specific examples of the lactone structure-containing repeating unit in the resin (P) are illustrated below, but the present invention is not limited thereto. In the formulae, Rx represents H, CH₃, CH₂OH or CF₃.

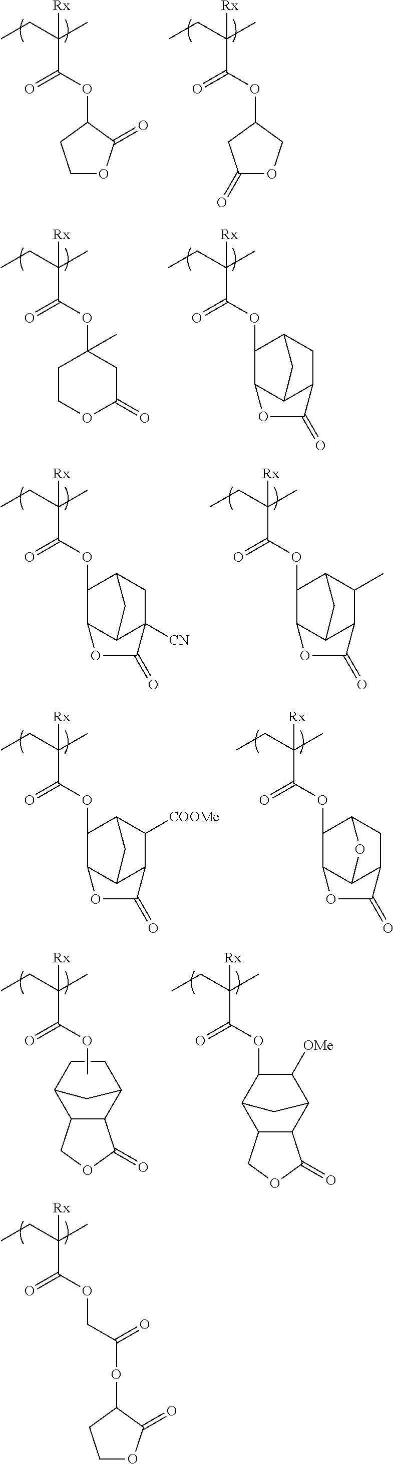

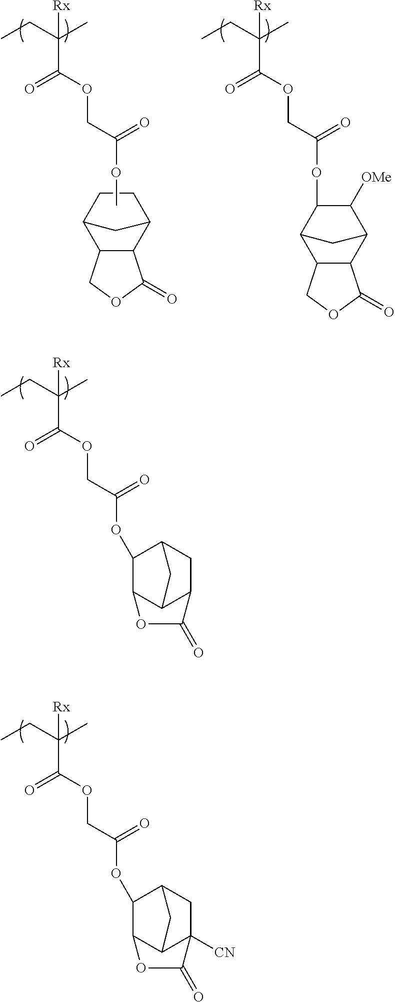

The sultone group which may be contained in the resin (P) is preferably a sultone group represented by the following formula (SL-1) or (SL-2). In the formulae, Rb₂ and n₂ have the same meanings as in formulae (LC1-1) to (LC1-17).

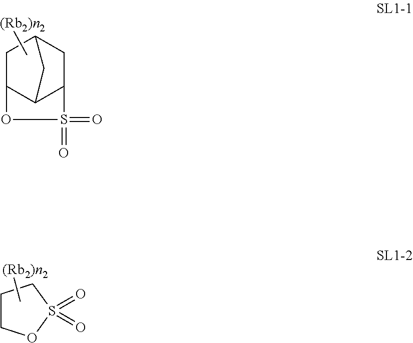

The sultone group-containing repeating unit which may be contained in the resin (P) is preferably a repeating unit where the lactone group in the above-described lactone group-containing repeating unit is replaced by a sultone group.

It is also one of particularly preferred embodiments that the polar group which can be contained in the repeating unit (a) is an acidic group. Preferred acidic groups include a phenolic hydroxyl group, a carboxylic acid group, a sulfonic acid group, a fluorinated alcohol group (such as hexafluoroisopropanol group), a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group. Among others, the repeating unit (a) is preferably a repeating unit having a carboxyl group. By virtue of containing a repeating unit having an acidic group, the resolution increases in usage of forming contact holes. As the repeating unit having an acidic group, all of a repeating unit where an acidic group is directly bonded to the main chain of the resin, such as repeating unit by an acrylic acid or a methacrylic acid, a repeating unit where an acidic group is bonded to the main chain of the resin through a linking group, and a repeating unit where an acidic group is introduced into the polymer chain terminal by using an acidic group-containing polymerization initiator or chain transfer agent at the polymerization, are preferred. In particular, a repeating unit by an acrylic acid or a methacrylic acid is preferred.

The acidic group which can be contained in the repeating unit (a) may or may not contain an aromatic ring. In the case where the repeating unit (a) contains an acidic group, the content of the repeating unit having an acidic group is preferably 30 mol % or less, more preferably 20 mol % or less, based on all repeating units in the resin (P). In the case where the resin (P) contains a repeating unit having an acidic group, the content of the repeating unit having an acidic group in the resin (P) is usually 1 mol % or more.

Specific examples of the repeating unit having an acidic group are illustrated below, but the present invention is not limited thereto.

In specific examples, Rx represents H, CH₃, CH₂OH or CF₃.

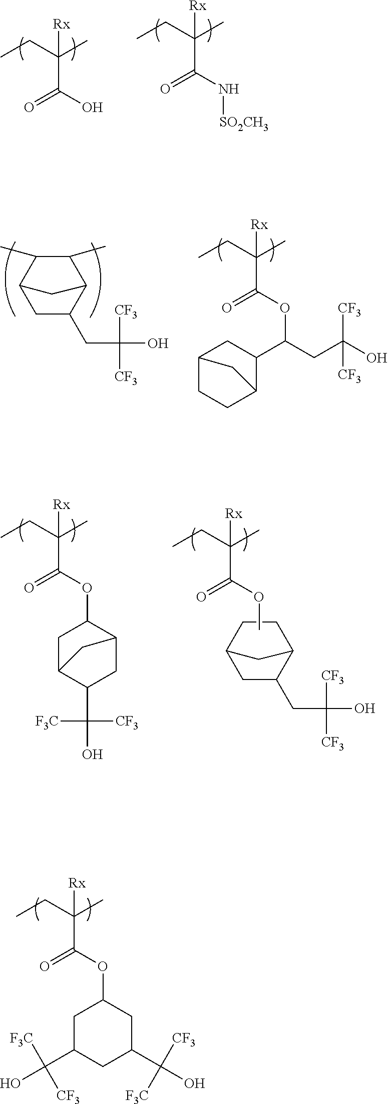

### (b) Repeating Unit Having a Plurality of Aromatic Rings

The resin (P) may contain (b) a repeating unit having a plurality of aromatic rings represented by the following formula (c1):

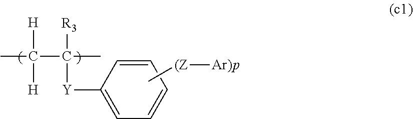

In formula (c1), R₃ represents a hydrogen atom, an alkyl group, a halogen atom, a cyano group or a nitro group;

Y represents a single bond or a divalent linking group;

Z represents a single bond or a divalent linking group;

Ar represents an aromatic ring group; and

p represents an integer of 1 or more.

The alkyl group as R₃ may be either linear or branched, and examples thereof include a methyl group, an ethyl group, an n-propyl group, an i-propyl group, an n-butyl group, a sec-butyl group, a tert-butyl group, an n-pentyl group, an n-hexyl group, an n-heptyl group, an n-octyl group, an n-nonyl group, an n-decanyl group, and an i-butyl group. The alkyl group may further have a substituent, and preferred examples of the substituent include an alkoxy group, a hydroxyl group, a halogen atom, and a nitro group. Among others, the alkyl group having a substituent is preferably, for example, a CF₃ group, an alkyloxycarbonylmethyl group, an alkylcarbonyloxymethyl group, a hydroxymethyl group or an alkoxymethyl group.

The halogen atom as R₃ includes fluorine atom, chlorine atom, bromine atom and iodine atom, with fluorine atom being preferred.

Y represents a single bond or a divalent linking group, and examples of the divalent linking group include an ether group (oxygen atom), a thioether group (sulfur atom), an alkylene group, an arylene group, a carbonyl group, a sulfide group, a sulfone group, —COO—, —CONH—, —SO₂NH—, —CF₂—, —CF₂CF₂—, —OCF₂O—, —CF₂OCF₂—, —SS—, —CH₂SO₂CH₂—, —CH₂COCH₂—, —COCF₂CO—, —COCO—, —OCOO—, —OSO₂O—, an amino group (nitrogen atom), an acyl group, an alkylsulfonyl group, —CH═CH—, —C≡C—, an aminocarbonylamino group, an aminosulfonylamino group, and a group formed by a combination thereof. Y preferably has a carbon number of 15 or less, more preferably a carbon number of 10 or less.

Y is preferably a single bond, a —COO— group, a —COS— group or a —CONH— group, more preferably a —COO— group or a —CONH— group, still more preferably a —COO— group.

Z represents a single bond or a divalent linking group, and examples of the divalent linking group include an ether group (oxygen atom), a thioether group (sulfur atom), an alkylene group, an arylene group, a carbonyl group, a sulfide group, a sulfone group, —COO—, —CONH—, —SO₂NH—, an amino group (nitrogen atom), an acyl group, an alkylsulfonyl group, —CH═CH—, an aminocarbonylamino group, an aminosulfonylamino group, and a group formed by a combination thereof.

Z is preferably a single bond, an ether group, a carbonyl group or —COO—, more preferably a single bond or an ether group, still more preferably a single bond.

Ar represents an aromatic ring group, and specific examples thereof include a phenyl group, a naphthyl group, an anthracenyl group, a phenanthrenyl group, a quinolinyl group, a furanyl group, a thiophenyl group, a fluorenyl-9-on-yl group, an anthraquinolinyl group, a phenanthraquinolinyl group, and a pyrrole group, with a phenyl group being preferred. Such an aromatic ring group may further have a substituent, and preferred examples of the substituent include an alkyl group, an alkoxy group, a hydroxy group, a halogen atom, a nitro group, an acyl group, an acyloxy group, an acylamino group, a sulfonylamino group, an aryl group such as phenyl group, an aryloxy group, an arylcarbonyl group, and a heterocyclic residue. Among these, from the standpoint of preventing deterioration of the exposure latitude or pattern profile due to out-of-band light, a phenyl group is preferred.

p is an integer of 1 or more and is preferably an integer of 1 to 3.

The repeating unit (b) is more preferably a repeating unit represented by the following formula (c2):

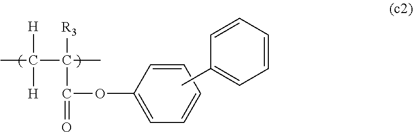

In formula (c2), R₃ represents a hydrogen atom or an alkyl group. Preferred examples of the alkyl group as R₃ are the same as in formula (c1).

Here, as concerns the extreme-ultraviolet (EUV) exposure, leakage light (out-of-band light) generated in the ultraviolet region at a wavelength of 100 to 400 nm worsens the surface roughness, as a result, the resolution and LWR performance tend to be impaired due to bridge between patterns or disconnection of pattern.

However, the aromatic ring in the repeating unit (b) functions as an internal filter capable of absorbing the above-described out-of-band light. Accordingly, in view of high resolution and low LWR, the resin (P) preferably contains the repeating unit (b).

In this connection, from the standpoint of obtaining high resolution, the repeating unit (b) is preferably free from a phenolic hydroxyl group (a hydroxyl group bonded directly on an aromatic ring).

Specific examples of the repeating unit (b) are illustrated below, but the present invention is not limited thereto.

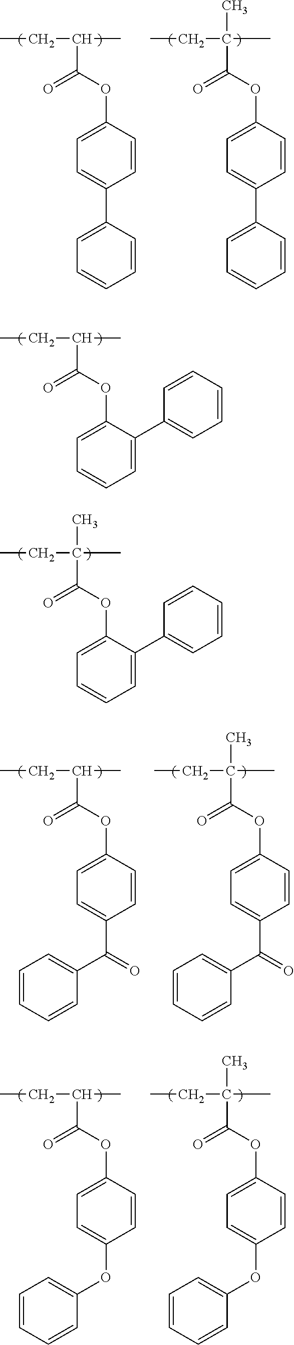

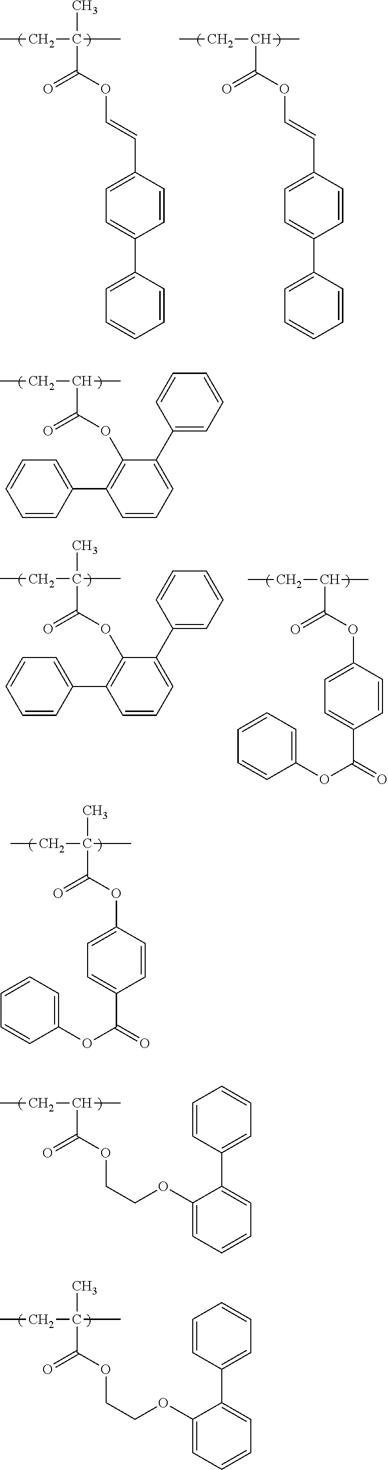

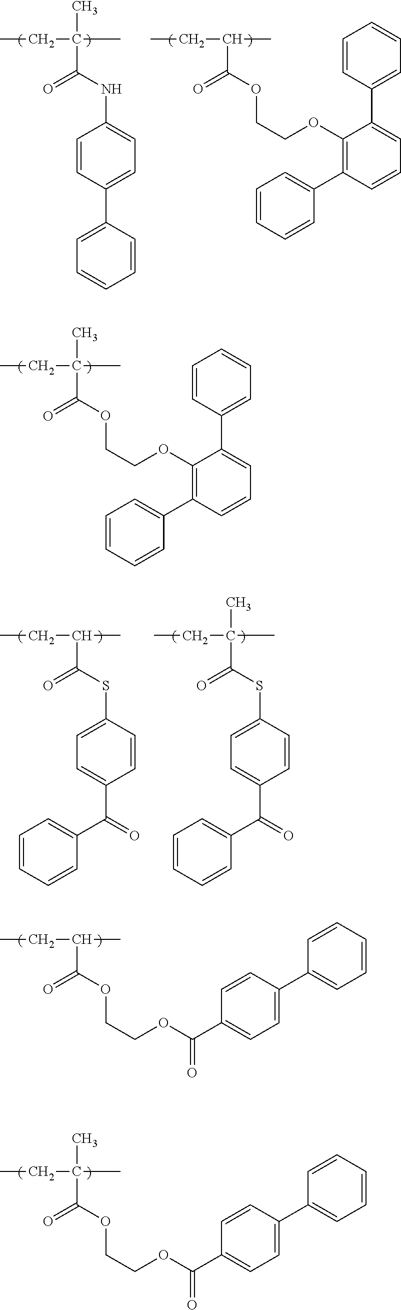

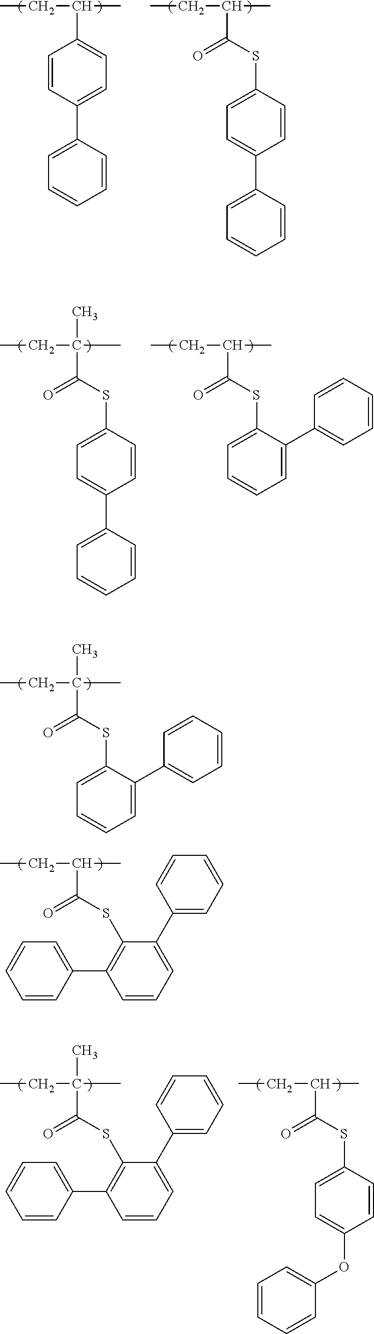

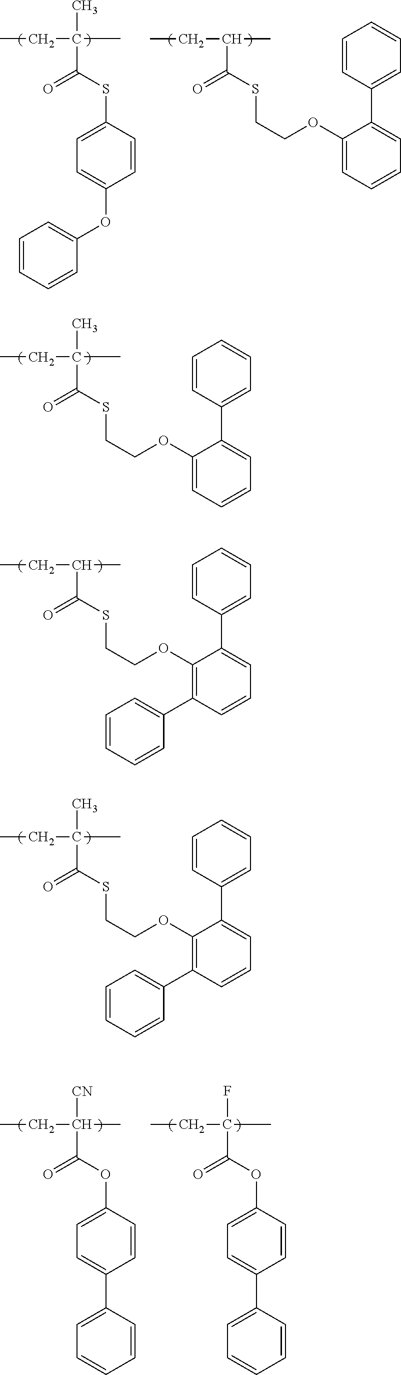

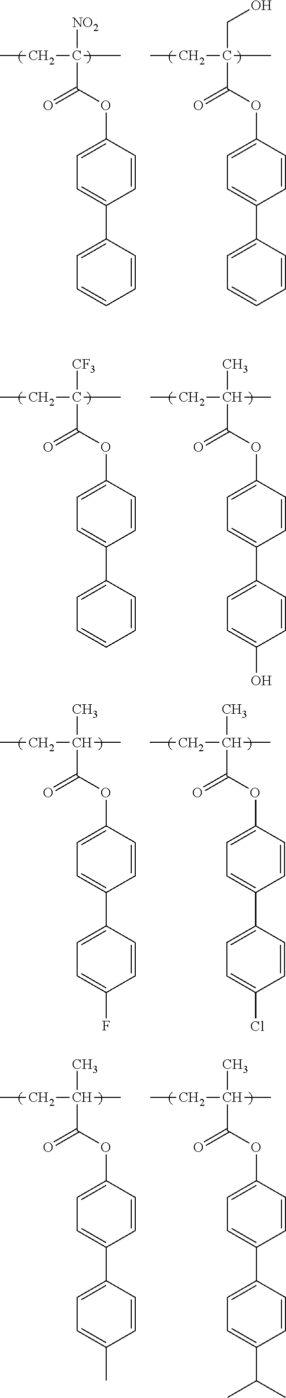

The resin (P) may or may not contain the repeating unit (b), but in the case containing the repeating unit (b), the content thereof is preferably from 1 to 30 mol %, more preferably from 1 to 20 mol %, still more preferably from 1 to 15 mol %, based on all repeating units in the resin (P). As for the repeating unit (b) contained in the resin (P), two or more kinds of repeating units may be contained in combination.

The resin (P) for use in the present invention may appropriately contain a repeating unit other than the above-described repeating unit (a) or (b). As an example of such a repeating unit, the resin may contain a repeating unit having an alicyclic hydrocarbon structure free from a polar group (for example, the above-described acid group, a hydroxyl group or a cyano group) and not exhibiting acid decomposability. Thanks to this configuration, the solubility of the resin at the development using an organic solvent-containing developer can be appropriately adjusted. Such a repeating unit includes a repeating unit represented by formula (IV):

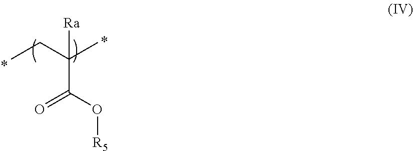

In formula (IV), R₅ represents a hydrocarbon group having at least one cyclic structure and having no polar group.

Ra represents a hydrogen atom, an alkyl group or a —CH₂—O—Ra₂ group, wherein Ra_{z} represents a hydrogen atom, an alkyl group or an acyl group. Ra is preferably a hydrogen atom, a methyl group, a hydroxymethyl group or a trifluoromethyl group, more preferably a hydrogen atom or a methyl group.

The cyclic structure contained in R₅ includes a monocyclic hydrocarbon group and a polycyclic hydrocarbon group. Examples of the monocyclic hydrocarbon group include a cycloalkyl group having a carbon number of 3 to 12, such as cyclopentyl group, cyclohexyl group, cycloheptyl group and cyclooctyl group, and a cycloalkenyl group having a carbon number of 3 to 12, such as cyclohexenyl group. The monocyclic hydrocarbon group is preferably a monocyclic hydrocarbon group having a carbon number of 3 to 7, more preferably a cyclopentyl group or a cyclohexyl group.

The polycyclic hydrocarbon group includes a ring assembly hydrocarbon group and a crosslinked cyclic hydrocarbon group. Examples of the ring assembly hydrocarbon group include a bicyclohexyl group and a perhydronaphthalenyl group. Examples of the crosslinked cyclic hydrocarbon ring include a bicyclic hydrocarbon ring such as pinane ring, bornane ring, norpinane ring, norbornane ring and bicyclooctane ring (e.g., bicyclo[2.2.2]octane ring, bicyclo[3.2.1]octane ring), a tricyclic hydrocarbon ring such as homobledane ring, adamantane ring, tricyclo[5.2.1.0^{2,6}]decane ring and tricyclo[4.3.1.1^{2,5}]undecane ring, and a tetracyclic hydrocarbon ring such as tetracyclo[4.4.0.1^{2,5}.1^{7,10}]dodecane ring and perhydro-1,4-methano-5,8-methanonaphthalene ring. The crosslinked cyclic hydrocarbon ring also includes a condensed cyclic hydrocarbon ring, for example, a condensed ring formed by fusing a plurality of 5- to 8-membered cycloalkane rings, such as perhydronaphthalene (decalin) ring, perhydroanthracene ring, perhydrophenathrene ring, perhydroacenaphthene ring, perhydrofluorene ring, perhydroindene ring and perhydrophenalene ring.

Preferred examples of the crosslinked cyclic hydrocarbon ring include a norbornyl group, an adamantyl group, a bicyclooctanyl group, and a tricyclo[5,2,1,0^{2,6}]decanyl group. Among these crosslinked cyclic hydrocarbon rings, a norbornyl group and an adamantyl group are more preferred.

Such an alicyclic hydrocarbon group may have a substituent, and preferred examples of the substituent include a halogen atom, an alkyl group, a hydroxyl group with a hydrogen atom being substituted for, and an amino group with a hydrogen atom being substituted for. The halogen atom is preferably bromine atom, chlorine atom or fluorine atom, and the alkyl group is preferably a methyl group, an ethyl group, a butyl group or a tert-butyl group. This alkyl group may further have a substituent, and the substituent which may be further substituted on the alkyl group includes a halogen atom, an alkyl group, a hydroxyl group with a hydrogen atom being substituted for, and an amino group with a hydrogen atom being substituted for.

Examples of the substituent for the hydrogen atom include an alkyl group, a cycloalkyl group, an aralkyl group, a substituted methyl group, a substituted ethyl group, an alkoxycarbonyl group, and an aralkyloxycarbonyl group. The alkyl group is preferably an alkyl group having a carbon number of 1 to 4; the substituted methyl group is preferably a methoxymethyl group, a methoxythiomethyl group, a benzyloxymethyl group, a tert-butoxymethyl group or a 2-methoxyethoxymethyl group; the substituted ethyl group is preferably a 1-ethoxyethyl group or a 1-methyl-1-methoxyethyl group; the acyl group is preferably an aliphatic acyl group having a carbon number of 1 to 6, such as formyl group, acetyl group, propionyl group, butyryl group, isobutyryl group, valeryl group and pivaloyl group; and the alkoxycarbonyl group includes, for example, an alkoxycarbonyl group having a carbon number of 1 to 4.

The resin (P) may or may not contain a repeating unit having an alicyclic hydrocarbon structure free from a polar group and not exhibiting acid decomposability, but in the case of containing this repeating unit, the content thereof is preferably from 1 to 20 mol %, more preferably from 5 to 15 mol %, based on all repeating units in the resin (P).

Specific examples of the repeating unit having an alicyclic hydrocarbon structure free from a polar group and not exhibiting acid decomposability are illustrated below, but the present invention is not limited thereto. In the formulae, Ra represents H, CH₃, CH₂OH or CF₃.

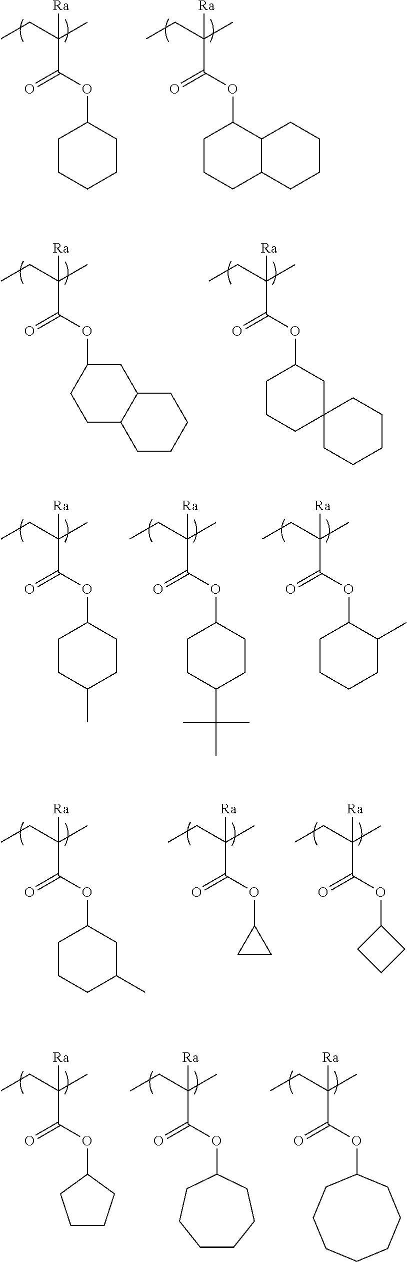

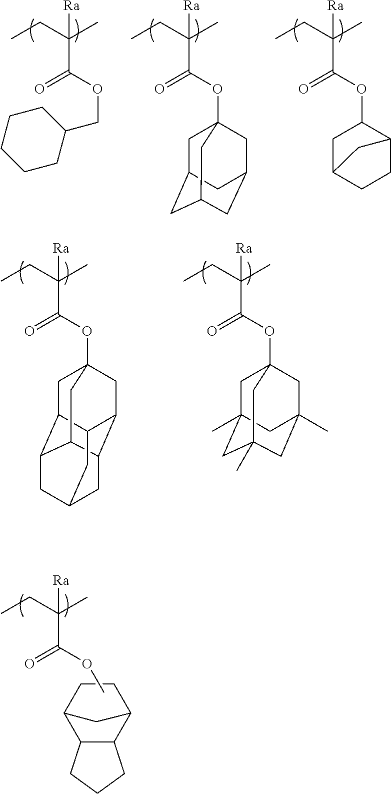

From the standpoint of elevating Tg, improving dry etching resistance and producing an effect such as internal filter for out-of-band-light, the resin (P) may contain the following monomer component.

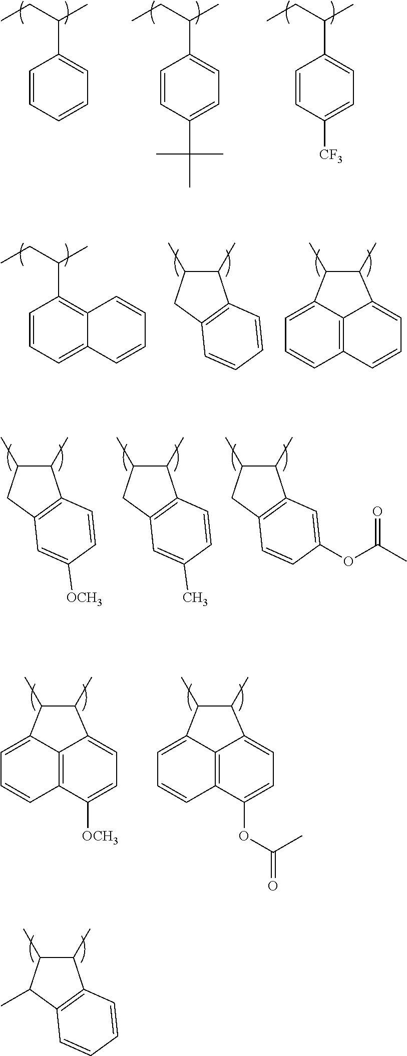

Also, the resin (P) may contain a repeating unit having a cyclic carbonic acid ester structure.

The repeating unit having a cyclic carbonic acid ester structure is preferably a repeating unit represented by the following formula (A-1):

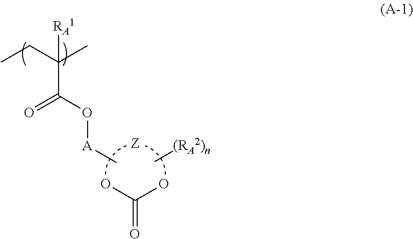

In formula (A-1), R_{A}¹ represents a hydrogen atom or an alkyl group.

R_{A}² represents, when n is 2 or more, each independently represents, a substituent.

A represents a single bond or a divalent linking group.

Z represents an atomic group necessary for forming a monocyclic or polycyclic structure together with the group represented by —O—C(═O)—O— in the formula.

n represents an integer of 0 or more.

Formula (A-1) is described in detail below.

The alkyl group represented by R_{A}¹ may have a substituent such as fluorine atom. R_{A}¹ preferably represents a hydrogen atom, a methyl group or a trifluoromethyl group, more preferably represents a methyl group.

The substituent represented by R_{A}² is, for example, an alkyl group, a cycloalkyl group, a hydroxyl group, an alkoxy group, an amino group or an alkoxycarbonyl group and is preferably an alkyl group having a carbon number of 1 to 5, and examples thereof include a linear alkyl group having a carbon number of 1 to 5, such as methyl group, ethyl group, propyl group and butyl group, and a branched alkyl group having a carbon number of 3 to 5, such as isopropyl group, isobutyl group and tert-butyl group. The alkyl may have a substituent such as hydroxyl group.

n represents the number of substituents and is an integer of 0 or more. For example,

n is preferably from 0 to 4, more preferably 0.

The divalent linking group represented by A includes, for example, an alkylene group, a cycloalkylene group, an ester bond, an amido bond, an ether bond, a urethane bond, a urea bond, and a combination thereof. The alkylene group is preferably an alkylene group having a carbon number of 1 to 10, more preferably an alkylene group having a carbon number of 1 to 5, and examples thereof include a methylene group, an ethylene group, and a propylene group.

In one embodiment of the present invention, A is preferably a single bond or an alkylene group.

The monocyclic ring containing —O—C(═O)—O— represented by Z includes, for example, a 5- to 7-membered ring where in the cyclic carbonic acid ester represented by the following formula (a), n_{A} is from 2 to 4, and is preferably a 5- or 6-membered ring (n_{A} is 2 or 3), more preferably a 5-membered ring (n_{A} is 2).

The polycyclic ring containing —O—C(═O)—O— represented by Z includes, for example, a structure where the cyclic carbonic acid ester represented by the following formula (a) forms a condensed ring together with one other ring structure or two or more other ring structures, and a structure where a spiro ring is formed. The “other ring structure” capable of forming a condensed ring or a spiro ring may be an alicyclic hydrocarbon group or an aromatic hydrocarbon group or may be a heterocyclic ring.

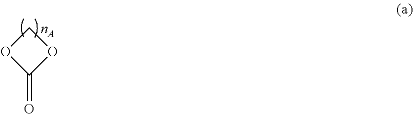

The monomer corresponding to the repeating unit represented by formula (A-1) can be synthesized by a conventionally known method described, for example, in Tetrahedron Letters, Vol. 27, No. 32, page 3741 (1986), and Organic Letters, Vol. 4, No. 15, page 2561 (2002).

In the resin (P), one of repeating units represented by formula (A-1) may be contained alone, or two or more thereof may be contained.

Specific examples of the repeating unit having a cyclic carbonic acid ester structure are illustrated below, but the present invention is not limited thereto.

In specific examples, R_{A}¹ has the same meaning as R_{A}¹ in formula (A-1).

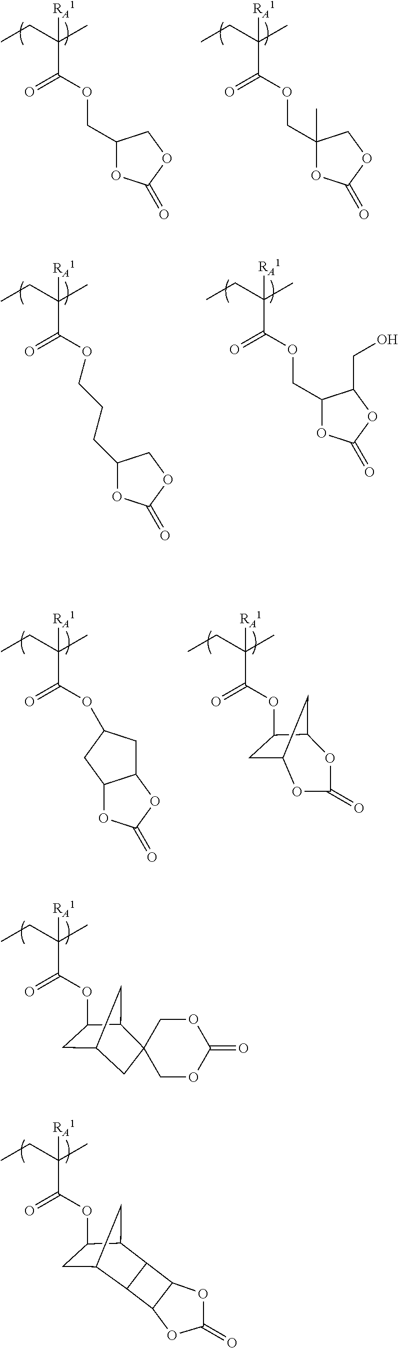

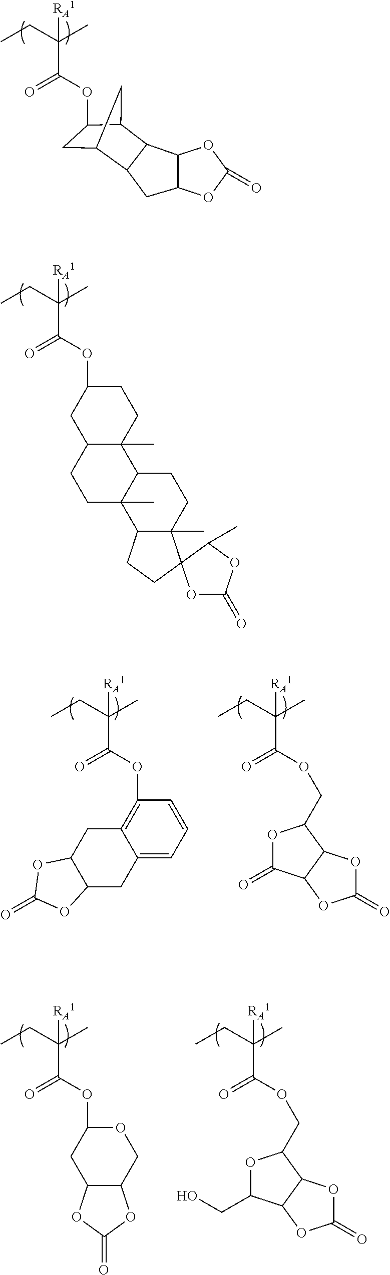

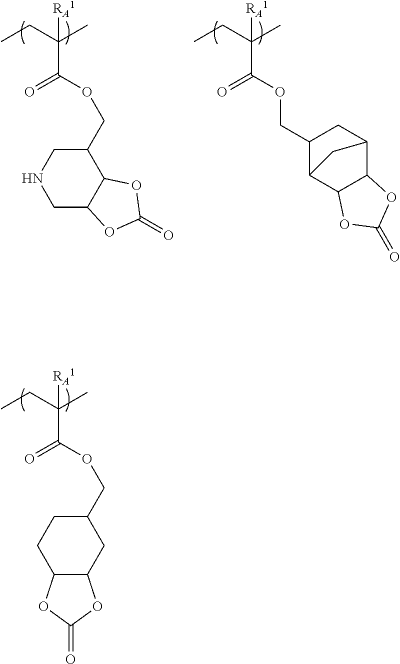

As for the repeating unit having a cyclic carbonic acid ester structure, the resin (P) may contain one repeating unit or may contain two or more repeating units.

In the case where the resin (P) contains a repeating unit having a cyclic carbonic acid ester structure, the content of the repeating unit having a cyclic carbonic acid ester structure is preferably from 5 to 60 mol %, more preferably from 5 to 55 mol %, still more preferably from 10 to 50 mol %, based on all repeating units in the resin (P).

In the resin (P) for use in the composition of the present invention, the molar ratio of respective repeating structural units contained is appropriately set so as to control the dry etching resistance of resist, the suitability for standard developer, the adherence to substrate, the resist profile, and performances generally required of the resist, such as resolution, heat resistance and sensitivity.

The form of the resin (P) for use in the present invention may be any of random type, block type, comb type and star type.

The resin (P) can be synthesized, for example, by radical, cationic or anionic polymerization of unsaturated monomers corresponding to respective structures. It is also possible to obtain the target resin by polymerizing unsaturated monomers corresponding to precursors of respective structures and then performing a polymer reaction.

Examples of the general synthesis method include a batch polymerization method of dissolving unsaturated monomers and a polymerization initiator in a solvent and heating the solution, thereby effecting the polymerization, and a dropping polymerization method of adding dropwise a solution containing unsaturated monomers and a polymerization initiator to a heated solvent over 1 to 10 hours. A dropping polymerization method is preferred.

The solvent used for the polymerization includes, for example, a solvent which can be used when preparing the later-described actinic ray-sensitive or radiation-sensitive resin composition, and it is more preferred to perform the polymerization by using the same solvent as the solvent used in the composition of the present invention. By the use of this solvent, production of particles during storage can be suppressed.

The polymerization reaction is preferably performed in an inert gas atmosphere such as nitrogen or argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile, and dimethyl 2,2′-azobis(2-methylpropionate). If desired, the polymerization may be performed in the presence of a chain transfer agent (e.g., alkylmercaptan).

The concentration during the reaction is from 5 to 70 mass %, preferably from 10 to 50 mass %, and the reaction temperature is usually from 10 to 150° C., preferably from 30 to 120° C., more preferably from 40 to 100° C.

The reaction time is usually from 1 to 48 hours, preferably from 1 to 24 hours, more preferably from 1 to 12 hours.

After the completion of reaction, the reaction solution is allowed to cool to room temperature and purified. In the purification, a conventional method, for example, a liquid-liquid extraction method of applying water washing or combining an appropriate solvent to remove residual monomers or oligomer components, a purification method in a solution sate, such as ultrafiltration of removing by extraction only polymers having a molecular weight lower than a specific molecular weight, a reprecipitation method of adding dropwise the resin solution to a poor solvent to solidify the resin in the poor solvent and thereby remove residual monomers or the like, or a purification method in a solid state, such as washing of the resin slurry with a poor solvent after separation of the slurry by filtration, may be applied. For example, the resin is precipitated as a solid by contacting the reaction solution with a solvent in which the resin is sparingly soluble or insoluble (poor solvent) and which is in a volumetric amount of 10 times or less, preferably from 10 to 5 times, the reaction solution.

The solvent used at the operation of precipitation or reprecipitation from the polymer solution (precipitation or reprecipitation solvent) may be sufficient if it is a poor solvent to the polymer, and the solvent which can be used may be appropriately selected from a hydrocarbon, a halogenated hydrocarbon, a nitro compound, an ether, a ketone, an ester, a carbonate, an alcohol, a carboxylic acid, water, a mixed solvent containing such a solvent, and the like, according to the kind of the polymer. Among these solvents, a solvent containing at least an alcohol (particularly, methanol or the like) or water is preferred as the precipitation or reprecipitation solvent.

The amount of the precipitation or reprecipitation solvent used may be appropriately selected by taking into consideration the efficiency, yield and the like, but in general, the amount used is from 100 to 10,000 parts by mass, preferably from 200 to 2,000 parts by mass, more preferably from 300 to 1,000 parts by mass, per 100 parts by mass of the polymer solution.

The temperature at the precipitation or reprecipitation may be appropriately selected by taking into consideration the efficiency or operability but is usually on the order of 0 to 50° C., preferably in the vicinity of room temperature (for example, approximately from 20 to 35° C.). The precipitation or reprecipitation operation may be performed using a commonly employed mixing vessel such as stirring tank, by a known method such as batch system and continuous system.

The precipitated or reprecipitated polymer is usually subjected to commonly employed solid-liquid separation such as filtration and centrifugation, then dried and used. The filtration is performed using a solvent-resistant filter element preferably under pressure. The drying is performed under atmospheric pressure or reduced pressure (preferably under reduced pressure) at a temperature of approximately from 30 to 100° C., preferably on the order of 30 to 50° C.

Incidentally, after the resin is once precipitated and separated, the resin may be again dissolved in a solvent and then put into contact with a solvent in which the resin is sparingly soluble or insoluble. That is, there may be used a method comprising, after the completion of radical polymerization reaction, bringing the polymer into contact with a solvent in which the polymer is sparingly soluble or insoluble, to precipitate a resin (step a), separating the resin from the solution (step b), anew dissolving the resin in a solvent to prepare a resin solution A (step c), bringing the resin solution A into contact with a solvent in which the resin is sparingly soluble or insoluble and which is in a volumetric amount of less than 10 times (preferably 5 times or less) the resin solution A, to precipitate a resin solid (step d), and separating the precipitated resin (step e).

The polymerization reaction is preferably performed in an inert gas atmosphere such as nitrogen or argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile, and dimethyl 2,2′-azobis(2-methylpropionate). The initiator is added additionally or in parts, if desired. After the completion of reaction, the reaction product is poured in a solvent, and the desired polymer is collected, for example, by a method for powder or solid recovery. The concentration during the reaction is from 5 to 50 mass %, preferably from 10 to 30 mass %, and the reaction temperature is usually from 10 to 150° C., preferably from 30 to 120° C., more preferably from 60 to 100° C.

The molecular weight of the resin (P) according to the present invention is not particularly limited, but the weight average molecular weight is preferably from 1,000 to 100,000, more preferably from 1,500 to 60,000, still more preferably from 2,000 to 30,000. When the weight average molecular weight is from 1,000 to 100,000, the heat resistance and dry etching resistance can be kept from deterioration and at the same time, the film-forming property can be prevented from becoming poor due to impairment of developability or increase in the viscosity. Here, the weight average molecular weight of the resin indicates a molecular weight in terms of polystyrene measured by GPC (carrier: THF (tetrahydrofuran) or N-methyl-2-pyrrolidone (NMP)).

The polydispersity (Mw/Mn) is preferably from 1.00 to 5.00, more preferably from 1.03 to 3.50, still more preferably from 1.05 to 2.50. As the molecular weight distribution is narrower, the resolution and resist profile are more excellent, the side wall of the resist pattern is smoother, and the roughness is more improved.

As for the resin (P) used in the present invention, one kind of a resin may be used alone, or two or more kinds of resins may be used in combination. The content of the resin (P) is preferably from 20 to 99 mass %, more preferably from 30 to 89 mass %, still more preferably from 40 to 79 mass %, based on the total solid content in the actinic ray-sensitive or radiation-sensitive resin composition of the present invention.

Specific examples of the resin (P) are illustrated below, but the present invention is not limited thereto.

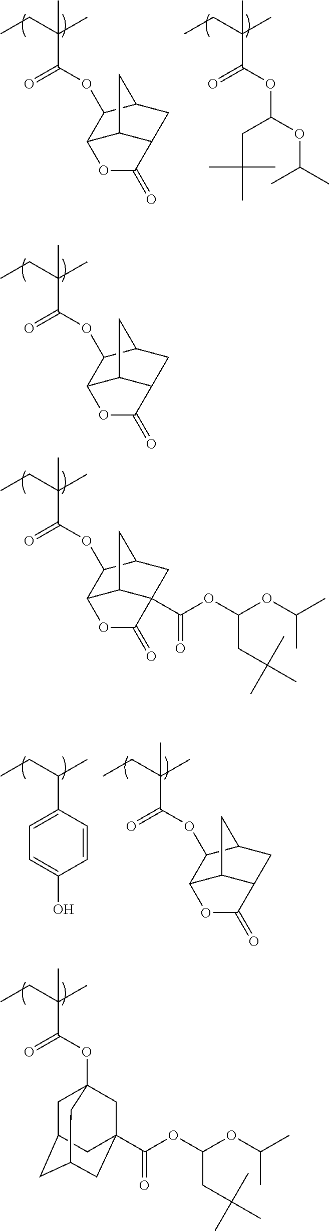

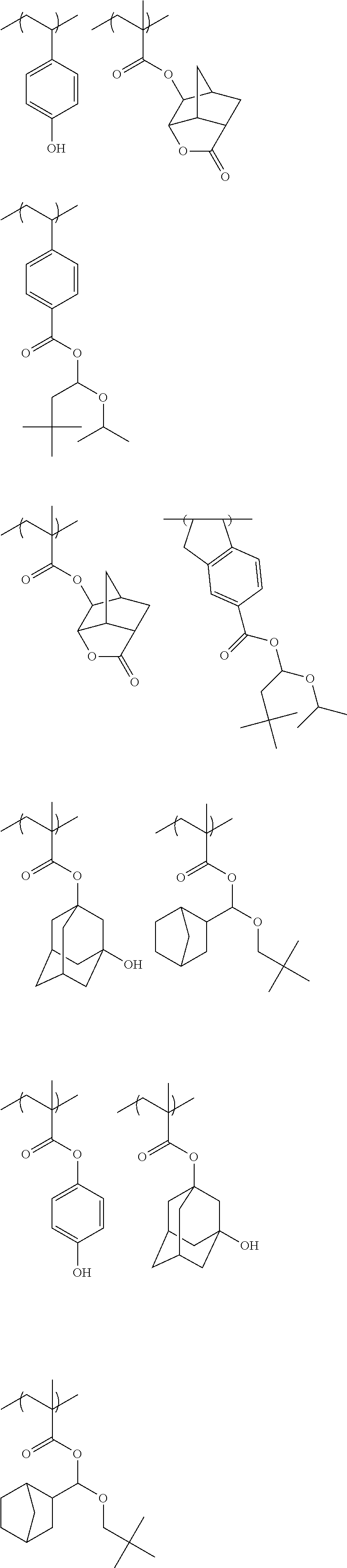

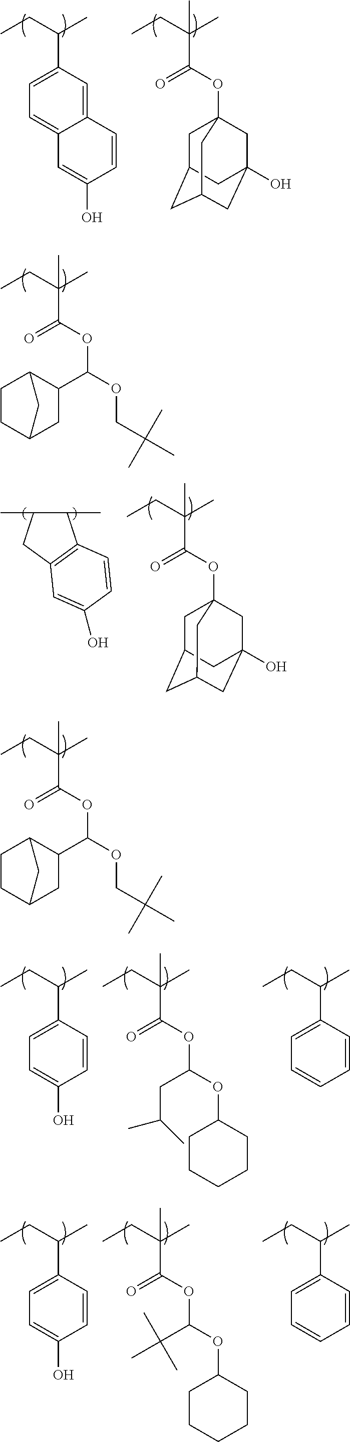

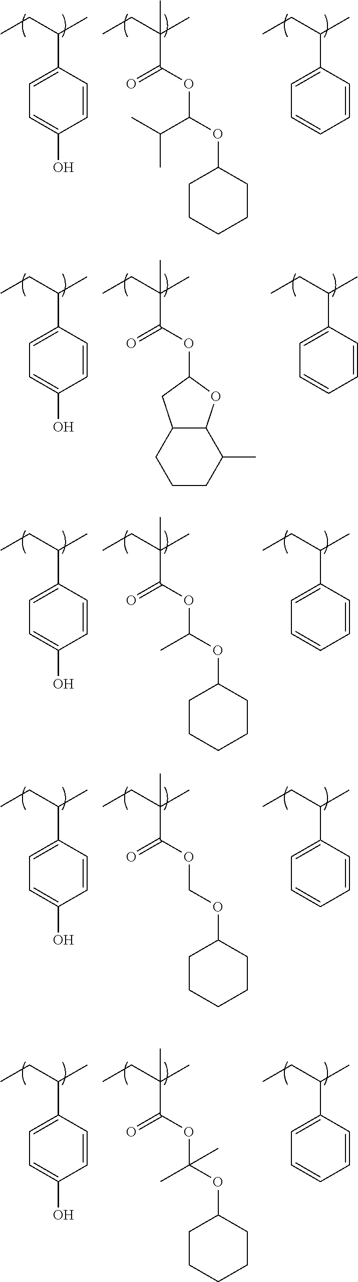

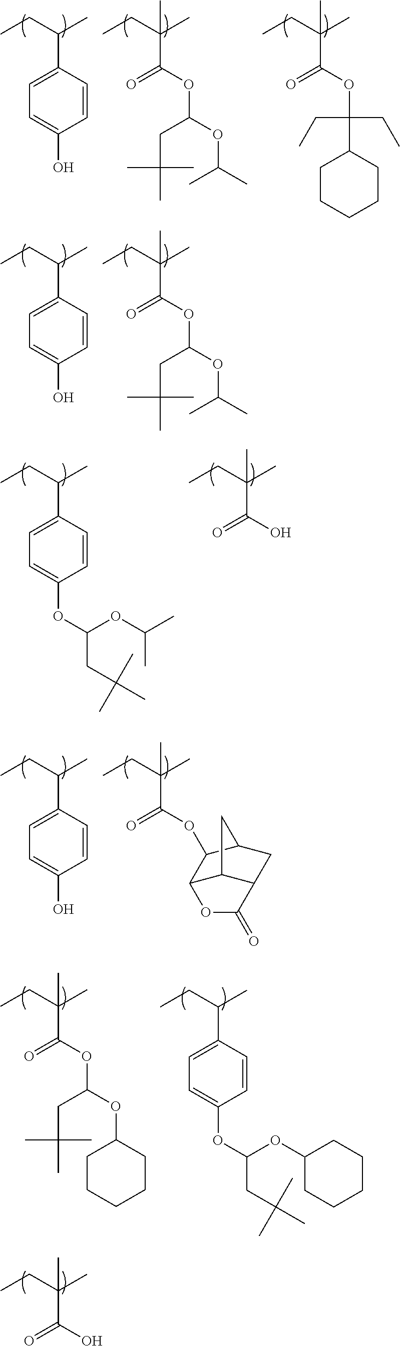

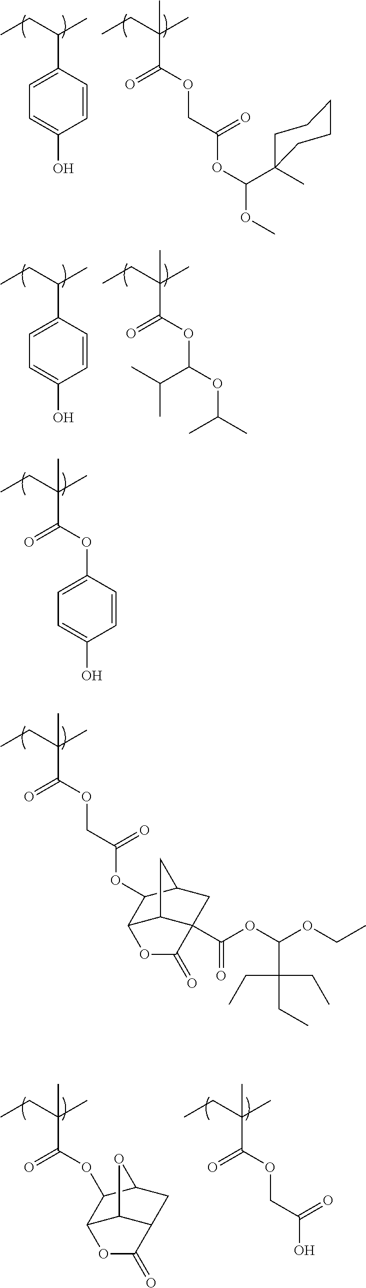

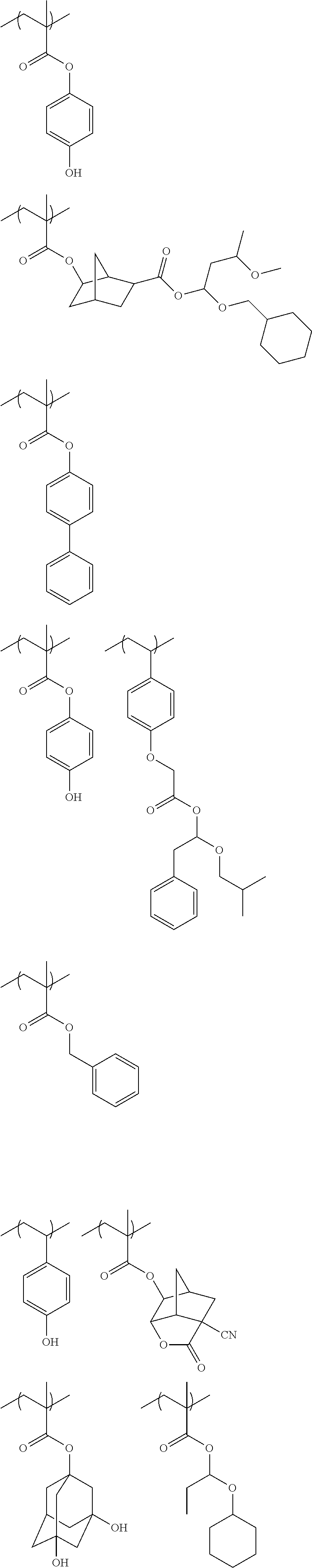

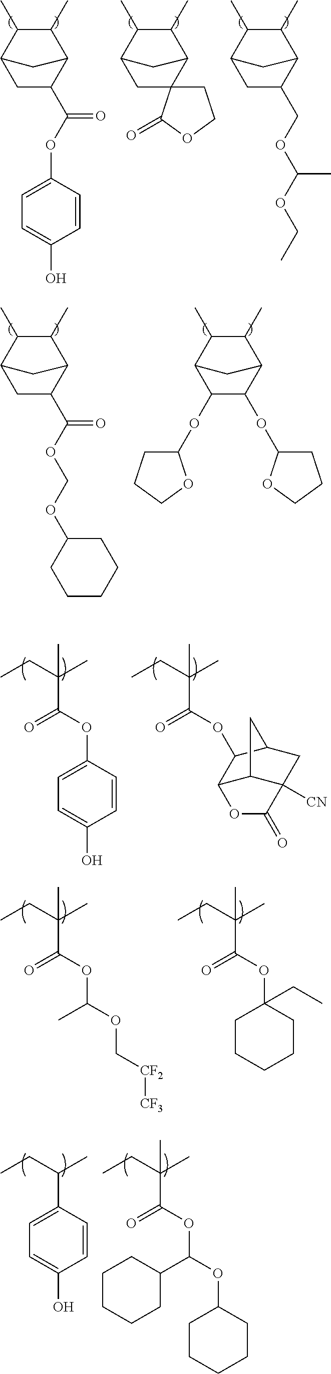

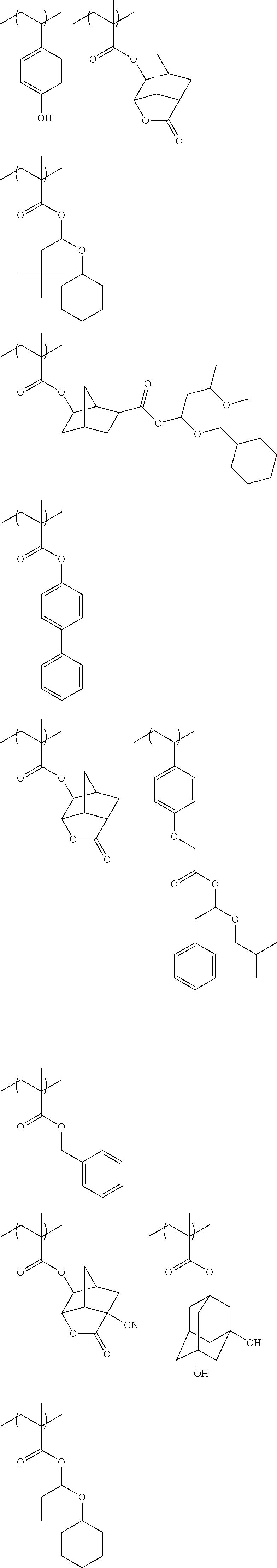

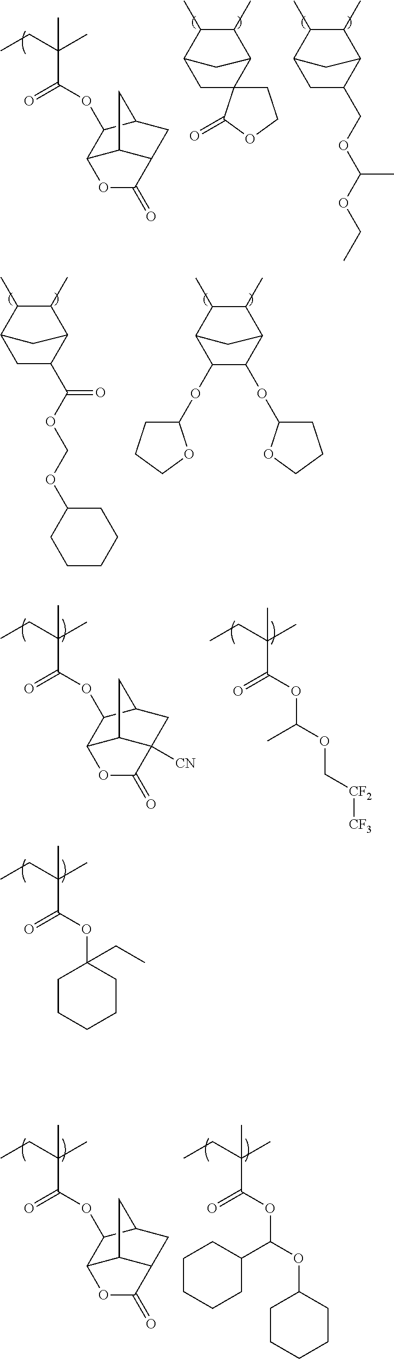

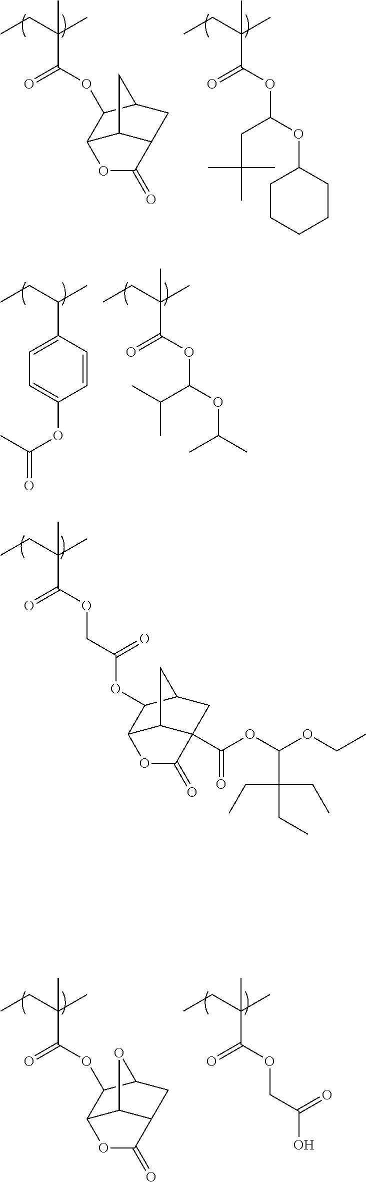

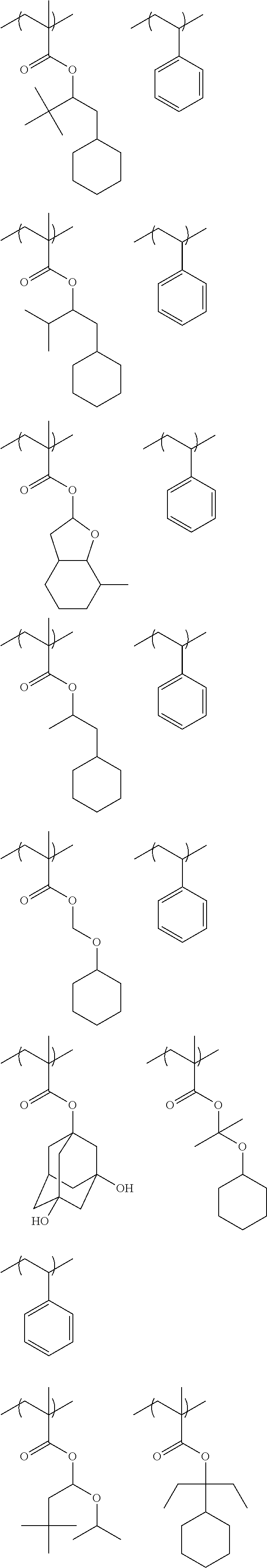

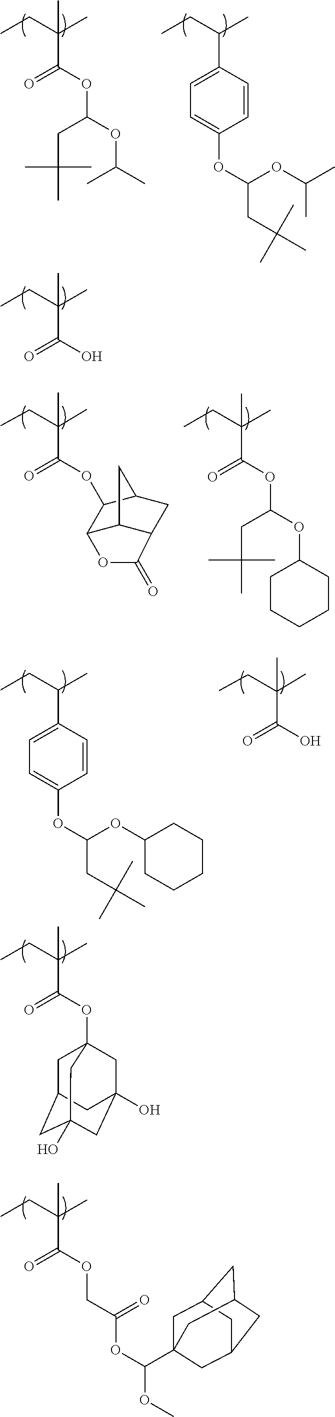

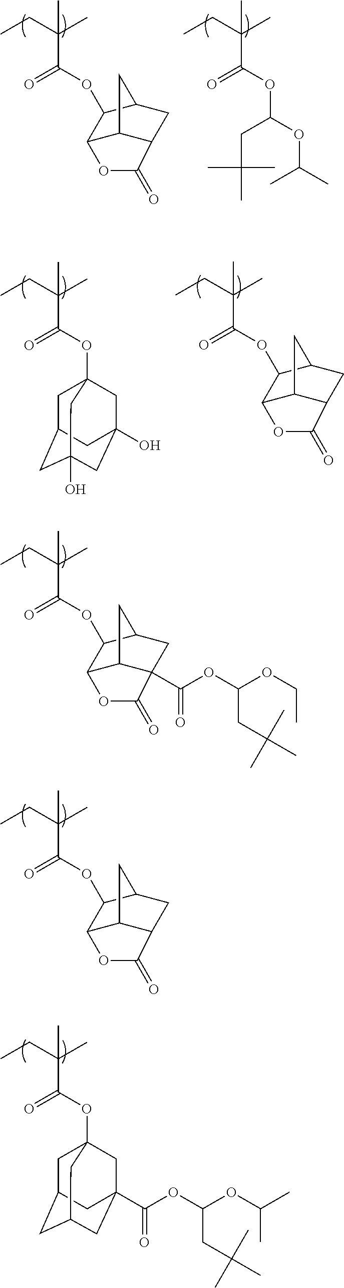

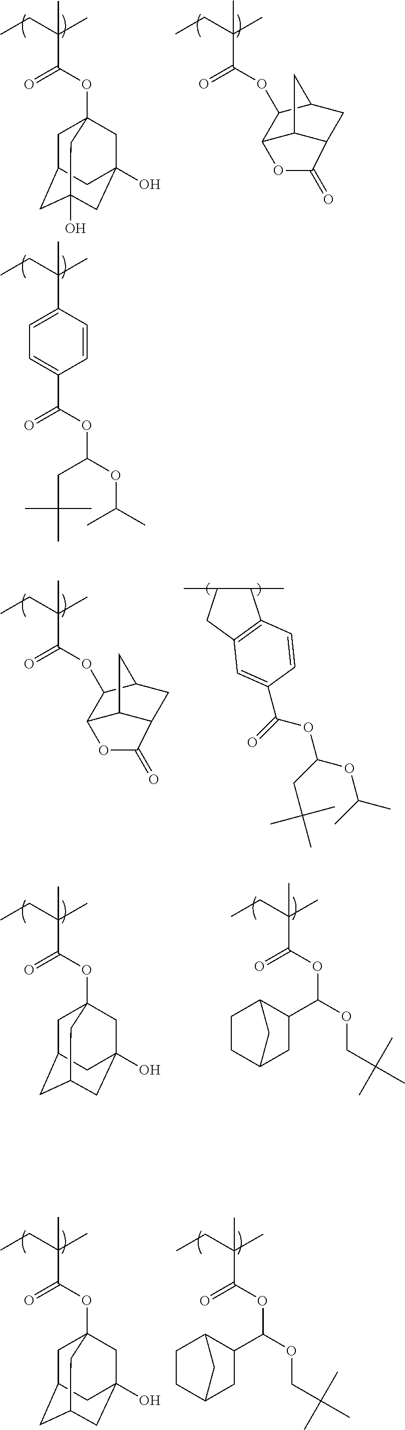

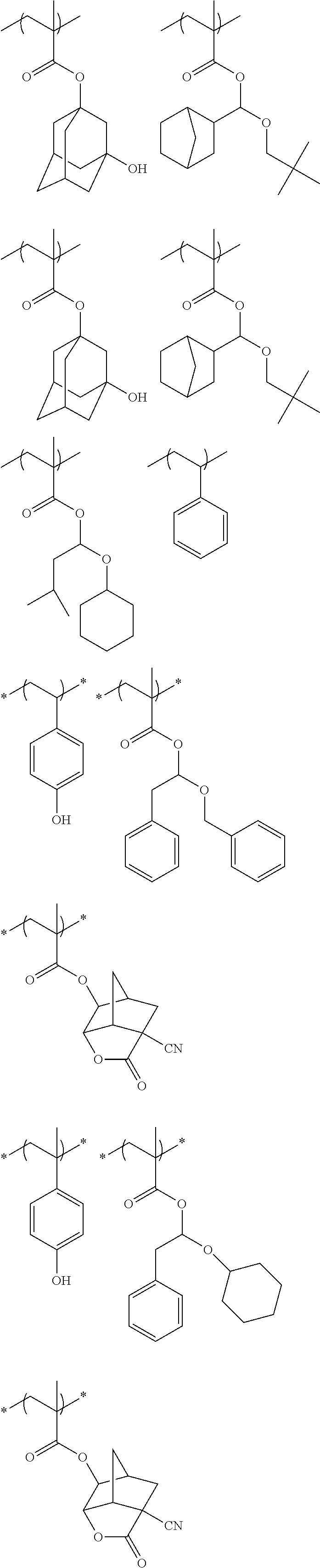

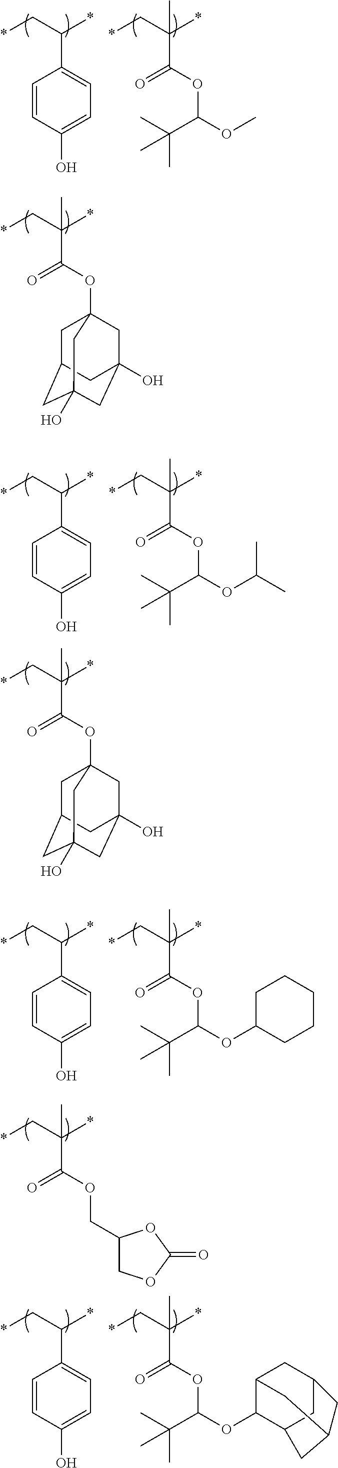

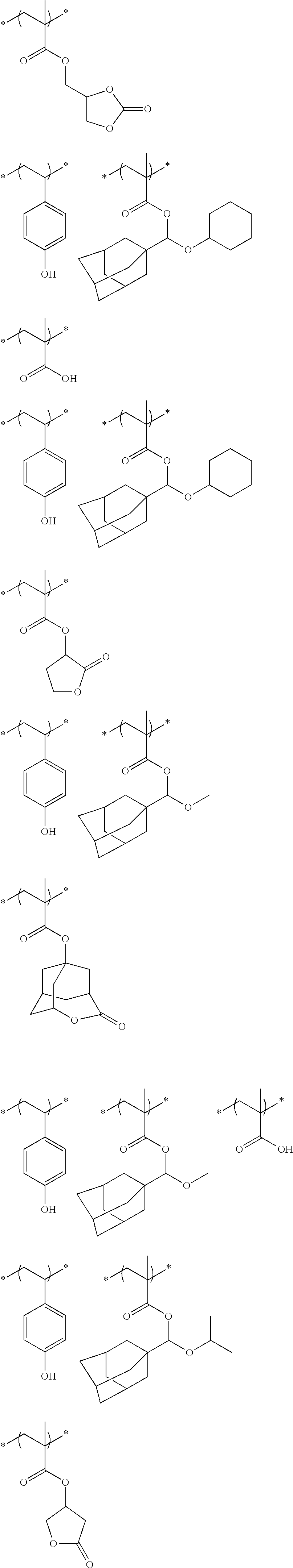

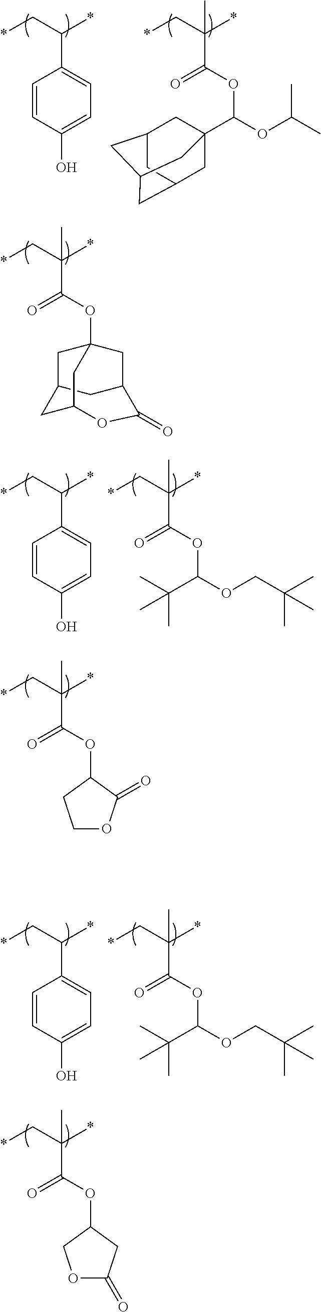

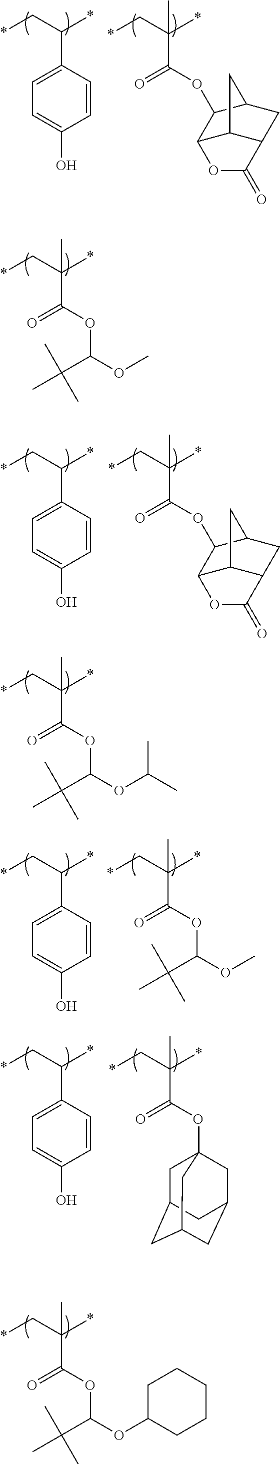

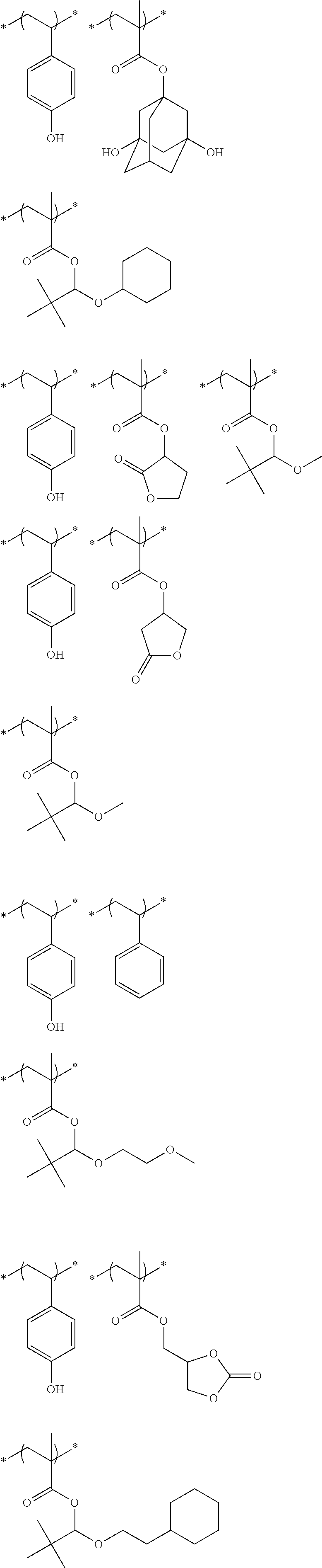

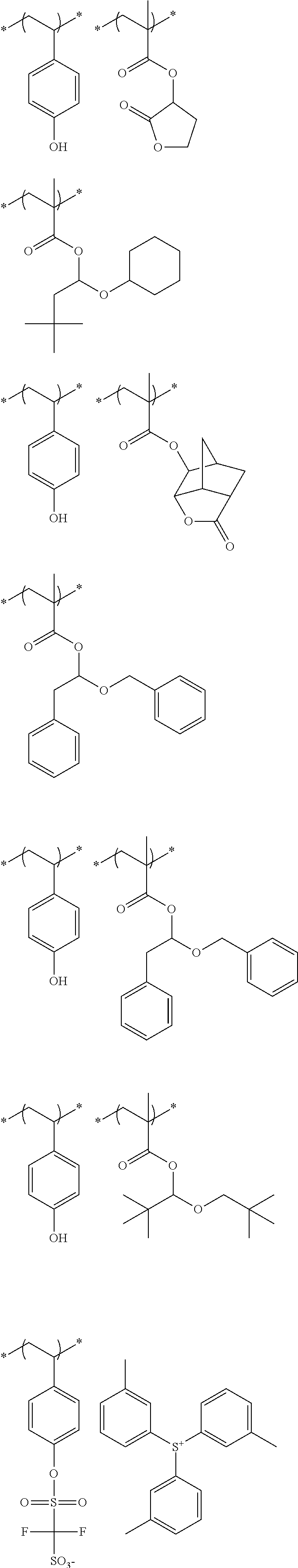

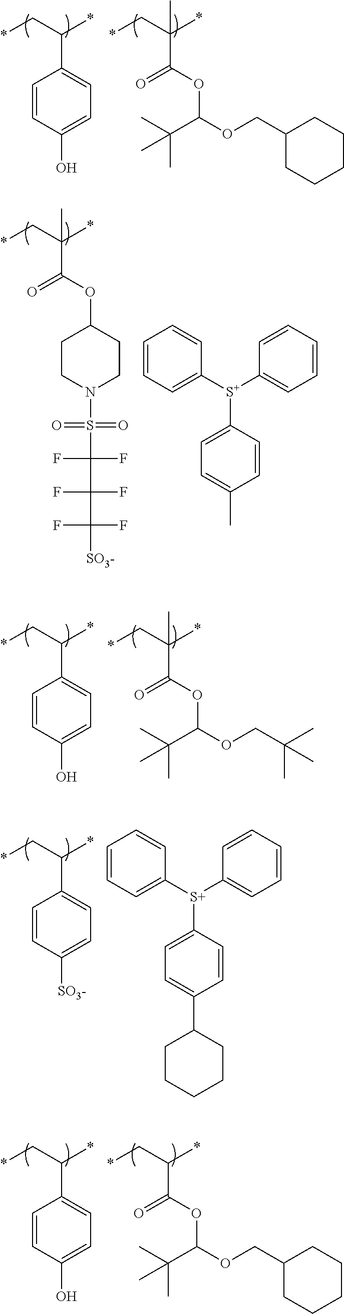

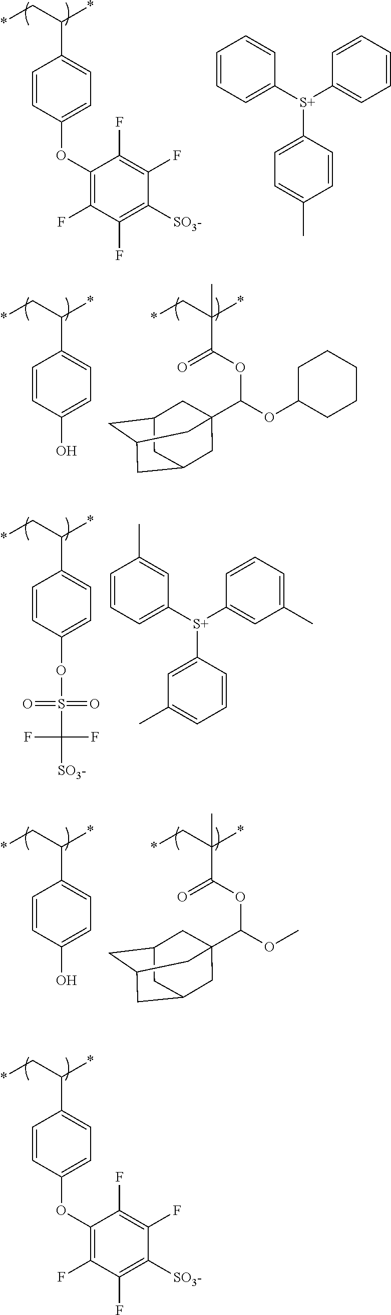

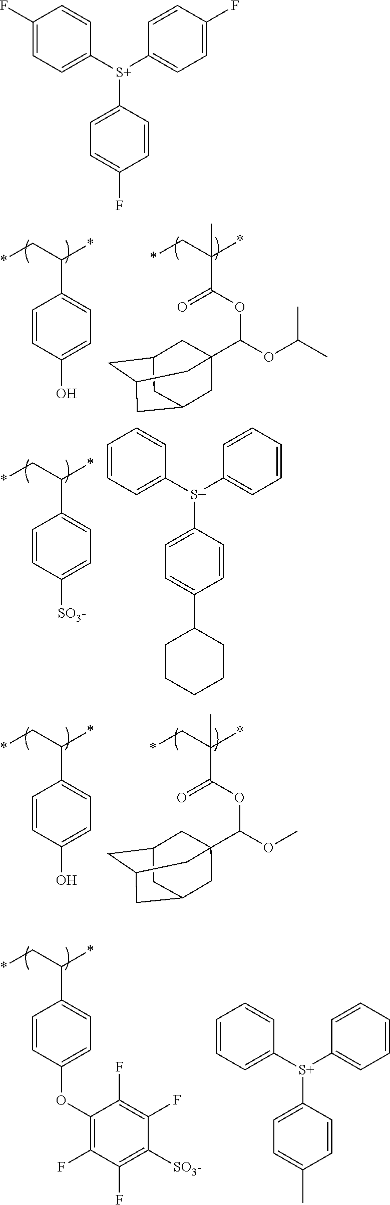

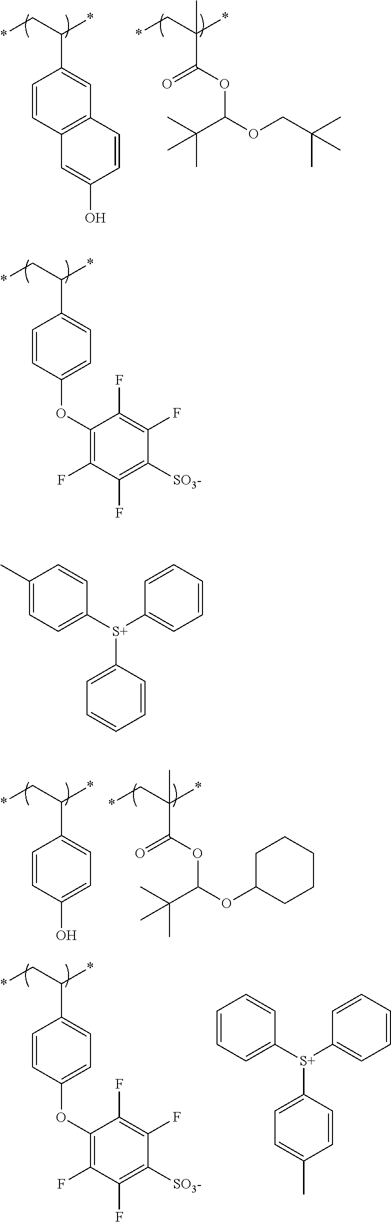

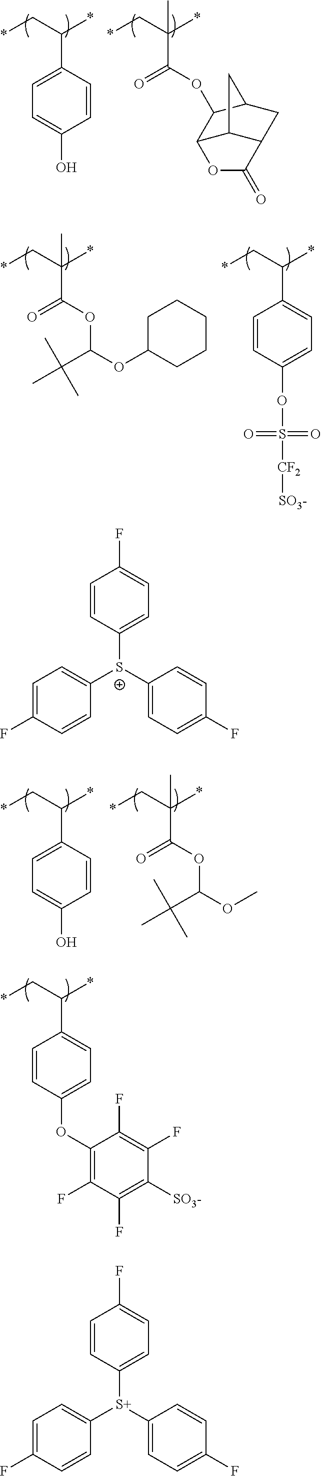

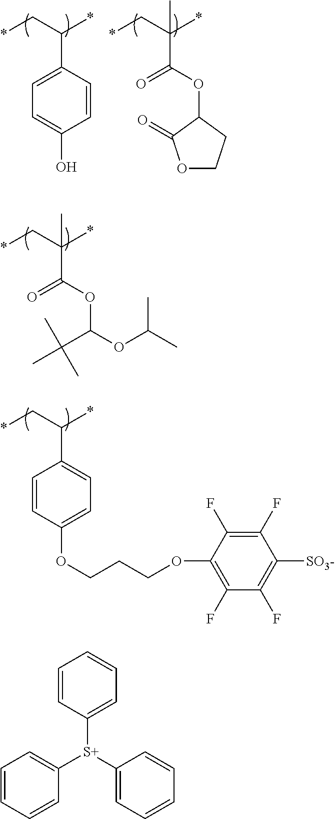

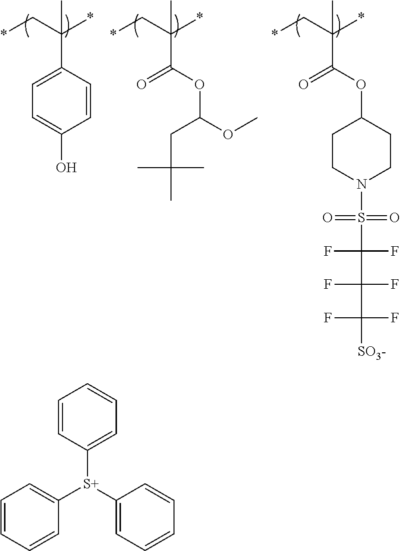

[2] (B) Resin Capable of Decomposing by the Action of an Acid to Change in the Solubility for a Developer, which is Different from the Resin (P)

The actinic ray-sensitive or radiation-sensitive resin composition of the present invention may contain a resin capable of decomposing by the action of an acid to change in the solubility for a developer, which is different from the resin (P) (hereinafter, the resin is sometimes referred to as “resin (B)”).

The resin (B) is a resin having a structure where a polar group is protected by a leaving group capable of decomposing and leaving by the action of an acid (hereinafter, sometimes referred to as “acid-decomposable group”).

The resin (B) preferably contains a repeating unit having an acid-decomposable group.

Examples of the polar group include a carboxyl group, a phenolic hydroxyl group, a sulfonic acid group, a thiol group, and an alcoholic hydroxyl group.

Examples of the group capable of leaving by the action of an acid include —C(R₃₆)(R₃₇)(R₃₈), —C(R₃₆)(R₃₇)(OR₃₉), —C(═O)—O—C(R₃₆)(R₃₇)(R₃₈), —C(R₀₁)(R₀₂)(OR₃₉), and —C(R₀₁)(R₀₂)—C(═O)—O—C(R₃₆)(R₃₇)(R₃₈).

In the formulae above, each of R₃₆ to R₃₉ independently represents an alkyl group, a cycloalkyl group, an aryl group, an aralkyl group or an alkenyl group, and R₃₆ and R₃₇ may combine with each other to form a ring. Each of R₀₁ and R₀₂ independently represents a hydrogen atom, an alkyl group, a cycloalkyl group, an aryl group, an aralkyl group or an alkenyl group.

The resin (B) can be synthesized by a conventional method (for example, radical polymerization).

The weight average molecular weight of the resin (B) is preferably from 1,000 to 200,000, more preferably from 2,000 to 20,000, still more preferably from 3,000 to 15,000, yet still more preferably from 3,000 to 10,000, in terms of polystyrene as measured by the GPC method. When the weight average molecular weight is from 1,000 to 200,000, the heat resistance and dry etching resistance can be kept from deterioration and at the same time, the film-forming property can be prevented from becoming poor due to impairment of developability or increase in the viscosity.

The polydispersity (molecular weight distribution) is usually from 1 to 3, preferably from 1 to 2.6, more preferably from 1 to 2, still more preferably from 1.4 to 1.7. As the molecular weight distribution is narrower, the resolution and resist profile are more excellent,

*
the side wall of the resist pattern is smoother, and the roughness is more improved.

As for the resin (B), two or more kinds of resins may be used in combination.

The actinic ray-sensitive or radiation-sensitive resin composition of the present invention may or may not contain the resin (B), but in the case of containing the resin (B), the content thereof is usually from 1 to 50 mass %, preferably from 1 to 30 mass %, more preferably from 1 to 15 mass %, based on the total solid content of the actinic ray-sensitive or radiation-sensitive resin composition.

Examples of the resin (B) include those described in paragraphs [0214] to [0594] of Japanese Patent Application No. 2011-217048 and paragraphs [0059] to [0169] of JPA-2010-217884.

[3] Compound Capable of Generating an Acid Upon Irradiation with an Actinic Ray or Radiation

The actinic ray-sensitive or radiation-sensitive resin composition of the present invention may further contain a compound capable of generating an acid upon irradiation with an actinic ray or radiation (hereinafter, sometimes referred to as “photoacid generator”).

The acid generator is not particularly limited as long as it is a known acid generator, but a compound capable of generating an organic acid, for example, at least any one of a sulfonic acid, a bis(alkylsulfonyl)imide and a tris(alkylsulfonyl)methide, upon irradiation with an actinic ray or radiation is preferred.

The (B) compound capable of generating an acid upon irradiation with an actinic ray or radiation may be in a low molecular compound form or in a form of being incorporated into a part of a polymer. Also, a low molecular compound form and a form of being incorporated into a part of a polymer may be used in combination.

In the case where the (B) compound capable of generating an acid upon irradiation with an actinic ray or radiation is in a low molecular compound form, the molecular weight is preferably 3,000 or less, more preferably 2,000 or less, still more preferably 1,000 or less.

In the case where the (B) compound capable of generating an acid upon irradiation with an actinic ray or radiation is in a form of being incorporated into a part of a polymer, the compound may be incorporated into a part of the above-described acid-decomposable resin or may be incorporated into a resin different from the acid-decomposable resin.

More preferred compounds include compounds represented by the following formulae (ZI), (ZII) and (ZIII):

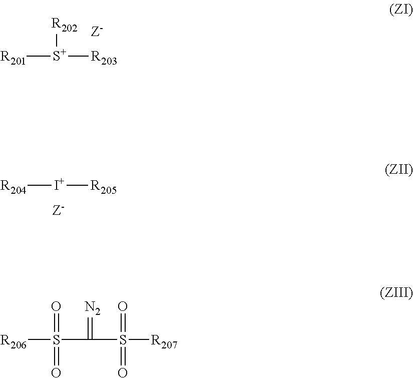

In formula (ZI), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain therein an oxygen atom, a sulfur atom, an ester bond, an amide bond or a carbonyl group. The group formed by combining two members out of R₂₀₁ to R₂₀₃ includes an alkylene group (e.g., butylenes group, pentylene group).

Z⁻ represents a non-nucleophilic anion (an anion having an extremely low ability of causing a nucleophilic reaction).

Examples of the non-nucleophilic anion include a sulfonate anion (such as aliphatic sulfonate anion, aromatic sulfonate anion and camphorsulfonate anion), a carboxylate anion (such as aliphatic carboxylate anion, aromatic carboxylate anion and aralkylcarboxylate anion), a sulfonylimide anion, a bis(alkylsulfonyl)imide anion, and a tris(alkylsulfonyl)methide anion.

The aliphatic moiety in the aliphatic sulfonate anion and aliphatic carboxylate anion may be an alkyl group or a cycloalkyl group but is preferably a linear or branched alkyl group having a carbon number of 1 to 30 or a cycloalkyl group having a carbon number of 3 to 30.

The aromatic group in the aromatic sulfonate anion and aromatic carboxylate anion is preferably an aryl group having a carbon number of 6 to 14, and examples thereof include a phenyl group, a tolyl group and a naphthyl group.

The alkyl group, cycloalkyl group and aryl group above may have a substituent. Specific examples of the substituent include a nitro group, a halogen atom such as fluorine atom, a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkyliminosulfonyl group (preferably having a carbon number of 2 to 15), an aryloxysulfonyl group (preferably having a carbon number of 6 to 20), an alkylaryloxysulfonyl group (preferably having a carbon number of 7 to 20), a cycloalkylaryloxysulfonyl group (preferably having a carbon number of 10 to 20), an alkyloxyalkyloxy group (preferably having a carbon number of 5 to 20), and a cycloalkylalkyloxyalkyloxy group (preferably having a carbon number of 8 to 20). The aryl group or ring structure, which each group has, may further have an alkyl group (preferably having a carbon number of 1 to 15) as a substituent.

The aralkyl group in the aralkylcarboxylate anion is preferably an aralkyl group having a carbon number of 6 to 12, and examples thereof include a benzyl group, a phenethyl group, a naphthylmethyl group, a naphthylethyl group and a naphthylbutyl group.

Examples of the sulfonylimide anion include saccharin anion.

The alkyl group in the bis(alkylsulfonyl)imide anion and tris(alkylsulfonyl)methide anion is preferably an alkyl group having a carbon number of 1 to 5, and examples of the substituent on this alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom and a fluorine atom-substituted alkyl group being preferred.

Also, the alkyl groups in the bis(alkylsulfonyl)imide anion may combine with each other to form a ring structure. In this case, the acid strength is increased.

Other examples of the non-nucleophilic anion include fluorinated phosphorus (e.g., PF₆), fluorinated boron (e.g., BF₄⁻), and fluorinated antimony (e.g., SbF6⁻).

The non-nucleophilic anion is preferably an aliphatic sulfonate anion substituted with a fluorine atom at least at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion (preferably having a carbon number of 4 to 8) or a fluorine atom-containing benzenesulfonate anion, still more preferably nonafluorobutanesulfonate anion, perfluorooctanesulfonate anion, pentafluorobenzenesulfonate anion or 3,5-bis(trifluoromethyl)benzenesulfonate anion.

As regards the acid strength, the pKa of the acid generated is preferably −1 or less for enhancing the sensitivity.

An anion represented by the following formula (AN1) is also a preferred embodiment of the non-nucleophilic anion:

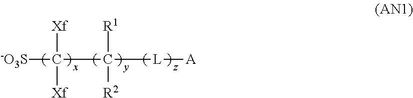

In the formula, each Xf independently represents a fluorine atom or an alkyl group substituted with at least one fluorine atom.

Each of R¹ and R² independently represents a hydrogen atom, a fluorine atom or an alkyl group, and when a plurality of R¹s or R²s are present, each R¹ or R² may be the same as or different from every other R¹ or R².

L represents a divalent linking group, and when a plurality of L's are present, each L may be the same as or different from every other L.

A represents a cyclic organic group.

x represents an integer of 1 to 20, y represents an integer of 0 to 10, and z represents an integer of 0 to 10.

Formula (AN1) is described in more detail.

The alkyl group in the fluorine atom-substituted alkyl group of Xf is preferably an alkyl group having a carbon number of 1 to 10, more preferably from 1 to 4. Also, the fluorine atom-substituted alkyl group of Xf is preferably a perfluoroalkyl group.

Xf is preferably a fluorine atom or a perfluoroalkyl group having a carbon number of 1 to 4. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with a fluorine atom and CF₃ being preferred. In particular, it is preferred that both Xfs are a fluorine atom.

The alkyl group of R¹ and R² may have a substituent (preferably a fluorine atom) and is preferably an alkyl group having a carbon number of 1 to 4, more preferably a perfluoroalkyl group having a carbon number of 1 to 4. Specific examples of the alkyl group having a substituent of R¹ and R² include CF₃, C2F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with CF₃ being preferred.

Each of R¹ and R² is preferably a fluorine atom or CF₃.

x is preferably from 1 to 10, more preferably from 1 to 5.

y is preferably from 0 to 4, more preferably 0.

z is preferably from 0 to 5, more preferably from 0 to 3.

The divalent linking group of L is not particularly limited and includes, for example, —COO—, —COO—, —CO—, —O—, —S—, —SO—, —SO₂—, an alkylene group, a cycloalkylene group, an alkenylene group, and a linking group formed by combining a plurality thereof. A linking group having a total carbon number of 12 or less is preferred. Among these, —COO—, —COO—, —CO— and —O— are preferred, and —COO—, —COO— are more preferred.

The cyclic organic group of A is not particularly limited as long as it has a cyclic structure, and examples thereof include an alicyclic group, an aryl group and a heterocyclic group (including not only those having aromaticity but also those having no aromaticity).

The alicyclic group may be monocyclic or polycyclic and is preferably a monocyclic cycloalkyl group such as cyclopentyl group, cyclohexyl group and cyclooctyl group, or a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint that the diffusion in the film during heating after exposure can be suppressed and MEEF can be improved.

The aryl group includes a benzene ring, a naphthalene ring, a phenanthrene ring, and an anthracene ring.

The heterocyclic group includes those derived from a furan ring, a thiophene ring, a benzofuran ring, a benzothiophene ring, a dibenzofuran ring, a dibenzothiophene ring and a pyridine ring. Among these, heterocyclic groups derived from a furan ring, a thiophene ring and a pyridine ring are preferred.

The cyclic organic group also includes a lactone structure. Specific examples thereof include lactone structures represented by formulae (LC1-1) to (LC1-17) which may be contained in the resin (A).

The cyclic organic group may have a substituent, and examples of the substituent include an alkyl group (may be any of linear, branched or cyclic; preferably having a carbon number of 1 to 12), a cycloalkyl group (may be any of monocyclic, polycyclic or spirocyclic; preferably having a carbon number of 3 to 20), an aryl group (preferably having a carbon number of 6 to 14), a hydroxy group, an alkoxy group, an ester group, an amide group, a urethane group, a ureido group, a thioether group, a sulfonamido group, and a sulfonic acid ester group. Incidentally, the carbon constituting the cyclic organic group (the carbon contributing to ring formation) may be a carbonyl carbon.

Examples of the organic group of R₂₀₁, R₂₀₂ and R₂₀₃ include an aryl group, an alkyl group, and a cycloalkyl group.

At least one of three members R₂₀₁, R₂₀₂ and R₂₀₃ is preferably an aryl group, and it is more preferred that all of these three members are an aryl group. The aryl group may be a heteroaryl group such as indole residue and pyrrole residue, other than a phenyl group, a naphthyl group and the like. The alkyl group and cycloalkyl group of R₂₀₁ to R₂₀₃ may be preferably a linear or branched alkyl group having a carbon number of 1 to 10 and a cycloalkyl group having a carbon number of 3 to 10. More preferred examples of the alkyl group include a methyl group, an ethyl group, an n-propyl group, an i-propyl group, and an n-butyl group. More preferred examples of the cycloalkyl group include a cyclopropyl group, a cyclobutyl group, a cyclopentyl group, a cyclohexyl group, and a cycloheptyl group. These groups may further have a substituent, and examples of the substituent include, but are not limited to, a nitro group, a halogen atom such as fluorine atom, a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), and an alkoxycarbonyloxy group (preferably having a carbon number of 2 to 7).

In the case where two members out of R₂₀₁ to R₂₀₃ are combined to form a ring structure, the ring structure is preferably a structure represented by the following formula (A1):

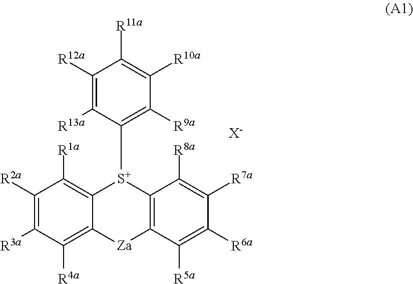

In formula (A1), each of R^{1a} to R^{13a} independently represents a hydrogen atom or a substituent.

It is preferred that from one to three members out of R^{1a} to R^{13a} are not a hydrogen atom; and it is more preferred that any one of R^{9a} to R^{13a} is not a hydrogen atom.

Za represents a single bond or a divalent linking group.

X⁻ has the same meaning as Z⁻ in formula (ZI).

Specific examples of R^{1a} to R^{13a} when these are not a hydrogen atom include a halogen atom, a linear, branched or cyclic alkyl group, an alkenyl group, an alkynyl group, an aryl group, a heterocyclic group, a cyano group, a nitro group, a carboxyl group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkylsulfonylamino group, an arylsulfonylamino group, a mercapto group, an alkylthio group, an arylthio group, a heterocyclic thio group, a sulfamoyl group, a sulfo group, an alkylsulfinyl group, an arylsulfinyl group, an alkylsulfonyl group, an arylsulfonyl group, an acyl group, an aryloxycarbonyl group, an alkoxycarbonyl group, a carbamoyl group, an arylazo group, a heterocyclic azo group, an imido group, a phosphino group, a phosphinyl group, a phosphinyloxy group, a phosphinylamino group, a phosphono group, a silyl group, a hydrazino group, a ureido group, a boronic acid group (—B(OH)₂), a phosphato group (—OPO(OH)₂), a sulfato group (—OSO₃H), and other known substituents.

In the case where R^{1a} to R^{13a} are not a hydrogen atom, each of R^{1a} to R^{13a} is preferably a linear, branched or cyclic alkyl group substituted with a hydroxyl group.

Examples of the divalent linking group of Za include an alkylene group, an arylene group, a carbonyl group, a sulfonyl group, a carbonyloxy group, a carbonylamino group, a sulfonylamide group, an ether bond, a thioether bond, an amino group, a disulfide group, —(CH₂)ₙ—CO—, —(CH₂)ₙ—SO₂—, —CH═CH—, an aminocarbonyl amino group, and an aminosulfonylamino group (n is an integer of 1 to 3).

Incidentally, when at least one of R₂₀₁, R₂₀₂ and R₂₀₃ is not an aryl group, the preferred structure includes a cation structure such as compounds described in paragraphs 0047 and 0048 of JP-A-2004-233661 and paragraphs 0040 to 0046 of JP-A-2003-35948, compounds illustrated as formulae (I-1) to (I-70) in U.S. Patent Application Publication No. 2003/0224288A1, and compounds illustrated as formulae (IA-1) to (IA-54) and formulae (IB-1) to (IB-24) in U.S. Patent Application Publication No. 2003/0077540A1.

In formulae (ZIT) and (ZIII), each of R₂₀₄ to R₂₀₇ independently represents an aryl group, an alkyl group or a cycloalkyl group.

The aryl group, alkyl group and cycloalkyl group of R₂₀₄ to R₂₀₇ are the same as the aryl group, alkyl group and cycloalkyl group of R₂₀₁ to R₂₀₃ in the compound (ZI).

The aryl group, alkyl group and cycloalkyl group of R₂₀₄ to R₂₀₇ may have a substituent. Examples of the substituent include those of the substituent which may be substituted on the aryl group, alkyl group and cycloalkyl group of R₂₀₁ to R₂₀₃ in the compound (ZI).

Z⁻ represents a non-nucleophilic anion, and examples thereof are the same as those of the non-nucleophilic anion of Z in formula (ZI).

The acid generator further includes compounds represented by the following formulae (ZIV), (ZV) and (ZVI):

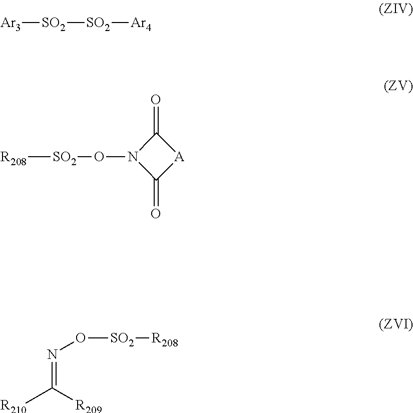

In formulae (ZIV) to (ZVI), each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group of R₂₀₁, R₂₀₂ and R₂₀₃ in formula (ZI).

Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI).

The alkylene group of A includes an alkylene group having a carbon number of 1 to 12 (e.g., methylene group, ethylene group, propylene group, isopropylene group, butylenes group, isobutylene group); the alkenylene group of A includes an alkenylene group having a carbon number of 2 to 12 (e.g., ethenylene group, propenylene group, butenylene group); and the arylene group of A includes an arylene group having a carbon number of 6 to 10 (e.g., phenylene group, tolylene group, naphthylene group).

Out of the acid generators, particularly preferred examples are illustrated below.

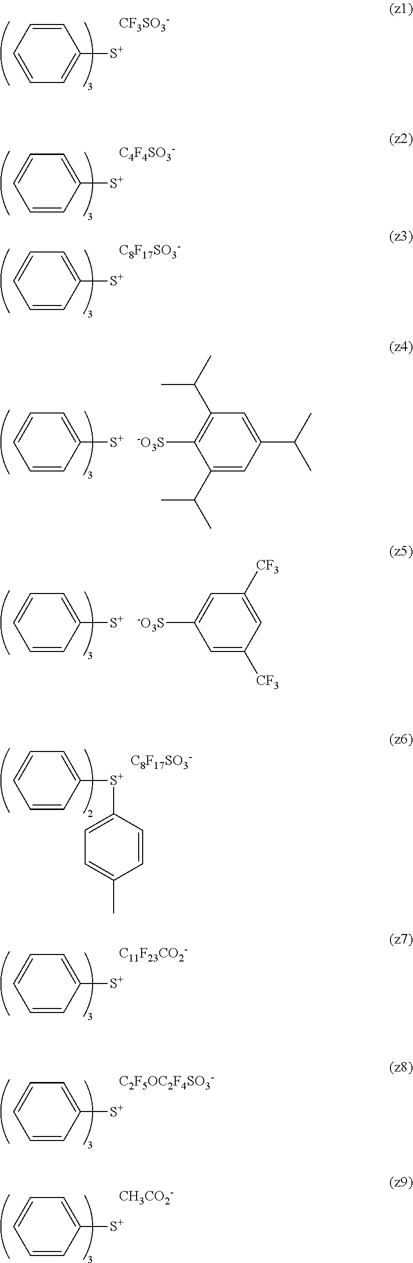

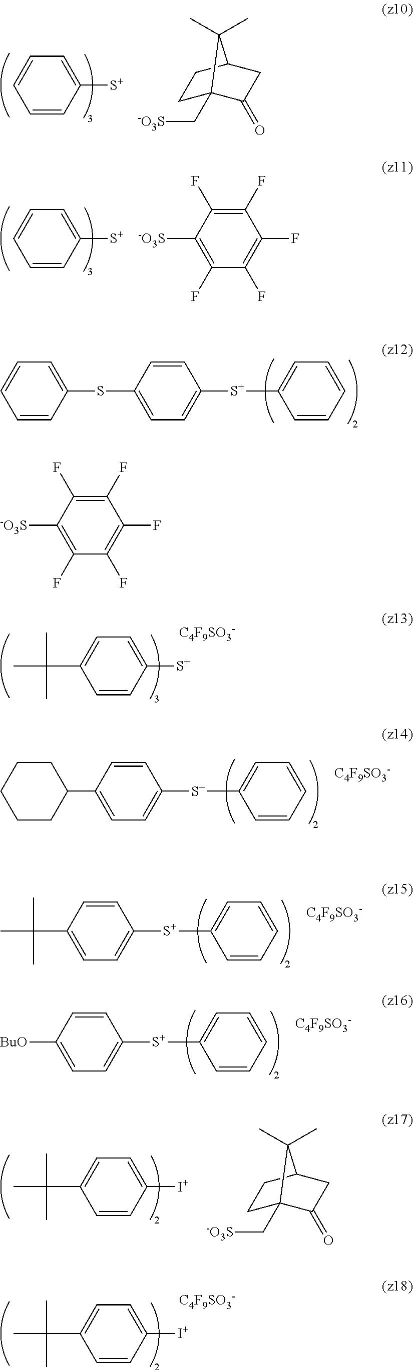

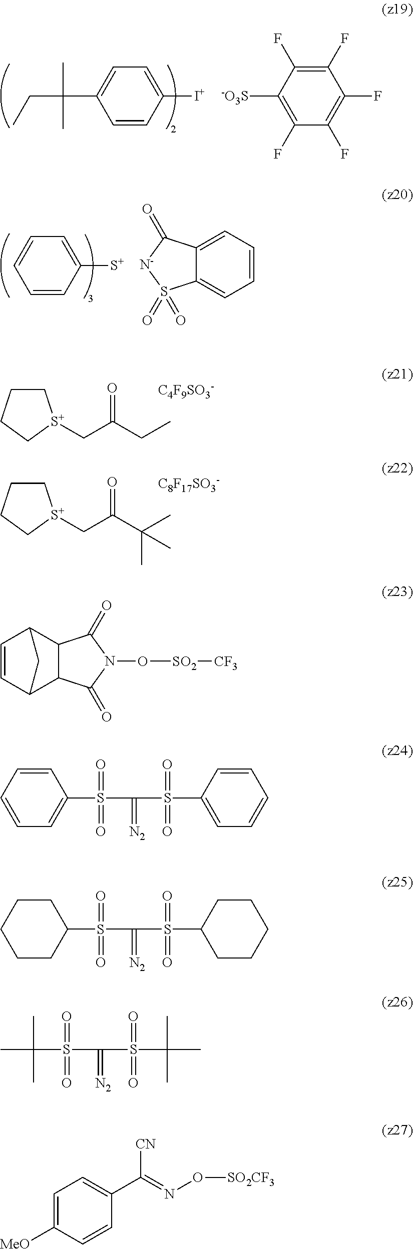

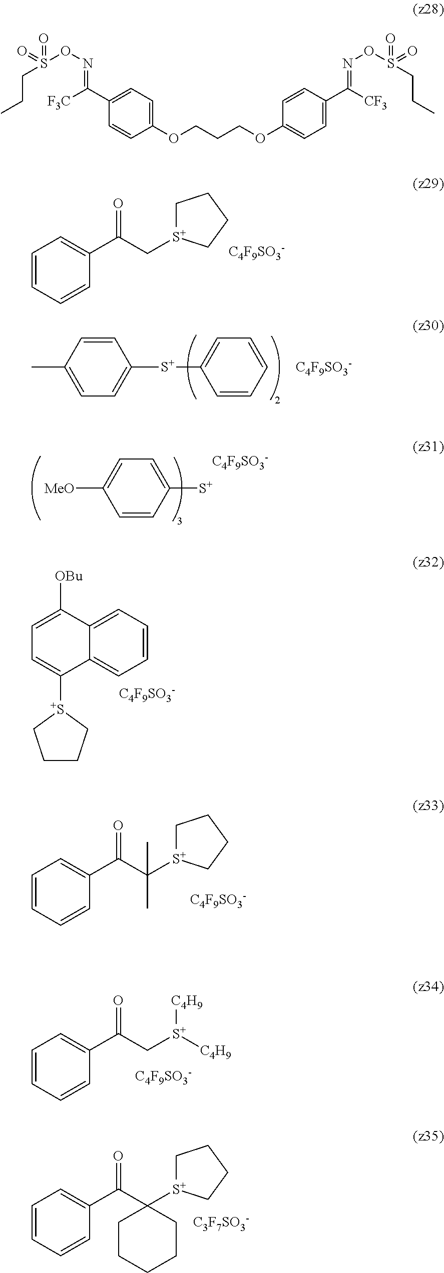

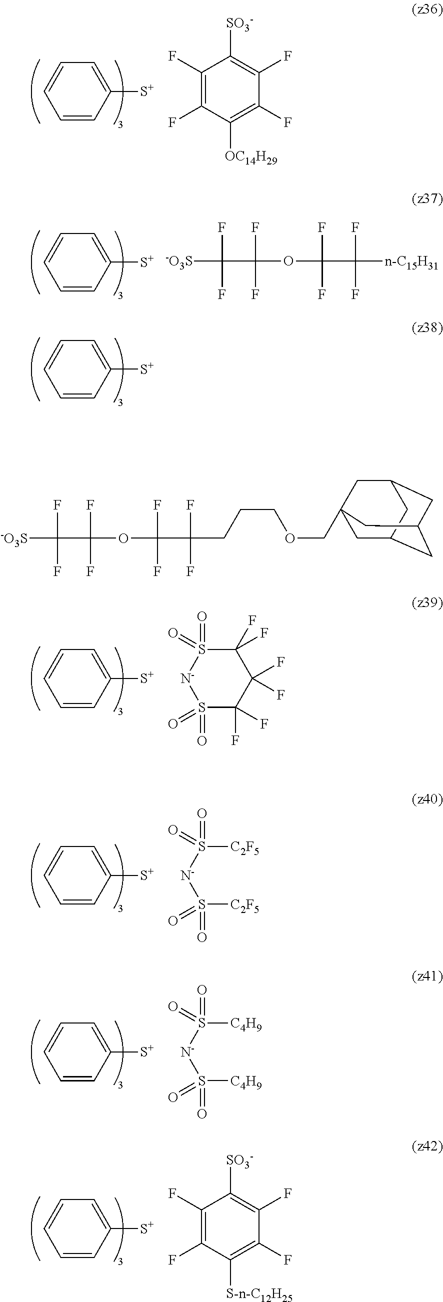

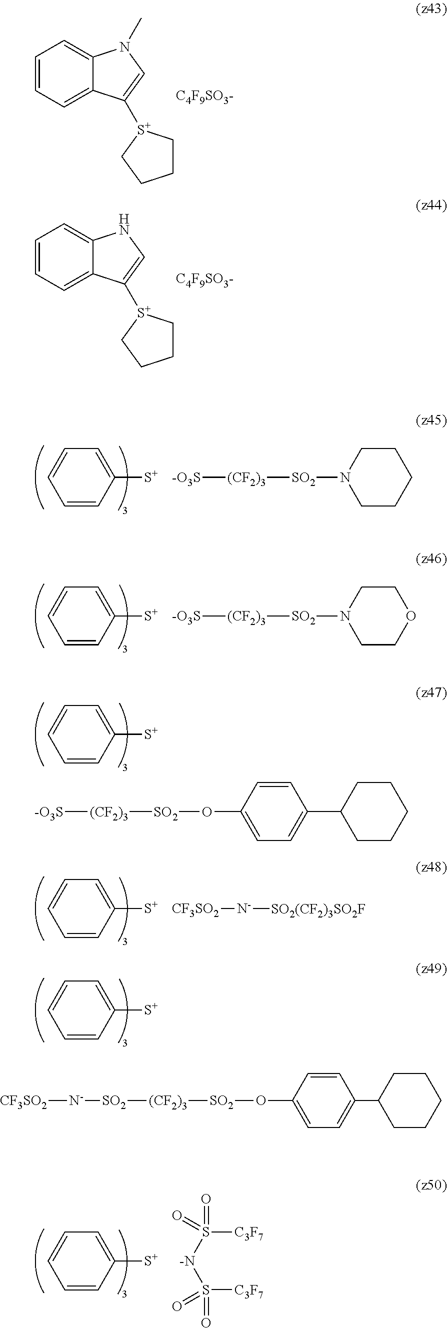

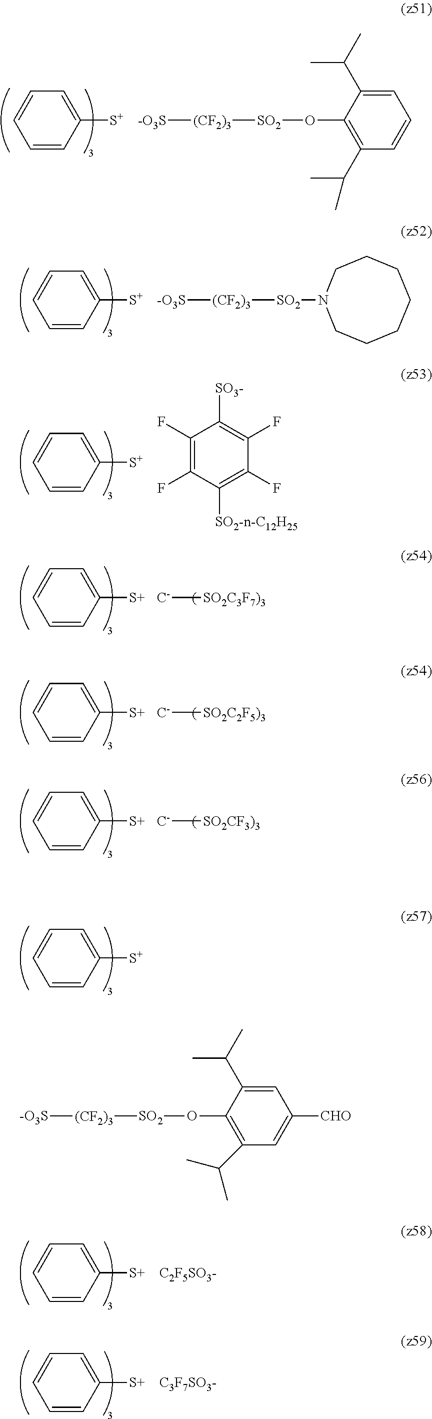

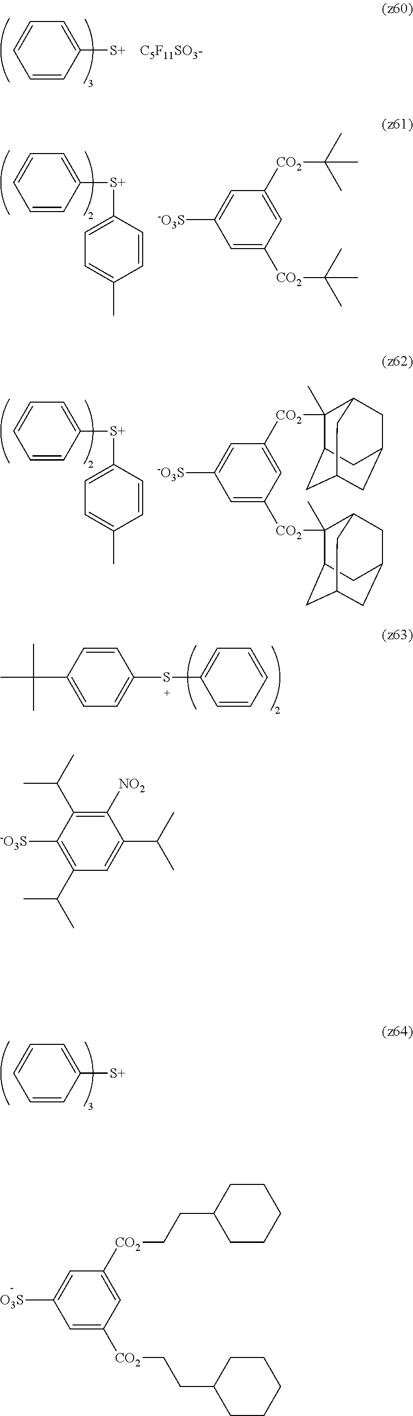

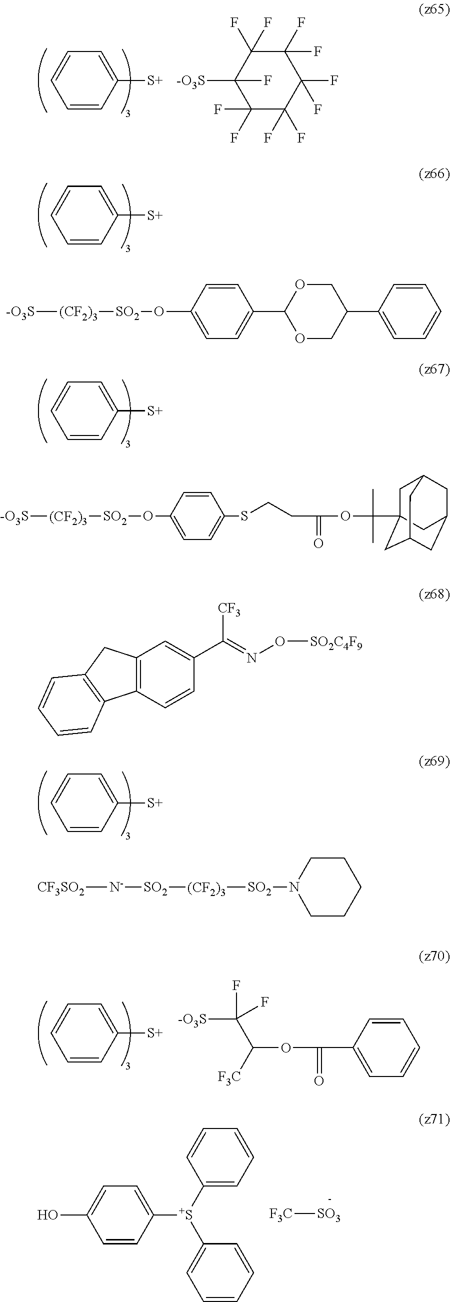

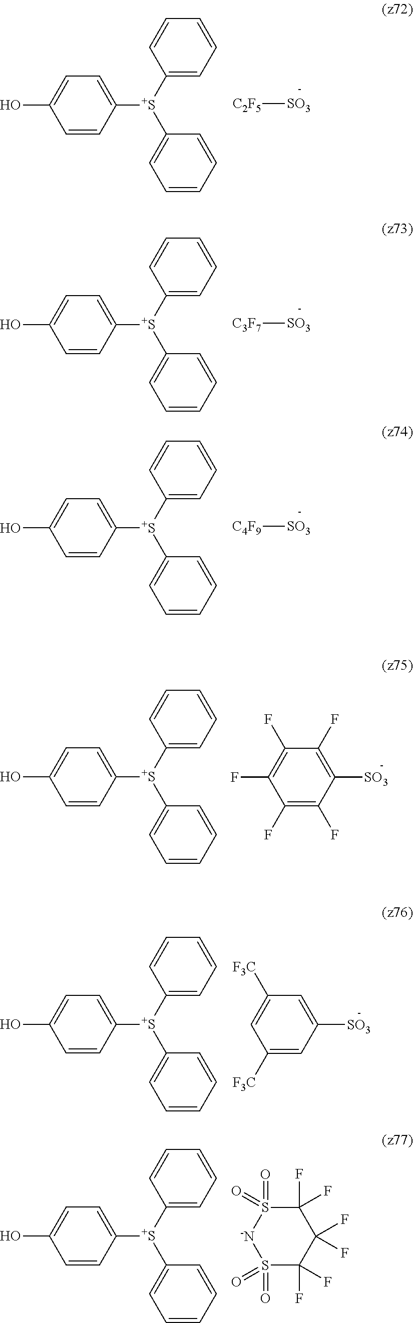

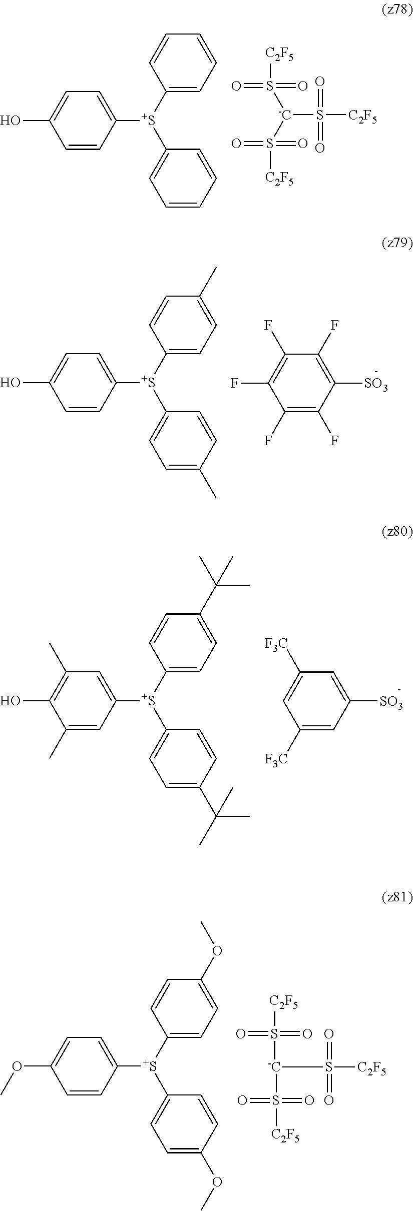

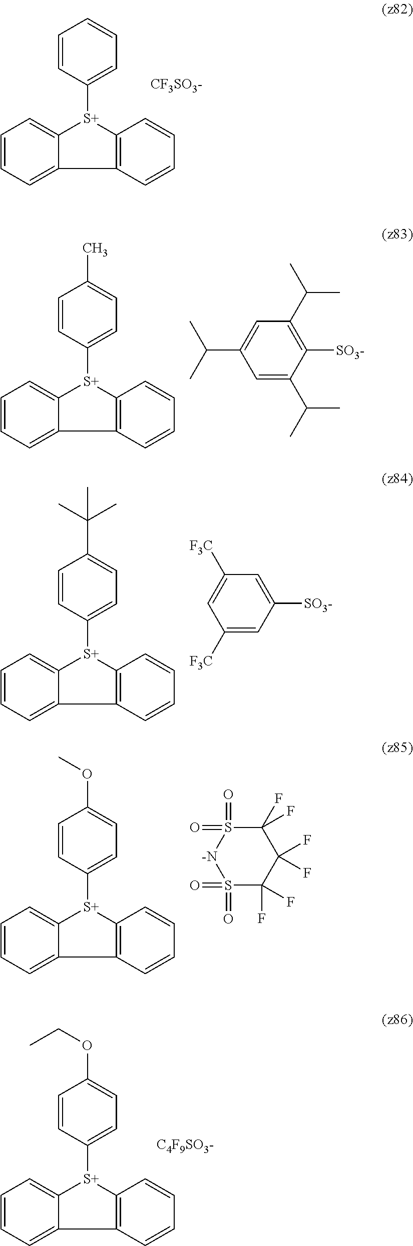

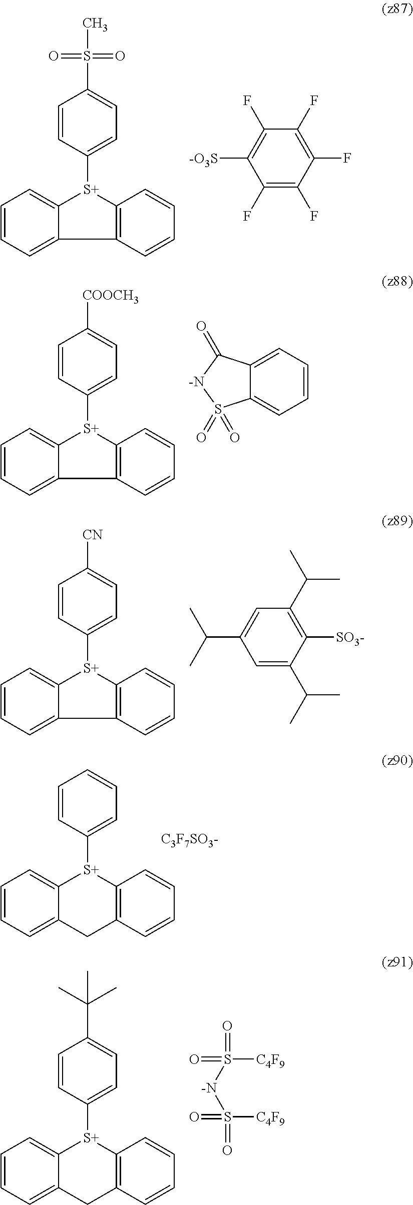

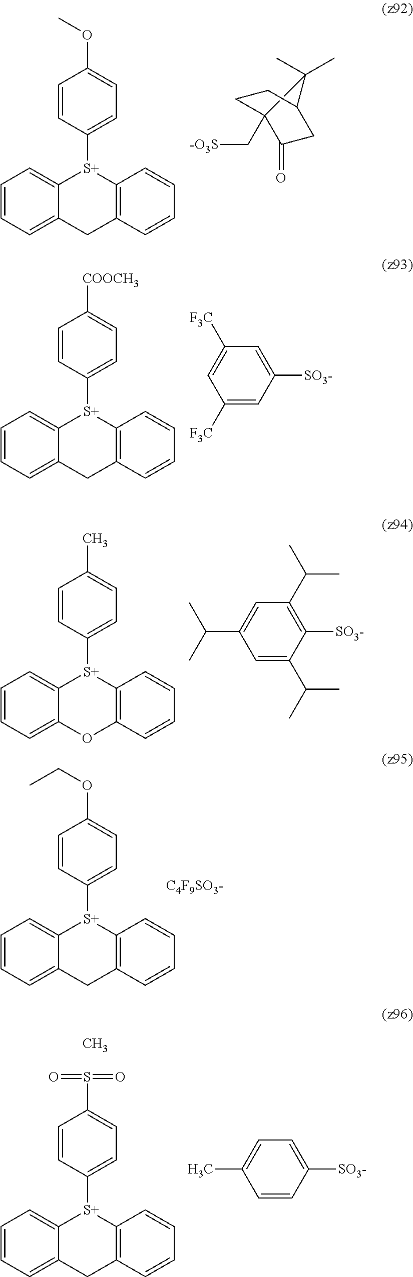

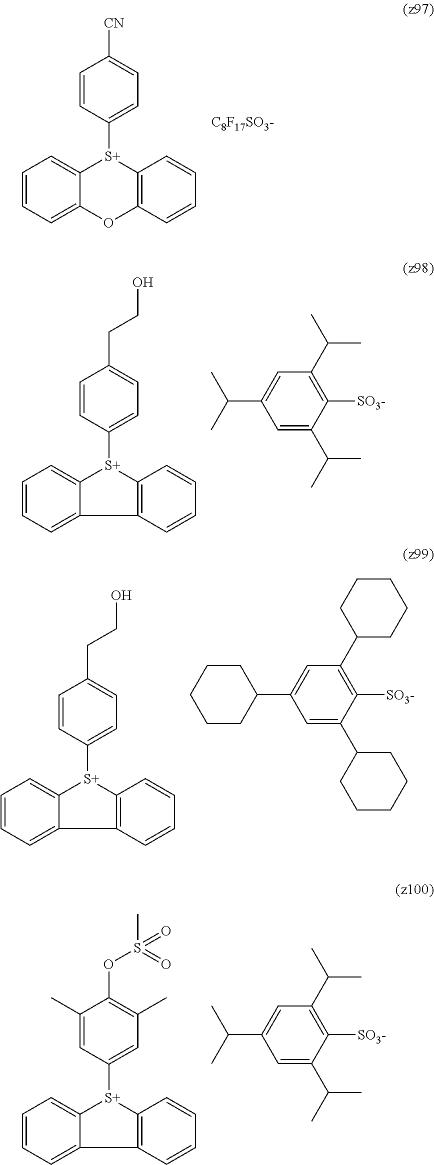

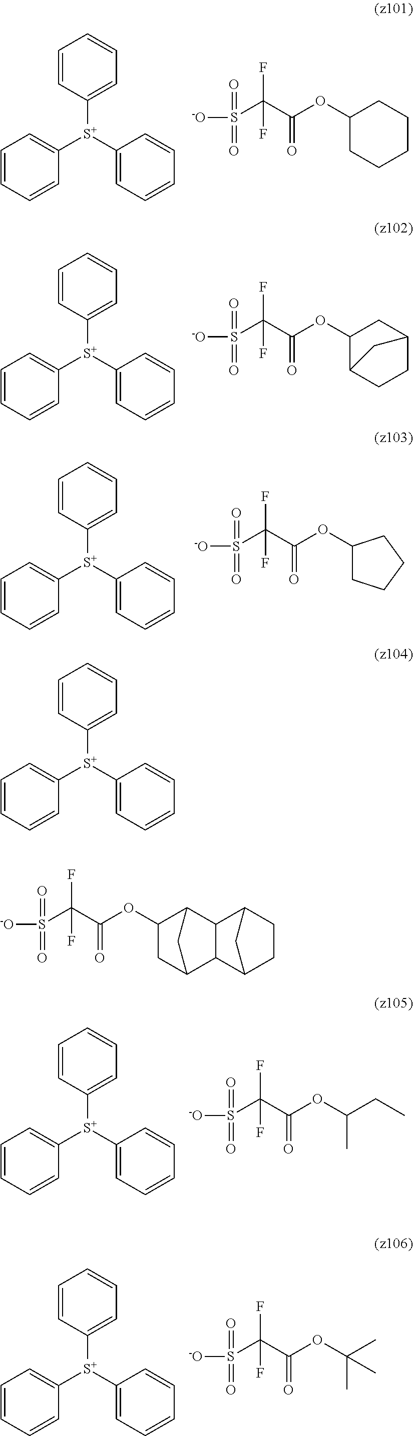

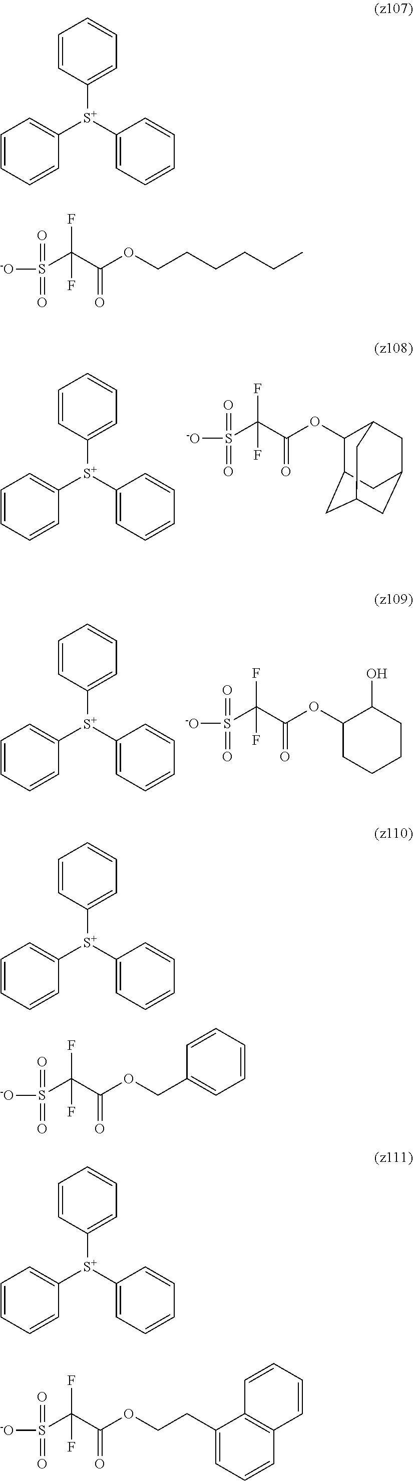

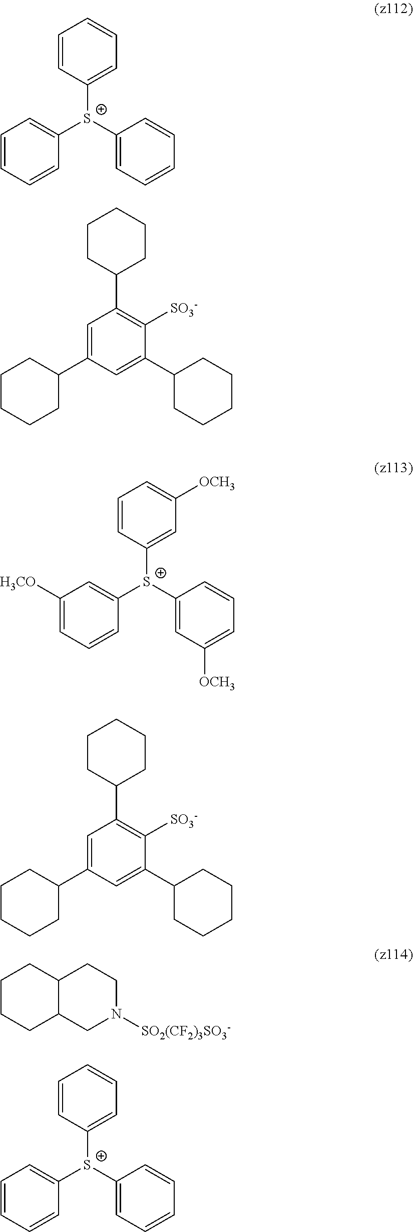

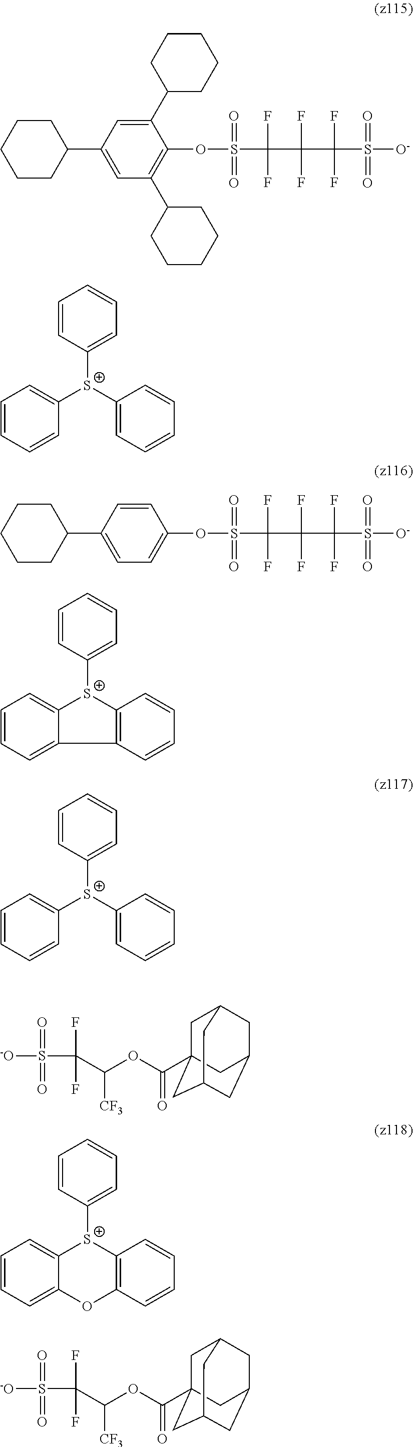

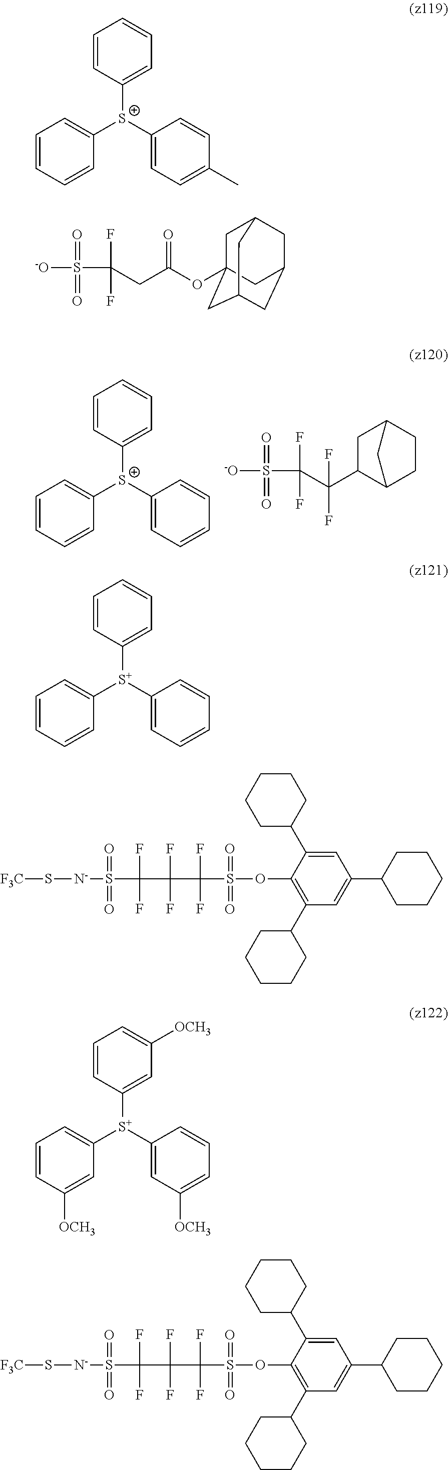

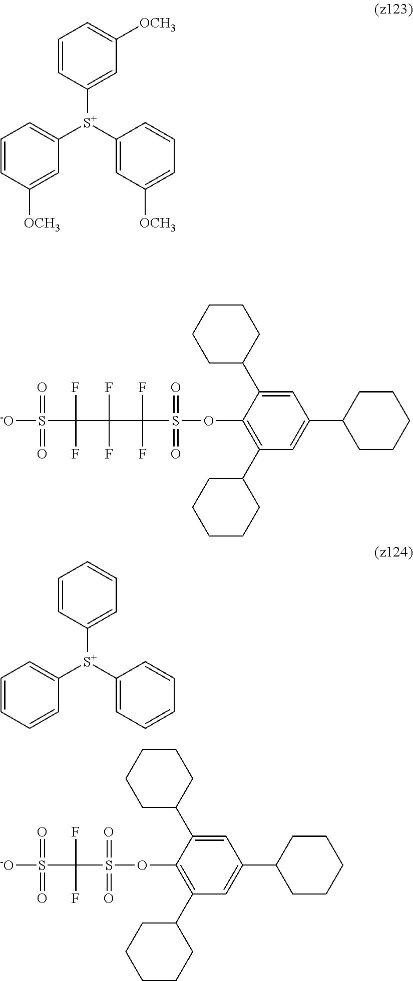

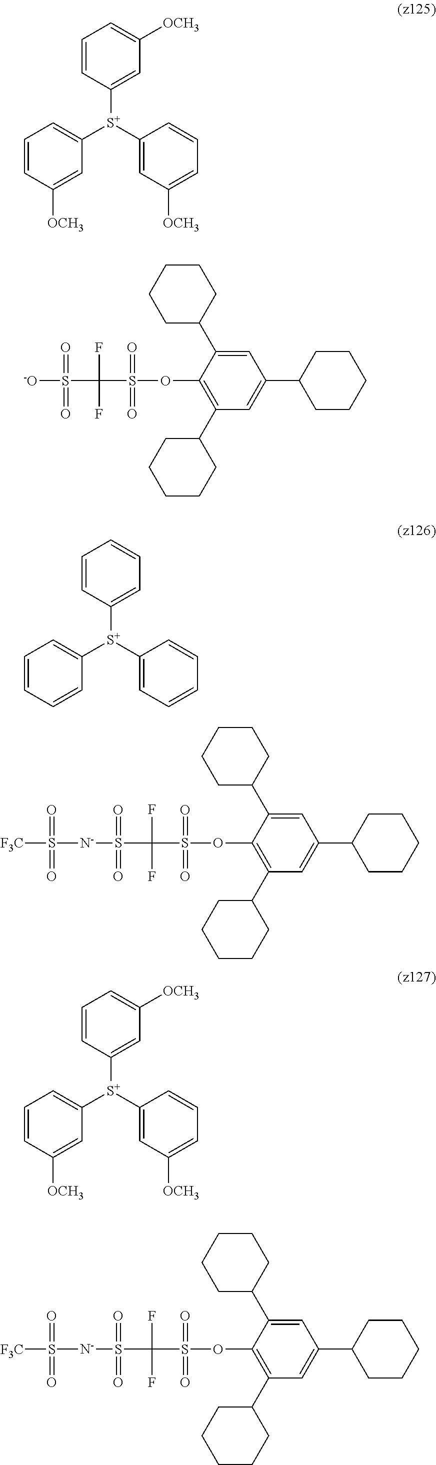

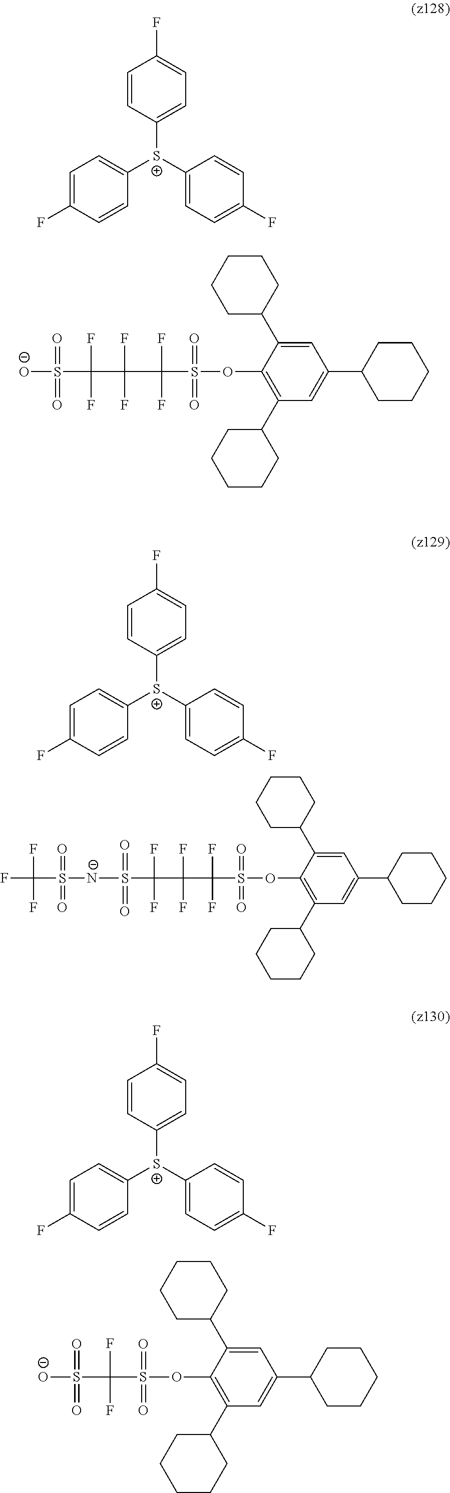 [SMILES: Fc1ccc([S+](c2ccc(F)cc2)c2ccc(F)cc2)cc1 ; O=S(=O)([O-])C(F)(F)C(F)(F)C(F)(F)S(=O)(=O)Oc1c(C2CCCCC2)cc(C2CCCCC2)cc1C1CCCCC1 ; Fc1ccc([S+](c2ccc(F)cc2)c2ccc(F)cc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F ; Fc1ccc([S+](c2ccc(F)cc2)c2ccc(F)cc2)cc1 ; O=S(=O)([O-])C(F)(F)S(=O)(=O)Oc1c(C2CCCCC2)cc(C2CCCCC2)cc1C1CCCCC1]

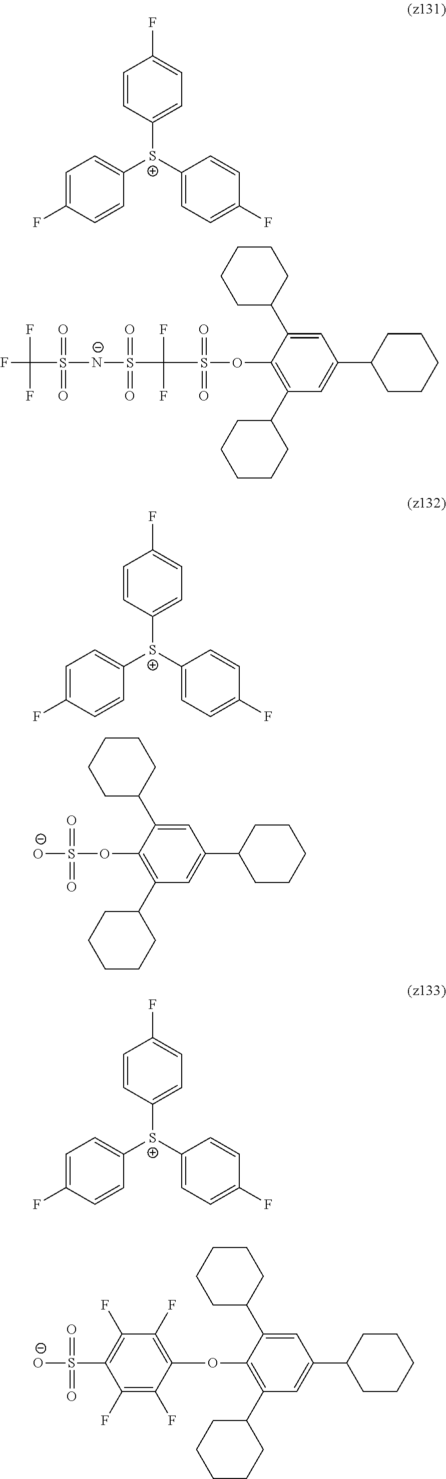 [SMILES: Fc1ccc([S+](c2ccc(F)cc2)c2ccc(F)cc2)cc1 ; O=S(=O)([N-]S(=O)(=O)C(F)(F)S(=O)(=O)Oc1c(C2CCCCC2)cc(C2CCCCC2)cc1C1CCCCC1)C(F)(F)F ; Fc1ccc([S+](c2ccc(F)cc2)c2ccc(F)cc2)cc1 ; O=S(=O)([O-])Oc1c(C2CCCCC2)cc(C2CCCCC2)cc1C1CCCCC1 ; Fc1ccc([S+](c2ccc(F)cc2)c2ccc(F)cc2)cc1 ; O=S(=O)([O-])c1c(F)c(F)c(Oc2c(C3CCCCC3)cc(C3CCCCC3)cc2C2CCCCC2)c(F)c1F]

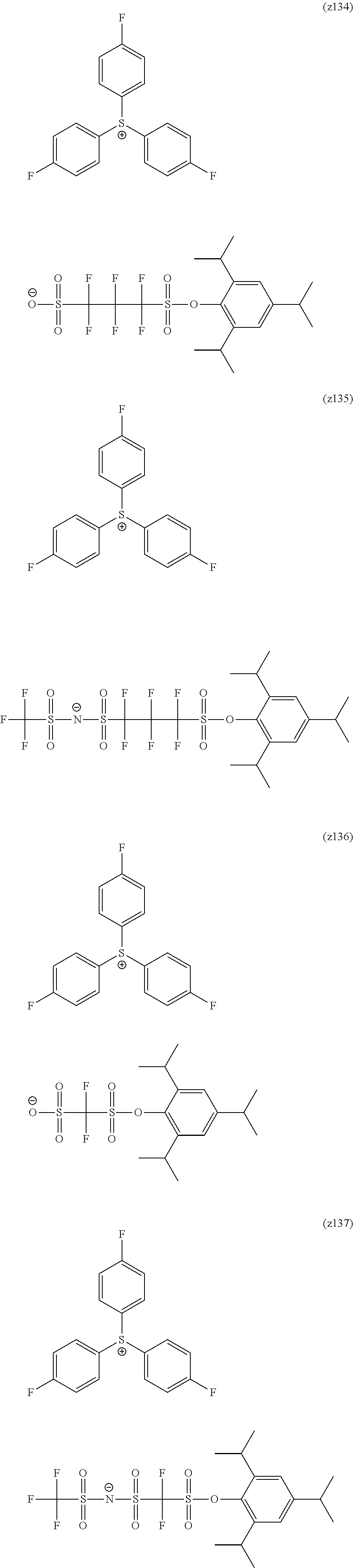

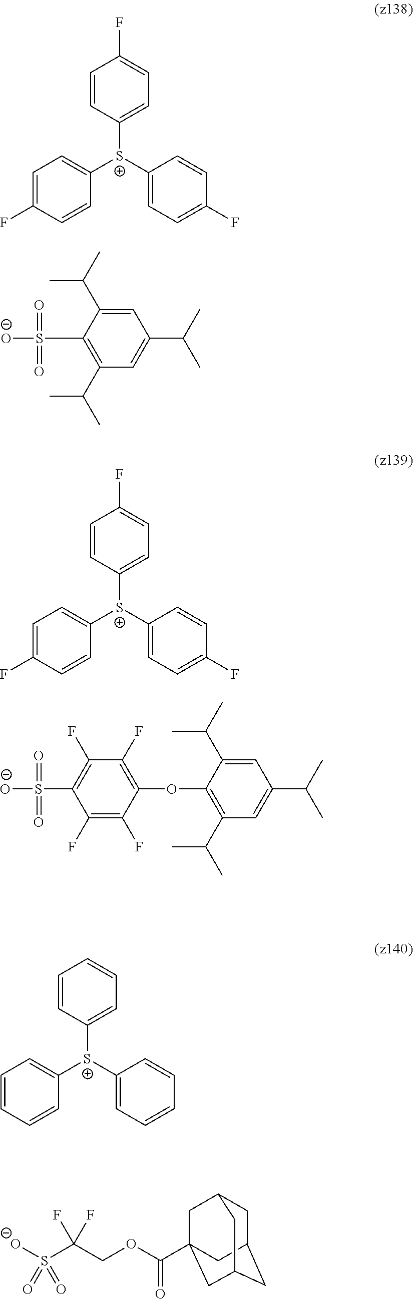 [SMILES: Fc1ccc([S+](c2ccc(F)cc2)c2ccc(F)cc2)cc1 ; CC(C)c1cc(C(C)C)c(S(=O)(=O)[O-])c(C(C)C)c1 ; Fc1ccc([S+](c2ccc(F)cc2)c2ccc(F)cc2)cc1 ; CC(C)c1cc(C(C)C)c(Oc2c(F)c(F)c(S(=O)(=O)[O-])c(F)c2F)c(C(C)C)c1 ; c1ccc([S+](c2ccccc2)c2ccccc2)cc1 ; O=C(OCC(F)(F)S(=O)(=O)[O-])C12CC3CC(CC(C3)C1)C2]

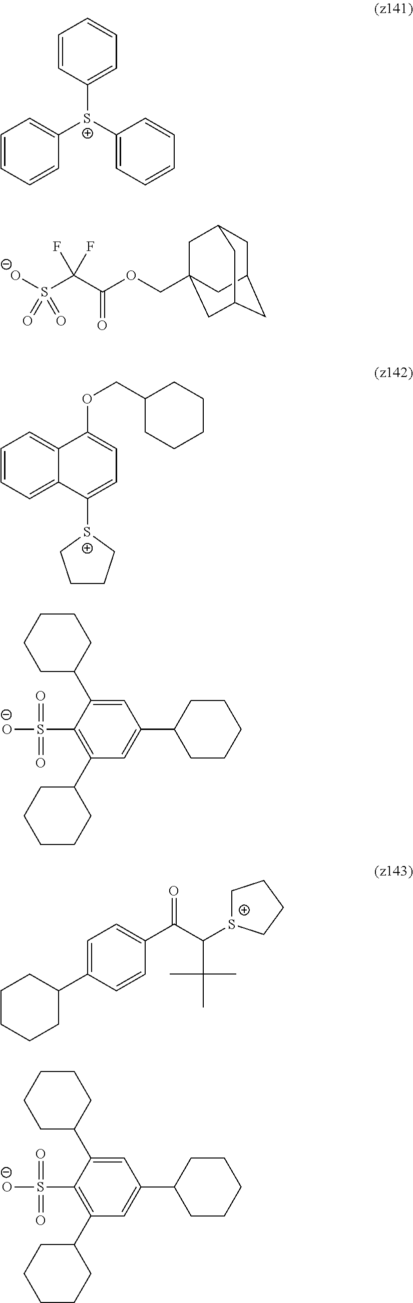 [SMILES: c1ccc([S+](c2ccccc2)c2ccccc2)cc1 ; O=C(OCC12CC3CC(CC(C3)C1)C2)C(F)(F)S(=O)(=O)[O-] ; c1ccc2c([S+]3CCCC3)ccc(OCC3CCCCC3)c2c1 ; O=S(=O)([O-])c1c(C2CCCCC2)cc(C2CCCCC2)cc1C1CCCCC1 ; CC(C)(C)C(C(=O)c1ccc(C2CCCCC2)cc1)[S+]1CCCC1 ; O=S(=O)([O-])c1c(C2CCCCC2)cc(C2CCCCC2)cc1C1CCCCC1]

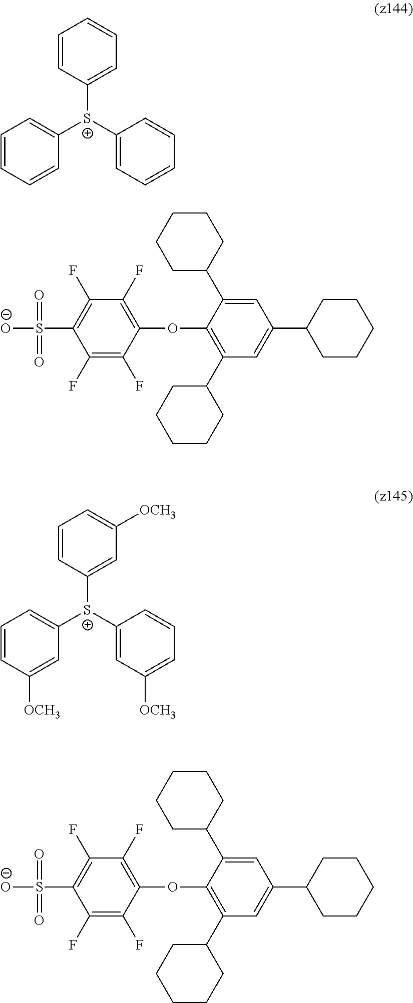 [SMILES: c1ccc([S+](c2ccccc2)c2ccccc2)cc1 ; O=S(=O)([O-])c1c(F)c(F)c(Oc2c(C3CCCCC3)cc(C3CCCCC3)cc2C2CCCCC2)c(F)c1F ; COc1cccc([S+](c2cccc(OC)c2)c2cccc(OC)c2)c1 ; O=S(=O)([O-])c1c(F)c(F)c(Oc2c(C3CCCCC3)cc(C3CCCCC3)cc2C2CCCCC2)c(F)c1F]

One kind of an acid generator may be used alone, or two or more kinds of acid generators may be used in combination.

The content of the photoacid generator is preferably from 0.1 to 50 mass %, more preferably from 0.5 to 45 mass %, still more preferably from 1 to 40 mass %, based on the total solid content of the composition.

### [5] Compound Capable of Decomposing by the Action of an Acid to Generate an Acid

The actinic ray-sensitive or radiation-sensitive resin composition of the present invention may further contain one compound or two or more compounds capable of decomposing by the action of an acid to generate an acid. The acid generated from the compound capable of decomposing by the action of an acid to generate an acid is preferably a sulfonic acid, a methide acid or an imide acid.

Examples of the compound which can be used in the present invention are illustrated below, but the present invention is not limited thereto.

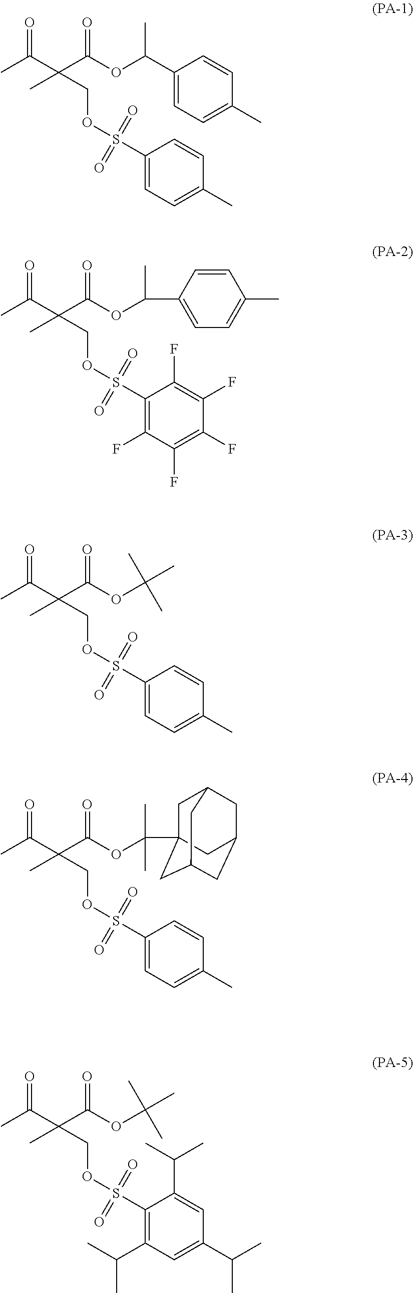

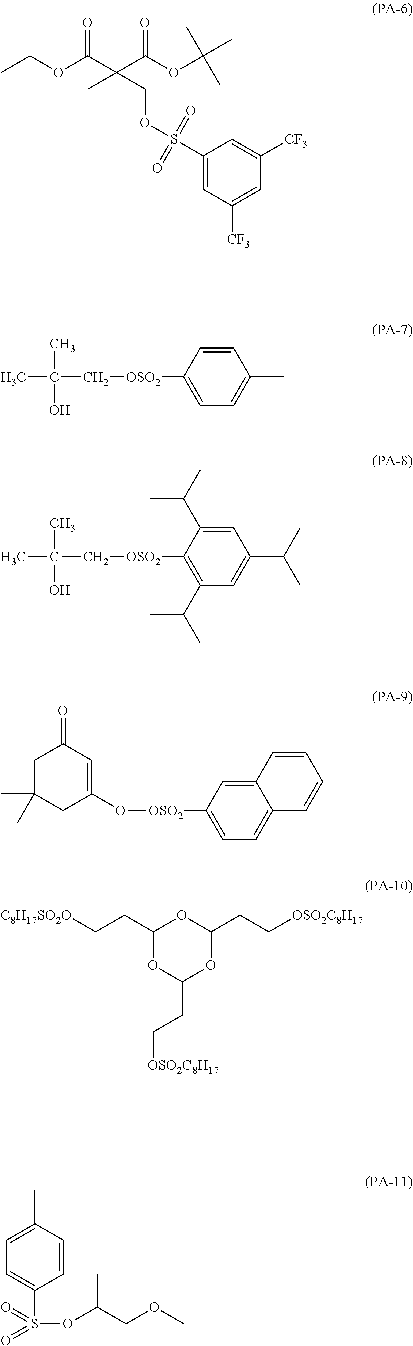

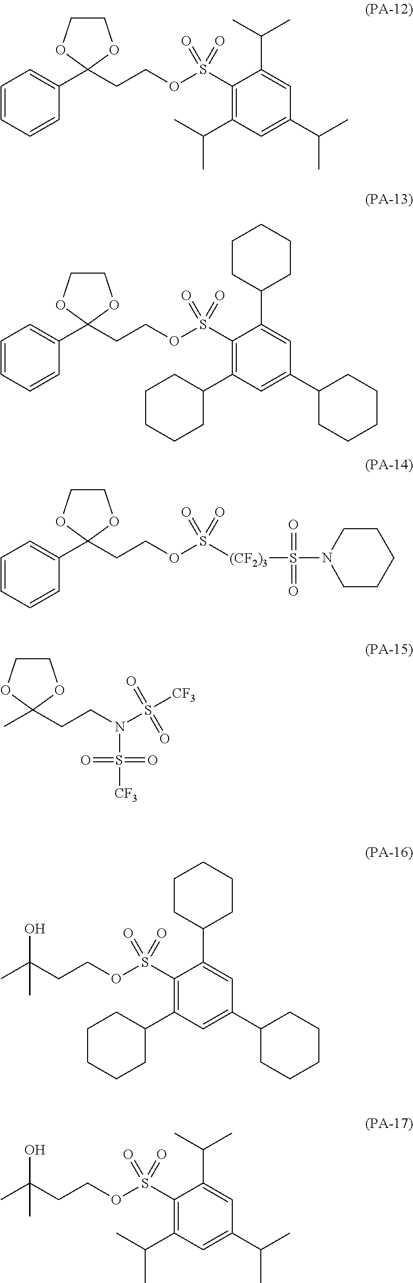

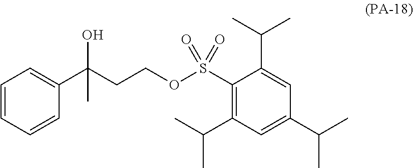 [SMILES: CC(C)c1cc(C(C)C)c(S(=O)(=O)OCCC(C)(O)c2ccccc2)c(C(C)C)c1]

As for the compound capable of decomposing by the action of an acid to generate an acid, one compound may be used alone, or two or more compounds may be used in combination.

Incidentally, the content of the compound capable of decomposing by the action of an acid to generate an acid is preferably from 0.1 to 40 mass %, more preferably from 0.5 to 30 mass %, still more preferably from 1.0 to 20 mass %, based on the total solid content of the actinic ray-sensitive or radiation-sensitive resin composition.

### [4] Resist Solvent (Coating Solvent)

The solvent which can be used when preparing the composition is not particularly limited as long as it dissolves respective components, but examples thereof include an alkylene glycol monoalkyl ether carboxylate (e.g., propylene glycol monomethyl ether acetate (PGMEA; another name: 1-methoxy-2-acetoxypropane)), an alkylene glycol monoalkyl ether (e.g., propylene glycol monomethyl ether (PGME; 1-methoxy-2-propanol)), a lactic acid alkyl ester (e.g., ethyl lactate, methyl lactate), a cyclic lactone (e.g., γ-butyrolactone; preferably having a carbon number of 4 to 10), a chain or cyclic ketone (e.g., 2-heptanone, cyclohexanone; preferably having a carbon number of 4 to 10), an alkylene carbonate (e.g., ethylene carbonate, propylene carbonate), an alkyl carboxylate (preferably an alkyl acetate such as butyl acetate), and an alkyl alkoxyacetate (e.g., ethyl ethoxypropionate). Other examples of the solvent which can be used include solvents described in paragraph [0244] et seq. of U.S. Patent Application Publication No. 2008/0248425A1.

Among the solvents above, an alkylene glycol monoalkyl ether carboxylate and an alkylene glycol monoalkyl ether are preferred.

One of these solvents may be used alone, or two or more thereof may be mixed and used. In the case of mixing two or more solvents, it is preferred to mix a solvent having a hydroxyl group and a solvent having no hydroxyl group. The mass ratio between the solvent having a hydroxyl group and the solvent having no hydroxyl group is from 1/99 to 99/1, preferably from 10/90 to 90/10, more preferably from 20/80 to 60/40.

The solvent having a hydroxy group is preferably an alkylene glycol monoalkyl ether, and the solvent having no hydroxyl group is preferably an alkylene glycol monoalkyl ether carboxylate.

### [6] Basic Compound

The actinic ray-sensitive or radiation-sensitive resin composition of the present invention may further contain a basic compound. The basic compound is preferably a compound having basicity stronger than that of phenol. The basic compound is preferably an organic basic compound, more preferably a nitrogen-containing basic compound.

The nitrogen-containing basic compound which can be used is not particularly limited, but, for example, compounds classified into the following (1) to (7) may be used.

### (1) Compound Represented by Formula (BS-1):

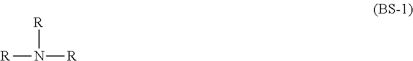

In formula (BS-1), each R independently represents a hydrogen atom or an organic group, provided that at least one of three R is an organic group. The organic group is a linear or branched alkyl group, a monocyclic or polycyclic cycloalkyl group, an aryl group or an aralkyl group.

The carbon number of the alkyl group as R is not particularly limited but is usually from 1 to 20, preferably from 1 to 12.

The carbon number of the cycloalkyl group as R is not particularly limited but is usually from 3 to 20, preferably from 5 to 15.

The carbon number of the aryl group as R is not particularly limited but is usually from 6 to 20, preferably from 6 to 10. Specific examples thereof include a phenyl group and a naphthyl group.

The carbon number of the aralkyl group as R is not particularly limited but is usually from 7 to 20, preferably from 7 to 11. Specific examples thereof include a benzyl group.

In the alkyl group, cycloalkyl group, aryl group and aralkyl group as R, a hydrogen atom may be substituted for by a substituent. Examples of the substituent include an alkyl group, a cycloalkyl group, an aryl group, an aralkyl group, a hydroxy group, a carboxy group, an alkoxy group, an aryloxy group, an alkylcarbonyloxy group, and an alkyloxycarbonyl group.

In the compound represented by formula (BS-1), it is preferred that at least two R are an organic group.

Specific examples of the compound represented by formula (BS-1) include tri-n-butylamine, tri-n-pentylamine, tri-n-octylamine, tri-n-decylamine, triisodecylamine, dicyclohexylmethylamine, tetradecyl amine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, and 2,4,6-tri(tert-butyl)aniline.

Also, the preferred basic compound represented by formula (BS-1) includes a compound where at least one R is an alkyl group substituted with a hydrophilic group. Specific examples thereof include triethanolamine and N,N-dihydroxyethylaniline.

The alkyl group as R may have an oxygen atom in the alkyl chain. That is, an oxyalkylene chain may be formed. The oxyalkylene chain is preferably —CH₂CH₂O—. Specific examples thereof include tris(methoxyethoxyethyl)amine and compounds illustrated in column 3, line 60 et seq. of U.S. Pat. No. 6,040,112.

Out of basic compounds represented by formula (BS-1), examples of the compounds having a hydroxyl group, an oxygen atom or the like include the followings.

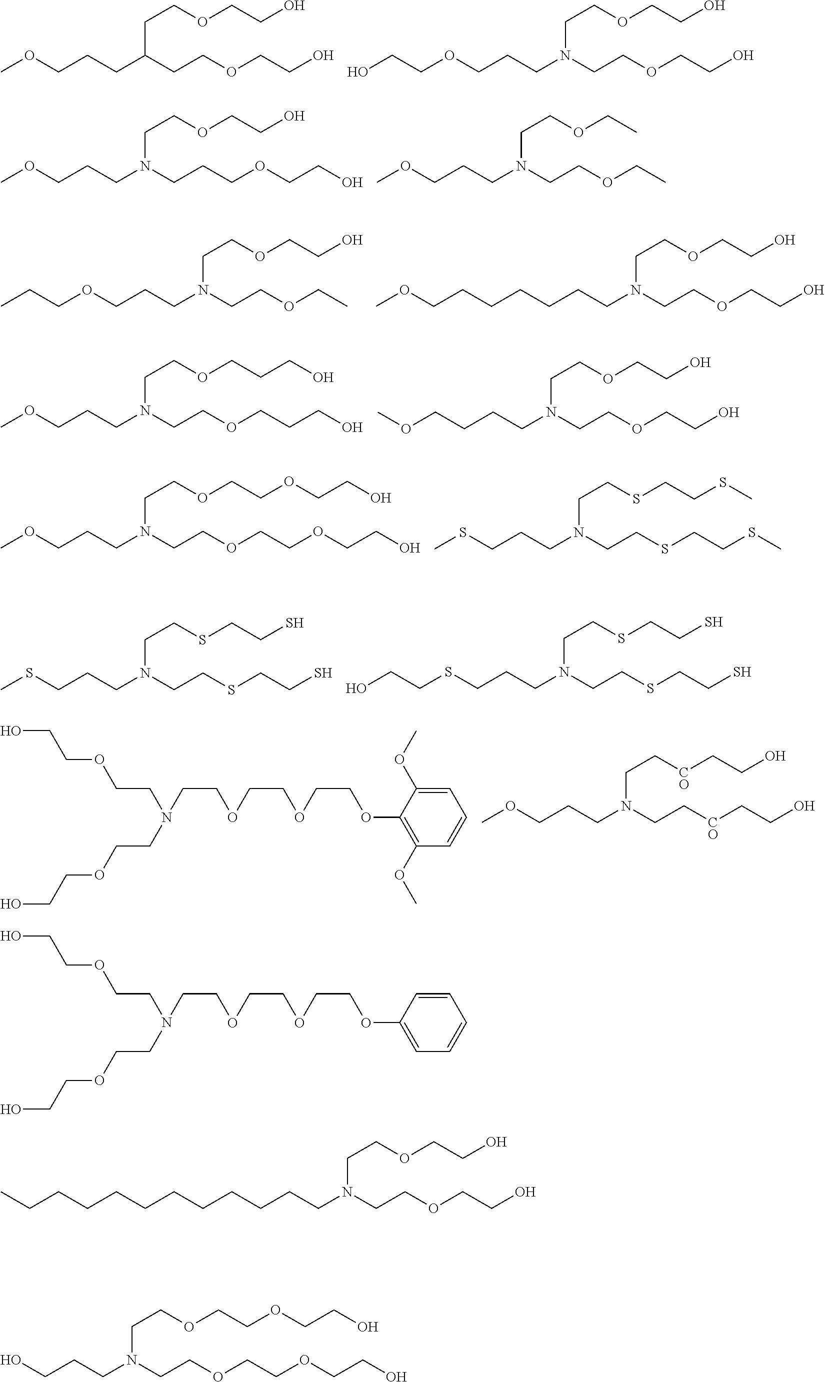

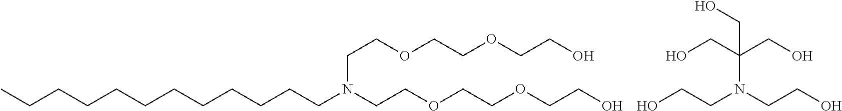

### (2) Compound Having a Nitrogen-Containing Heterocyclic Structure

The nitrogen-containing heterocyclic ring may or may not have aromaticity, may contain a plurality of nitrogen atoms, and may further contain a heteroatom other than nitrogen. Specific examples of the compound include a compound having an imidazole structure (e.g., 2-phenylbenzimidazole, 2,4,5-triphenylimidazole), a compound having a piperidine structure [e.g., N-hydroxyethylpiperidine, bis(1,2,2,6,6-pentamethyl-4-piperidyl)sebacate], a compound having a pyridine structure (e.g., 4-dimethylaminopyridine), and a compound having an antipyrine structure (e.g., antipyrine, hydroxyantipyrine).

Preferred examples of the compound having a nitrogen-containing heterocyclic structure include guanidine, aminopyridine, aminoalkylpyridine, aminopyrrolidine, indazole, imidazole, pyrazole, pyrazine, pyrimidine, purine, imidazoline, pyrazoline, piperazine, aminomorpholine, and aminoalkylmorpholine. These compounds may further have a substituent.

Preferred examples of the substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

More preferred examples of the basic compound include imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine.

A compound having two or more ring structures is also suitably used. Specific examples thereof include 1,5-diazabicyclo[4.3.0]non-5-ene and 1,8-diazabicyclo[5.4.0]undec-7-ene.

### (3) Phenoxy Group-Containing Amine Compound

The phenoxy group-containing amine compound is a compound where the alkyl group contained in an amine compound has a phenoxy group at the terminal opposite the N atom. The phenoxy group may have a substituent such as alkyl group, alkoxy group, halogen atom, cyano group, nitro group, carboxy group, carboxylic acid ester group, sulfonic acid ester group, aryl group, aralkyl group, acyloxy group and aryloxy group.

The compound preferably has at least one oxyalkylene chain between the phenoxy group and the nitrogen atom. The number of oxyalkylene chains per molecule is preferably from 3 to 9, more preferably from 4 to 6. Among oxyalkylene chains, —CH₂CH₂O— is preferred.

Specific examples of the compound include 2-[2-{2-(2,2-dimethoxy-phenoxyethoxy)ethyl}-bis-(2-methoxyethyl)]-amine and Compounds (C1-1) to (C3-3) illustrated in paragraph [0066] of U.S. Patent Application Publication No. 2007/0224539A1.

The phenoxy group-containing amine compound is obtained, for example, by reacting a primary or secondary amine having a phenoxy group with a haloalkyl ether under heating and after adding an aqueous solution of a strong base such as sodium hydroxide, potassium hydroxide and tetraalkylammonium, extracting the reaction product with an organic solvent such as ethyl acetate and chloroform. The phenoxy group-containing amine compound can be also obtained by reacting a primary or secondary amine with a haloalkyl ether having a phenoxy group at the terminal under heating and after adding an aqueous solution of a strong base such as sodium hydroxide, potassium hydroxide and tetraalkylammonium, extracting the reaction product with an organic solvent such as ethyl acetate and chloroform.

### (4) Ammonium Salt

An ammonium salt may be also appropriately used as the basic compound.

The cation of the ammonium salt is preferably a tetraalkylammonium cation substituted with an alkyl group having a carbon number of 1 to 18, more preferably a tetramethylammonium cation, a tetraethylammonium cation, a tetra(n-butyl)ammonium cation, a tetra(n-heptyl)ammonium cation, a tetra(n-octyl)ammonium cation, a dimethyl-hexadecylammonium cation, a benzyltrimethyl cation or the like, still more preferably a tetra(n-butyl)ammonium cation.

The anion of the ammonium salt includes, for example, hydroxide, carboxylate, halide, sulfonate, borate and phosphate. Among these, hydroxide and carboxylate are preferred.

The halide is preferably chloride, bromide or iodide.

The sulfonate is preferably an organic sulfonate having a carbon number of 1 to 20. Examples of the organic sulfonate include an alkylsulfonate having a carbon number of 1 to 20, and an arylsulfonate.

The alkyl group contained in the alkylsulfonate may have a substituent, and examples of the substituent include a fluorine atom, a chlorine atom, a bromine atom, an alkoxy group, an acyl group, and an aryl group. Specific examples of the alkylsulfonate include methanesulfonate, ethanesulfonate, butanesulfonate, hexanesulfonate, octanesulfonate, benzylsulfonate, trifluoromethanesulfonate, pentafluoroethanesulfonate, and nonafluorobutanesulfonate.

Examples of the aryl group contained in the arylsulfonate include a phenyl group, a naphthyl group, and an anthryl group. Such an aryl group may have a substituent. The substituent is preferably, for example, a linear or branched alkyl group having a carbon number of 1 to 6, or a cycloalkyl group having a carbon number of 3 to 6. Specific preferred examples thereof include a methyl group, an ethyl group, an n-propyl group, an isopropyl group, an n-butyl group, an i-butyl group, a tert-butyl group, an n-hexyl group and a cyclohexyl group. Other substituents include an alkoxy group having a carbon number of 1 to 6, a halogen atom, cyano, nitro, an acyl group, and an acyloxy group.

The carboxylate may be either an aliphatic carboxylate or an aromatic carboxylate, and examples thereof include acetate, lactate, pyruvate, trifluoroacetate, adamantanecarboxylate, hydroxyadamantanecarboxylate, benzoate, naphthoate, salicylate, phthalate, and phenolate. Among these, benzoate, naphthoate, phenolate and the like are preferred, and benzoate is most preferred.

In this case, the ammonium salt is preferably, for example, tetra(n-butyl)ammonium benzoate or tetra(n-butyl)ammonium phenolate.

In the case of a hydroxide, the ammonium salt is preferably a tetraalkylammonium hydroxide having a carbon number of 1 to 8 (e.g., tetramethylammonium hydroxide, tetraethylammonium hydroxide, tetra-(n-butyl)ammonium hydroxide).

(5) (PA) Compound Having a Proton Acceptor Functional Group and Undergoing Decomposition Upon Irradiation with an Actinic Ray or Radiation to Generate a Compound Reduced in or Deprived of the Proton Acceptor Property or Changed from Proton Acceptor-Functioning to Acidic

The composition of the present invention may further contain, as a basic compound, a compound having a proton acceptor functional group and undergoing decomposition upon irradiation with an actinic ray or radiation to generate a compound reduced in or deprived of the proton acceptor property or changed from proton acceptor-functioning to acidic [hereinafter, sometimes referred to as “compound (PA)”].

The proton acceptor functional group is a functional group having a group or electron capable of electrostatically interacting with a proton and means, for example, a functional group having a macrocyclic structure such as cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following formulae:

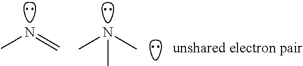

Preferred examples of the partial structure for the proton acceptor functional group include a crown ether structure, an aza-crown ether structure, a primary to tertiary amine structure, a pyridine structure, an imidazole structure, and a pyrazine structure.

The compound (PA) decomposes upon irradiation with an actinic ray or radiation to generate a compound reduced in or deprived of the proton acceptor property or changed from proton acceptor-functioning to acidic. The “reduced in or deprived of the proton acceptor property or changed from proton acceptor-functioning to acidic” as used herein indicates a change in the proton acceptor property due to addition of a proton to the proton acceptor functional group and specifically means that when a proton adduct is produced from the proton acceptor functional group-containing compound (PA) and a proton, the equilibrium constant in the chemical equilibrium decreases.

Specific examples of the compound (PA) are illustrated below, but the present invention is not limited thereto.

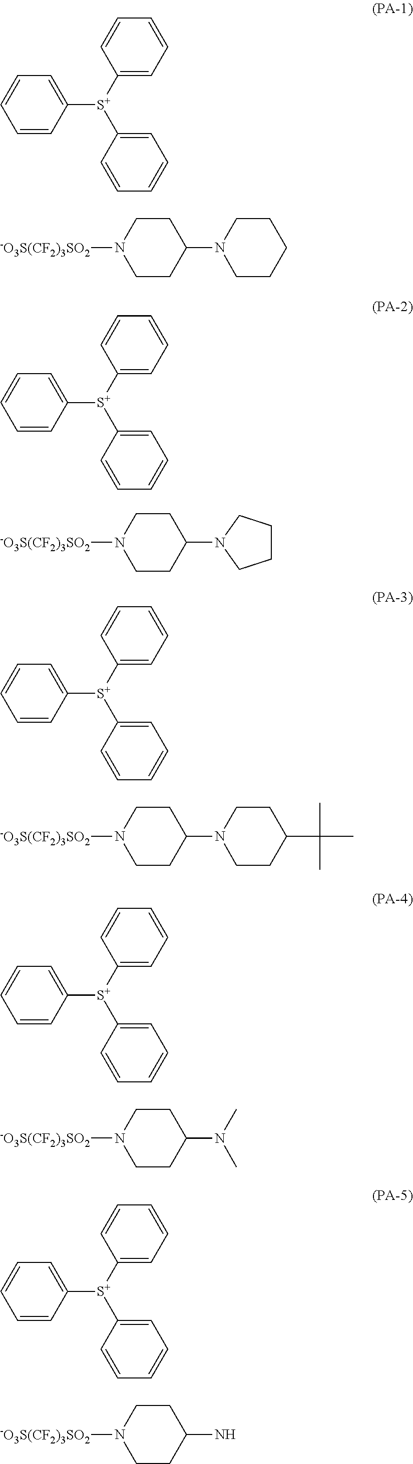

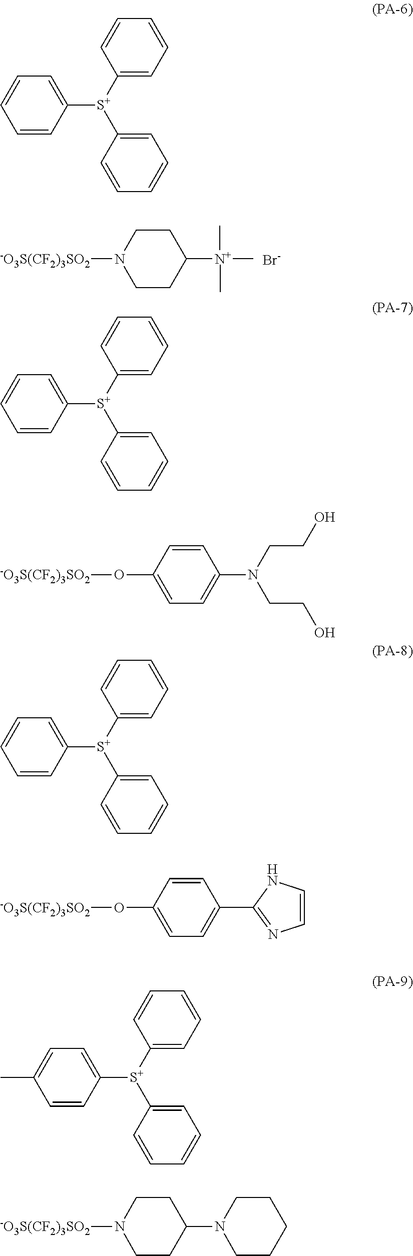

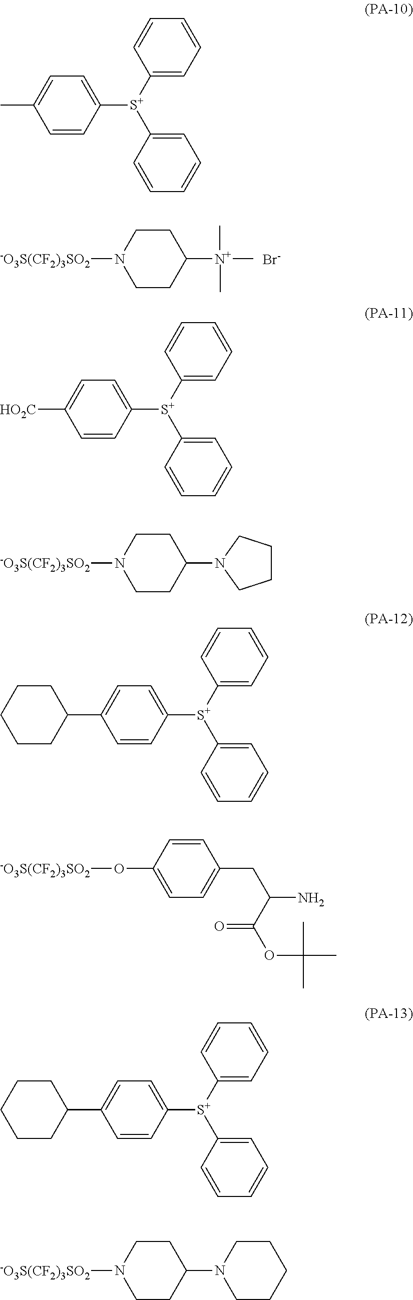

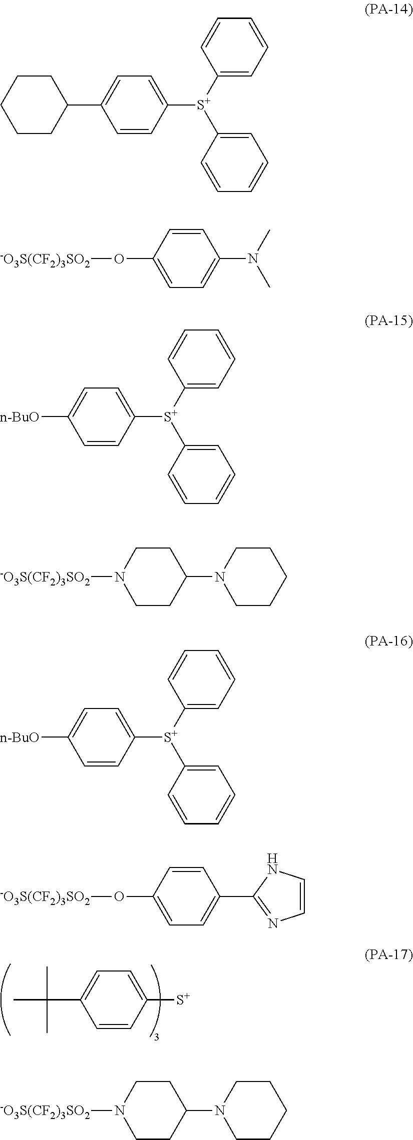

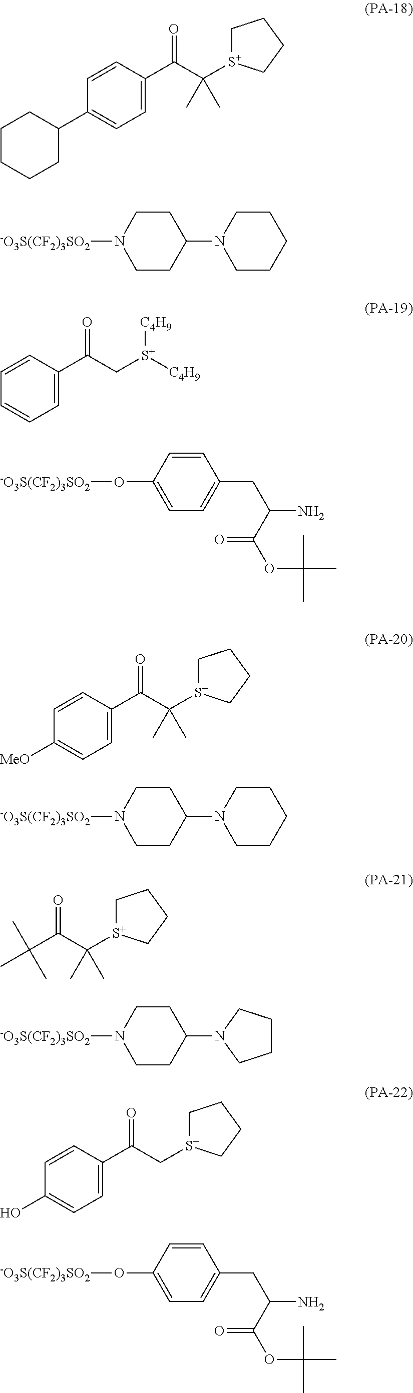

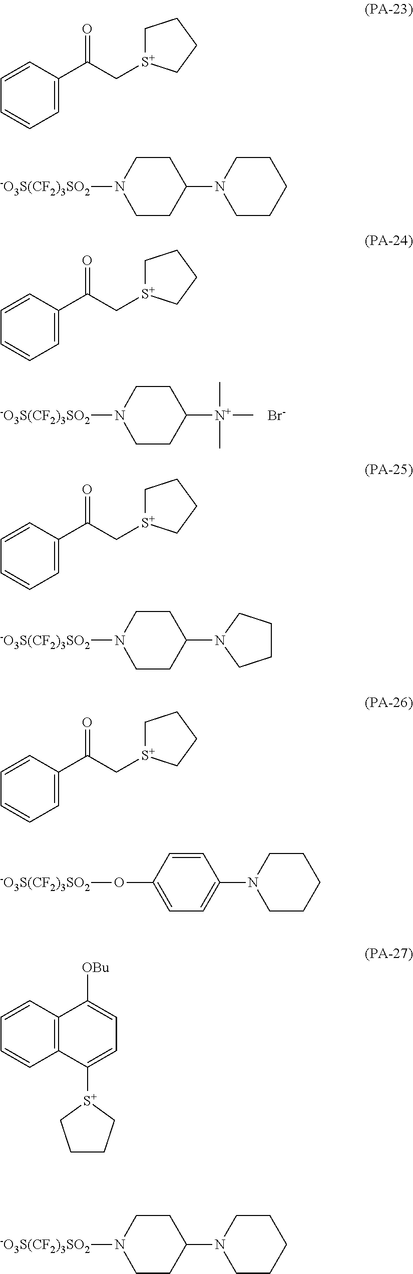

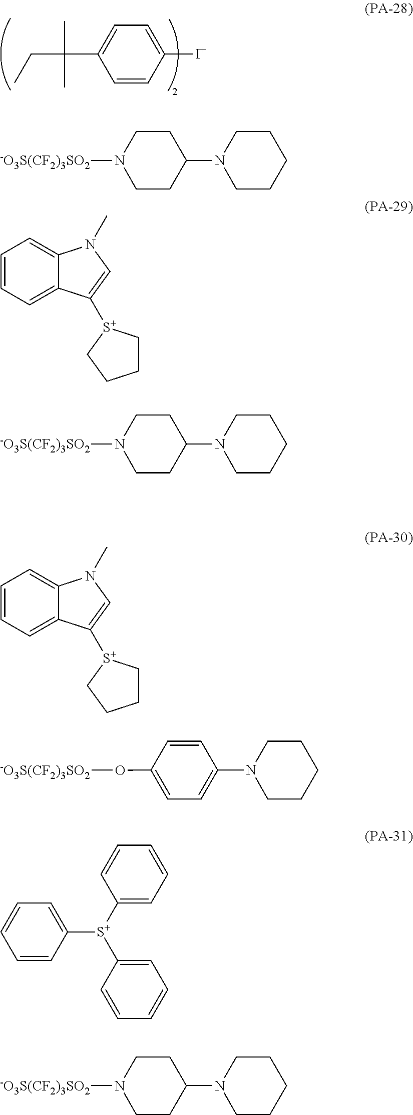

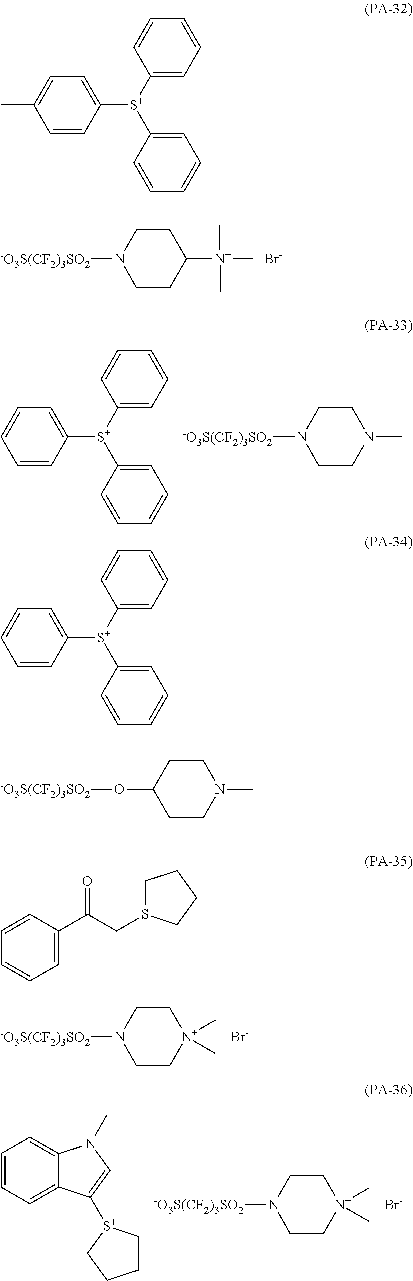

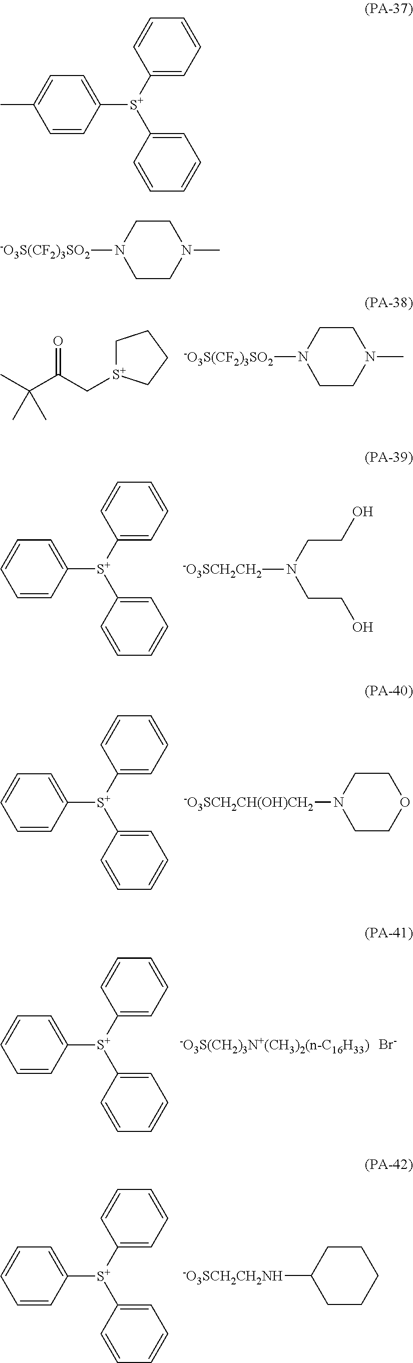

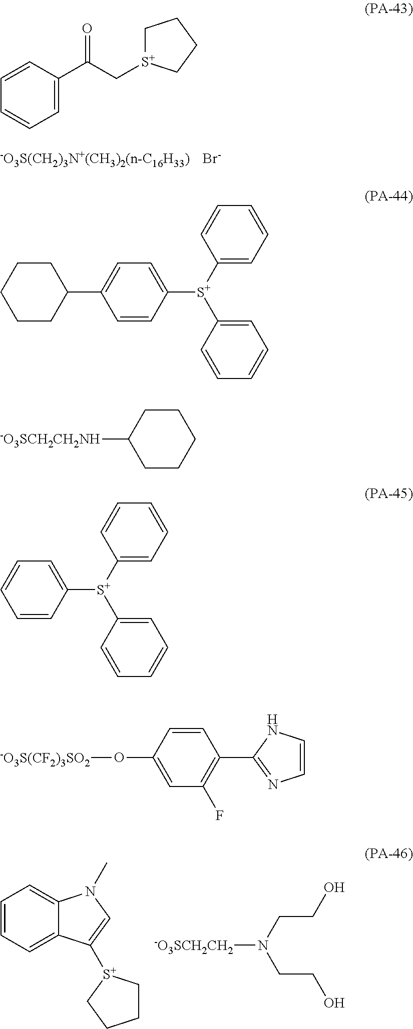

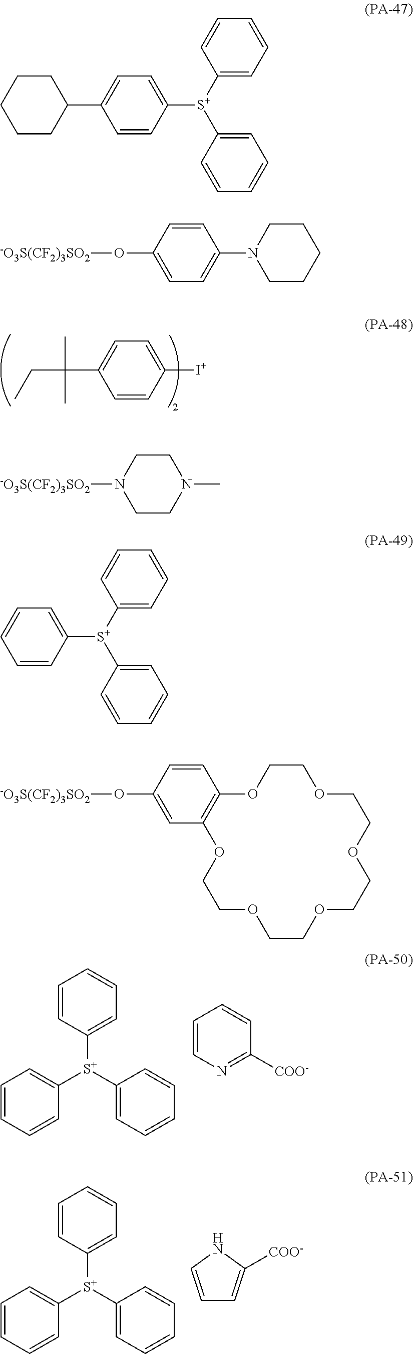

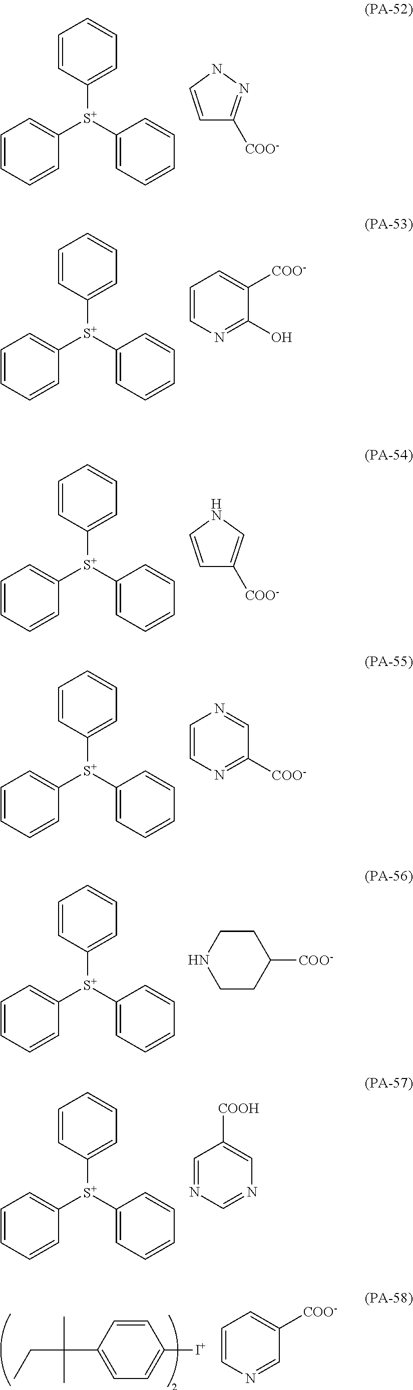

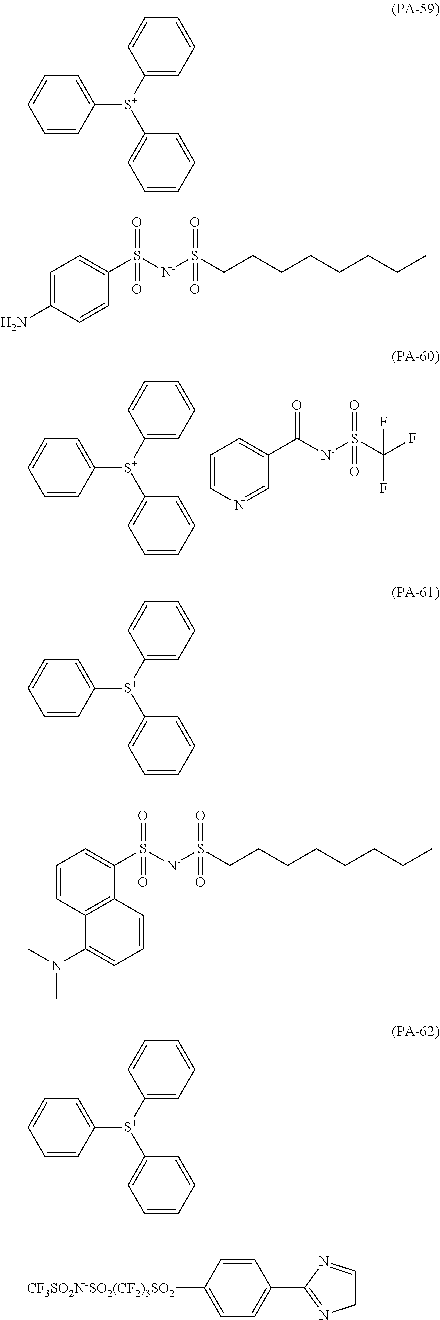

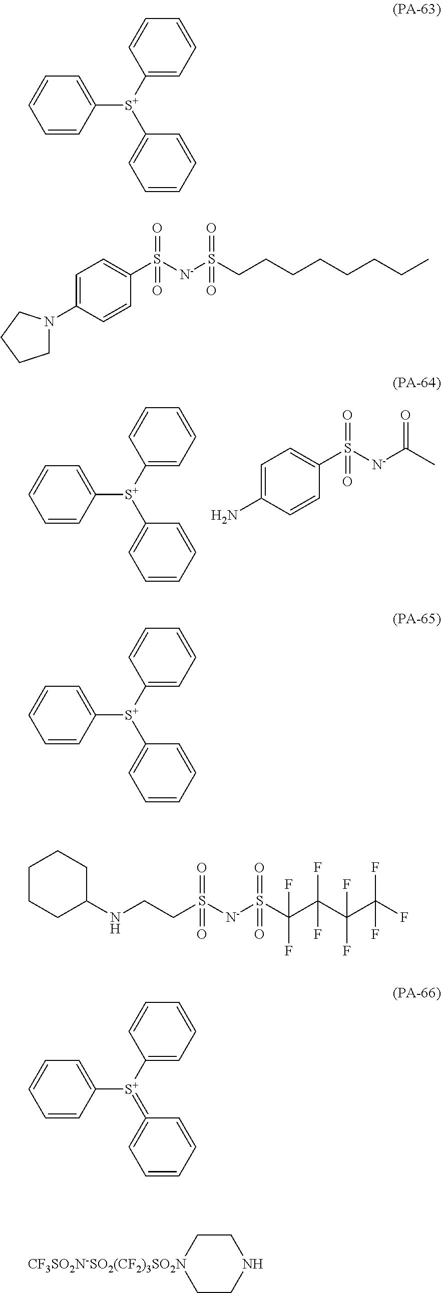

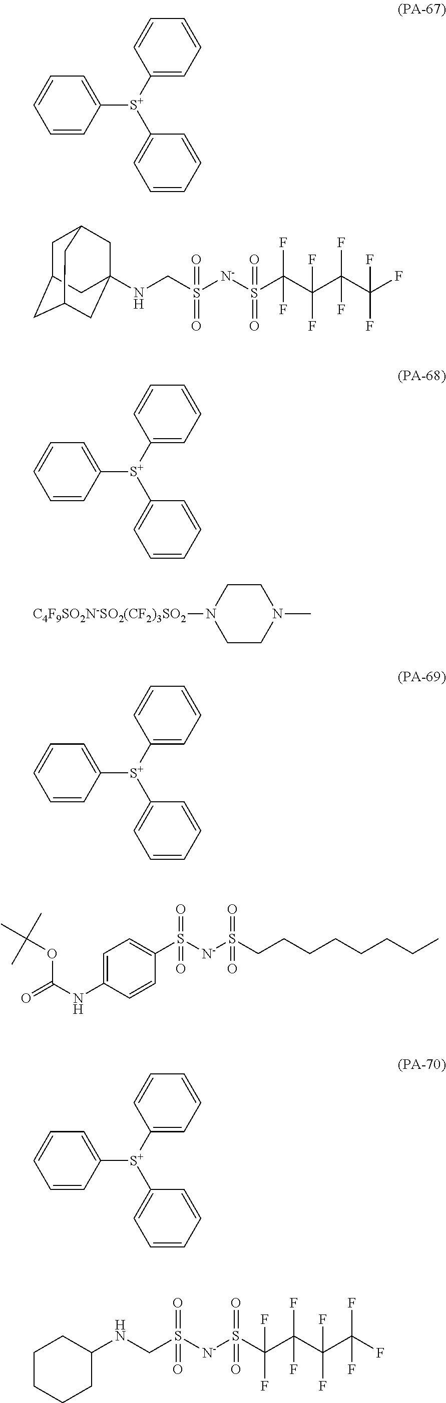

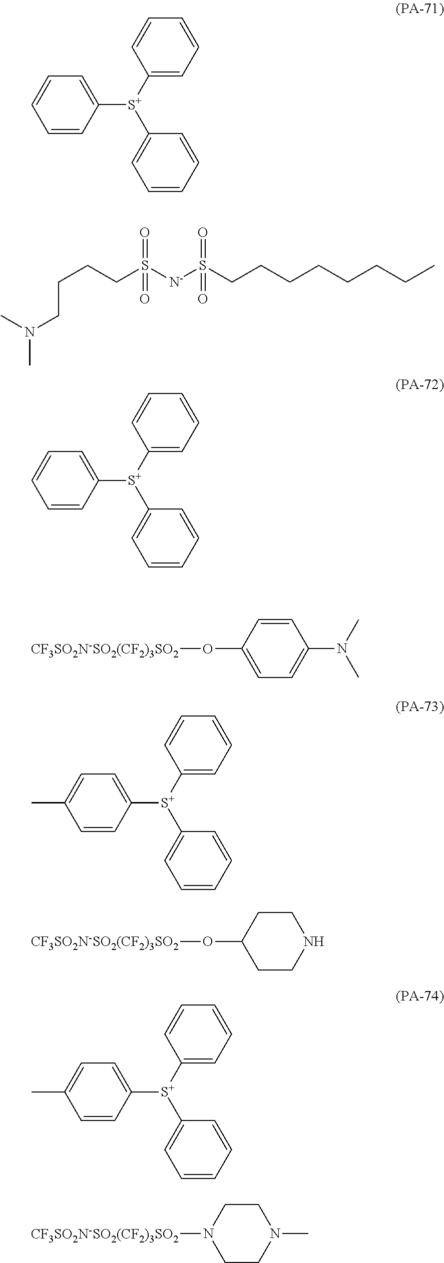

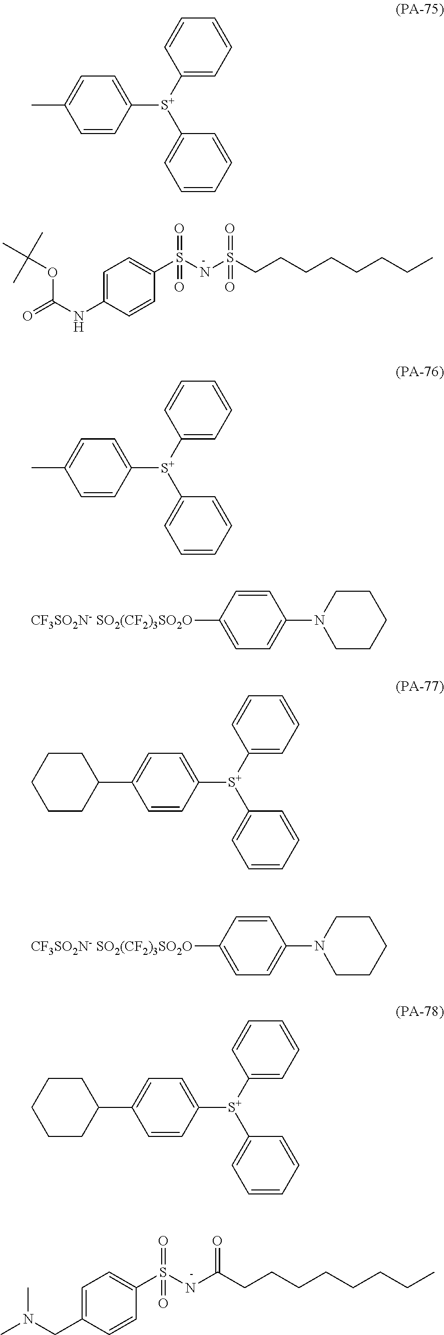

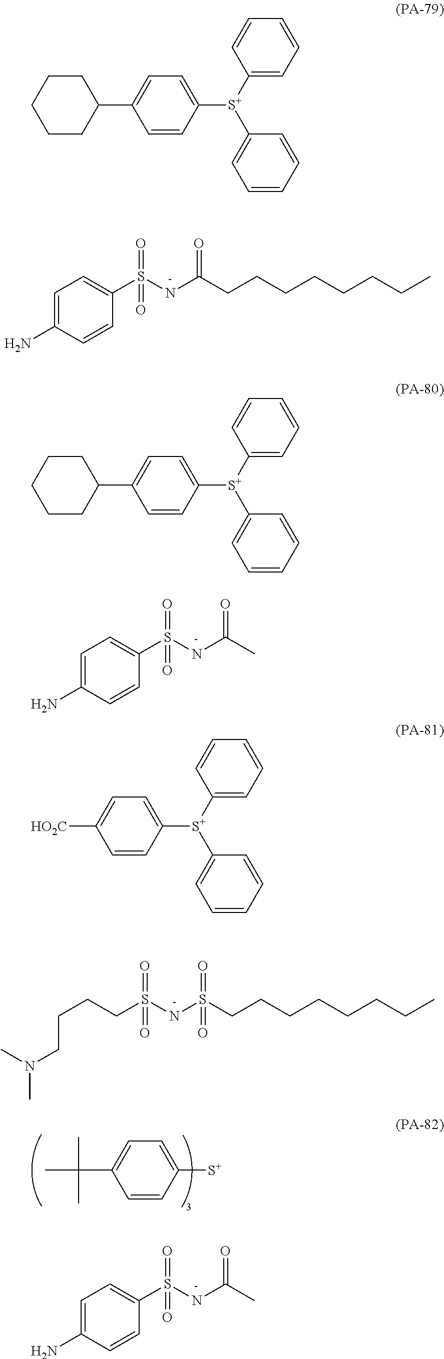

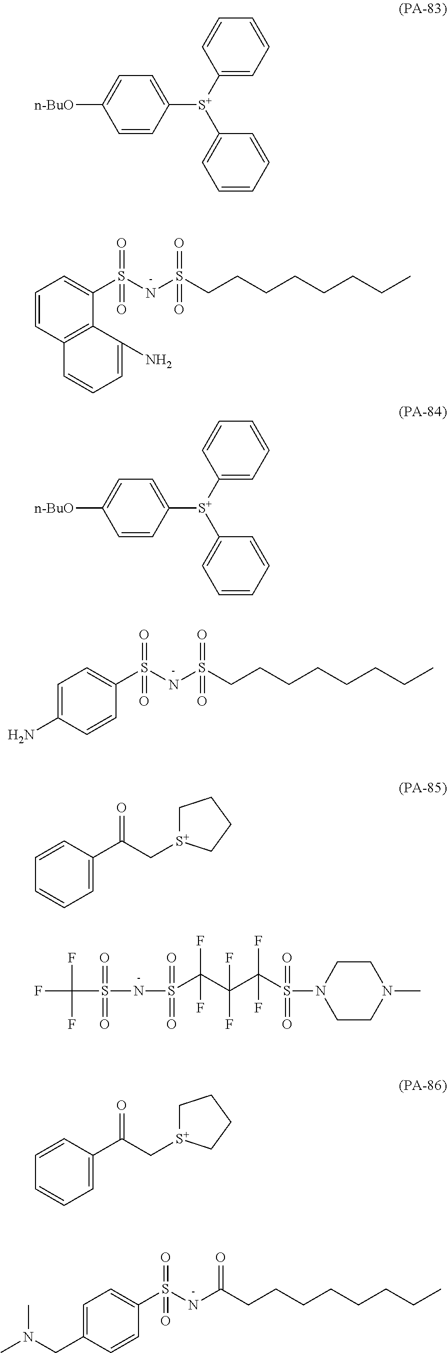

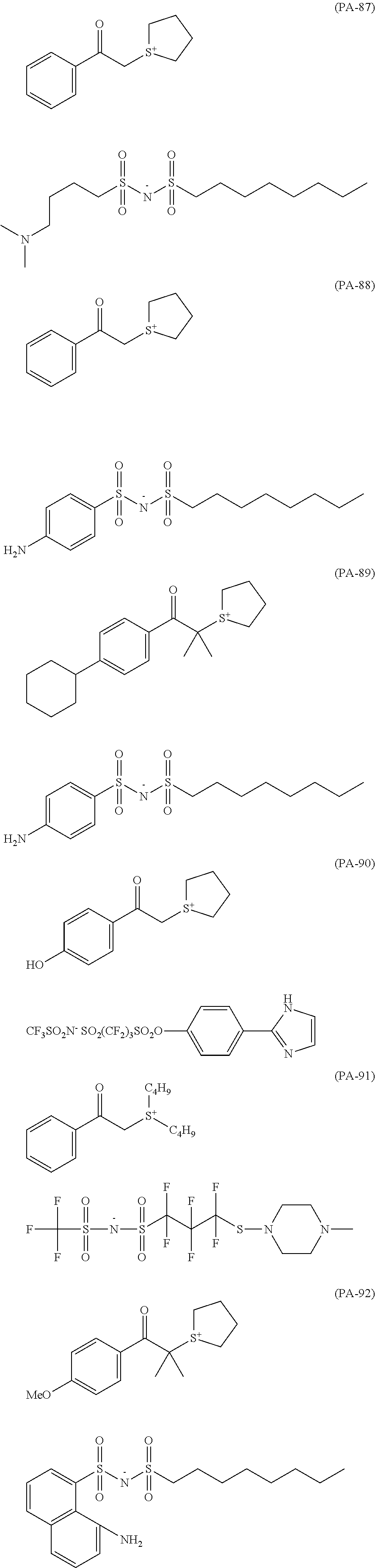

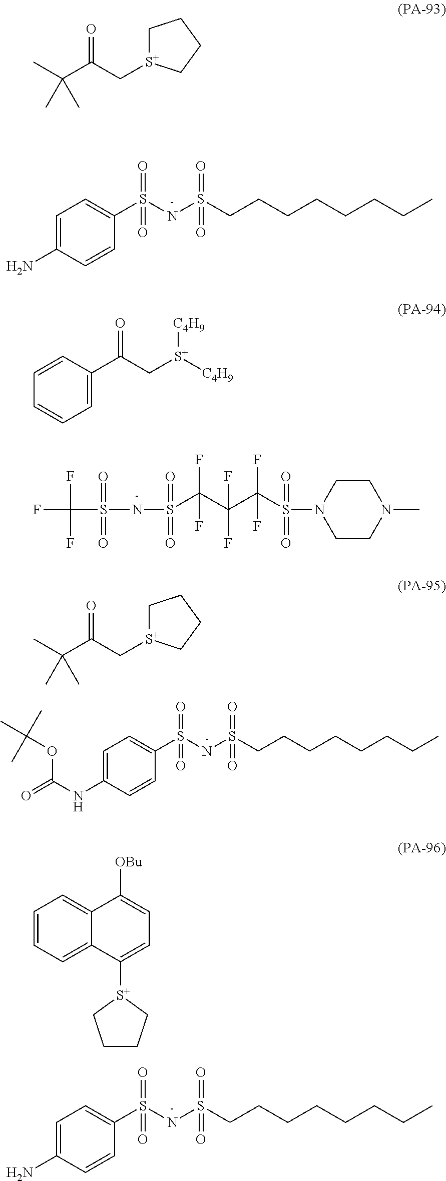

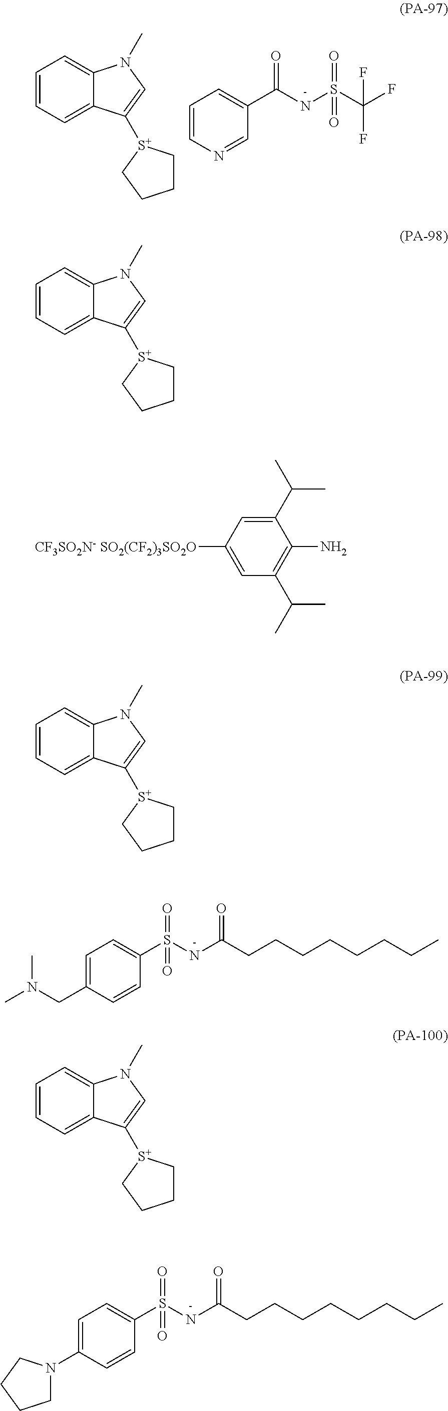

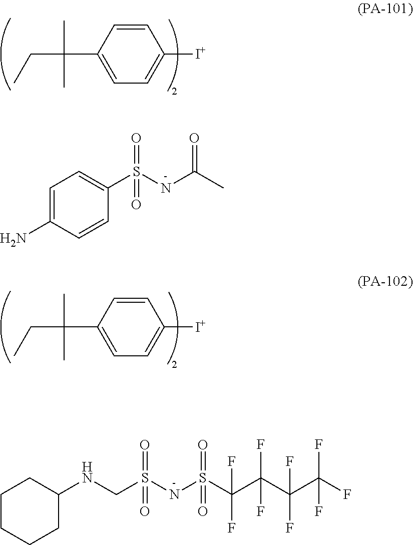

In the present invention, a compound (PA) other than the compound capable of generating a compound represented by formula (PA-1) can be also appropriately selected. For example, a compound that is an ionic compound and has a proton acceptor site in the cation moiety may be used. More specifically, examples of such a compound include a compound represented by the following formula (7):

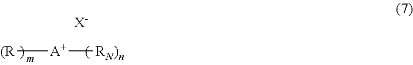

In the formula, A represents a sulfur atom or an iodine atom.

m represents 1 or 2, and n represents 1 or 2, provided that when A is a sulfur atom, m+n=3 and when A is an iodine atom, m+n=2.

R represents an aryl group.

R_{N} represents an aryl group substituted with a proton acceptor functional group.

X⁻ represents a counter anion.

Specific examples of X⁻ are the same as those of X⁻ in formula (ZI).

Specific preferred examples of the aryl group of R and R_{N} include a phenyl group.

Specific examples of the proton acceptor functional group contained in R_{N} are the same as those of the proton acceptor functional group described above in formula (PA-1).

In the composition of the present invention, the blending ratio of the compound (PA) in the entire composition is preferably from 0.1 to 10 mass %, more preferably from 1 to 8 mass %, based on the total solid content.

### (6) Guanidine Compound

The composition of the present invention may further contain a guanidine compound having a structure represented by the following formula:

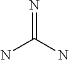

The guanidine compound exhibits strong basicity because thanks to three nitrogens, dispersion of positive electric charges of a conjugate acid is stabilized.

As for the basicity of the guanidine compound (A) for use in the present invention, the pKa of the conjugate acid is preferably 6.0 or more, more preferably from 7.0 to 20.0 in view of high neutralization reactivity with an acid and excellent roughness characteristics, and still more preferably from 8.0 to 16.0.

Such strong basicity makes it possible to suppress diffusion of an acid and contribute to formation of an excellent pattern profile.

The “pKa” as used herein is pKa in an aqueous solution and described, for example, in Kagaku Binran (Chemical Handbook) (II) (4th revised edition, compiled by The Chemical Society of Japan, Maruzen (1993)), and as this value is lower, the acid strength is higher. Specifically, the acid dissociation constant at 25° C. is measured using an aqueous infinite dilution solution, whereby pKa in an aqueous solution can be actually measured. Alternatively, a value based on Hammett's substituent constants and data base containing values known in publications can be determined by computation using the following software package 1. The pKa values referred to in the description of the present invention all are a value determined by computation using this software package.

Software Package 1: Advanced Chemistry Development (ACD/Labs) Software V8.14 for Solaris (1994-2007 ACD/Labs)

In the present invention, the log P is a logarithmic value of the n-octanol/water partition coefficient (P) and is an effective parameter capable of characterizing the hydrophilicity/hydrophobicity for compounds over a wide range. The partition coefficient is generally determined by computation but not from experiments and in the present invention, a value computed using CS ChemDraw Ultra Ver. 8.0 software package (Crippen's fragmentation method) is employed.

The log P of the guanidine compound (A) is preferably 10 or less. With this value or less, the compound can be uniformly incorporated in the resist film.

The log P of the guanidine compound (A) for use in the present invention is preferably from 2 to 10, more preferably from 3 to 8, still more preferably 4 to 8.

The guanidine compound (A) for use in the present invention preferably contains no nitrogen atom except for in the guanidine structure.

Specific examples of the guanidine compound are illustrated below, but the present invention is not limited thereto.

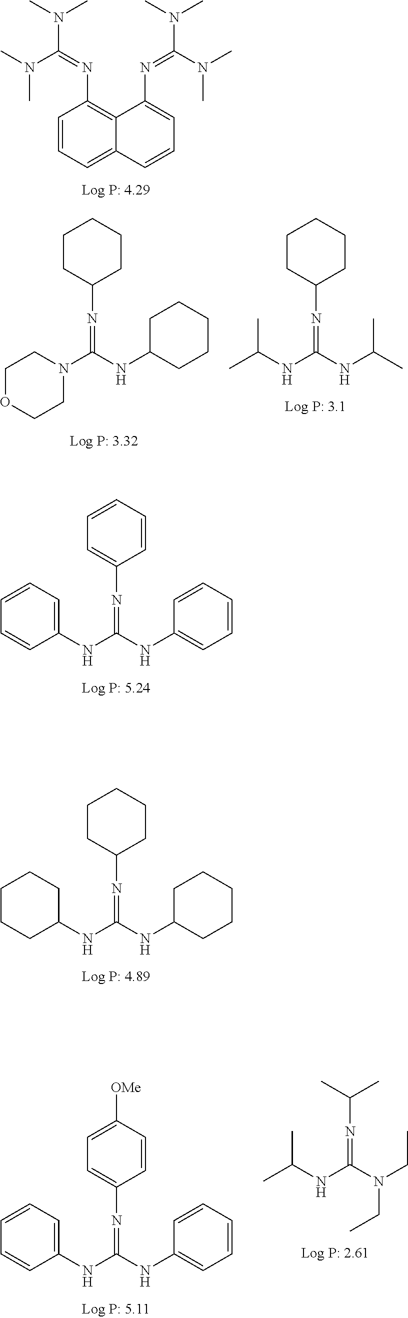

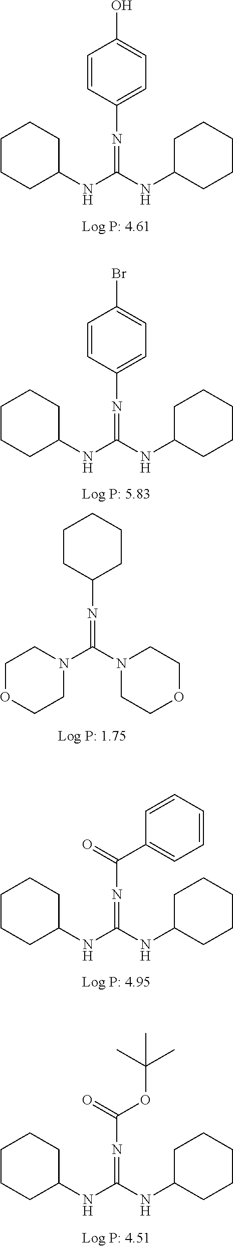 [SMILES: Oc1ccc(N=C(NC2CCCCC2)NC2CCCCC2)cc1 ; Brc1ccc(N=C(NC2CCCCC2)NC2CCCCC2)cc1 ; C1CCC(N=C(N2CCOCC2)N2CCOCC2)CC1 ; O=C(N=C(NC1CCCCC1)NC1CCCCC1)c1ccccc1 ; CC(C)(C)OC(=O)N=C(NC1CCCCC1)NC1CCCCC1]

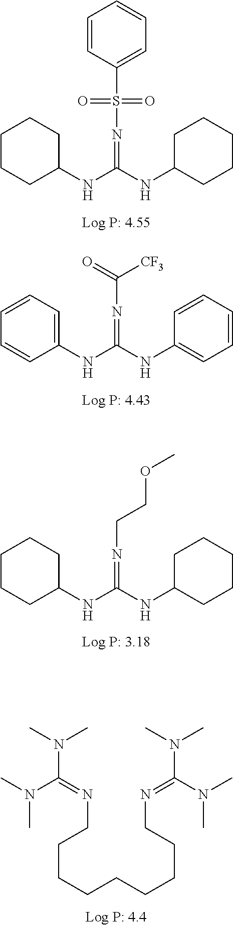

### (7) Low Molecular Compound Having a Nitrogen Atom and Having a Group Capable of Leaving by the Action of an Acid

The composition of the present invention may contain a low molecular compound having a nitrogen atom and having a group capable of leaving by the action of an acid (hereinafter, sometimes referred to as “low molecular compound (D)” or “compound (D)”). The low molecular compound (D) preferably exhibits basicity after the group capable of leaving by the action of an acid is eliminated.

The group capable of leaving by the action of an acid is not particularly limited but is preferably an acetal group, a carbonate group, a carbamate group, a tertiary ester group, a tertiary hydroxyl group or a hemiaminal ether group, more preferably a carbamate group or a hemiaminal ether group.

The molecular weight of the (D) low molecular compound having a group capable of leaving by the action of an acid is preferably from 100 to 1,000, more preferably from 100 to 700, still more preferably from 100 to 500.

The compound (D) is preferably an amine derivative having on the nitrogen atom a group capable of leaving by the action of an acid.

The compound (D) may have a protective group-containing carbamate group on the nitrogen atom. The protective group constituting the carbamate group can be represented by the following formula (d-1):

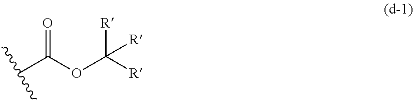

In formula (d-1), each R′ independently represents a hydrogen atom, a linear or branched alkyl group, a cycloalkyl group, an aryl group, an aralkyl group or an alkoxyalkyl group. R′ may combine with each other to form a ring.

R′ is preferably a linear or branched alkyl group, a cycloalkyl group or an aryl group, more preferably a linear or branched alkyl group or a cycloalkyl group.

Specific structures of the protective group are illustrated below.

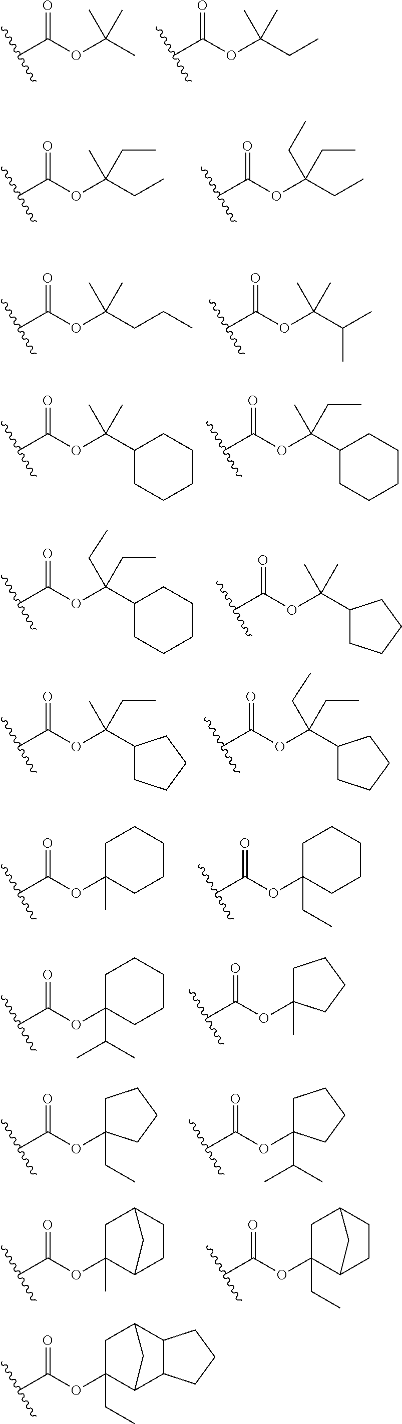

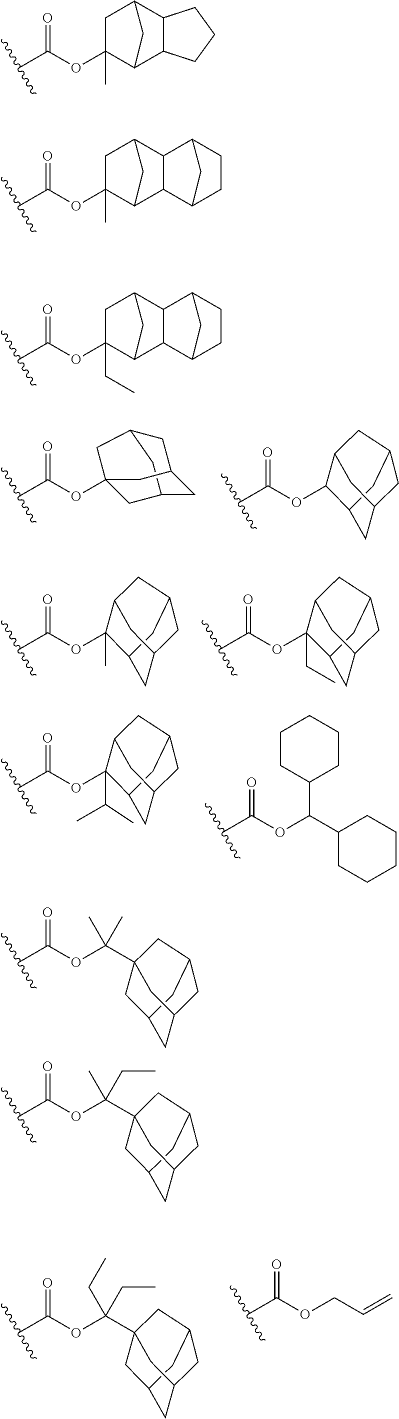

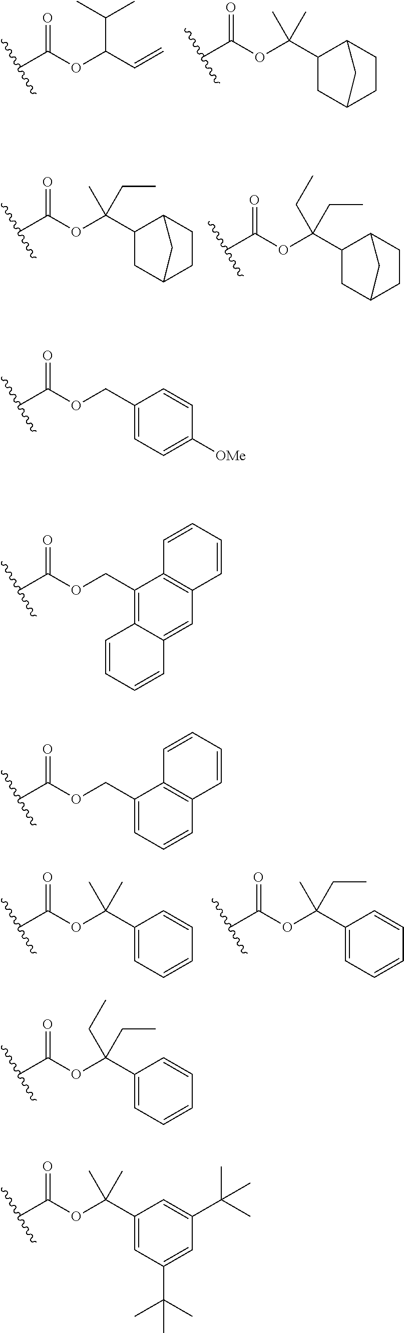

The compound (D) may be also composed by arbitrarily combining the basic compound and the structure represented by formula (d-1).

The compound (D) is more preferably a compound having a structure represented by the following formula (A).

Incidentally, the compound (D) may be a compound corresponding to the above-described basic compound as long as it is a low molecular compound having a group capable of leaving by the action of an acid.

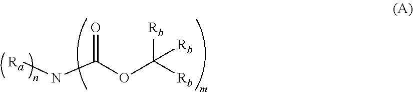

In formula (A), Ra represents a hydrogen atom, an alkyl group, a cycloalkyl group, an aryl group or an aralkyl group. Also, when n=2, two Ra may be the same or different, and two Ra may combine with each other to fond a divalent heterocyclic hydrocarbon group (preferably having a carbon number of 20 or less) or a derivative thereof.

Each Rb independently represents a hydrogen atom, an alkyl group, a cycloalkyl group, an aryl group, an aralkyl group or an alkoxyalkyl group, provided that in —C(Rb)(Rb)(Rb), when one or more Rb are a hydrogen atom, at least one of the remaining Rb is a cyclopropyl group, a 1-alkoxyalkyl group or an aryl group.

At least two Rb may combine to form an alicyclic hydrocarbon group, an aromatic hydrocarbon group, a heterocyclic hydrocarbon group, or a derivative thereof,

n represents an integer of 0 to 2, m represents an integer of 1 to 3, and n+m=3.

In formula (A), the alkyl group, cycloalkyl group, aryl group and aralkyl group of Ra and Rb may be substituted with a functional group such as hydroxyl group, cyano group, amino group, pyrrolidino group, piperidino group, morpholino group and oxo group, an alkoxy group, or a halogen atom. The same applies to the alkoxyalkyl group of Rb.

Examples of the alkyl group, cycloalkyl group, aryl group and aralkyl group (these alkyl, cycloalkyl, aryl and aralkyl groups may be substituted with the above-described functional group, an alkoxy group or a halogen atom) of Ra and/or Rb include:

a group derived from a linear or branched alkane such as methane, ethane, propane, butane, pentane, hexane, heptane, octane, nonane, decane, undecane and dodecane, or a group where the group derived from an alkane is substituted with one or more kinds of or one or more groups of cycloalkyl groups such as cyclobutyl group, cyclopentyl group and cyclohexyl group;

a group derived from a cycloalkane such as cyclobutane, cyclopentane, cyclohexane, cycloheptane, cyclooctane, norbornane, adamantane and noradamantane, or a group where the group derived from a cycloalkane is substituted with one or more kinds of or one or more groups of linear or branched alkyl groups such as methyl group, ethyl group, n-propyl group, i-propyl group, n-butyl group, 2-methylpropyl group, 1-methylpropyl group and tert-butyl group;

a group derived from an aromatic compound such as benzene, naphthalene and anthracene, or a group where the group derived from an aromatic compound is substituted with one or more kinds of or one or more groups of linear or branched alkyl groups such as methyl group, ethyl group, n-propyl group, i-propyl group, n-butyl group, 2-methylpropyl group, 1-methylpropyl group and tert-butyl group;

a group derived from a heterocyclic compound such as pyrrolidine, piperidine, morpholine, tetrahydrofuran, tetrahydropyran, indole, indoline, quinoline, perhydroquinoline, indazole and benzimidazole, or a group where the group derived from a heterocyclic compound is substituted with one or more kinds of or one or more groups of linear or branched alkyl groups or aromatic compound-derived groups; a group where the group derived from a linear or branched alkane or the group derived from a cycloalkane is substituted with one or more kinds of or one or more groups of aromatic compound-derived groups such as phenyl group, naphthyl group and anthracenyl group; and a group where the substituent above is substituted with a functional group such as hydroxyl group, cyano group, amino group, pyrrolidino group, piperidino group, morpholino group and oxo group.

Examples of the divalent heterocyclic hydrocarbon group (preferably having a carbon number of 1 to 20) formed by combining Ra with each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0] dec-5-ene, indole, indoline, 1,2,3,4-tetrahydroquinoxaline, perhydroquinoline and 1,5,9-triazacyclododecane, and a group where the group derived from a heterocyclic compound is substituted with one or more kinds of or one or more groups of linear or branched alkane-derived groups, cycloalkane-derived groups, aromatic compound-derived groups, heterocyclic compound-derived groups, and functional groups such as hydroxyl group, cyano group, amino group, pyrrolidino group, piperidino group, morpholino group and oxo group.

Specific examples of the compound (D) particularly preferred in the present invention are illustrated below, but the present invention is not limited thereto.

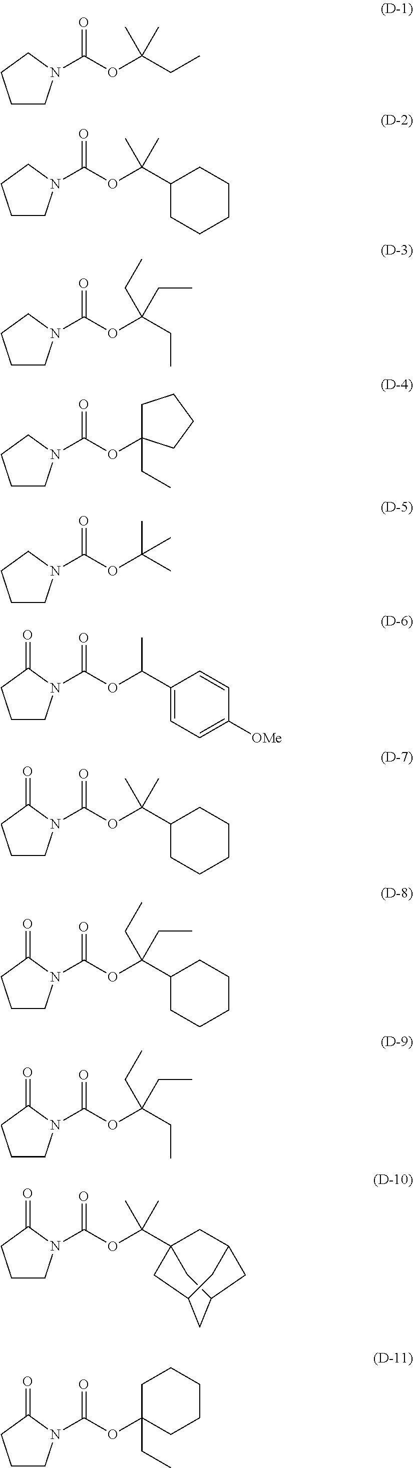

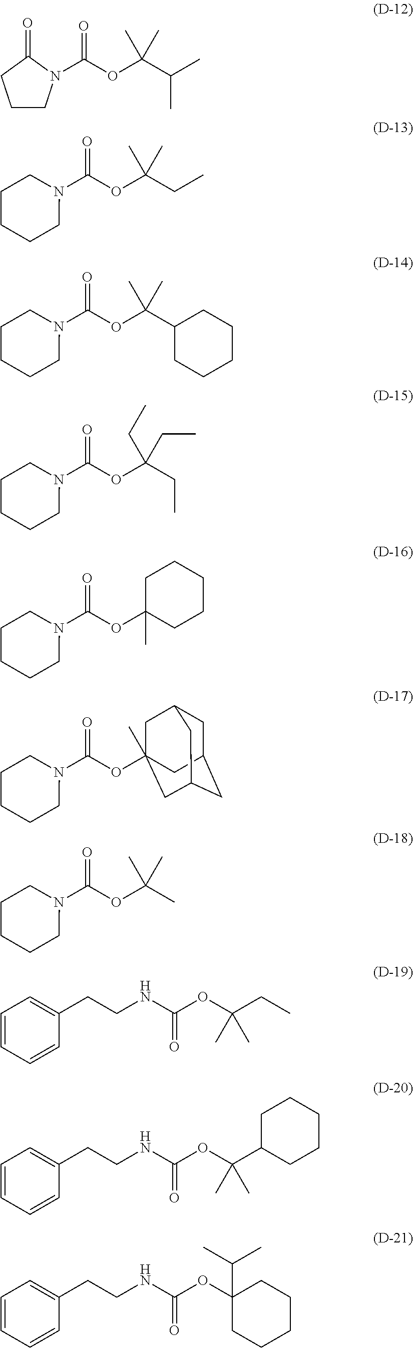

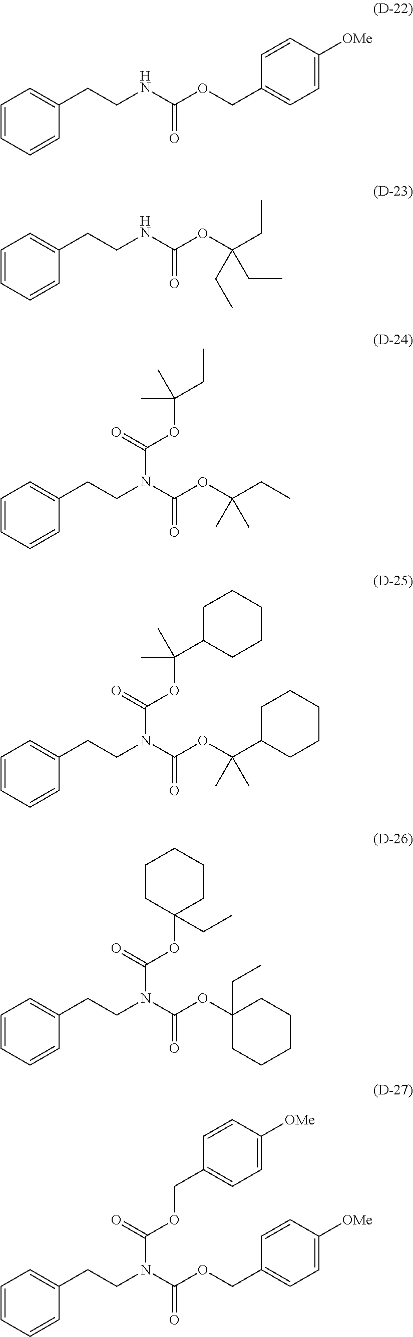 [SMILES: COc1ccc(COC(=O)NCCc2ccccc2)cc1 ; CCC(CC)(CC)OC(=O)NCCc1ccccc1 ; CCC(C)(C)OC(=O)N(CCc1ccccc1)C(=O)OC(C)(C)CC ; CC(C)(OC(=O)N(CCc1ccccc1)C(=O)OC(C)(C)C1CCCCC1)C1CCCCC1 ; CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1]

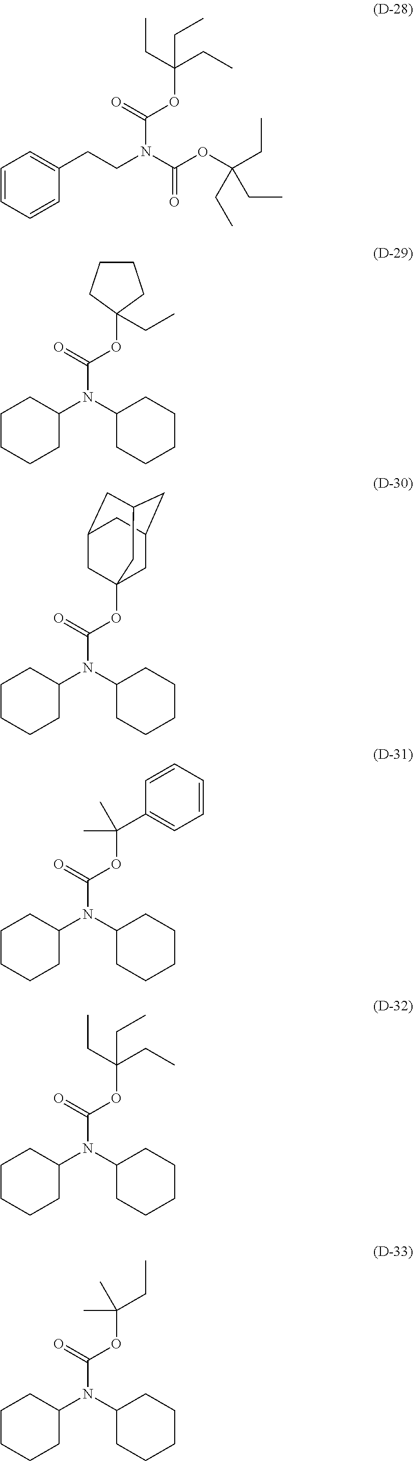

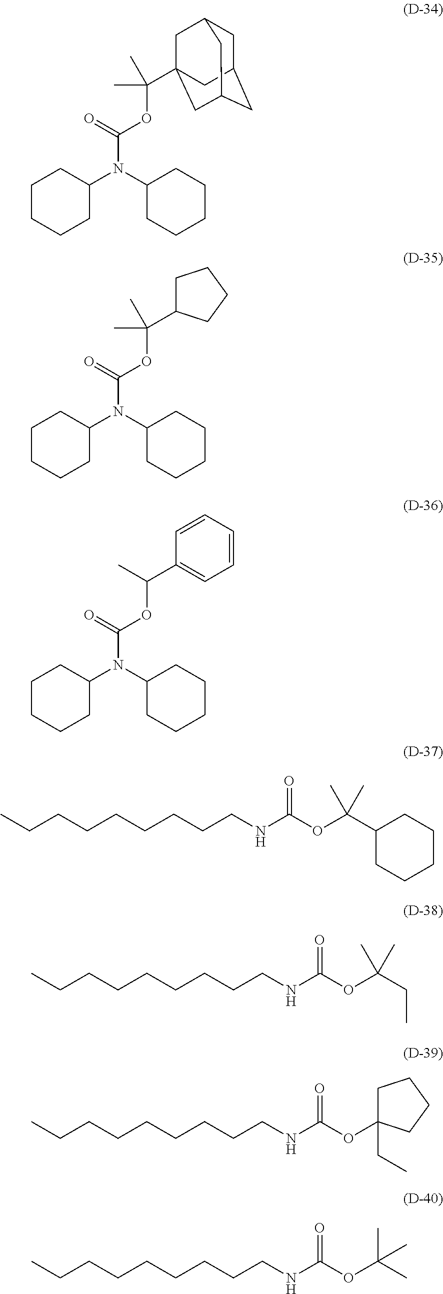

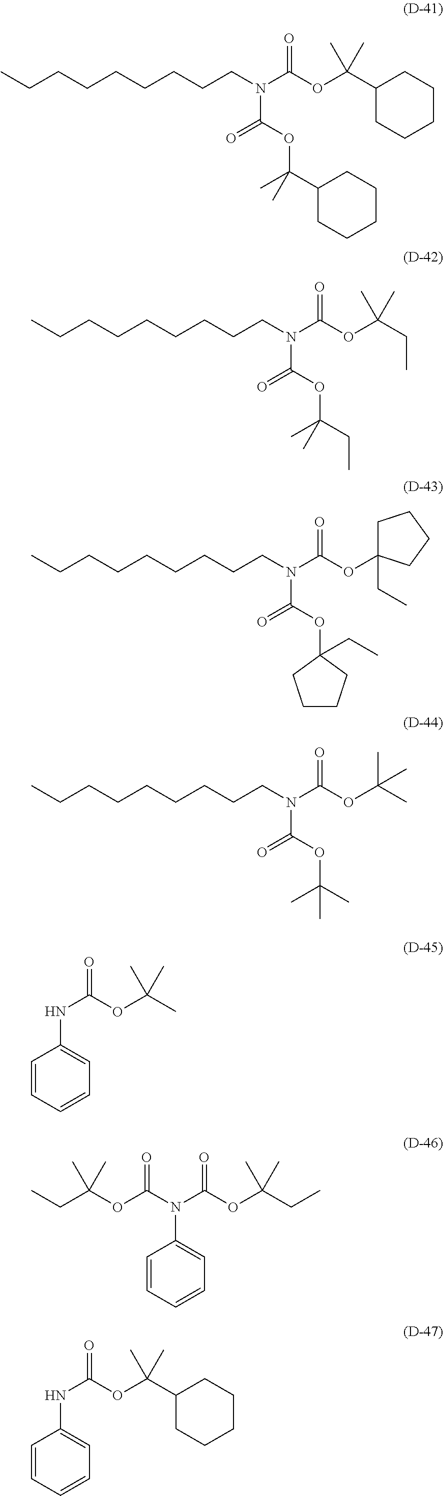

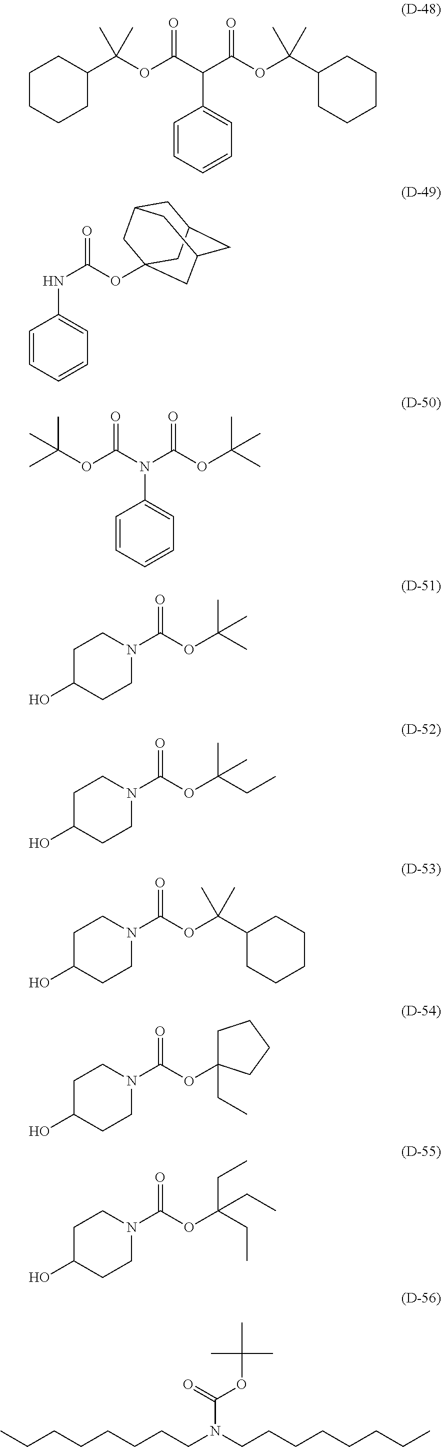

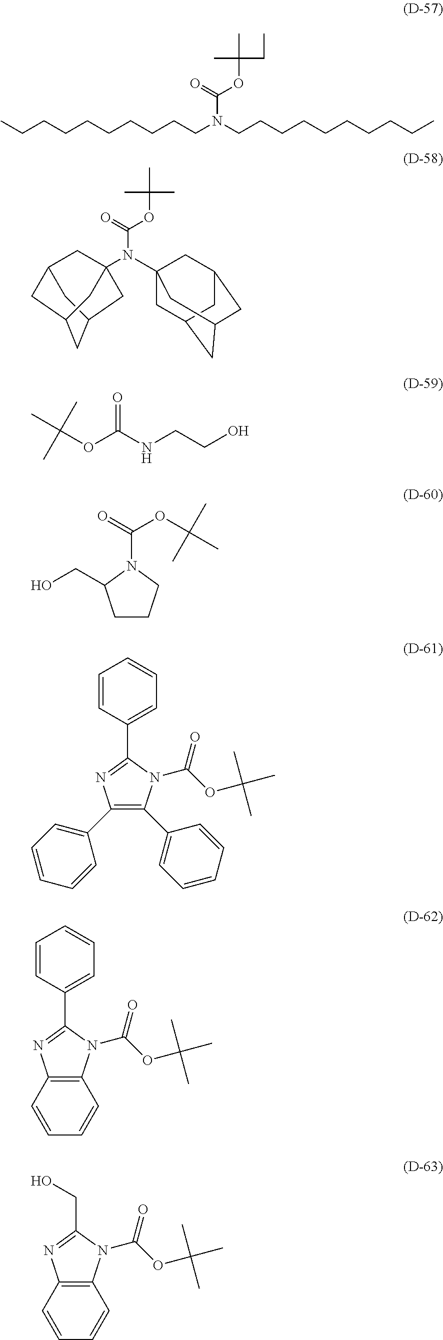

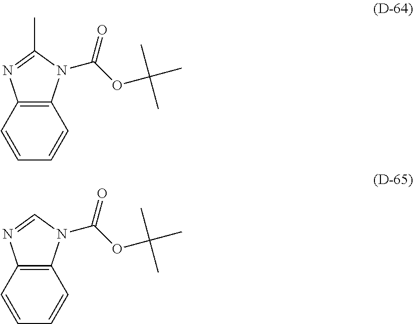 [SMILES: Cc1nc2ccccc2n1C(=O)OC(C)(C)C ; CC(C)(C)OC(=O)n1cnc2ccccc21]

The compound represented by formula (A) can be synthesized by referring to, for example, JP-A-2007-298569 and JP-A-2009-199021.

In the present invention, as for the low molecular weight compound (D), one compound may be used alone, or two or more compounds may be mixed and used.

The composition of the present invention may or may not contain the low molecular compound (D), but in the case of containing the compound (D), the content thereof is usually from 0.001 to 20 mass %, preferably from 0.001 to 10 mass %, more preferably from 0.01 to 5 mass %, based on the total solid content of the composition combined with the basic compound.

In the case where the composition of the present invention contains an acid generator, the ratio between the acid generator and the compound (D) used in the composition is preferably acid generator/[compound (D)+basic compound] (by mol)=from 2.5 to 300. That is, the molar ratio is preferably 2.5 or more in view of sensitivity and resolution and is preferably 300 or less from the standpoint of suppressing the reduction in resolution due to thickening of the resist pattern over time after exposure until heat treatment. The acid generator/[compound (D)+basic compound] (by mol) is more preferably from 5.0 to 200, still more preferably from 7.0 to 150.

Other examples of the basic compound which can be used in the composition of the present invention include compounds synthesized in Examples of JP-A-2002-363146 and compounds described in paragraph 0108 of JP-A-2007-298569.

A photosensitive basic compound may be also used as the basic compound. Examples of the photosensitive basic compound which can be used include compounds described in JP-T-2003-524799 (the term “JP-T” as used herein means a “published Japanese translation of a PCT patent application”) and J. Photopolym. Sci. & Tech., Vol. 8, pp. 543-553 (1995).

The molecular weight of the basic compound is usually from 100 to 1,500, preferably from 150 to 1,300, more preferably from 200 to 1,000.

One kind of these basic compounds may be used alone, or two or more kinds thereof may be used in combination.

In the case where the composition of the present invention contains a basic compound, the content thereof is preferably from 0.01 to 8.0 mass %, more preferably from 0.1 to 5.0 mass %, still more preferably from 0.2 to 4.0 mass %, based on the total solid content of the composition.

The molar ratio of the basic compound to the photoacid generator is preferably from 0.01 to 10, more preferably from 0.05 to 5, still more preferably from 0.1 to 3. If the molar ratio is excessively large, the sensitivity and/or resolution may be reduced, whereas if the molar ratio is excessively small, thinning of the pattern may occur between exposure and heating (post-baking). The molar ratio is more preferably from 0.05 to 5, still more preferably from 0.1 to 3. In this molar ratio, the proportion of the photoacid generator is based on the total amount of the repeating unit (B) of the resin and the photoacid generator that may be further contained in the resin.

### [7] Surfactant

The actinic ray-sensitive or radiation-sensitive resin composition of the present invention may further contain a surfactant. Among others, the surfactant is preferably a fluorine-containing and/or silicon-containing surfactant.

Examples of the fluorine-containing and/or silicon-containing surfactant include Megaface F176 and Megaface R08 produced by Dainippon Ink & Chemicals, Inc.; PF656 and PF6320 produced by OMNOVA; Troysol S-366 produced by Troy Chemical; Florad FC430 produced by Sumitomo 3M Inc.; and Polysiloxane Polymer KP-341 produced by Shin-Etsu Chemical Co., Ltd.

A surfactant other than the fluorine-containing and/or silicon-containing surfactant may be also used. Examples of this surfactant include a nonionic surfactant such as polyoxyethylene alkyl ethers and polyoxyethylene alkylaryl ethers.

In addition, known surfactants may be appropriately used. Examples of the surfactant which can be used include surfactants described in paragraph [0273] et seq. of U.S. Patent Application Publication No. 2008/0248425A1.

One kind of a surfactant may be used alone, or two or more kinds of surfactants may be used in combination.

In the case where the composition of the present invention further contains a surfactant, the content of the surfactant is preferably from 0.0001 to 2 mass %, more preferably from 0.001 to 1 mass %, based on the total solid content of the resin composition.

On the other hand, by setting the amount added of the surfactant to 10 ppm or less based on the total amount of the actinic ray-sensitive or radiation-sensitive resin composition (excluding the solvent), the hydrophobic resin is more unevenly distributed to the surface, so that the resist film surface can be made more hydrophobic and the followability of water at the immersion exposure can be enhanced.

### [8] Hydrophobic Resin (HR)

The actinic ray-sensitive or radiation-sensitive resin composition of the present invention may contain (HR) a hydrophobic resin separately from the resin (P).

The hydrophobic resin (HR) preferably contains a fluorine atom-containing group, a silicon atom-containing group or a hydrocarbon group having a carbon number of 5 or more so as to be unevenly distributed to the film surface. Such a group may be present in the main chain of the resin or may be substituted on the side chain. Specific examples of the hydrophobic resin (HR) are illustrated below.

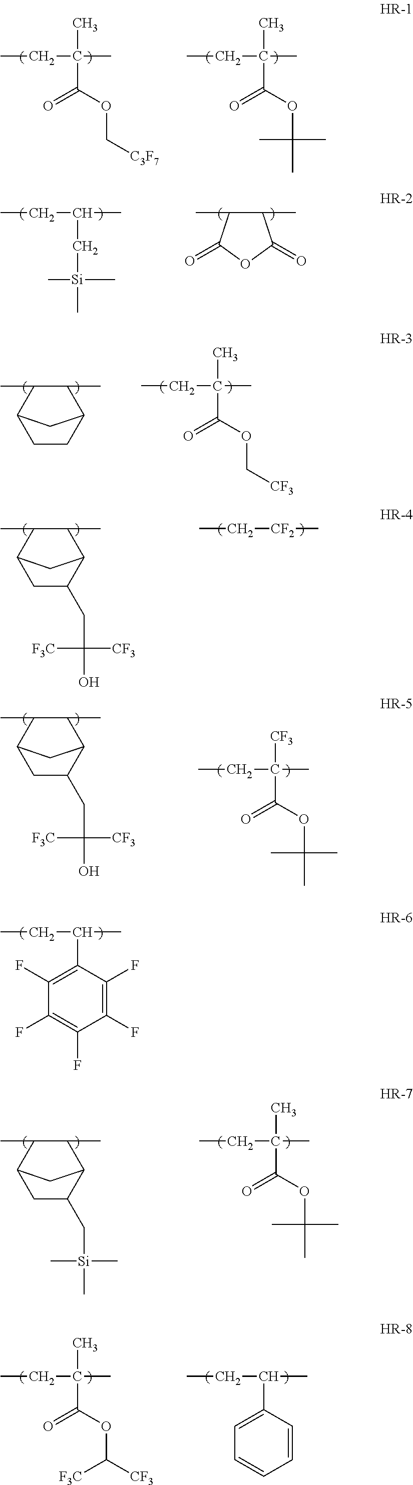

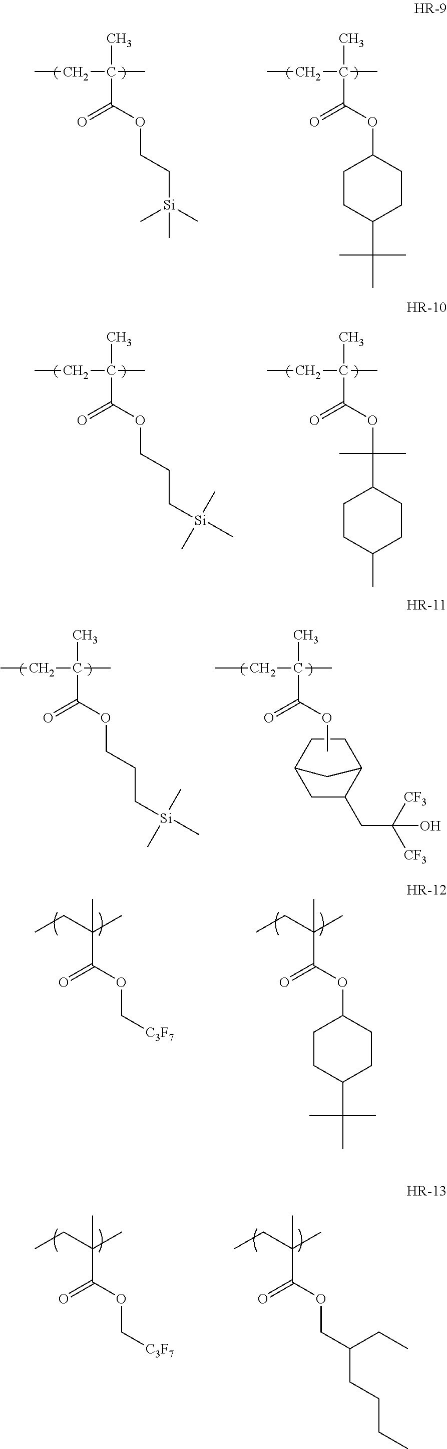

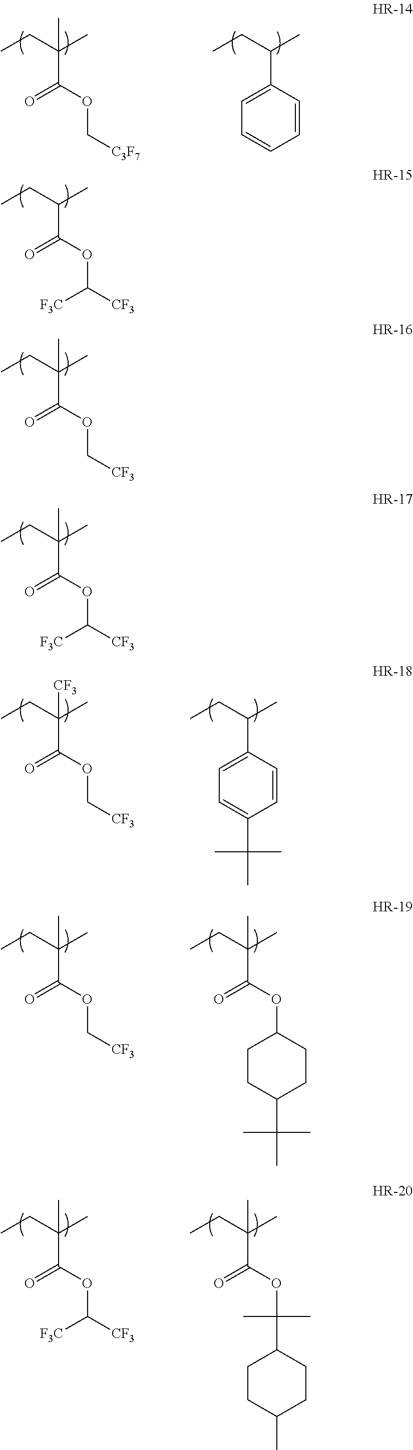

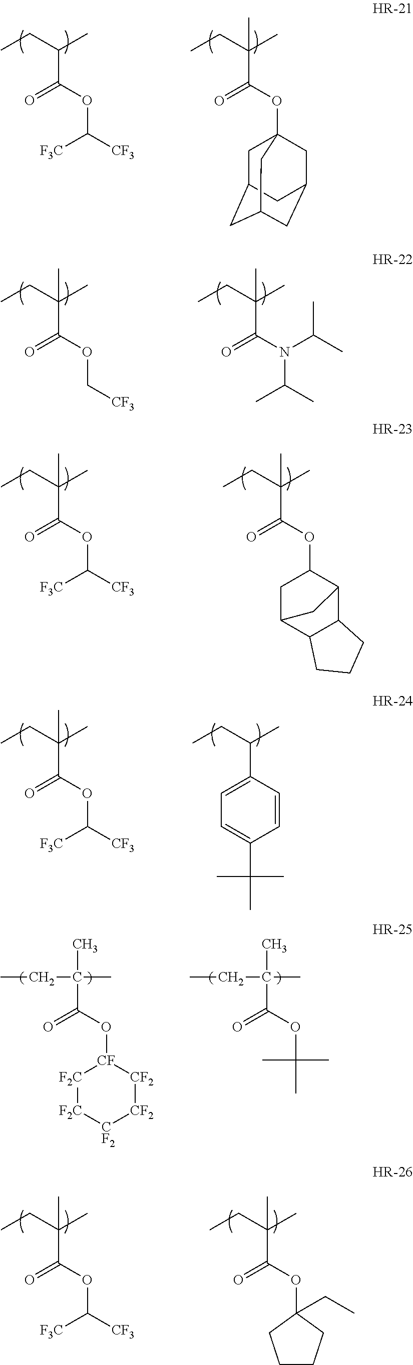

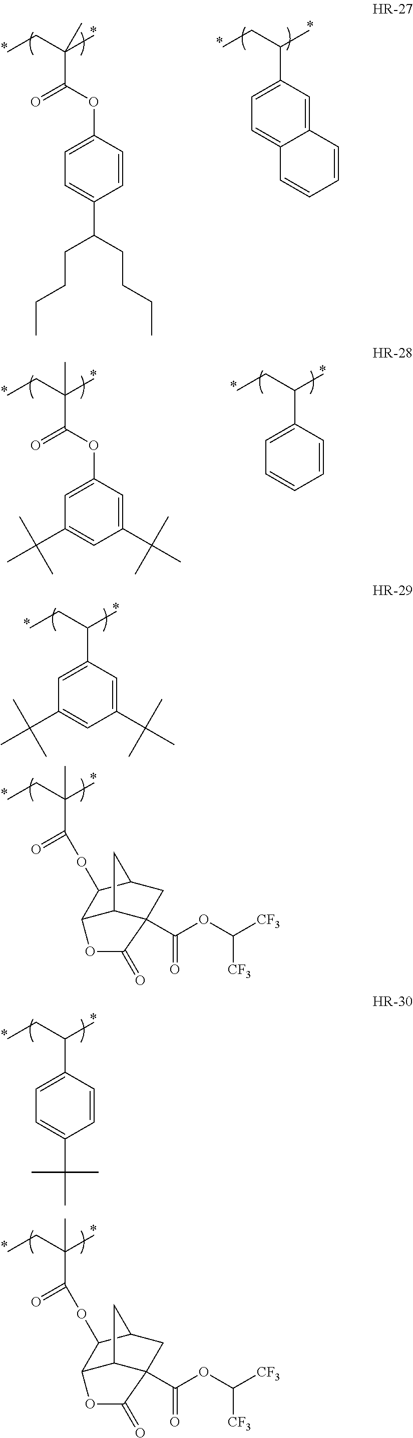

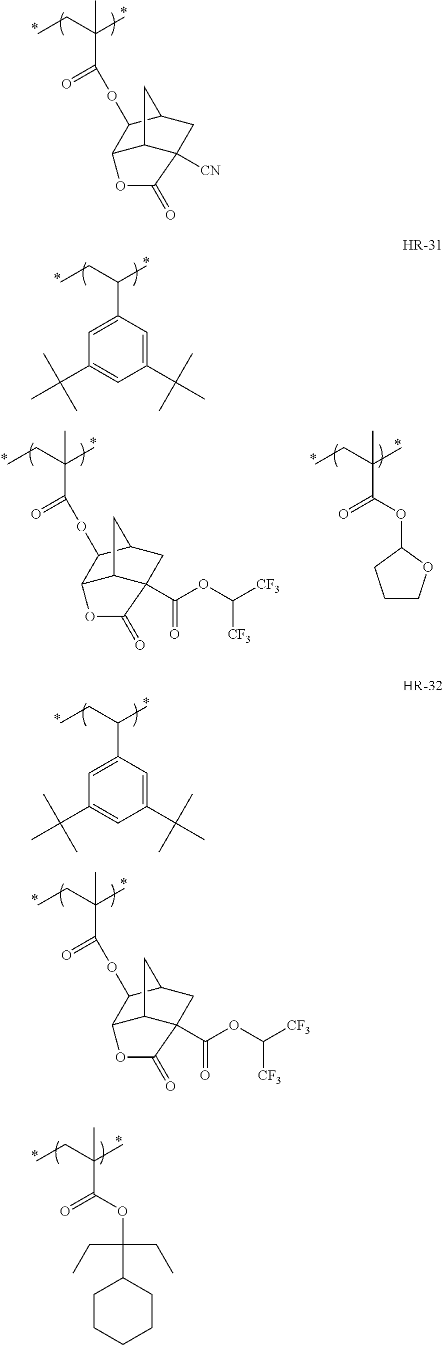

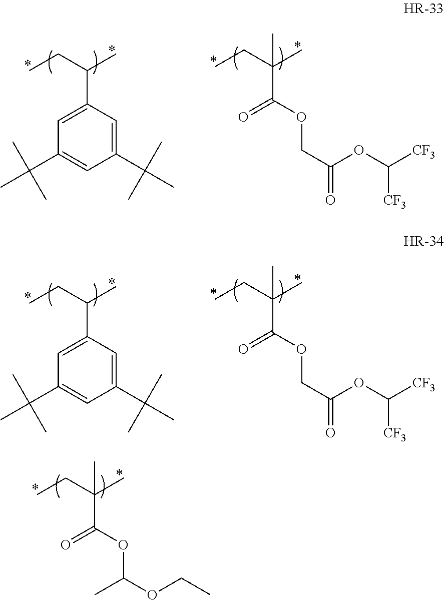

As the hydrophobic resin, in addition, those described in JP-A-2011-248019, JP-A-2010-175859 and JP-A-2012-032544 may be also preferably used.

### [9] Other Additives

The composition of the present invention may appropriately contain, in addition to the components described above, a carboxylic acid, an onium carboxylate, a dissolution inhibiting compound having a molecular weight of 3,000 or less described, for example, in Proceeding of SPIE, 2724, 355 (1996), a dye, a plasticizer, a photosensitizer, a light absorber, an antioxidant and the like.

In particular, a carboxylic acid is suitably used for enhancing the performance. The carboxylic acid is preferably an aromatic carboxylic acid such as benzoic acid and naphthoic acid.

The content of the carboxylic acid is preferably from 0.01 to 10 mass %, more preferably from 0.01 to 5 mass %, still more preferably from 0.01 to 3 mass %, based on the total solid content concentration of the composition.

From the standpoint of enhancing the resolution, the actinic ray-sensitive or radiation-sensitive resin composition of the present invention is preferably used in a film thickness of 10 to 250 nm, more preferably from 20 to 200 nm, still more preferably from 30 to 100 nm. Such a film thickness can be achieved by setting the solid content concentration in the composition to an appropriate range, thereby imparting an appropriate viscosity and enhancing the coatability and film-forming property.

The solid content concentration in the actinic ray-sensitive or radiation-sensitive resin composition of the present invention is usually from 1.0 to 10 mass %, preferably from 2.0 to 5.7 mass %, more preferably from 2.0 to 5.3 mass %. By setting the solid content concentration to the range above, the resist solution can be uniformly coated on a substrate and furthermore, a resist pattern improved in the line width roughness can be formed. The reason therefor is not clearly known, but it is considered that probably thanks to a solid content concentration of 10 mass % or less, preferably 5.7 mass % or less, aggregation of materials, particularly, a photoacid generator, in the resist solution is suppressed, as a result, a uniform resist film can be formed.

The solid content concentration is a weight percentage of the weight of resist components excluding the solvent, based on the total weight of the actinic ray-sensitive or radiation-sensitive resin composition.

The actinic ray-sensitive or radiation-sensitive resin composition of the present invention is used by dissolving the components above in a predetermined organic solvent, preferably in the above-described mixed solvent, filtering the solution, and coating the filtrate on a predetermined support (substrate). The filter used for filtration is preferably a polytetrafluoroethylene-, polyethylene- or nylon-made filter having a pore size of 0.1 μm or less, more preferably 0.05 μm or less, still more preferably 0.03 μm or less. In the filtration through a filter, as described, for example, in JP-A-2002-62667, circulating filtration may be performed, or the filtration may be performed by connecting a plurality of kinds of filters in series or in parallel. Also, the composition may be filtered a plurality of times. Furthermore, a deaeration treatment or the like may be applied to the composition before and after filtration through a filter.

### [Usage]

The pattern forming method of the present invention is suitably used for the fabrication of a semiconductor microcircuit, for example, in the production of VLSI or a high-capacity microchip. Incidentally, at the fabrication of a semiconductor microcircuit, the resist film having formed therein a pattern is subjected to circuit formation or etching and the remaining resist film part is finally removed with a solvent or the like. Therefore, unlike a so-called permanent resist used for a printed board and the like, the resist film derived from the actinic ray-sensitive or radiation-sensitive resin composition of the present invention does not remain in the final product such as microchip.

The present invention also relates to a method for manufacturing an electronic device, comprising the pattern forming method of the present invention, and an electronic device manufactured by this manufacturing method.

The electronic device of the present invention is suitably mounted on electric electronic equipment (such as home electronics, OA•media equipment, optics and communication equipment).

### EXAMPLES

### Reference Synthesis Example 1

### Synthesis of M-I-1

### Synthesis of Chloroether Compound

In a 300 mL-volume eggplant-type flask equipped with a Dean-Stark tube, 10.51 g of isovaleraldehyde, 12.35 g of ethanol, 1.41 g of camphorsulfonic acid and 100 mL of heptane were added, and refluxing was performed for 8 hours. After returning the temperature to room temperature, 3.1 g of triethylamine was added and stirred, and the organic layer was washed with saturated sodium bicarbonate water twice and with distilled water once. By removing heptane and unreacted ethanol under the conditions of reduced pressure and heating, Acetal Compound 1 shown below was obtained as an acetal compound.

Subsequently, 11.47 g of acetyl chloride was added to the entire amount of Acetal Compound 1 obtained, and the mixture was stirred in a water bath at 45° C. for 4 hours. After returning the temperature to room temperature, unreacted acetyl chloride was removed under the reduced pressure condition, whereby Compound C1-1 shown below was obtained as a chloroether compound.

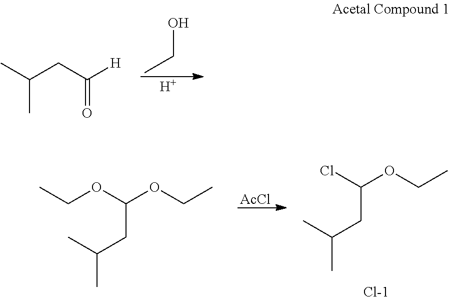

### Synthesis of M-I-1

An eggplant-type flask was charged with 36 g of methacrylic acid, 46 g of triethylamine, 36 g of magnesium sulfate and 200 g of THF (tetrahydrofuran), and the contents were stirred at 0° C. for 10 minutes. Thereto, 57 g of C1-1 was added dropwise over 30 minutes. After returning the temperature to room temperature, 300 mL of ethyl acetate was added, and the organic layer was washed with saturated brine twice and with distilled water twice. After drying over magnesium sulfate, ethyl acetate was removed by distillation under reduced pressure to obtain 65 g of M-I-1.

### Synthesis Example 1

### Synthesis of Resin P-1

In a nitrogen stream, 23 g of cyclohexanone was charged into a three-neck flask (Solvent 1) and heated at 85° C. Subsequently, 14 g of M-I-1 and 6.7 g of M-II-1 were dissolved in 60 g of cyclohexanone and furthermore, 0.92 g of initiator V-601 (produced by Wako Pure Chemical Industries, Ltd.) was dissolved therein. The obtained solution was added dropwise to (Solvent 1) over 4 hours. After the completion of dropwise addition, the reaction was further allowed to proceed at 85° C. for 2 hours. The reaction solution was allowed to cool and then added dropwise to 1,200 mL of hexane, and the precipitated powder was collected by filtration and dried to obtain 17 g of Resin (P-1).

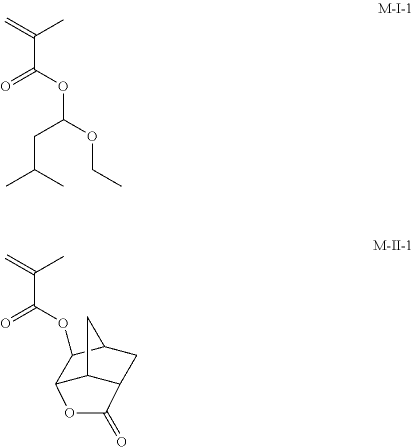

With respect to the obtained Resin (P-1), the compositional ratio (molar ratio) of Resin (P-1) was calculated by ¹³C-NMR measurement. Also, the weight average molecular weight (Mw: in terms of polystyrene), number average molecular weight (Mn: in terms of polystyrene) and polydispersity (Mw/Mn, hereinafter sometimes referred to as “PDI”) of Resin (P-1) were calculated by GPC (solvent: NMP) measurement. These results are shown in the chemical formulae later.

### Synthesis Examples 2 to 32, 43 to 52 and 57 to 62

### Synthesis of Resins (P-2) to (P-32), (P-43) to (P-52) and (P-57) to (P-62)

Resins (P-2) to (P-32), (P-43) to (P-52) and (P-57) to (P-62) were synthesized by the same method as in Synthesis Example 1 except for appropriately changing the chloroether compound used.

### Reference Synthesis Example 2

### Synthesis of M-III-1

### Synthesis of M-III-1

After dissolving 100.00 g of p-acetoxystyrene in 400 g of ethyl acetate, the solution was cooled to 0° C., and 47.60 g of sodium methoxide (28% methanol solution) was added dropwise thereto over 30 minutes, followed by stirring at room temperature for 5 hours. After adding ethyl acetate, the organic layer was washed with distilled water three times and then dried over anhydrous sodium sulfate, and the solvent was removed by distillation to obtain 131.70 g of p-hydroxystyrene (54% ethyl acetate solution).

After dissolving 18.52 g of p-hydroxystyrene (54% ethyl acetate solution) in 56.00 g of ethyl acetate, 31.58 g of 1,1,2,2,3,3-hexafluoropropane-1,3-disulfonyl difluoride was added, and the system was cooled to 0° C. A solution obtained by dissolving 12.63 g of triethylamine in 25.00 g of ethyl acetate was added dropwise thereto over 30 minutes and while keeping the temperature at 0° C., the mixture was stirred for 4 hours. After adding ethyl acetate, the organic layer was washed with saturated brine three times and then dried over anhydrous sodium sulfate, and the solvent was removed by distillation to obtain 32.90 g of Compound A.

After dissolving 35.00 g of Compound A in 315 g of methanol, the resulting solution was cooled to 0° C., and 245 g of an aqueous 1 N sodium hydroxide solution was added thereto, followed by stirring at room temperature for 2 hours. The solvent was removed by distillation. After adding ethyl acetate, the organic layer was washed with saturated brine three times and then dried over anhydrous sodium sulfate, and the solvent was removed by distillation to obtain 34.46 g of Compound B.

After dissolving 28.25 g of Compound B in 254.25 g of methanol, 23.34 g of triphenylsulfonium bromide was added thereto, followed by stirring at room temperature for 3 hours. The solvent was removed by distillation and after adding distilled water, the mixture was extracted with chloroform three times. The obtained organic layer was washed with distilled water three times, and the solvent was removed by distillation to obtain 42.07 g of the target Compound (M-III-1).

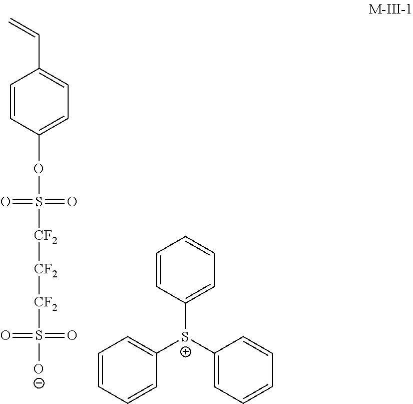 [SMILES: C=Cc1ccc(OS(=O)(=O)C(F)(F)C(F)(F)C(F)(F)S(=O)(=O)[O-])cc1 ; c1ccc([S+](c2ccccc2)c2ccccc2)cc1]

### Synthesis Example 33

### Synthesis of Resin P-33

In a nitrogen stream, 31 g of PGMEA (propylene glycol monomethyl ether acetate) was charged into a three-neck flask (Solvent 1) and heated at 85° C. Subsequently, 14 g of M-I-1, 4.4 g of M-II-1 and 9.1 g of M-III-1 were dissolved in 80 g of PGMEA and furthermore, 0.92 g of initiator V-601 (produced by Wako Pure Chemical Industries, Ltd.) was dissolved therein. The obtained solution was added dropwise to (Solvent 1) over 4 hours. After the completion of dropwise addition, the reaction was further allowed to proceed at 85° C. for 2 hours. The reaction solution was allowed to cool and then added dropwise to a solution obtained by mixing 1,700 mL of hexane and 400 mL of ethyl acetate, and the precipitated powder was collected by filtration and dried to obtain 17 g of Resin P-33.

### Synthesis Examples 34 to 42 and 53 to 56

### Synthesis of Resins (P-34) to (P-42) and (P-53) to (P-56)

Resins (P-34) to (P-42) and (P-53) to (P-56) were synthesized by the same method as in Synthesis Example 33 except for appropriately changing the polymerizable compound used. The structure, compositional ratio (by mol), weight average molecular weight and polydispersity of each of the resins used in Examples are shown below.

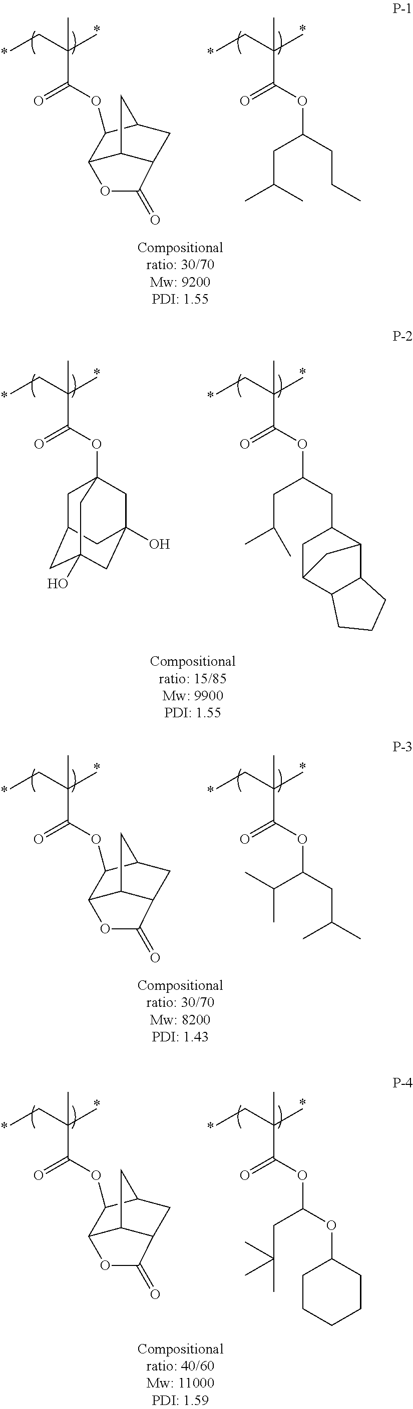

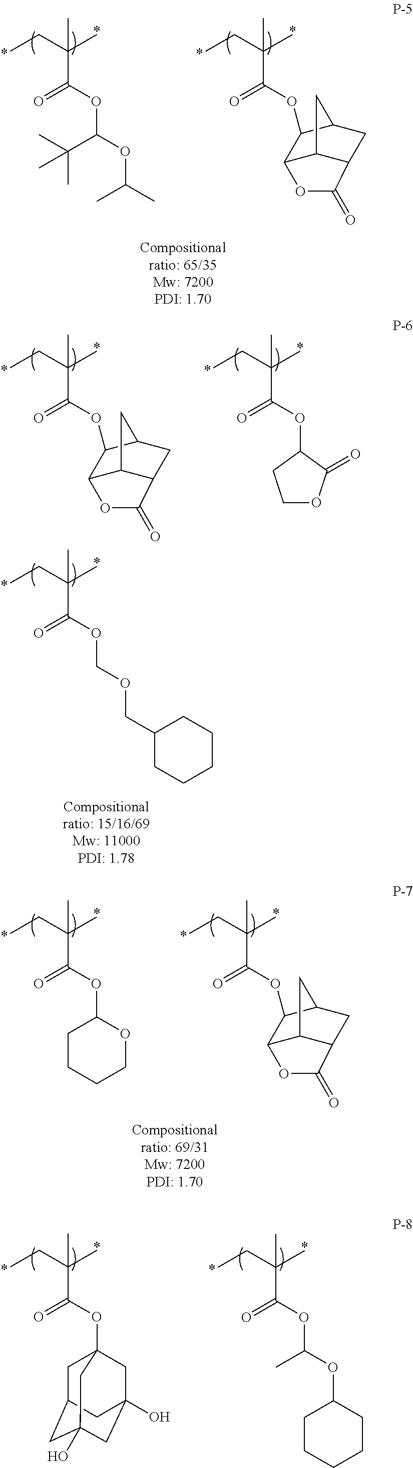

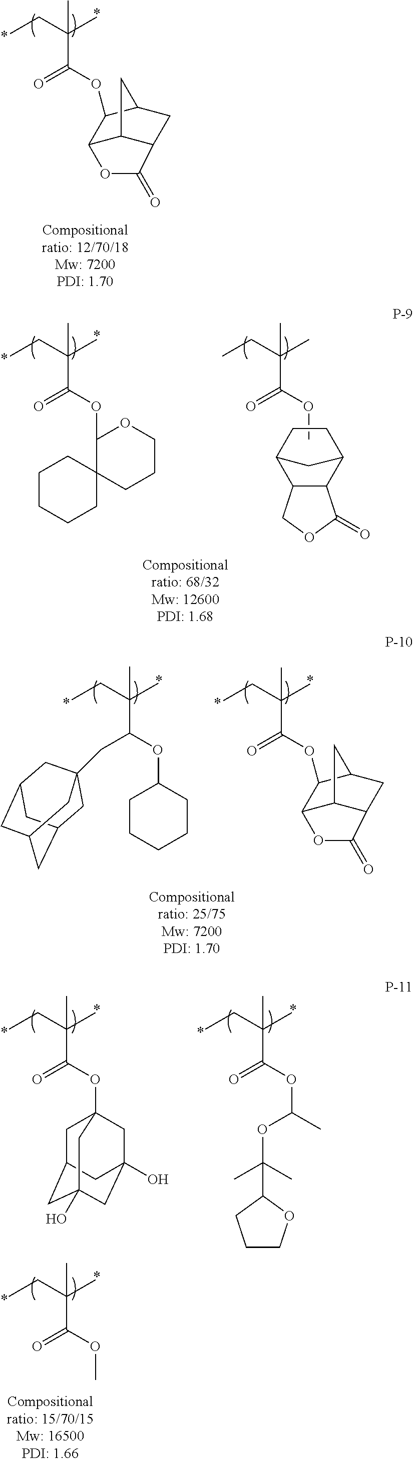

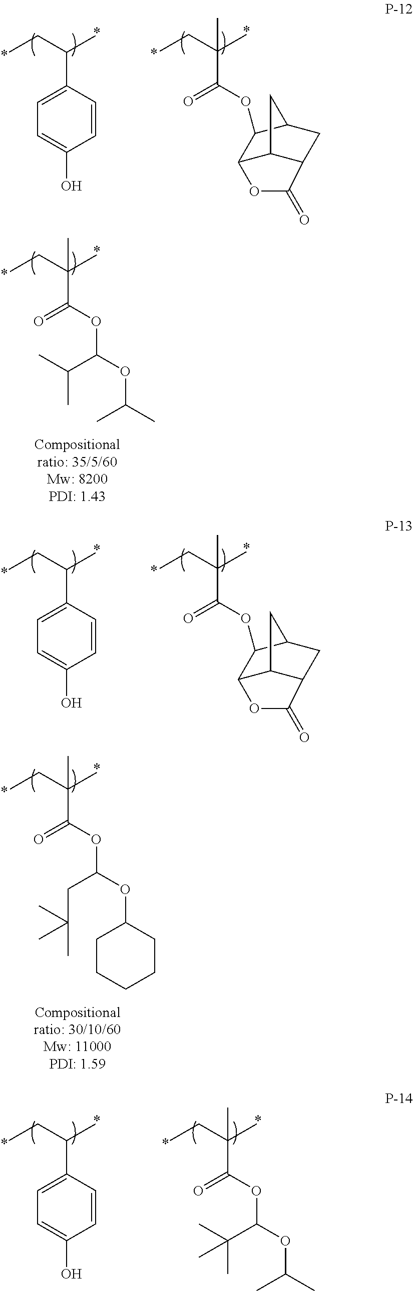

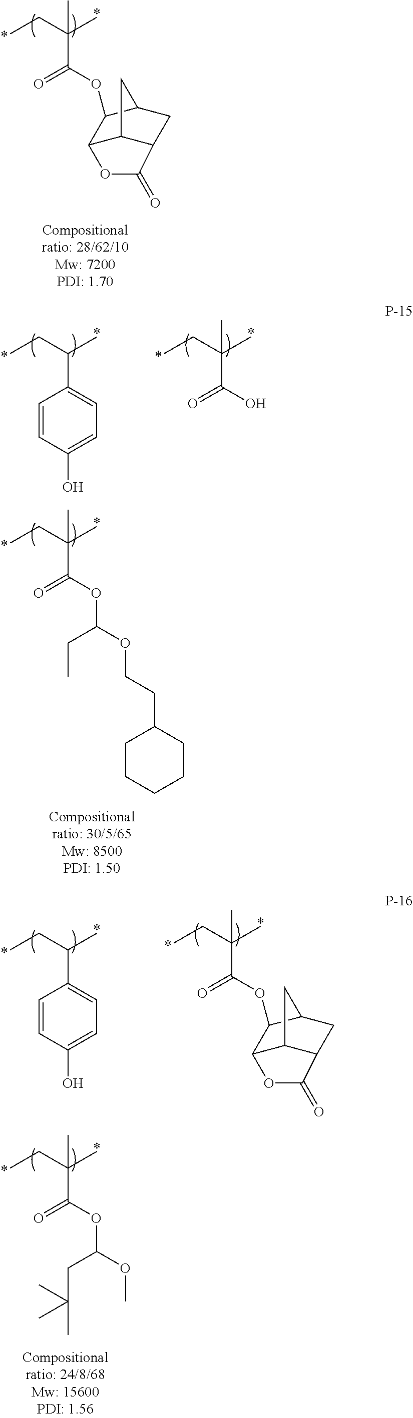

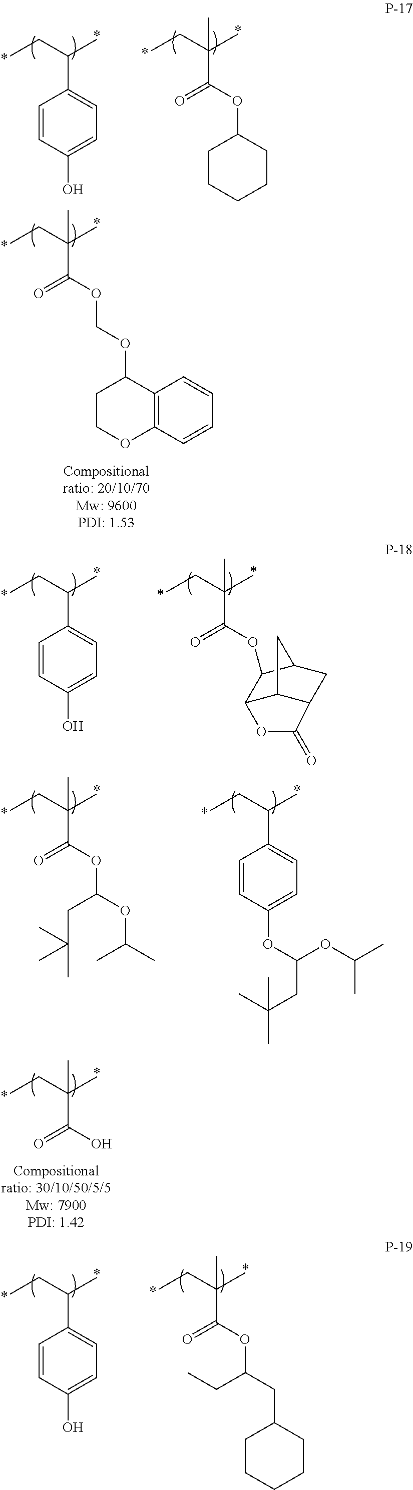

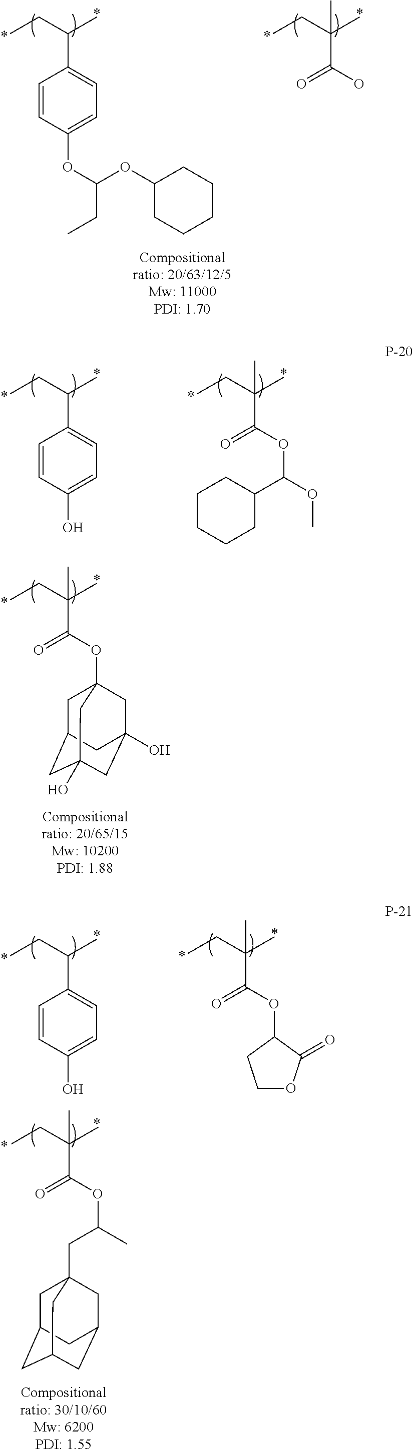

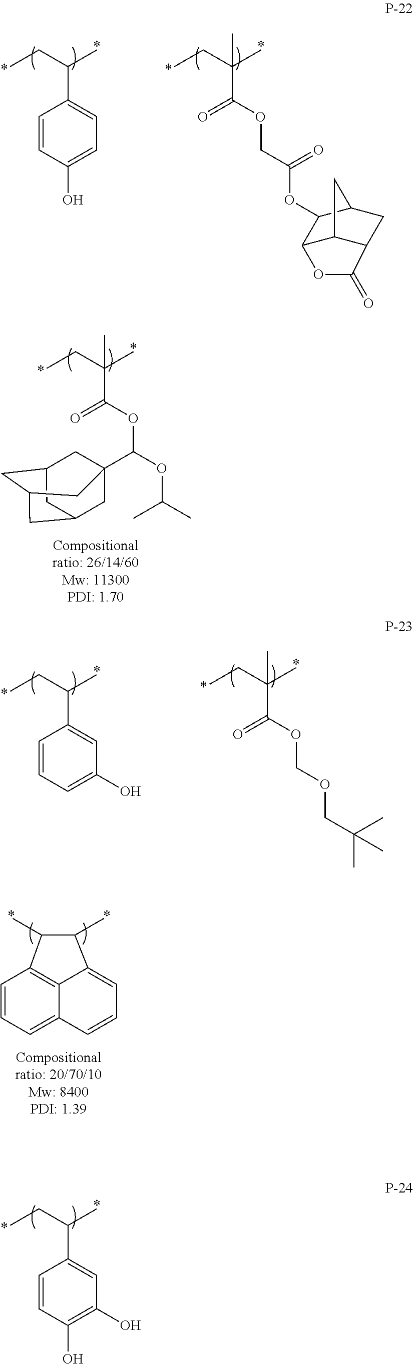

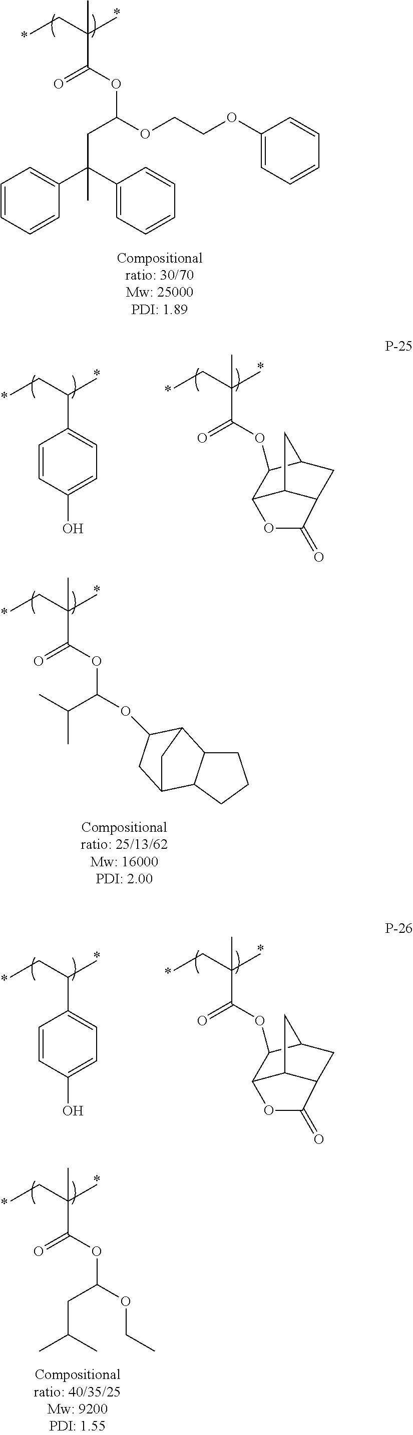

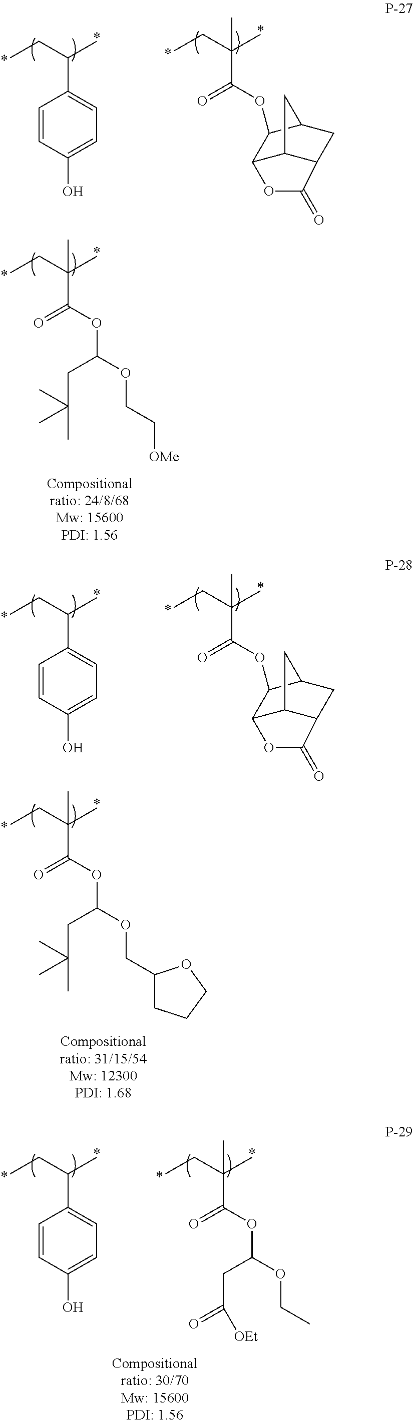

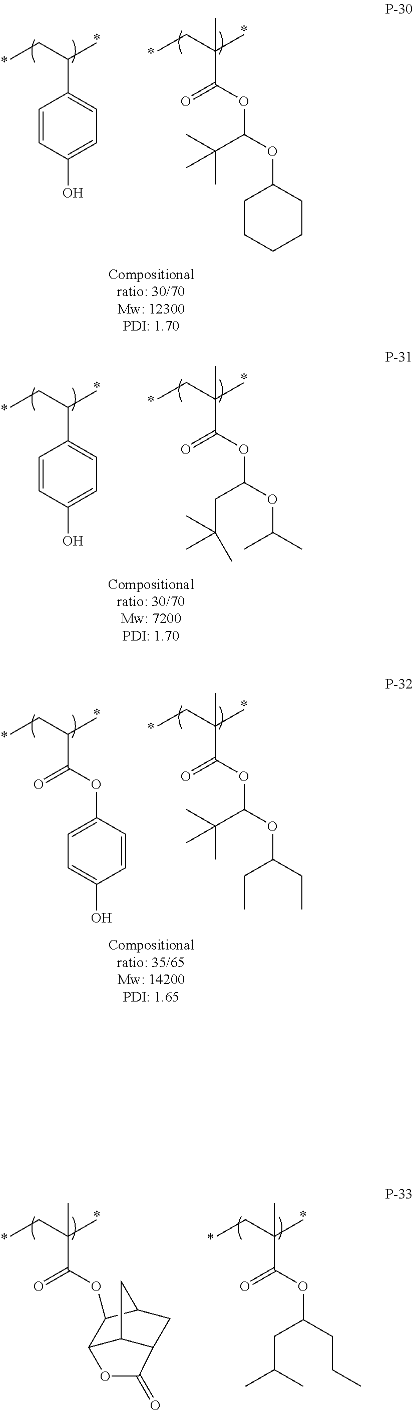

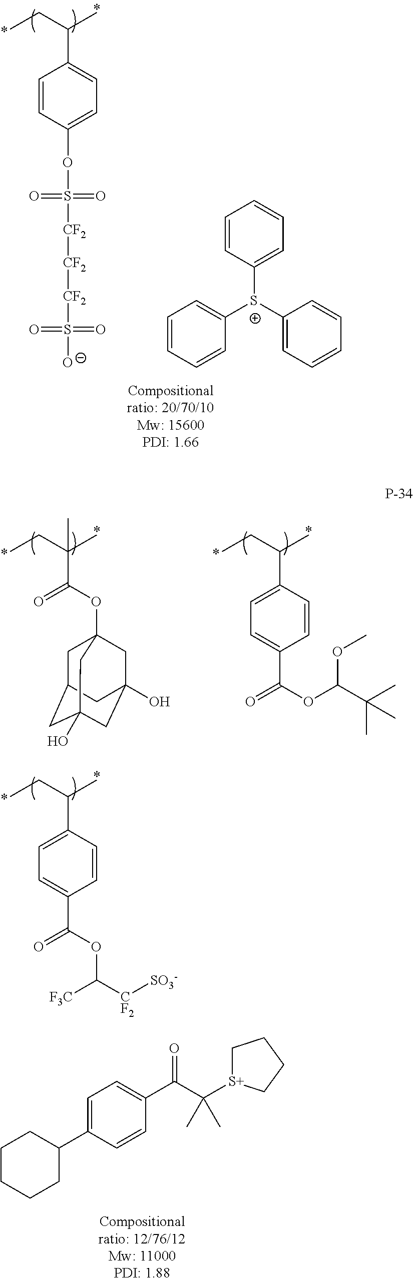

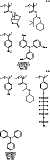

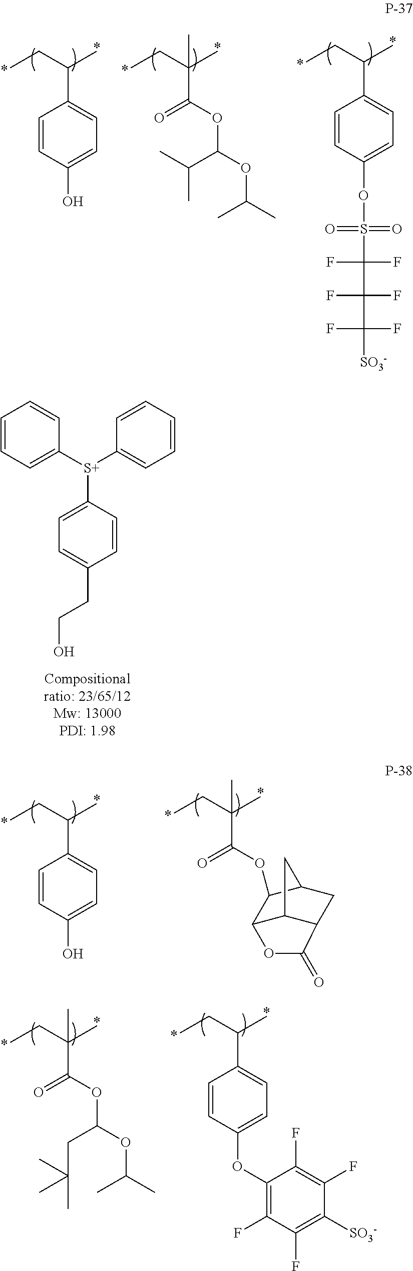

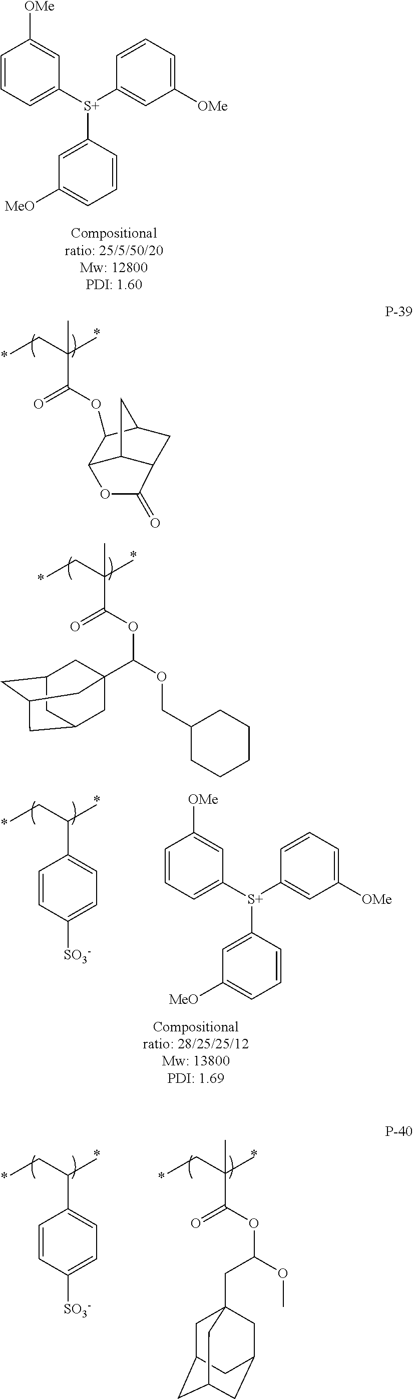

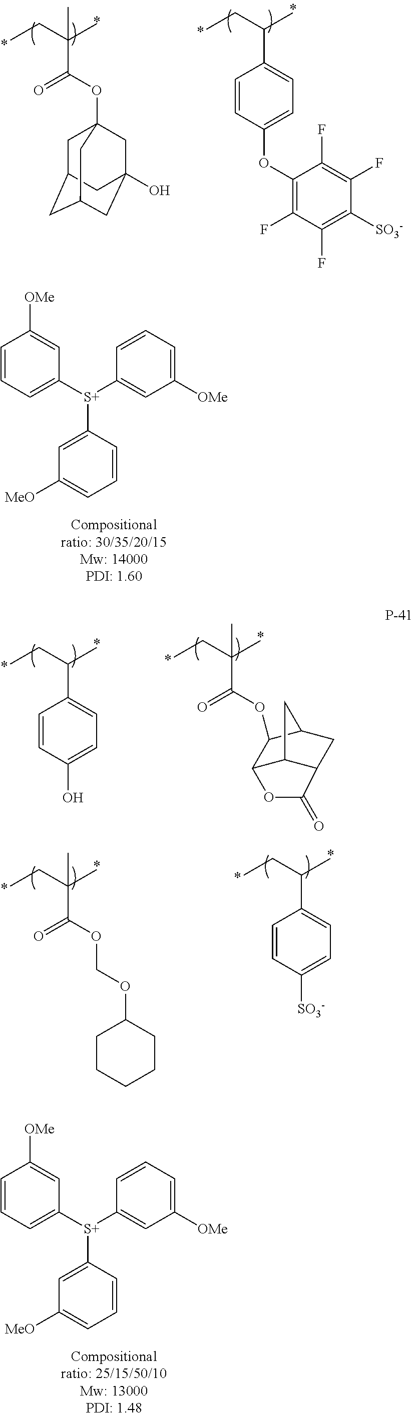

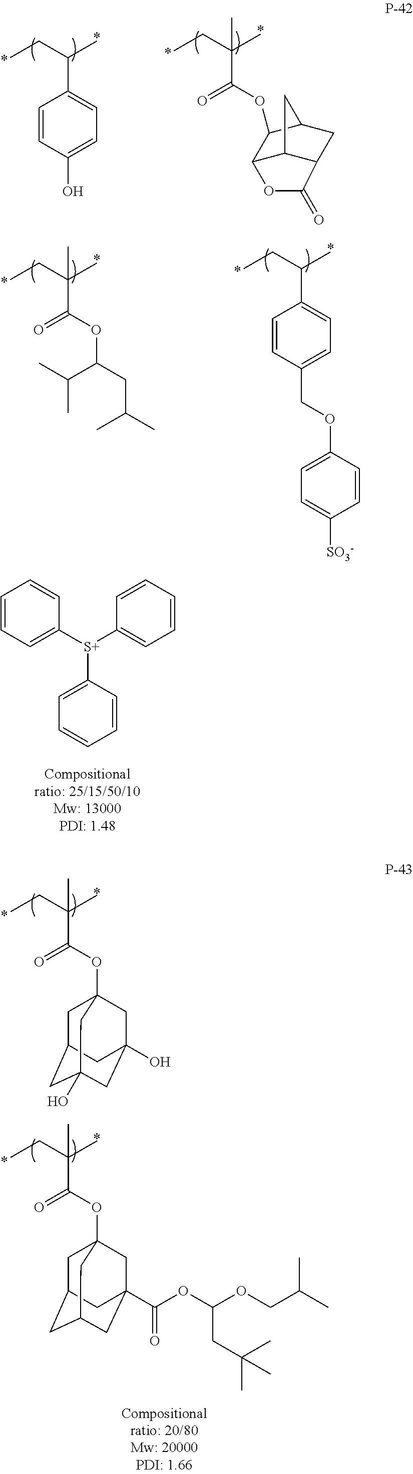

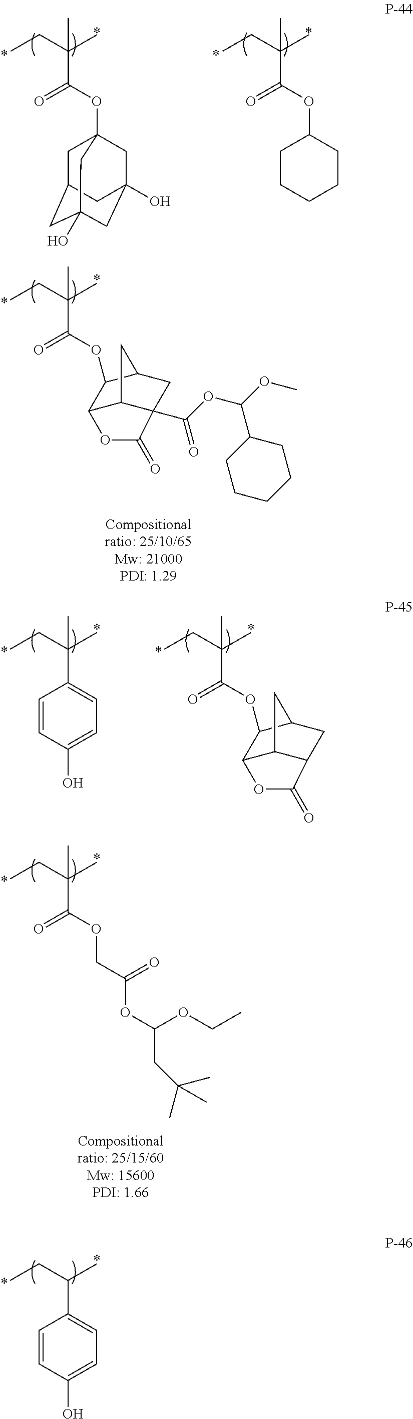

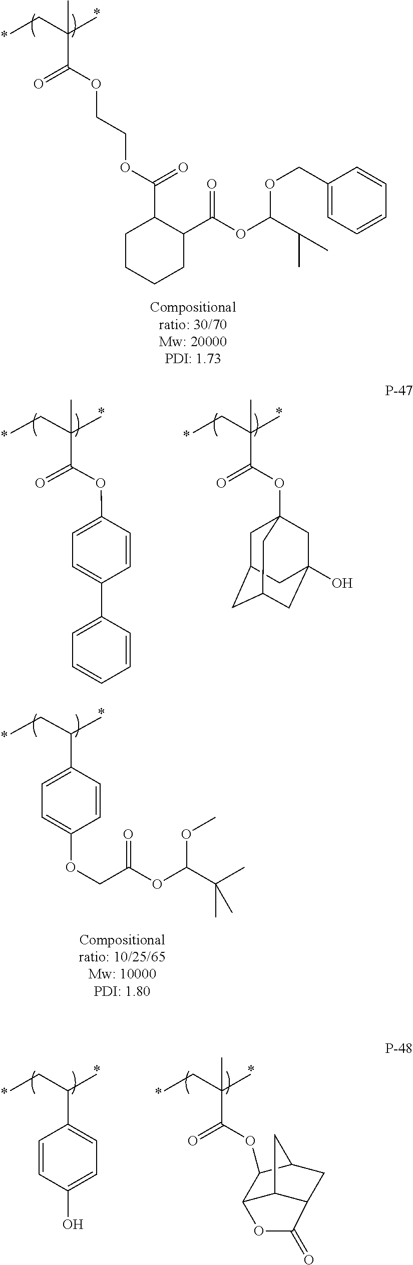

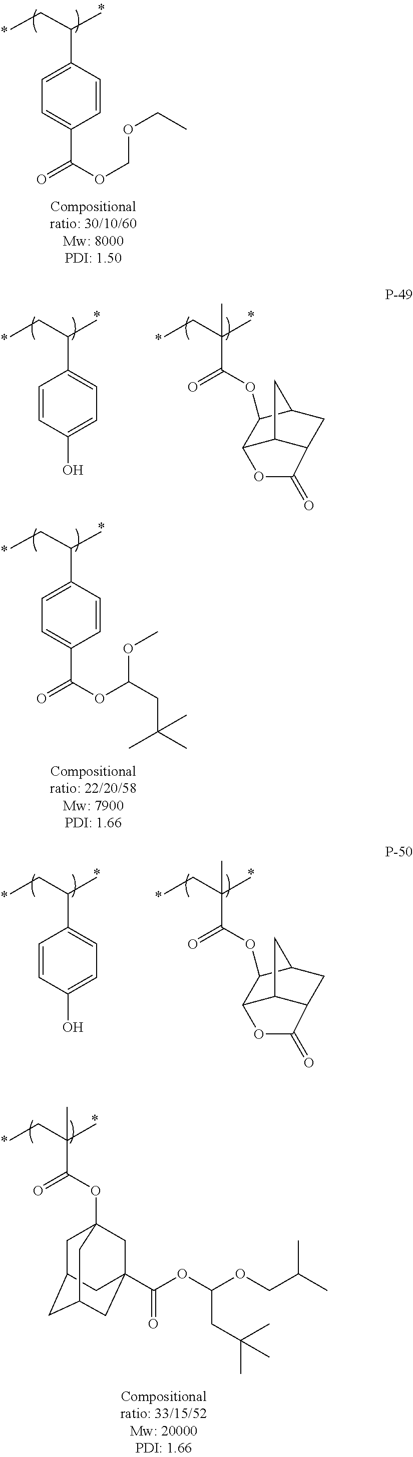

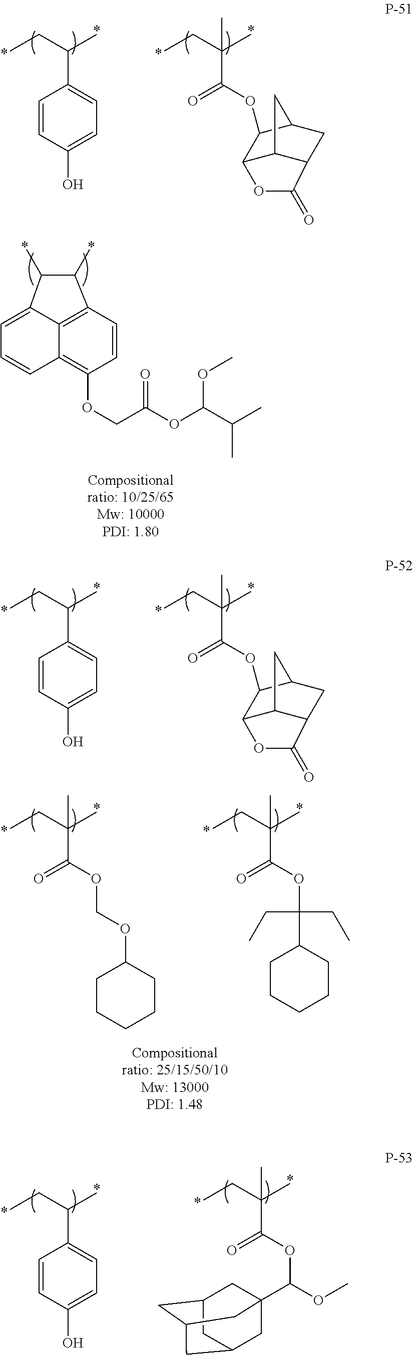

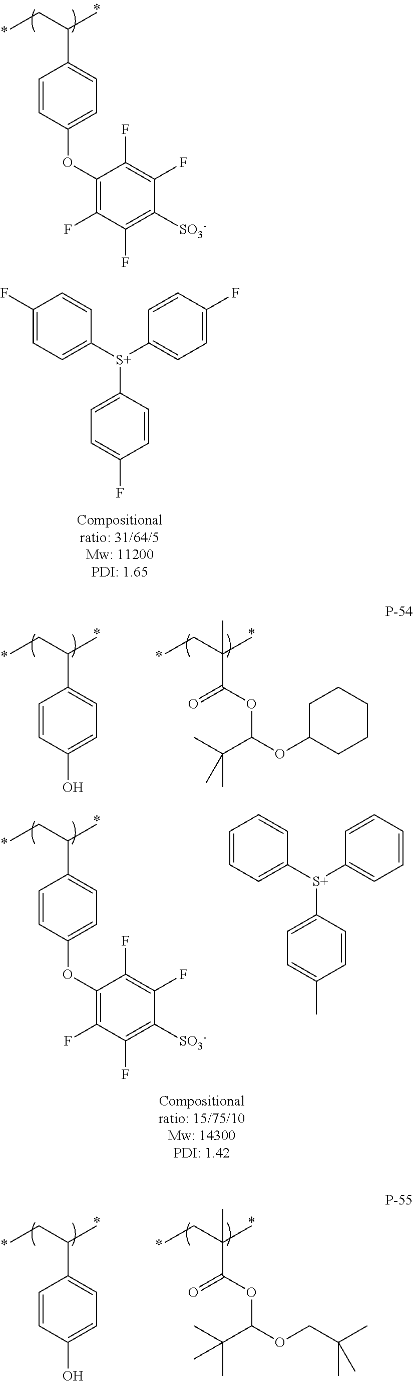

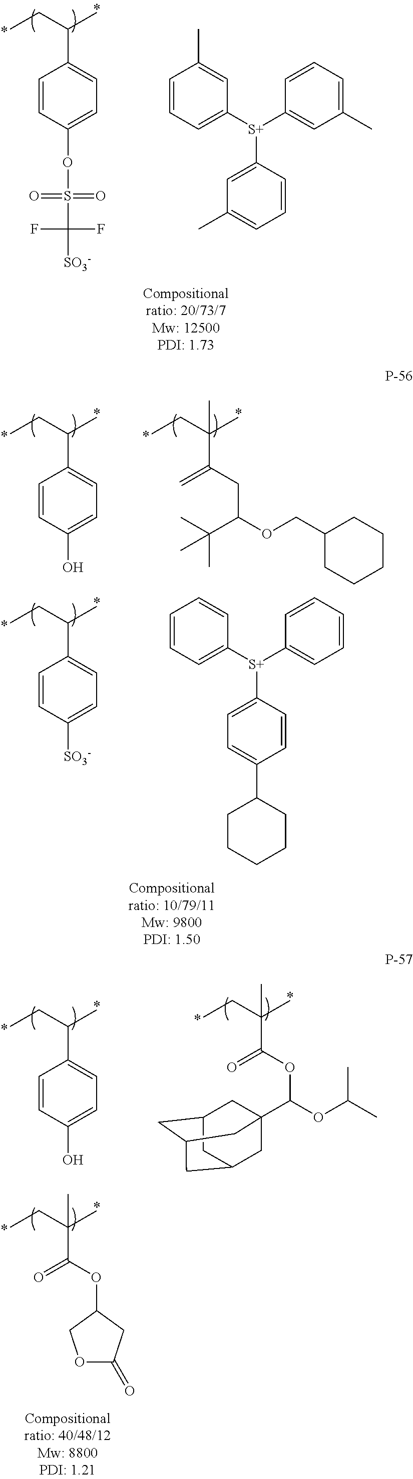

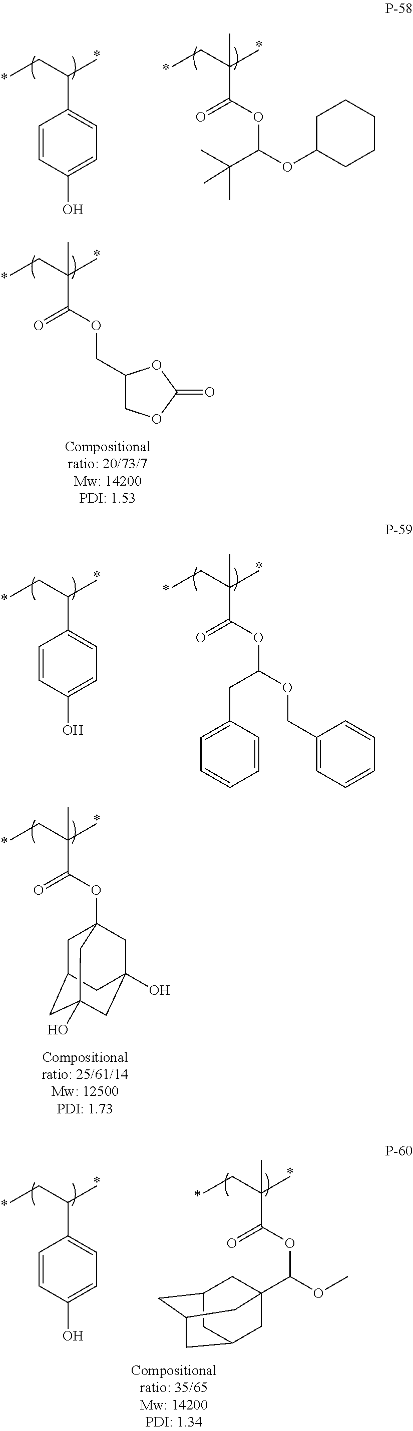

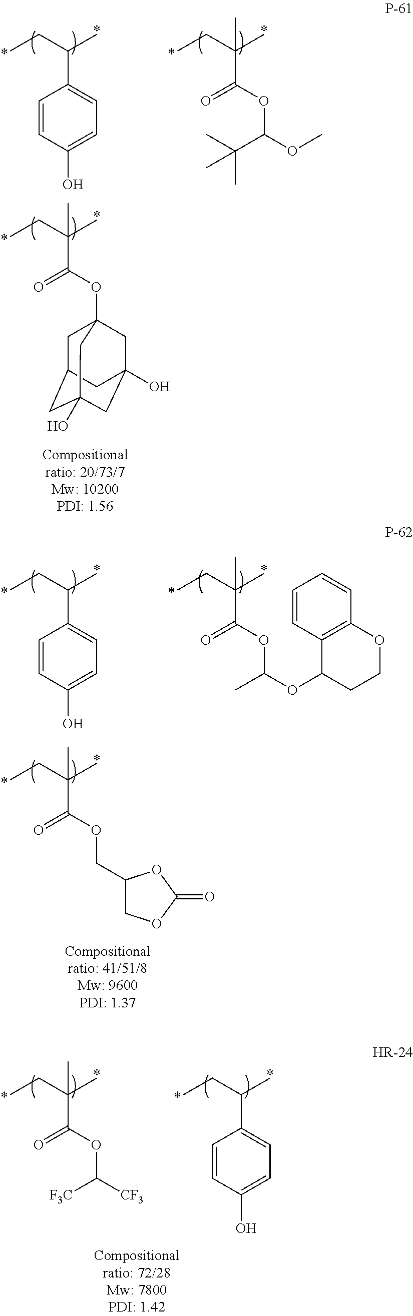

For comparison, the following compounds were used.

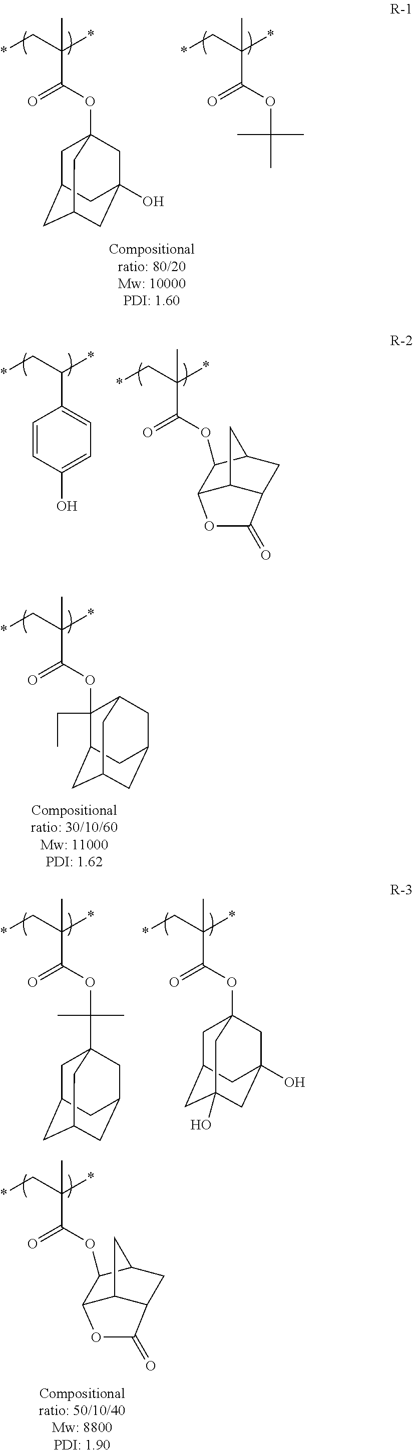

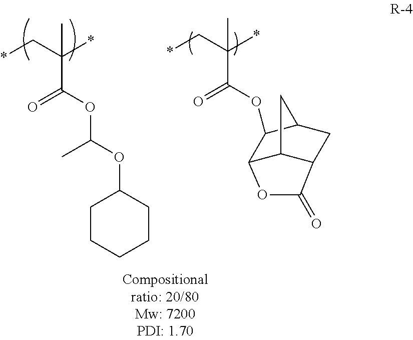

### [Photoacid Generator]

As the photoacid generator, the compounds represented by the following formulae were used.

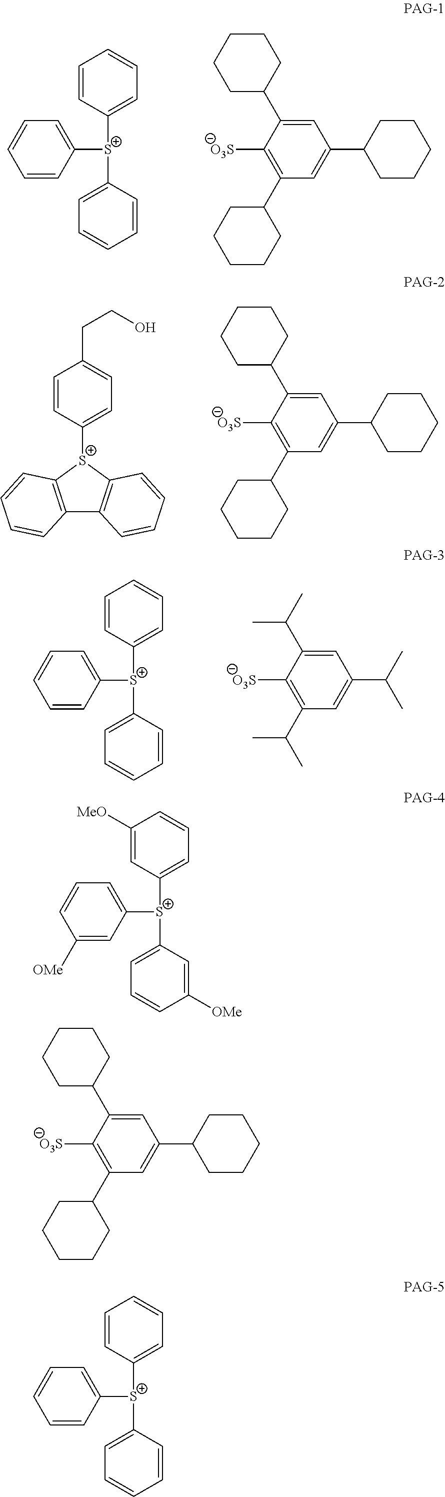

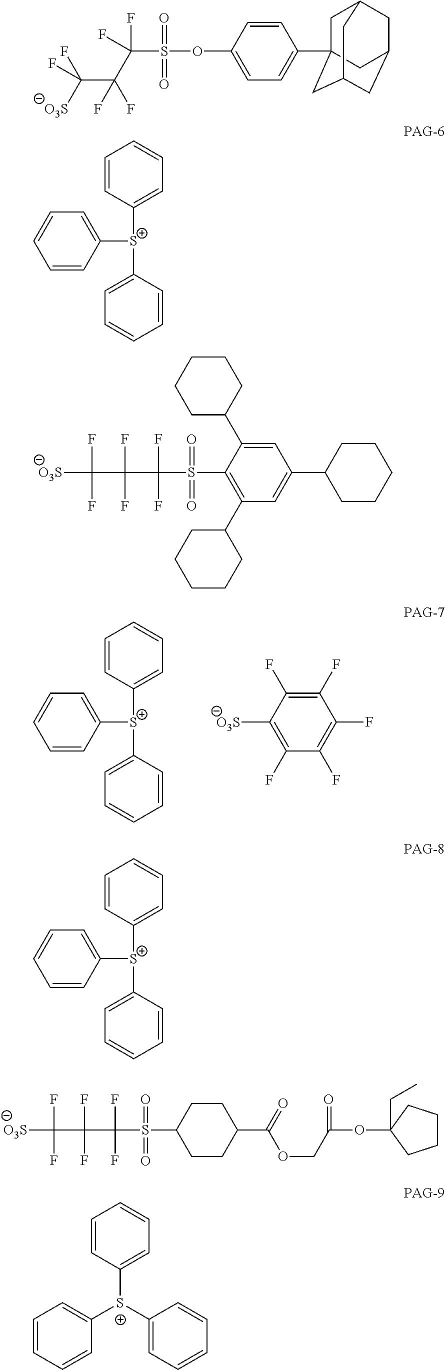

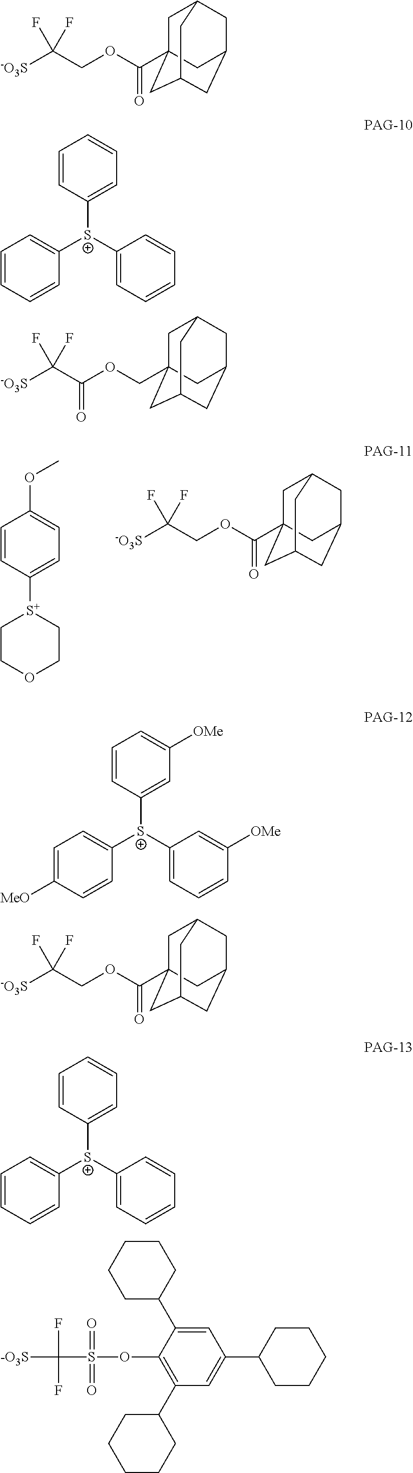

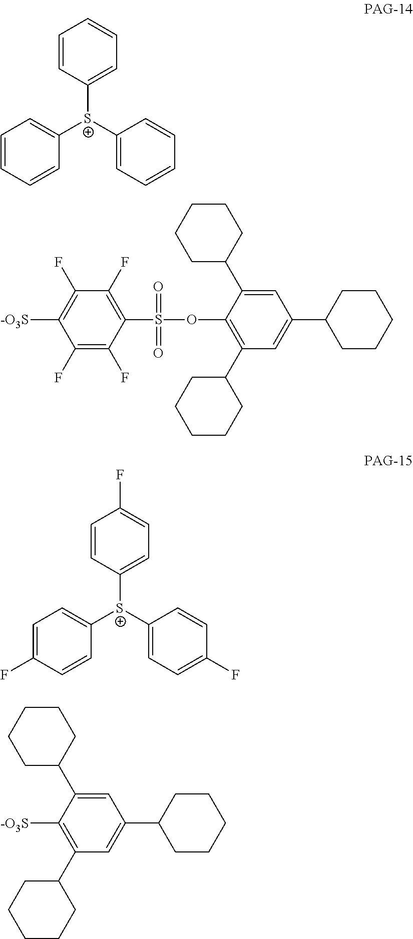

### [Basic Compound]

As the basic compound, any one of the following compounds (N-1) to (N-11) was used.

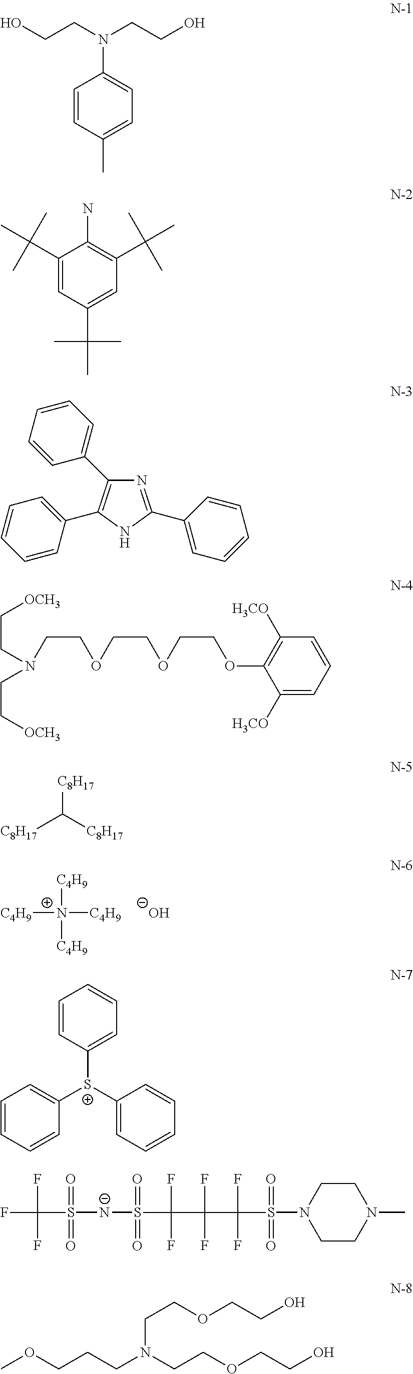

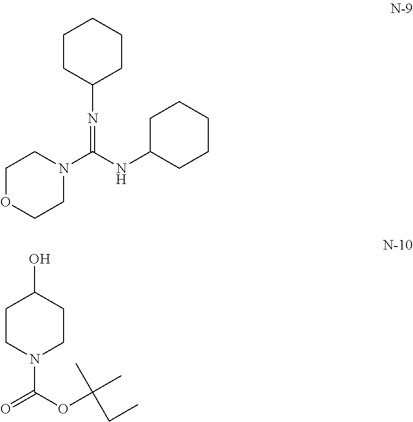

Compound (N-7) comes under the compound (PA) and was synthesized based on the description in paragraph [0354] of JP-A-2006-330098.

### [Surfactant and Solvent]

As the surfactant, the following W-1 to W-3 were used.

W-1: Megaface R08 (produced by DIC Corporation, containing fluorine and silicon)
W-2: Polysiloxane Polymer KP-341 (produced by Shin-Etsu Chemical Co., Ltd.; silicon-containing)
W-3: Troysol S-366 (produced by Troy Chemical; fluorine-containing)

As the solvent, any solvents of the following S1 to S4 were appropriately mixed and used.

S1: Propylene glycol monomethyl ether acetate (PGMEA; b.p.=146° C.)
S2: Propylene glycol monomethyl ether (PGME; b.p.=120° C.)
S3: Methyl lactate (b.p.=145° C.)

### S4: Cyclohexanone (b.p.=157° C.)

### [Developer]

As the developer, the followings were used.

### SG-1: 2-Nonanone

SG-2: Methyl amyl ketone
SG-3: Butyl acetate
SG-4: TMAH: an aqueous 2.38 mass % tetramethylammonium hydroxide solution

### [Rinsing Solution]

As the rinsing solution, the followings were used.

SR-1: 4-Methyl-2-pentanol

### SR-2: 1-Hexanol

SR-3: Methyl isobutyl carbinol

### Examples 1-1 to 1-53 and Comparative Examples 1-1 to 1-4

### Electron Beam (EB) Exposure

### (1) Preparation and Coating of Coating Solution of Actinic Ray-Sensitive or Radiation-Sensitive Resin Composition

The coating solution composition having a solid content concentration of 2.5 mass % according to the formulation shown in the Table below was microfiltered through a membrane filter having a pore size of 0.1 μm to obtain an actinic ray-sensitive or radiation-sensitive resin composition (resist composition) solution.

This actinic ray-sensitive or radiation-sensitive resin composition solution was coated on a 6-inch Si wafer previously subjected to a hexamethyldisilazane (HMDS) treatment, by using a spin coater, Mark 8, manufactured by Tokyo Electron Ltd. and dried on a hot plate at 100° C. for 60 seconds to obtain a resist film having a thickness of 50 nm.

### (2) EB Exposure and Development

The resist film-coated wafer obtained in (1) above was patternwise irradiated by using an electron beam lithography apparatus (HL750, manufactured by Hitachi, Ltd., accelerating voltage: 50 KeV). At this time, the lithography was performed to form a 1:1 line-and-space pattern. After the electron beam lithography, the wafer was heated on a hot plate at 110° C. for 60 seconds, then developed by puddling the organic developer shown in the Table below for 30 seconds, rinsed by using the rinsing solution shown in the Table below, spun at a rotational speed of 4,000 rpm for 30 seconds and baked at 90° C. for 60 seconds to obtain a 1:1 line-and-space pattern having a line width of 100 nm.

### (3) Evaluation of Resist Pattern

Using a scanning electron microscope (S-9220, manufacture by Hitachi Ltd.), the obtained resist pattern was evaluated for sensitivity, resolution, isolated space resolution and LWR by the following methods. The results obtained are shown in the Table below.

### (3-1) Sensitivity

The irradiation energy below which a 1:1 line-and-space pattern having a line width of 100 nm cannot be resolved was taken as the sensitivity (Eop). A smaller value indicates higher performance.

### (3-2) Resolution

The minimum line width below which the line-and-space (1:1) pattern at the Eop above cannot be separated was taken as the resolution. A smaller value indicates higher performance.

### (3-3) Isolated Space Resolution

Using a 1:100 line-and-space mask, the minimum space width below which the line-and-space pattern of 100:1 (that is, an isolated space pattern) cannot be separated was taken as the resolution. This value was designated as “isolated space resolution (nm)”. A smaller value indicates higher performance

### (3-4) Line Width Roughness (LWR)

With respect to the line width roughness, the line width was measured at arbitrary 50 points in the longitudinal 0.5 μm region of a 1:1 line-and-space space pattern having a line width of 100 nm at Eop and after determining the standard deviation thereof, 3σ was computed. A smaller value indicates higher performance.

These evaluation results are shown in the Table below.

TABLE 1

| | Acid- | | | | | | | | | | Isolated |
|---|---|---|---|---|---|---|---|---|---|---|---|
| | Decomposable | Photoacid | Basic | | | | | | | | Space |
| | Compound | Generator | Compound | Solvent | Surfactant | | Rinsing | Resolution | Sensitivity | LWR | Resolution |
| | (mass %) | (mass %) | (mass %) | (mass %) | (mass %) | Developer | Solution | (nm) | (μC/cm²) | (nm) | (nm) |
| Example | P-4 | PAG-1 | N-1 | S1/S2 | W-3 | SG-3 | SR-3 | 37.5 | 16.9 | 7.0 | 62.5 |
| 1-1 | 62.95 | 35 | 2 | 80/20 | 0.01 | | | | | | |
| Example | P-4 | PAG-9 | N-1 | S1/S2 | W-3 | SG-3 | SR-3 | 37.5 | 15.5 | 7.2 | 62.5 |
| 1-2 | 62.95 | 35 | 2 | 80/20 | 0.01 | | | | | | |
| Example | P-5 | PAG-6 | N-3 | S1/S2 | W-2 | SG-3 | SR-3 | 37.5 | 23 | 6.9 | 62.5 |
| 1-3 | 62.95 | 35 | 2 | 80/20 | 0.01 | | | | | | |
| Example | P-5 | PAG-12 | N-3 | S1/S2 | W-2 | SG-3 | SR-3 | 37.5 | 22.2 | 7.2 | 62.5 |
| 1-4 | 62.95 | 35 | 2 | 80/20 | 0.01 | | | | | | |
| Example | P-7 | PAG-1 | N-9 | S1/S2 | W-3 | SG-3 | SR-1 | 62.5 | 25.3 | 9.0 | 87.5 |
| 1-5 | 62.95 | 35 | 2 | 80/20 | 0.01 | | | | | | |
| Example | P-8 | PAG-7 | N-6 | S1/S2 | W-3 | SG-3 | SR-2 | 62.5 | 17.3 | 9.3 | 87.5 |
| 1-6 | 62.95 | 35 | 2 | 80/20 | 0.01 | | | | | | |
| Example | P-9 | PAG-12 | N-8 | S1/S2 | W-3 | SG-3 | SR-3 | 37.5 | 22.6 | 6.8 | 62.5 |
| 1-7 | 62.95 | 35 | 2 | 80/20 | 0.01 | | | | | | |
| Example | P-10 | PAG-8 | N-4 | S1/S2 | W-3 | SG-3 | SR-3 | 75 | 18.2 | 9.8 | 100 |
| 1-8 | 62.95 | 35 | 2 | 80/20 | 0.01 | | | | | | |
| Example | P-11 | PAG-6 | N-3 | S1/S2 | W-3 | SG-3 | SR-3 | 37.5 | 17.8 | 7.0 | 62.5 |
| 1-9 | 62.95 | 35 | 2 | 80/20 | 0.01 | | | | | | |
| Example | P-12 | PAG-4 | N-1 | S1/S2 | W-3 | SG-3 | — | 50 | 19.6 | 8.2 | 50 |
| 1-10 | 62.95 | 35 | 2 | 80/20 | 0.01 | | | | | | |
| Example | P-12 | PAG-12 | N-1 | S1/S2 | W-3 | SG-3 | — | 50 | 19.6 | 8.2 | 75 |
| 1-11 | 62.95 | 35 | 2 | 80/20 | 0.01 | | | | | | |
| Example | P-12 | PAG-9 | N-1 | S1/S2 | W-3 | SG-3 | — | 50 | 19.6 | 8.2 | 75 |
| 1-12 | 62.95 | 35 | 2 | 80/20 | 0.01 | | | | | | |
| Example | P-13 | PAG-6 | N-3 | S1/S2 | W-3 | SG-3 | — | 37.5 | 17.5 | 7.1 | 62.5 |
| 1-13 | 62.95 | 35 | 2 | 80/20 | 0.01 | | | | | | |
| Example | P-14 | PAG-4 | N-10 | S1/S2 | W-3 | SG-3 | — | 37.5 | 22.6 | 7.2 | 37.5 |
| 1-14 | 75.99 | 20 | 4 | 80/20 | 0.01 | | | | | | |
| Example | P-15 | PAG-3 | N-3 | S1/S2 | W-3 | SG-3 | — | 62.5 | 18.2 | 9.2 | 87.5 |
| 1-15 | 77.99 | 20 | 2 | 80/20 | 0.01 | | | | | | |
| Example | P-16 | PAG-4 | N-3 | S1/S2 | W-2 | SG-3 | — | 37.5 | 17.5 | 6.7 | 62.5 |
| 1-16 | 77.99 | 20 | 2 | 80/20 | 0.01 | | | | | | |
| Example | P-17 | PAG-5 | N3 | S1/S2 | W-3 | SG-3 | — | 62.5 | 26 | 9.3 | 34 |
| 1-17 | 77.99 | 20 | 2 | 80/20 | 0.01 | | | | | | |
| Example | P-18 | PAG-1 | N-8 | S1/S2 | W-3 | SG-3 | — | 37.5 | 18.1 | 6.8 | 62.5 |
| 1-18 | 77.99 | 20 | 2 | 80/20 | 0.01 | | | | | | |
| Example | P-19 | PAG-4 | N-4 | S1/S2 | W-3 | SG-3 | — | 62.5 | 17.9 | 8.7 | 34 |
| 1-19 | 77.99 | 20 | 2 | 80/20 | 0.01 | | | | | | |
| Example | P-20 | PAG-4 | N-8 | S1/S2 | W-3 | SG-3 | — | 50 | 19.6 | 7.9 | 75 |
| 1-20 | 77.99 | 20 | 2 | 80/20 | 0.01 | | | | | | |
| Example | P-21 | PAG-6 | N-3 | S1/S2 | W-3 | SG-3 | — | 37.5 | 18.1 | 7.1 | 62.5 |
| 1-21 | 77.99 | 20 | 2 | 80/20 | 0.01 | | | | | | |
| Example | P-22 | PAG-11 | N-2 | S1/S2 | W-3 | SG-3 | — | 37.5 | 22.6 | 7.5 | 62.5 |
| 1-22 | 88.99 | 10 | 1 | 80/20 | 0.01 | | | | | | |
| Example | P-23 | PAG-8 | N-6 | S1/S2 | W-3 | SG-3 | — | 62.5 | 24.6 | 9.2 | 87.5 |
| 1-23 | 77.99 | 20 | 2 | 50/50 | 0.01 | | | | | | |
| Example | P-24 | PAG-6 | N-3 | S1/S2 | W-1 | SG-3 | — | 37.5 | 17.9 | 7.1 | 62.5 |
| 1-24 | 77.99 | 20 | 2 | 80/20 | 0.01 | | | | | | |
| Example | P-25 | PAG-1 | N-3 | S1/S2 | W-2 | SG-3 | — | 50 | 20 | 8.2 | 75 |
| 1-25 | 78.99 | 20 | 1 | 80/20 | 0.01 | | | | | | |
| Example | P-26 | PAG-6 | N-4 | S1/S2 | W-1 | SG-3 | — | 75 | 18.5 | 9.7 | 100 |
| 1-26 | 77.99 | 20 | 2 | 80/20 | 0.01 | | | | | | |
| Example | P-27 | PAG-4 | N-3 | S1/S2 | W-3 | SG-3 | — | 37.5 | 17.9 | 6.9 | 62.5 |
| 1-27 | 79.39 | 20 | 0.6 | 80/20 | 0.01 | | | | | | |
| Example | P-28 | PAG-10 | N-3 | S1/S3 | W-3 | SG-3 | — | 37.5 | 18.1 | 6.9 | 62.5 |
| 1-28 | 79.39 | 20 | 0.6 | 80/20 | 0.01 | | | | | | |
| Example | P-29 | PAG-4 | N-6 | S1/S2 | W-3 | SG-3 | — | 50 | 18.4 | 8.4 | 75 |
| 1-29 | 77.99 | 20 | 2 | 50/50 | 0.01 | | | | | | |
| Example | P-30 | PAG-4 | N-3 | S1/S2 | W-2 | SG-3 | — | 37.5 | 24.2 | 7.0 | 37.5 |
| 1-30 | 79.39 | 20 | 0.6 | 80/20 | 0.01 | | | | | | |
| Example | P-30 | PAG-6 | N-3 | S1/S2 | — | SG-3 | — | 37.5 | 22.6 | 7.3 | 62.5 |
| 1-31 | 79.4 | 20 | 0.6 | 80/20 | | | | | | | |
| Example | P-30 | PAG-6 | N-3 | S1/S2 | W-3 | SG-2 | — | 37.5 | 23.3 | 7.6 | 62.5 |
| 1-32 | 79.39 | 20 | 0.6 | 80/20 | 0.01 | | | | | | |
| Example | P-31 | PAG-4 | N-3 | S1/S2 | — | SG-3 | — | 37.5 | 18.6 | 7.6 | 62.5 |
| 1-33 | 79.4 | 20 | 0.6 | 80/20 | | | | | | | |
| Example | P-31 | PAG-1 | N-3 | S1/S2 | — | SG-3 | — | 37.5 | 19.2 | 7.5 | 62.5 |
| 1-34 | 79.4 | 20 | 0.6 | 80/20 | | | | | | | |
| Example | P-31 | PAG-12 | N-3 | S1/S4 | — | SG-3 | — | 37.5 | 13.6 | 8.0 | 62.5 |
| 1-35 | 79.4 | 20 | 0.6 | 80/20 | | | | | | | |
| Example | P-32 | PAG-4 | N-6 | S1/S2 | W-3 | SG-3 | — | 37.5 | 21.9 | 7.1 | 62.5 |
| 1-36 | 77.99 | 20 | 2 | 80/20 | 0.01 | | | | | | |
| Example | P-33 | — | N-6 | S1/S2 | W-3 | SG-3 | — | 50 | 17.9 | 7.9 | 75 |
| 1-37 | 97.99 | | 2 | 80/20 | 0.01 | | | | | | |
| Example | P-35 | — | N-6 | S1/S2 | W-3 | SG-3 | — | 37.5 | 17.8 | 7.0 | 62.5 |
| 1-38 | 97.99 | | 2 | 50/50 | 0.01 | | | | | | |
| Example | P-36 | — | N-6 | S1/S2 | W-3 | SG-3 | — | 62.5 | 18.4 | 9.3 | 87.5 |
| 1-39 | 97.99 | | 2 | 80/20 | 0.01 | | | | | | |
| Example | P-37 | — | N-3 | S1/S2 | W-3 | SG-3 | — | 50 | 20.3 | 8.1 | 75 |
| 1-40 | 97.99 | | 2 | 80/20 | 0.01 | | | | | | |
| Example | P-38 | — | N-6 | S1/S2 | W-3 | SG-3 | — | 37.5 | 18.1 | 6.7 | 62.5 |
| 1-41 | 97.99 | | 2 | 50/50 | 0.01 | | | | | | |
| Example | P-39 | — | N-6 | S1/S2 | W-3 | SG-3 | — | 75 | 23.5 | 9.8 | 100 |
| 1-42 | 97.99 | | 2 | 50/50 | 0.01 | | | | | | |
| Example | P-40 | — | N-6 | S1/S2 | W-3 | SG-3 | — | 37.5 | 18.2 | 6.8 | 62.5 |
| 1-43 | 97.99 | | 2 | 50/50 | 0.01 | | | | | | |
| Example | P-41 | — | N-6 | S1/S2 | W-3 | SG-3 | — | 62.5 | 25.1 | 8.7 | 87.5 |
| 1-44 | 97.99 | | 2 | 50/50 | 0.01 | | | | | | |
| Example | P-42 | — | N-5 | S1/S2 | W-3 | SG-3 | — | 50 | 20 | 7.9 | 75 |
| 1-45 | 97.99 | | 2 | 50/50 | 0.01 | | | | | | |
| Example | P-45 | PAG-4 | N-6 | S1/S2 | W-3 | SG-3 | — | 50 | 18.5 | 8.2 | 75 |
| 1-46 | 77.99 | 20 | 2 | 50/50 | 0.01 | | | | | | |
| Example | P-46 | PAG-9 | N-10 | S1/S2 | W-3 | SG-3 | — | 62.5 | 20.1 | 8.7 | 87.5 |
| 1-47 | 78.99 | 20 | 1 | 50/50 | 0.01 | | | | | | |
| Example | P-47 | PAG-10 | N-8 | S1/S2 | W-3 | SG-3 | — | 50 | 22.6 | 8.3 | 75 |
| 1-48 | 77.99 | 20 | 2 | 50/50 | 0.01 | | | | | | |
| Example | P-48 | PAG-11 | N-6 | S1/S2 | W-3 | SG-3 | — | 75 | 25.1 | 9.7 | 100 |
| 1-49 | 77.99 | 20 | 2 | 50/50 | 0.01 | | | | | | |
| Example | P-49 | PAG-12 | N-6 | S1/S2 | W-3 | SG-3 | — | 50 | 18.5 | 8.0 | 75 |
| 1-50 | 77.99 | 20 | 2 | 50/50 | 0.01 | | | | | | |
| Example | P-50 | PAG-4 | N-6 | S1/S2 | W-3 | SG-3 | — | 50 | 18.4 | 8.0 | 75 |
| 1-51 | 77.99 | 20 | 2 | 50/50 | 0.01 | | | | | | |
| Example | P-51 | PAG-9 | N-7 | S1/S2 | W-3 | SG-3 | — | 62.5 | 20.2 | 9.3 | 87.5 |
| 1-52 | 78.99 | 20 | 1 | 50/50 | 0.01 | | | | | | |
| Example | P-52 | PAG-9 | N-6 | S1/S2 | W-3 | SG-3 | — | 75 | 24.8 | 9.9 | 100 |
| 1-53 | 77.99 | 20 | 2 | 50/50 | 0.01 | | | | | | |
| Comparative | R-1 | PAG-4 | N-6 | S1/S2 | W-3 | SG-3 | — | 100 | 40.4 | 10.0 | CND |
| Example 1-1 | 77.99 | 20 | 2 | 80/20 | 0.01 | | | | | | |
| Comparative | R-2 | PAG-4 | N-6 | S1/S2 | W-3 | SG-3 | — | 100 | 41.1 | 10.2 | CND |
| Example 1-2 | 77.99 | 20 | 2 | 80/20 | 0.01 | | | | | | |
| Comparative | R-3 | PAG-1 | N-6 | S1/S2 | W-3 | SG-3 | — | 100 | 35.1 | 10.5 | 125 |
| Example 1-3 | 77.99 | 20 | 2 | 80/20 | 0.01 | | | | | | |
| Comparative | R-4 | PAG-1 | N-6 | S1/S3 | W-3 | SG-3 | — | 100 | 43.0 | 11.2 | CND |
| Example 1-4 | 77.95 | 20 | 2 | 80/20 | 0.05 | | | | | | |

CND: could not be resolved

As apparent from the results shown in the Table above, in all of Examples 1-1 to 1-53 using the pattern forming method according to the present invention, as compared with Comparative Examples 1-1 to 1-3 not using a resin having a repeating unit represented by formula (I) and Comparative Example 1-4 where a resin containing a repeating unit represented by formula (I) is used but the content of the repeating unit is less than 25 mol % based on all repeating units in the resin, the resolution and sensitivity at EB exposure are excellent, LWR is small, and the resolution in an isolated space is also excellent.

### Examples 2-1 to 2-65 and Comparative Examples 2-1 to 2-4

### Extreme Ultraviolet (EUV) Exposure

### (1) Preparation and Coating of Coating Solution of Actinic Ray-Sensitive or Radiation-Sensitive Resin Composition

The coating solution composition having a solid content concentration of 1.5 mass % according to the formulation shown in the Table below was microfiltered through a membrane filter having a pore size of 0.05 μm to obtain an actinic ray-sensitive or radiation-sensitive resin composition (resist composition) solution.

This actinic ray-sensitive or radiation-sensitive resin composition solution was coated on a 6-inch Si wafer previously subjected to a hexamethyldisilazane (HMDS) treatment, by using a spin coater, Mark 8, manufactured by Tokyo Electron Ltd. and dried on a hot plate at 100° C. for 60 seconds to obtain a resist film having a thickness of 50 nm.

### (2) EUV Exposure and Development

The resist film-coated wafer obtained in (1) above was patternwise exposed through an exposure mask (line/space=1/1) by using an EUV exposure apparatus. After the irradiation, the wafer was heated on a hot plate at 110° C. for 60 seconds, then developed by puddling the organic developer shown in the Table below for 30 seconds, rinsed by using the rinsing solution shown in the Table below, spun at a rotational speed of 4,000 rpm for 30 seconds and baked at 90° C. for 60 seconds to obtain a 1:1 line-and-space pattern having a line width of 50 nm.

### (3) Evaluation of Resist Pattern

Using a scanning electron microscope (S-9380II, manufacture by Hitachi Ltd.), the obtained resist pattern was evaluated for sensitivity, resolution, isolated space resolution and LWR by the following methods The results obtained are shown in the Table below.

### (3-1) Sensitivity

The irradiation energy below which a 1:1 line-and-space pattern having a line width of 50 nm cannot be resolved was taken as the sensitivity (Eop). A smaller value indicates higher performance.

### (3-2) Resolution

The minimum line width below which the line-and-space (1:1) pattern at the Eop above cannot be separated was taken as the resolution. A smaller value indicates higher performance.

### (3-3) Isolated Space Resolution (EUV)

Using a 1:5 line-and-space mask, the minimum space width below which the line-and-space pattern of 5:1 (that is, an isolated space pattern) cannot be separated was taken as the resolution. A smaller value indicates higher performance.

### (3-4) Line Width Roughness (LWR)

With respect to the line width roughness, the line width was measured at arbitrary 50 points in the longitudinal 0.5 μm region of a 1:1 line-and-space space pattern having a line width of 50 nm at Eop and after determining the standard deviation thereof, 3σ was computed. A smaller value indicates higher performance.

TABLE 2

| | Acid- | | | | | | | | | | Isolated |
|---|---|---|---|---|---|---|---|---|---|---|---|
| | Decomposable | Photoacid | Basic | | | | | | | | Space |
| | Compound | Generator | Compound | Solvent | Surfactant | | Rinsing | Resolution | Sensitivity | LWR | Resolution |
| | (mass %) | (mass %) | (mass %) | (mass %) | (mass %) | Developer | Solution | (nm) | (mJ/cm²) | (nm) | (nm) |
| Example | P-4 | PAG-1 | N-1 | S1/S2 | W-3 | SG-3 | SR-3 | 24 | 11.9 | 4.0 | 26 |
| 2-1 | 62.95 | 35 | 2 | 80/20 | 0.05 | | | | | | |
| Example | P-4 | PAG-9 | N-1 | S1/S2 | W-3 | SG-1 | SR-3 | 24 | 10.5 | 4.2 | 28 |
| 2-2 | 62.95 | 35 | 2 | 80/20 | 0.05 | | | | | | |
| Example | P-5 | PAG-6 | N-3 | S1/S2 | W-2 | SG-3 | SR-3 | 22 | 18 | 3.9 | 22 |
| 2-3 | 62.95 | 35 | 2 | 80/20 | 0.05 | | | | | | |
| Example | P-5 | PAG-12 | N-3 | S1/S3 | W-2 | SG-3 | SR-3 | 22 | 17.2 | 4.2 | 24 |
| 2-4 | 62.95 | 35 | 2 | 80/20 | 0.05 | | | | | | |
| Example | P-7 | PAG-1 | N-9 | S1/S2 | W-3 | SG-3 | SR-1 | 28 | 20.3 | 6.0 | 32 |
| 2-5 | 62.95 | 35 | 2 | 80/20 | 0.05 | | | | | | |
| Example | P-8 | PAG-7 | N-6 | S1/S2 | W-3 | SG-3 | SR-2 | 26 | 12.3 | 6.3 | 32 |
| 2-6 | 62.95 | 35 | 2 | 80/20 | 0.05 | | | | | | |
| Example | P-9 | PAG-12 | N-8 | S1/S4 | W-3 | SG-3 | SR-3 | 22 | 17.6 | 3.8 | 24 |
| 2-7 | 62.95 | 35 | 2 | 80/20 | 0.05 | | | | | | |
| Example | P-10 | PAG-8 | N-4 | S1/S2 | W-3 | SG-3 | SR-3 | 30 | 13.2 | 6.8 | 36 |
| 2-8 | 62.95 | 35 | 2 | 80/20 | 0.05 | | | | | | |
| Example | P-11 | PAG-6 | N-3 | S1/S2 | W-3 | SG-3 | SR-3 | 24 | 12.8 | 5 | 26 |
| 2-9 | 62.95 | 35 | 2 | 80/20 | 0.05 | | | | | | |
| Example | P-12 | PAG-4 | N-1 | S1/S2 | W-3 | SG-3 | — | 28 | 14.6 | 5.2 | 28 |
| 2-10 | 62.95 | 35 | 2 | 80/20 | 0.05 | | | | | | |
| Example | P-12 | PAG-12 | N-1 | S1/S2 | W-3 | SG-3 | — | 28 | 14.6 | 5.2 | 28 |
| 2-11 | 62.95 | 35 | 2 | 80/20 | 0.05 | | | | | | |
| Example | P-12 | PAG-9 | N-1 | S1/S4 | W-3 | SG-3 | — | 28 | 14.6 | 5.2 | 28 |
| 2-12 | 62.95 | 35 | 2 | 80/20 | 0.05 | | | | | | |
| Example | P-13 | PAG-6 | N-3 | S1/S2 | W-3 | SG-3 | — | 22 | 12.5 | 4.1 | 24 |
| 2-13 | 62.95 | 35 | 2 | 80/20 | 0.05 | | | | | | |
| Example | P-14 | PAG-4 | N-10 | S1/S2 | W-3 | SG-3 | — | 22 | 17.6 | 4.2 | 26 |
| 2-14 | 60.95 | 35 | 4 | 80/20 | 0.05 | | | | | | |
| Example | P-15 | PAG-3 | N-3 | S1/S2 | W-3 | SG-3 | — | 26 | 13.2 | 6.2 | 32 |
| 2-15 | 62.95 | 35 | 2 | 80/20 | 0.05 | | | | | | |
| Example | P-16 | PAG-4 | N-3 | S1/S2 | W-2 | SG-3 | — | 22 | 12.5 | 3.7 | 26 |
| 2-16 | 62.95 | 35 | 2 | 80/20 | 0.05 | | | | | | |
| Example | P-17 | PAG-5 | N3 | S1/S2 | W-3 | SG-3 | — | 26 | 21 | 6.3 | 34 |
| 2-17 | 62.95 | 35 | 2 | 80/20 | 0.05 | | | | | | |
| Example | P-18 | PAG-1 | N-8 | S1/S2 | W-3 | SG-3 | — | 22 | 13.1 | 3.8 | 24 |
| 2-18 | 62.95 | 35 | 2 | 80/20 | 0.05 | | | | | | |
| Example | P-19 | PAG-4 | N-4 | S1/S2 | W-3 | SG-3 | — | 28 | 12.9 | 5.7 | 34 |
| 2-19 | 62.95 | 35 | 2 | 80/20 | 0.05 | | | | | | |
| Example | P-20 | PAG-4 | N-8 | S1/S2 | W-3 | SG-3 | — | 26 | 14.6 | 4.9 | 28 |
| 2-20 | 62.95 | 35 | 2 | 80/20 | 0.05 | | | | | | |
| Example | P-21 | PAG-6 | N-3 | S1/S2 | W-3 | SG-3 | — | 22 | 13.1 | 4.1 | 26 |
| 2-21 | 62.95 | 35 | 2 | 80/20 | 0.05 | | | | | | |
| Example | P-22 | PAG-11 | N-2 | S1/S2 | W-3 | SG-3 | — | 24 | 17.6 | 4.5 | 26 |
| 2-22 | 81.95 | 17 | 1 | 80/20 | 0.05 | | | | | | |
| Example | P-23 | PAG-8 | N-6 | S1/S2 | W-3 | SG-3 | — | 28 | 19.6 | 6.2 | 32 |
| 2-23 | 62.95 | 35 | 2 | 50/50 | 0.05 | | | | | | |
| Example | P-24 | PAG-6 | N-3 | S1/S2 | W-1 | SG-3 | — | 22 | 12.9 | 4.1 | 24 |
| 2-24 | 62.95 | 35 | 2 | 80/20 | 0.05 | | | | | | |
| Example | P-25 | PAG-1 | N-3 | S1/S2 | W-2 | SG-3 | — | 26 | 15 | 5.2 | 28 |
| 2-25 | 63.95 | 35 | 1 | 80/20 | 0.05 | | | | | | |
| Example | P-26 | PAG-6 | N-4 | S1/S2 | W-1 | SG-3 | — | 30 | 13.5 | 6.7 | 36 |
| 2-26 | 62.95 | 35 | 2 | 80/20 | 0.05 | | | | | | |
| Example | P-27 | PAG-4 | N-3 | S1/S2 | W-3 | SG-3 | — | 22 | 12.9 | 3.9 | 26 |
| 2-27 | 64.35 | 35 | 0.6 | 80/20 | 0.05 | | | | | | |
| Example | P-28 | PAG-10 | N-3 | S1/S3 | W-3 | SG-3 | — | 22 | 13.1 | 3.9 | 26 |
| 2-28 | 64.35 | 35 | 0.6 | 80/20 | 0.05 | | | | | | |
| Example | P-29 | PAG-4 | N-6 | S1/S2 | W-3 | SG-3 | — | 26 | 13.4 | 5.4 | 30 |
| 2-29 | 62.95 | 35 | 2 | 50/50 | 0.05 | | | | | | |
| Example | P-30 | PAG-4 | N-3 | S1/S2 | W-2 | SG-3 | — | 22 | 19.2 | 4 | 24 |
| 2-30 | 64.35 | 35 | 0.6 | 80/20 | 0.05 | | | | | | |
| Example | P-30 | PAG-6 | N-3 | S1/S2 | — | SG-3 | — | 22 | 17.6 | 4.3 | 26 |
| 2-31 | 64.4 | 35 | 0.6 | 80/20 | | | | | | | |
| Example | P-30 | PAG-6 | N-3 | S1/S2 | W-3 | SG-2 | — | 24 | 18.3 | 4.6 | 26 |
| 2-32 | 64.35 | 35 | 0.6 | 80/20 | 0.05 | | | | | | |
| Example | P-31 | PAG-4 | N-3 | S1/S2 | — | SG-3 | — | 24 | 13.6 | 4.6 | 24 |
| 2-33 | 64.4 | 35 | 0.6 | 80/20 | | | | | | | |
| Example | P-31 | PAG-1 | N-3 | S1/S2 | — | SG-3 | — | 22 | 14.2 | 4.5 | 24 |
| 2-34 | 64.4 | 35 | 0.6 | 80/20 | | | | | | | |
| Example | P-31 | PAG-12 | N-3 | S1/S2 | — | SG-3 | — | 24 | 8.6 | 5 | 26 |
| 2-35 | 64.4 | 35 | 0.6 | 80/20 | | | | | | | |
| Example | P-32 | PAG-4 | N-6 | S1/S2 | W-3 | SG-3 | — | 24 | 16.9 | 4.1 | 26 |
| 2-36 | 62.95 | 35 | 2 | 80/20 | 0.05 | | | | | | |
| Example | P-33 | — | N-6 | S1/S2 | W-3 | SG-3 | — | 28 | 12.9 | 4.9 | 30 |
| 2-37 | 97.95 | | 2 | 80/20 | 0.05 | | | | | | |
| Example | P-35 | — | N-6 | S1/S2 | W-3 | SG-3 | — | 22 | 12.8 | 4 | 26 |
| 2-38 | 97.95 | | 2 | 50/50 | 0.05 | | | | | | |
| Example | P-36 | — | N-6 | S1/S2 | W-3 | SG-3 | — | 28 | 13.4 | 6.3 | 34 |
| 2-39 | 97.95 | | 2 | 80/20 | 0.05 | | | | | | |
| Example | P-37 | — | N-3 | S1/S2 | W-3 | SG-3 | — | 28 | 15.3 | 5.1 | 30 |
| 2-40 | 97.95 | | 2 | 80/20 | 0.05 | | | | | | |
| Example | P-38 | — | N-6 | S1/S2 | W-3 | SG-3 | — | 24 | 13.1 | 3.7 | 26 |
| 2-41 | 97.95 | | 2 | 50/50 | 0.05 | | | | | | |
| Example | P-39 | — | N-6 | S1/S2 | W-3 | SG-3 | — | 30 | 18.5 | 6.8 | 36 |
| 2-42 | 97.95 | | 2 | 50/50 | 0.05 | | | | | | |
| Example | P-40 | — | N-6 | S1/S2 | W-3 | SG-3 | — | 22 | 13.2 | 3.8 | 26 |
| 2-43 | 97.95 | | 2 | 50/50 | 0.05 | | | | | | |
| Example | P-41 | — | N-6 | S1/S2 | W-3 | SG-3 | — | 28 | 20.1 | 5.7 | 34 |
| 2-44 | 97.95 | | 2 | 50/50 | 0.05 | | | | | | |
| Example | P-42 | — | N-5 | S1/S2 | W-3 | SG-3 | — | 24 | 15 | 4.9 | 28 |
| 2-45 | 97.95 | | 2 | 50/50 | 0.05 | | | | | | |
| Example | P-45 | PAG-4 | N-6 | S1/S2 | W-3 | SG-3 | — | 24 | 13.5 | 5.2 | 30 |
| 2-46 | 62.95 | 35 | 2 | 50/50 | 0.05 | | | | | | |
| Example | P-46 | PAG-9 | N-10 | S1/S2 | W-3 | SG-3 | — | 28 | 15.1 | 5.7 | 32 |
| 2-47 | 63.95 | 35 | 1 | 50/50 | 0.05 | | | | | | |
| Example | P-47 | PAG-10 | N-8 | S1/S2 | W-3 | SG-3 | — | 28 | 17.6 | 5.3 | 30 |
| 2-48 | 62.95 | 35 | 2 | 50/50 | 0.05 | | | | | | |
| Example | P-48 | PAG-11 | N-6 | S1/S2 | W-3 | SG-3 | — | 30 | 20.1 | 6.7 | 36 |
| 2-49 | 62.95 | 35 | 2 | 50/50 | 0.05 | | | | | | |
| Example | P-49 | PAG-12 | N-6 | S1/S2 | W-3 | SG-3 | — | 28 | 13.5 | 5.0 | 28 |
| 2-50 | 62.95 | 35 | 2 | 50/50 | 0.05 | | | | | | |
| Example | P-50 | PAG-4 | N-6 | S1/S2 | W-3 | SG-3 | — | 26 | 13.4 | 5.0 | 30 |
| 2-51 | 62.95 | 35 | 2 | 50/50 | 0.05 | | | | | | |
| Example | P-51 | PAG-9 | N-7 | S1/S2 | W-3 | SG-3 | — | 28 | 15.2 | 6.3 | 32 |
| 2-52 | 63.95 | 35 | 1 | 50/50 | 0.05 | | | | | | |
| Example | P-52 | PAG-9 | N-6 | S1/S2 | W-3 | SG-3 | — | 30 | 19.8 | 6.9 | 36 |
| 2-53 | 62.95 | 35 | 2 | 50/50 | 0.05 | | | | | | |
| Comparative | R-1 | PAG-4 | N-6 | S1/S2 | W-3 | SG-3 | — | 36 | 35.4 | 7 | CND |
| Example 2-1 | 62.95 | 35 | 2 | 80/20 | 0.05 | | | | | | |
| Comparative | R-2 | PAG-4 | N-6 | S1/S2 | W-3 | SG-3 | — | 34 | 36.1 | 7.2 | CND |
| Example 2-2 | 62.95 | 35 | 2 | 80/20 | 0.05 | | | | | | |
| Comparative | R-3 | PAG-1 | N-6 | S1/S2 | W-3 | SG-3 | — | 34 | 30.1 | 7.5 | CND |
| Example 2-3 | 77.99 | 20 | 2 | 80/20 | 0.05 | | | | | | |
| Comparative | R-4 | PAG-1 | N-6 | S1/S3 | W-3 | SG-3 | — | 36 | 29.0 | 7.5 | CND |
| Example 2-4 | 62.95 | 35 | 2 | 80/20 | 0.05 | | | | | | |

CND: could not be resolved

TABLE 3

| | Acid- | | | | | | | | | | Isolated |
|---|---|---|---|---|---|---|---|---|---|---|---|
| | Decomposable | Photoacid | Basic | | | | | | | | Space |
| | Compound | Generator | Compound | Solvent | Surfactant | | Rinsing | Resolution | Sensitivity | LWR | Resolution |
| | (mass %) | (mass %) | (mass %) | (mass %) | (mass %) | Developer | Solution | (nm) | (mJ/cm²) | (nm) | (nm) |
| Example | P-14/HR-24 | PAG-1 | N-8 | S1/S4 | W-3 | SG-3 | — | 22 | 17.6 | 4.3 | 24 |
| 2-54 | 59.95/3 | 35 | 2 | 80/20 | 0.05 | | | | | | |
| Example | P-53 | — | N-2 | S1/S2 | — | SG-3 | SR-1 | 22 | 16.5 | 5.2 | 26 |
| 2-55 | 98 | | 2 | 80/20 | | | | | | | |
| Example | P-54 | — | N-2 | S1/S2 | — | SG-3 | — | 18 | 15.3 | 4.0 | 20 |
| 2-56 | 98 | | 2 | 80/20 | | | | | | | |
| Example | P-55 | — | N-2 | S1/S2 | — | SG-3 | — | 20 | 15.8 | 5.2 | 22 |
| 2-57 | 98 | | 2 | 80/20 | | | | | | | |
| Example | P-56 | — | N-2 | S1/S2 | — | SG-3 | — | 20 | 16.0 | 5.7 | 22 |
| 2-58 | 98 | | 2 | 80/20 | | | | | | | |
| Example | P-56 | — | N-2 | S1/S2 | — | SG-3 | SR-3 | 20 | 15.9 | 4.1 | 20 |
| 2-59 | 98 | | 2 | 80/20 | | | | | | | |
| Example | P-57 | PAG-15 | N-11 | S1/S2/S4 | W-3 | SG-3 | — | 24 | 16.2 | 5.3 | 26 |
| 2-60 | 62.95 | 35 | 2 | 70/20/10 | 0.05 | | | | | | |
| Example | P-58 | PAG-15 | N-11 | S1/S2/S4 | — | SG-3 | — | 22 | 17 | 5.0 | 22 |
| 2-61 | 63 | 35 | 2 | 70/20/10 | | | | | | | |
| Example | P-59 | PAG-14 | N-3 | S1/S2/S4 | — | SG-3 | — | 24 | 10.5 | 4.9 | 30 |
| 2-62 | 63 | 35 | 2 | 70/20/10 | | | | | | | |
| Example | P-60 | PAG-14 | N-3 | S1/S2 | — | SG-3 | — | 26 | 16.9 | 5.3 | 26 |
| 2-63 | 63 | 35 | 2 | 80/20 | | | | | | | |
| Example | P-61 | PAG-13 | N-2 | S1/S2 | — | SG-3 | — | 18 | 16.8 | 4.0 | 20 |
| 2-64 | 63 | 35 | 2 | 80/20 | | | | | | | |
| Example | P-62 | PAG-13 | N-2 | S1/S2 | — | SG-3 | — | 28 | 10.8 | 4.7 | 32 |
| 2-65 | 63 | 35 | 2 | 80/20 | | | | | | | |

As apparent from the results shown in the Table above, in all of Examples 2-1 to 2-65 using the pattern forming method according to the present invention, as compared with Comparative Examples 2-1 to 2-3 not using a resin having a repeating unit represented by formula (I) and Comparative Example 2-4 where a resin containing a repeating unit represented by formula (I) is used but the content of the repeating unit is less than 25 mol % based on all repeating units in the resin, the resolution and sensitivity at EUV exposure are excellent, LWR is small, and the resolution in an isolated space is also excellent.

### Examples 3-1 to 3-19 and Comparative Examples 3-1 and 3-2

### ArF Exposure

### (1) Preparation of Coating Solution of Actinic Ray-Sensitive or Radiation-Sensitive Resin Composition

The coating solution composition having a solid content concentration of 3.8 mass % according to the formulation shown in the Table below was microfiltered through a membrane filter having a pore size of 0.03 μm to prepare an actinic ray-sensitive or radiation-sensitive resin composition (resist composition) solution.

An organic antireflection film, ARC29A (produced by Nissan Chemical Industries, Ltd.), was coated on a 12-inch silicon wafer and baked at 205° C. for 60 seconds to form an antireflection film having a thickness of 75 nm, and the actinic ray-sensitive or radiation-sensitive resin composition prepared above was coated thereon and baked at 130° C. for 60 seconds to form a resist film having a thickness of 120 nm. This resist film was exposed through a mask by using an ArF excimer laser scanner (PAS5500/1100, manufactured by ASML, NA: 0.75, Dipole, σo/σi=0.89/0.65). Thereafter, the wafer was heated at 100° C. for 60 seconds, developed with the developer shown in the Table below for 30 seconds, rinsed with the rinsing solution shown in the Table below, and spin-dried to obtain a resist pattern.

### (3) Evaluation of Resist Pattern

Using a scanning electron microscope (S-9220, manufacture by Hitachi Ltd.), the obtained resist pattern was evaluated for sensitivity, resolution, isolated line resolution and LWR by the following methods. The results obtained are shown in the Table below.

### (3-1) Sensitivity

The irradiation energy below which a 1:1 line-and-space pattern having a line width of 50 nm cannot be resolved was taken as the sensitivity (Eop). A smaller value indicates higher performance.

### (3-2) Resolution

The minimum line width below which the line-and-space (1:1) pattern at the Eop above cannot be separated was taken as the resolution. A smaller value indicates higher performance.

### (3-3) Isolated Space Resolution

Using a 1:10 line-and-space mask, the minimum space width below which the line-and-space pattern of 10:1 (that is, an isolated space pattern) cannot be separated was taken as the resolution. A smaller value indicates higher performance.

### (3-4) Line Width Roughness (LWR)

With respect to the line width roughness, the line width was measured at arbitrary 50 points in the longitudinal 0.5 μm region of a 1:1 line-and-space space pattern having a line width of 50 nm at Eop and after determining the standard deviation thereof, 3σ was computed. A smaller value indicates higher performance.

TABLE 4

| | Acid- | | | | | | | | | | Isolated |
|---|---|---|---|---|---|---|---|---|---|---|---|
| | Decomposable | Photoacid | Basic | | | | | | | | Space |
| | Compound | Generator | Compound | Solvent | Surfactant | | Rinsing | Resolution | Sensitivity | LWR | Resolution |
| | (mass %) | (mass %) | (mass %) | (mass %) | (mass %) | Developer | Solution | (nm) | (mJ/cm²) | (nm) | (nm) |
| Example | P-1 | PAG-1 | N-1 | S1/S2 | W-3 | SG-3 | SR-3 | 38 | 15.2 | 5.2 | 40 |
| 3-1 | 79.95 | 15 | 5 | 80/20 | 0.05 | | | | | | |
| Example | P-2 | PAG-4 | N-8 | S1/S2 | W-3 | SG-1 | SR-3 | 36 | 15.3 | 4.9 | 40 |
| 3-2 | 79.95 | 15 | 5 | 80/20 | 0.05 | | | | | | |
| Example | P-3 | PAG-6 | N-6 | S1/S2 | W-3 | SG-3 | SR-3 | 38 | 16.2 | 4.9 | 42 |
| 3-3 | 79.95 | 15 | 5 | 80/20 | 0.05 | | | | | | |
| Example | P-4 | PAG-2 | N-1 | S1/S2 | W-3 | SG-3 | SR-3 | 34 | 15.4 | 4.0 | 38 |
| 3-4 | 79.95 | 15 | 5 | 80/20 | 0.05 | | | | | | |
| Example | P-4 | PAG-9 | N-1 | S1/S3 | W-3 | SG-3 | SR-3 | 34 | 16.2 | 3.9 | 42 |
| 3-5 | 79.95 | 15 | 5 | 80/20 | 0.05 | | | | | | |
| Example | P-4 | PAG-2 | N-1 | S1/S2 | W-3 | SG-2 | SR-3 | 36 | 13.5 | 4.5 | 40 |
| 3-6 | 79.95 | 15 | 5 | 80/20 | 0.05 | | | | | | |
| Example | P-5 | PAG-6 | N-3 | S1/S2 | W-2 | SG-3 | SR-3 | 32 | 16.9 | 3.9 | 36 |
| 3-7 | 79.95 | 15 | 5 | 80/20 | 0.05 | | | | | | |
| Example | P-5 | PAG-6 | N-3 | S1/S2 | W-2 | SG-2 | SR-3 | 32 | 15.2 | 4.3 | 32 |
| 3-8 | 79.95 | 15 | 5 | 80/20 | 0.05 | | | | | | |
| Example | P-6 | PAG-1 | N-9 | S1/S2 | W-3 | SG-3 | SR-1 | 38 | 17.8 | 6.0 | 46 |
| 3-9 | 79.95 | 15 | 5 | 80/20 | 0.05 | | | | | | |
| Example | P-7 | PAG-7 | N-6 | S1/S2 | W-3 | SG-3 | SR-1 | 36 | 19.2 | 6.3 | 40 |
| 3-10 | 79.95 | 15 | 5 | 80/20 | 0.05 | | | | | | |
| Example | P-8 | PAG-3 | N-3 | S1/S2 | W-3 | SG-3 | SR-3 | 36 | 14.2 | 6.2 | 42 |
| 3-11 | 79.95 | 15 | 5 | 80/20 | 0.05 | | | | | | |
| Example | P-9 | PAG-2 | N-8 | S1/S2 | W-3 | SG-3 | SR-3 | 32 | 16.9 | 3.8 | 32 |
| 3-12 | 79.95 | 15 | 5 | 80/20 | 0.05 | | | | | | |
| Example | P-10 | PAG-2 | N-4 | S1/S2 | W-3 | SG-3 | SR-3 | 40 | 14.8 | 6.8 | 46 |
| 3-13 | 79.95 | 15 | 5 | 80/20 | 0.05 | | | | | | |
| Example | P-11 | PAG-4 | N-3 | S1/S2 | W-2 | SG-3 | SR-3 | 32 | 14.8 | 3.7 | 36 |
| 3-14 | 82.95 | 15 | 2 | 80/20 | 0.05 | | | | | | |
| Example | P-33 | — | N-3 | S1/S2 | W-2 | SG-3 | SR-3 | 36 | 14.8 | 5.2 | 40 |
| 3-15 | 97.45 | | 2.5 | 80/20 | 0.05 | | | | | | |
| Example | P-33 | — | N-3 | S1/S2 | W-2 | SG-2 | SR-3 | 38 | 13.2 | 5.2 | 44 |
| 3-16 | 97.45 | | 2.5 | 80/20 | 0.05 | | | | | | |
| Example | P-34 | — | N-3 | S1/S2 | W-3 | SG-3 | SR-3 | 32 | 17.3 | 4.1 | 36 |
| 3-17 | 94.95 | | 5 | 80/20 | 0.05 | | | | | | |
| Example | P-43 | PAG-1 | N-3 | S1/S2 | W-3 | SG-3 | SR-3 | 38 | 14.2 | 5.1 | 40 |
| 3-18 | 79.95 | 15 | 5 | 80/20 | 0.05 | | | | | | |
| Example | P-44 | PAG-6 | N-3 | S1/S2 | W-3 | SG-3 | SR-3 | 36 | 15.8 | 6.3 | 40 |
| 3-19 | 79.95 | 15 | 5 | 80/20 | 0.05 | | | | | | |
| Comparative | R-1 | PAG-1 | N-6 | S1/S2 | W-3 | SG-3 | SR-3 | 46 | 35.4 | 7 | CND |
| Example 3-1 | 79.95 | 15 | 5 | 80/20 | 0.05 | | | | | | |
| Comparative | R-3 | PAG-1 | N-6 | S1/S2 | W-3 | SG-3 | SR-3 | 44 | 36.2 | 7.2 | CND |
| Example 3-2 | 79.95 | 15 | 5 | 80/20 | 0.05 | | | | | | |

CND: could not be resolved

As apparent from the results shown in the Table above, in all of Examples 3-1 to 3-19 using the pattern forming method according to the present invention, as compared with Comparative Examples 3-1 and 3-2 not using a resin having a repeating unit represented by formula (I), the resolution and sensitivity at ArF exposure are excellent, LWR is small, and the resolution in an isolated space is also excellent.

Furthermore, it is seen that in Examples 3-1 to 3-12 and 3-14 to 3-19 using a pattern forming method where the content of the repeating unit represented by formula (I) is 40 mol % or more based on all repeating units in the resin (P), the resolution and sensitivity at ArF exposure are more excellent and LWR becomes smaller.

### INDUSTRIAL APPLICABILITY

According to the present invention, a pattern forming method, an actinic ray-sensitive or radiation-sensitive resin composition, and a resist film, ensuring that in the formation of an ultrafine pattern (for example, the line width or space width is of the order of several tens of nm), a line pattern with small line width roughness (LWR) can be formed at high resolution and high sensitivity and an isolated pattern can be formed at high resolution, as well as a manufacturing method of an electronic device using the same, and an electronic device, can be provided.

This application is based on a Japanese patent application filed on Jul. 27, 2012 (Japanese Patent Application No. 2012-167817), U.S. provisional application filed on Oct. 2, 2012 (U.S. Provisional Application No. 61/708,819), and Japanese patent application filed on Mar. 15, 2013 (Japanese Patent Application No. 2013-054398), and the contents thereof are incorporated herein by reference.

1. A pattern forming method comprising:
(1) a step of forming a film by using an actinic ray-sensitive or radiation-sensitive resin composition containing (P) a resin having a repeating unit represented by the following formula (I),
(2) a step of exposing the film by using an actinic ray or radiation, and
(3) a step of developing the exposed film by using an organic solvent-containing developer to form a negative pattern,
wherein the content of the repeating unit represented by formula (I) is 25 mol % or more based on all repeating units in the resin (P): 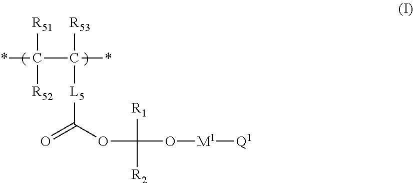
wherein
each of R₅₁, R₅₂ and R₅₃ independently represents a hydrogen atom, an alkyl group, a cycloalkyl group, a halogen atom, a cyano group or an alkoxycarbonyl group,
R₅₂ may combine with L₅ to form a ring, and in this case, R₅₂ represents an alkylene group;
L₅ represents a single bond or a divalent linking group, and in the case of forming a ring with R₅₂, L₅ represents a trivalent linking group;
R₁ represents a hydrogen atom or an alkyl group;
R₂ represents a hydrogen atom, an alkyl group, a cycloalkyl group, an aryl group, an aralkyl group, an alkoxy group, an acyl group or a heterocyclic group;
M¹ represents a single bond or a divalent linking group;
Q¹ represents an alkyl group, a cycloalkyl group, an aryl group or a heterocyclic group, and Q¹, M¹ and R₂ may combine with each other to form a ring; and
when M¹ is a divalent linking group, Q¹ may combine with M¹ through a single bond or another linking group to form a ring.

2. The pattern forming method as claimed in claim 1,
wherein the content of the repeating unit represented by formula (I) is from 40 to 70 mol % based on all repeating units in the resin (P).

3. The pattern forming method as claimed in claim 1,
wherein the resin (P) is a resin further having a repeating unit represented by the following formula (5) or (6): 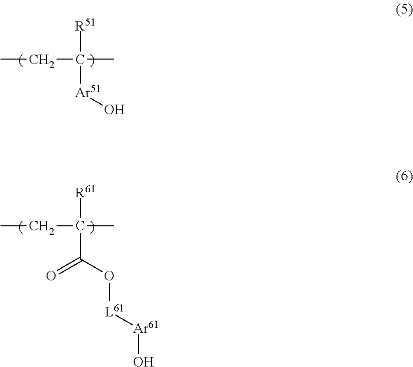
wherein each of R⁵¹ and R⁶¹ independently represents a hydrogen atom or a methyl group,
each of Ar⁵¹ and Ar⁶¹ independently represents an arylene group, and
R⁶¹ represents a single bond or an alkylene group.

4. The pattern forming method as claimed in claim 1,
wherein in formula (I), R₁ is a hydrogen atom.

5. The pattern forming method as claimed in claim 1,
wherein in formula (I), R₂ represents a group represented by —(CH₂)ₙ₁—C(R²¹)(R²²)(R²³),
each of R²¹ to R²³ independently represents a hydrogen atom, an alkyl group, a cycloalkyl group, an aryl group, an aralkyl group or a heterocyclic group,
each of at least two members of R²¹ to R²³ independently represents an alkyl group, a cycloalkyl group, an aryl group, an aralkyl group or a heterocyclic group,
at least two members of R²¹ to R²³ may combine with each other to form a ring, and
n1 represents an integer of 0 to 6.

6. The pattern forming method as claimed in claim 5,
wherein n1 is 0 or 1.

7. The pattern forming method as claimed in claim 5,
wherein n1 is 1.

8. The pattern forming method as claimed in claim 5,
wherein n1 is 0.

9. The pattern forming method as claimed in claim 5,
wherein each of R²¹ to R²³ is independently an alkyl group.

10. The pattern forming method as claimed in claim 1,
wherein in formula (I), L₅ is a single bond, a group represented by —COO-L₁- or a group represented by -L₂-O—CH₂—,
L₁ represents an alkylene group which may contain a heteroatom, and L₂ represents an arylene group.

11. The pattern forming method as claimed in claim 1,
wherein in formula (I), L₅ is a single bond.

12. The pattern forming method as claimed in claim 1,
wherein the resin (P) is a resin further having a repeating unit represented by the following formula (4): 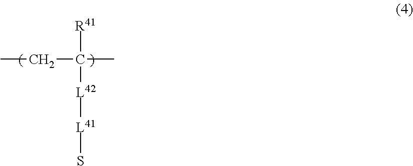
wherein R⁴¹ represents a hydrogen atom or a methyl group,
L⁴¹ represents a single bond or a divalent linking group,
L⁴² represents a divalent linking group, and
S represents a structural moiety capable of decomposing upon irradiation with an actinic ray or radiation to generate an acid in the side chain.

13. An actinic ray-sensitive or radiation-sensitive resin composition used in the pattern forming method claimed in claim 1.

14. A resist film formed using the actinic ray-sensitive or radiation-sensitive resin composition claimed in claim 13,

15. A method for manufacturing an electronic device, comprising the pattern forming method claimed in claim 1.

16. An electronic device manufactured by the manufacturing method of an electronic device claimed in claim 15.
